(19) United States
(12) Patent Application Publication
(10) Pub. No.: US 2025/0228123 A1
(43) Pub. Date: Jul. 10, 2025

(54) ORGANOMETALLIC COMPOUND, LIGHT-EMITTING DEVICE INCLUDING THE SAME, AND ELECTRONIC APPARATUS INCLUDING THE LIGHT-EMITTING DEVICE

(71) Applicant: Samsung Display Co., Ltd., Yongin-si (KR)

(72) Inventors: Youngki Lee, Yongin-si (KR); Soobyung Ko, Yongin-si (KR); Sungbum Kim, Yongin-si (KR); Hyunyoung Kim, Yongin-si (KR); Jaesung Lee, Yongin-si (KR)

(73) Assignee: Samsung Display Co., Ltd., Yongin-si (KR)

(21) Appl. No.: 18/960,088

(22) Filed: Nov. 26, 2024

(30) Foreign Application Priority Data
Jan. 8, 2024 (KR) 10-2024-0003124

(51) Int. Cl. H10K 85/30; C07F 15/00; C09K 11/02; C09K 11/06; H10K 50/12; H10K 85/60; H10K 101/25

(52) U.S. Cl. CPC H10K 85/346; C07F 15/0086; C09K 11/02; C09K 11/06; H10K 85/6572; C09K 2211/1007; C09K 2211/1011; C09K 2211/1014; C09K 2211/1022; C09K 2211/1029; C09K 2211/1044; C09K 2211/185; H10K 50/121; H10K 2101/25

(57) ABSTRACT

Embodiments provide an organometallic compound, and a light-emitting device including the organometallic compound. The light-emitting device includes a first electrode, a second electrode facing the first electrode, and an interlayer between the first electrode and the second electrode and including an emission layer. The interlayer includes the organometallic compound, which is represented by Formula 1 and satisfies Conditions A and B. Formula 1 and Conditions A and B are explained in the specification.

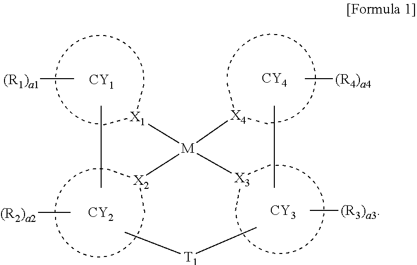

### CROSS-REFERENCE TO RELATED APPLICATION(S)

This application claims priority to and benefits of Korean Patent Application No. 10-2024-0003124 under 35 U.S.C. § 119, filed on Jan. 8, 2024, in the Korean Intellectual Property Office, the entire contents of which are incorporated herein by reference.

### BACKGROUND

### 1. Technical Field

Embodiments relate to an organometallic compound, a light-emitting device including the same, and an electronic apparatus including the light-emitting device.

### 2. Description of the Related Art

Light-emitting devices (for example, organic light-emitting devices) are self-emissive devices that have wide viewing angles, high contrast ratios, short response times, and excellent characteristics in terms of luminance, driving voltage, and response speed.

A light-emitting device may include a first electrode, a hole transport region, an emission layer, an electron transport region, and a second electrode, which may be arranged sequentially. Holes injected from the first electrode may move toward the emission layer through the hole transport region. Electrons injected from the second electrode may move toward the emission layer through the electron transport region. Carriers, such as holes and electrons, may recombine in the emission layer to produce excitons. When the excitons transition from an excited state to a ground state, light may be generated.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide conditions for a light-emitting device that emits blue phosphorescence and has low capacitance and a low amount of charge, an electronic apparatus having improved display quality by including the light-emitting device, and an organometallic compound (blue phosphorescent dopant or sensitizer) for reducing the capacitance and amount of charge of the light-emitting device.

Additional aspects will be set forth in part in the description which follows and, in part, will be apparent from the description, or may be learned by practice of the embodiments of the disclosure.

According to embodiments, a light-emitting device may include a first electrode, a second electrode facing the first electrode, and an interlayer between the first electrode and the second electrode and including an emission layer, wherein the interlayer includes an organometallic compound represented by Formula 1 and satisfies Conditions A and B.

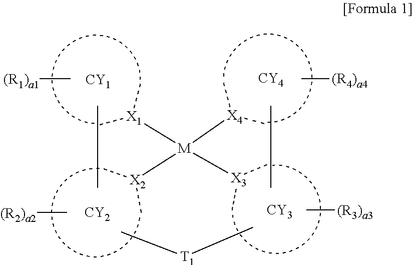

### [Condition A]

In Formula 1, a moiety represented by

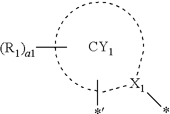

is a moiety represented by Formula 1-1 or Formula 1-2.

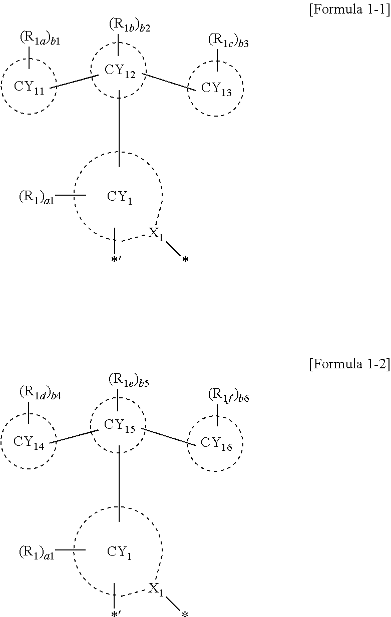

### [Condition B]

At least one of R₂ in the number of a2 is each independently deuterium, a methyl group, an ethyl group, a propyl group, a methyl group that is substituted with at least one deuterium, an ethyl group that is substituted with at least one deuterium, or a propyl group that is substituted with at least one deuterium.

In Formulae 1, 1-1, and 1-2,
M may be platinum (Pt), palladium (Pd), gold (Au), silver (Ag), nickel (Ni), or copper (Cu),
X₁ to X₄ may each independently be carbon (C) or nitrogen (N),
T₁ may be a single bond, O, N(Z₁), or C(Z₁)(Z₂), ring CY₁ to ring CY₄ and ring CY₁₁ to ring CY₁₆ may each independently be a C₃-C₆₀ carbocyclic group or a C₁-C₆₀ heterocyclic group,
Z₁, Z₂, R₁ to R₄, and R₁ₐ to R_{1f} may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a plurality of R₁ₐ may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1b} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1c} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1d} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R₁ₑ may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1f} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a1 to a4 and b1 to b6 may each independently be an integer from 0 to 20,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof,
* indicates a binding site to M in Formula 1, and
*′ indicates a binding site to ring CY₂ in Formula 1.

In an embodiment, the light-emitting device may further include a second compound including at least one π electron-deficient nitrogen-containing C₁-C₆₀ heterocyclic group, a third compound including a group represented by Formula 3, a fourth compound that is a delayed fluorescence compound, or any combination thereof, wherein
the organometallic compound represented by Formula 1, the second compound, the third compound, and the fourth compound may be different from each other, and wherein Formula 3 is explained below.

In an embodiment, the second compound may include a pyridine group, a pyrimidine group, a pyrazine group, a pyridazine group, a triazine group, or any combination thereof; and the fourth compound may be a compound including at least one cyclic group including boron (B) and nitrogen (N) as ring-forming atoms.

In an embodiment, the emission layer may include: the organometallic compound represented by Formula 1; and the second compound, the third compound, the fourth compound, or any combination thereof; and the emission layer may emit blue light.

According to embodiments, an electronic apparatus may include the light-emitting device, and a thin-film transistor electrically connected to the light-emitting device.

According to embodiments, an electronic equipment may include the light-emitting device, wherein the electronic equipment may be a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall including multiple displays tiled together, a theater screen, a stadium screen, a phototherapy device, or a signboard.

According to embodiments, an organometallic compound may be represented by Formula 1 and may satisfy Conditions A and B, wherein Formula 1 and Conditions A and B are explained herein.

In an embodiment, in Formula 1, X₁ may be a carbon atom of a carbene moiety.

In an embodiment, in Formula 1, ring CY₁ may be a nitrogen-containing C₁-C₆₀ heterocyclic group.

In an embodiment, ring CY₁₁ to ring CY₁₃ in Formula 1-1 may be identical to each other; and ring CY₁₄ to ring CY₁₆ in Formula 1-2 may be identical to each other.

In an embodiment, at least one of Conditions 1 to 3 may be satisfied, which are explained below.

In an embodiment, in Formula 1-2, a ring formed to be surrounded by CY₁-CY₁₄-CY₁₅-CY₁₆ may be a 9-membered ring.

In an embodiment, in Formula 1, a moiety represented by

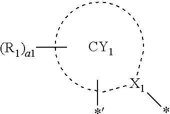

may be a moiety represented by one of Formulae 1A to 1C, which are explained below.

In an embodiment, in Formulae 1A and 1B, a moiety represented by

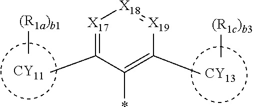

may be a moiety represented by Formula AS, which is explained below.

In an embodiment, in Formula 1C:
X₁₃ₑ may be C(R₁₃ₑ), and R₁₃ₑ may be a phenyl group that is substituted with at least one of deuterium and a tert-butyl group;
X_{14f} may be C(R_{14f}), and R_{14f} may be a phenyl group that is substituted with at least one of deuterium and a tert-butyl group; or
X₁₃ₑ may be C(R₁₃ₑ), X_{14f} may be C(R_{14f}), and R₁₃ₑ and R_{14f} may each independently be a phenyl group that is substituted with at least one of deuterium and a tert-butyl group.

In an embodiment, in Formula 1, a moiety represented by

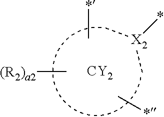

may be a moiety represented by Formula 2-1, which is explained below.

In an embodiment, in Formula 1, ring CY₃ may be:
a C₂-C₈ monocyclic group; or
a C₄-C₂₀ polycyclic group in which two or three C₂-C₈ monocyclic groups are condensed with each other.

In an embodiment, in Formula 1, a moiety represented by

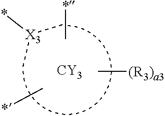

may be a moiety represented by one of Formulae 3A to 3F, which are explained below.

In an embodiment, in Formula 1, a moiety represented by

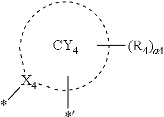

may be a moiety represented by Formula 4-1, which is explained below.

In an embodiment, the organometallic compound represented by Formula 1 is one of Compounds BD1 to BD27, which are explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will be more apparent by describing in detail embodiments thereof with reference to the accompanying drawings, in which:

FIG. 1 is a graph showing the results of measuring an amount of charge of a light-emitting device including an organometallic compound according to the structure of the organometallic compound;

FIG. 2 is a schematic cross-sectional view of a light-emitting device according to an embodiment;

FIG. 3 is a schematic cross-sectional view of an electronic apparatus according to an embodiment;

FIG. 4 is a schematic cross-sectional view of an electronic apparatus according to another embodiment;

FIG. 5 is a schematic perspective view of an electronic equipment including a light-emitting device according to an embodiment;

FIG. 6 is a schematic view of an exterior of a vehicle as an electronic equipment including a light-emitting device, according to an embodiment; and

FIGS. 7A to 7C are each a schematic diagram of an interior of the vehicle in FIG. 6 according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, 10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

According to embodiments, a light-emitting device may include:
a first electrode;
a second electrode facing the first electrode; and
an interlayer between the first electrode and the second electrode and including an emission layer, wherein
the interlayer includes an organometallic compound represented by Formula 1 and satisfies Conditions A and B:

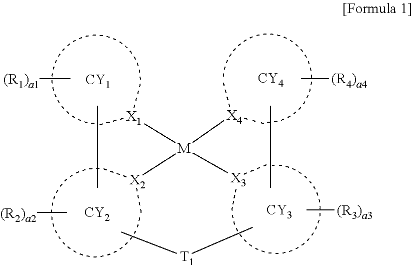

[Condition A]
in Formula 1, a moiety represented by

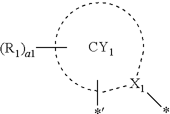

may be a moiety represented by Formula 1-1 or Formula 1-2; and

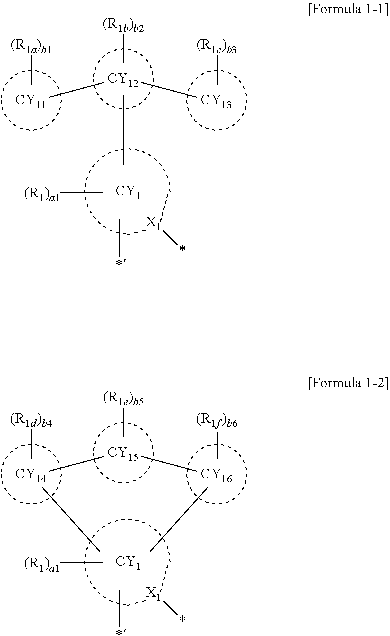

[Condition B]
at least one of R₂ in the number of a2 may each independently be deuterium, a methyl group, an ethyl group, a propyl group, a methyl group that is substituted with at least one deuterium, an ethyl group that is substituted with at least one deuterium, or a propyl group that is substituted with at least one deuterium.

In Formulae 1, 1-1, and 1-2,
M may be platinum (Pt), palladium (Pd), gold (Au), silver (Ag), nickel (Ni), or copper(Cu),
X₁ to X₄ may each independently be carbon (C) or nitrogen (N),
T₁ may be a single bond, O, N(Z₁), or C(Z₁)(Z₂),
ring CY₁ to ring CY₄ and ring CY₁₁ to ring CY₁₆ may each independently be a C₃-C₆₀ carbocyclic group or a C₁-C₆₀ heterocyclic group,

Z₁, Z₂, R₁ to R₄, and R₁ₐ to R_{1f} may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a plurality of R₁ₐ may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1b} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1c} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1d} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R₁ₑ may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1f} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a1 to a4 and b1 to b6 may each independently be an integer from 0 to 20,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof,
* indicates a binding site to M in Formula 1, and
*′ indicates a binding site to ring CY₂ in Formula 1.

Formulae 1, 1-1, and 1-2 are respectively the same as described in the specification.

Because the light-emitting device includes the organometallic compound represented by Formula 1 and satisfies Conditions A and B, the light-emitting device may have low capacitance and a low amount of charge.

In an embodiment, the emission layer may include the organometallic compound represented by Formula 1.

In an embodiment, the light-emitting device may include a second compound including at least one π electron-deficient nitrogen-containing C₁-C₆₀ heterocyclic group, a third compound including a group represented by Formula 3, a fourth compound capable of emitting delayed fluorescence (for example, a delayed fluorescence compound), or any combination thereof, wherein the organometallic compound represented by Formula 1, the second compound, the third compound, and the fourth compound may be different from each other:

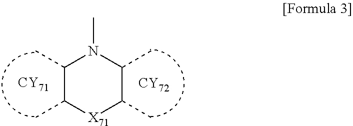

In Formula 3,
ring CY₇₁ and ring CY₇₂ may each independently be a π electron-rich C₃-C₆₀ cyclic group or a pyridine group,
X₇₁ may be: a single bond; or a linking group including O, S, N, B, C, Si, or any combination thereof, and
* indicates a binding site to any atom included in a remaining part other than Formula 3 in the third compound.

In an embodiment, the organometallic compound represented by Formula 1 and the second compound to the fourth compound may each include at least one deuterium atom.

In an embodiment, the second compound and the third compound may each include at least one silicon atom.

In an embodiment, the interlayer (for example, the emission layer) may include: the organometallic compound; the organometallic compound and the second compound; the organometallic compound and the third compound; the organometallic compound and the fourth compound; the organometallic compound, the second compound, and the third compound; the organometallic compound, the second compound, and the fourth compound; the organometallic compound, the third compound, and the fourth compound; or the organometallic compound and the second compound to the fourth compound.

In an embodiment, the second compound and the third compound may form an exciplex.

In an embodiment, the fourth compound may serve to improve color purity, luminescence efficiency, and lifespan characteristics of the light-emitting device.

In an embodiment, a highest occupied molecular orbital (HOMO) energy level of the organometallic compound may be in a range of about −5.35 eV to about −5.15 eV. For example, the HOMO energy level of the organometallic compound may be in a range of about −5.30 eV to about −5.20 eV.

In an embodiment, a lowest unoccupied molecular orbital (LUMO) energy level of the organometallic compound may be in a range of about −2.20 eV to about −1.80 eV. For example, the LUMO energy level of the organometallic compound may be in a range of about −2.15 eV to about −1.90 eV.

The HOMO and LUMO energy levels may each be evaluated by cyclic voltammetry analysis for the organometallic compound.

In an embodiment, a maximum emission wavelength (or an emission peak wavelength) of an emission spectrum in film of the organometallic compound may be in a range of about 430 nm to about 475 nm. For example, the maximum emission wavelength (or an emission peak wavelength) of an emission spectrum in film of the organometallic compound may be in a range of about 440 nm to about 475 nm. For example, the maximum emission wavelength (or an emission peak wavelength) of an emission spectrum in film of the organometallic compound may be in a range of about 450 nm to about 475 nm. For example, maximum emission wavelength (or an emission peak wavelength) of an emission spectrum in film of the organometallic compound may be in a range of about 430 nm to about 470 nm. For example, the maximum emission wavelength (or an emission peak wavelength) of an emission spectrum in film of the organometallic compound may be in a range of about 440 nm to about 470 nm. For example, the maximum emission wavelength (or an emission peak wavelength) of an emission spectrum in film of the organometallic compound may be in a range of about 450 nm to about 470 nm. For example, the maximum emission wavelength (or an emission peak wavelength) of an emission spectrum in film of the organometallic compound may be in a range of about 430 nm to about 465 nm. For example, maximum emission wavelength (or an emission peak wavelength) of an emission spectrum in film of the organometallic compound may be in a range of about 440 nm to about 465 nm. For example, the maximum emission wavelength (or an emission peak wavelength) of an emission spectrum in film of the organometallic compound may be in a range of about 450 nm to about 465 nm. For example, the maximum emission wavelength (or an emission peak wavelength) of an emission spectrum in film of the organometallic compound may be in a range of about 430 nm to about 460 nm. For example, the maximum emission wavelength (or an emission peak wavelength) of an emission spectrum in film of the organometallic compound may be in a range of about 440 nm to about 460 nm. For example, the maximum emission wavelength (or an emission peak wavelength) of an emission spectrum in film of the organometallic compound may be in a range of about 450 nm to about 460 nm.

In an embodiment, a full width at half maximum (FWHM) of an emission spectrum in film of the organometallic compound may be less than or equal to about 40 nm. For example, the FWHM of the emission spectrum may be in a range of about 5 nm to about 40 nm. For example, the FWHM of the emission spectrum may be in a range of about 10 nm to about 40 nm. For example, the FWHM of the emission spectrum may be in a range of about 15 nm to about 40 nm. For example, the FWHM of the emission spectrum may be in a range of about 20 nm to about 40 nm. For example, the FWHM of the emission spectrum may be in a range of about 5 nm to about 37 nm. For example, the FWHM of the emission spectrum may be in a range of about 10 nm to about 37 nm. For example, the FWHM of the emission spectrum may be in a range of about 15 nm to about 37 nm. For example, the FWHM of the emission spectrum may be in a range of about 20 nm to about 37 nm.

The maximum emission wavelength and FWHM of the emission spectrum of the organometallic compound may be evaluated for a film including the organometallic compound.

In an embodiment, the emission layer may include: the organometallic compound; and the second compound, the third compound, the fourth compound, or any combination thereof, wherein the emission layer may emit blue light.

In an embodiment, a maximum emission wavelength of a blue light may be in a range of about 430 nm to about 475 nm. For example, the maximum emission wavelength of the blue light may be in a range of about 440 nm to about 475 nm. For example, the maximum emission wavelength of the blue light may be in a range of about 450 nm to about 475 nm. For example, the maximum emission wavelength of the blue light may be in a range of about 430 nm to about 470 nm. For example, the maximum emission wavelength of the blue light may be in a range of about 440 nm to about 470 nm. For example, the maximum emission wavelength of the blue light may be in a range of about 450 nm to about 470 nm. For example, the maximum emission wavelength of the blue light may be in a range of about 430 nm to about 465 nm. For example, the maximum emission wavelength of the blue light may be in a range of about 440 nm to about 465 nm. For example, the maximum emission wavelength of the blue light may be in a range of about 450 nm to about 465 nm. For example, the maximum emission wavelength of the blue light may be in a range of about 430 nm to about 460 nm. For example, the maximum emission wavelength of the blue light may be in a range of about 440 nm to about 460 nm. For example, the maximum emission wavelength of the blue light may be in a range of about 450 nm to about 460 nm.

In an embodiment, a FWHM of an emission spectrum of the blue light may be less than or equal to about 40 nm. For example, the FWHM of the emission spectrum of the blue light may be in a range of about 5 nm to about 40 nm. For example, the FWHM of the emission spectrum of the blue light may be in a range of about 10 nm to about 40 nm. For example, the FWHM of the emission spectrum of the blue light may be in a range of about 15 nm to about 40 nm. For example, the FWHM of the emission spectrum of the blue light may be in a range of about 20 nm to about 40 nm. For example, the FWHM of the emission spectrum of the blue light may be in a range of about 5 nm to about 37 nm. For example, the FWHM of the emission spectrum of the blue light may be in a range of about 10 nm to about 37 nm. For example, the FWHM of the emission spectrum of the blue light may be in a range of about 15 nm to about 37 nm. For example, the FWHM of the emission spectrum of the blue light may be in a range of about 20 nm to about 37 nm.

In an embodiment, the blue light may be deep blue light.

In an embodiment, the ClEx coordinate (for example, the bottom emission ClEx coordinate) of the blue light may be in a range of about 0.125 to about 0.140. For example, the ClEx coordinate (for example, the bottom emission ClEx coordinate) of the blue light may be in a range of about 0.130 to about 0.140.

In an embodiment, the ClEy coordinate (for example, the bottom emission ClEy coordinate) of the blue light may be in a range of about 0.120 to about 0.210.

In an embodiment, the second compound may include a pyridine group, a pyrimidine group, a pyrazine group, a pyridazine group, a triazine group, or any combination thereof.

In an embodiment, the second compound may include a compound represented by Formula 2:

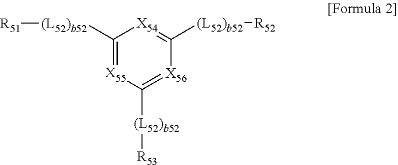

In Formula 2,
L₅₁ to L₅₃ may each independently be a single bond, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
b51 to b53 may each independently be an integer from 1 to 5,
X₅₄ may be N or C(R₅₄), X₅₅ may be N or C(R₅₅), X₅₆ may be N or C(R₅₆), and at least one of X₅₄ to X₅₆ may each be N, and
R₅₁ to R₅₆ may each independently be the same as described in connection with R₁₀ₐ.

In an embodiment, the third compound may include a compound represented by Formula 3-1, a compound represented by Formula 3-2, a compound represented by Formula 3-3, a compound represented by Formula 3-4, a compound represented by Formula 3-5, or any combination thereof:

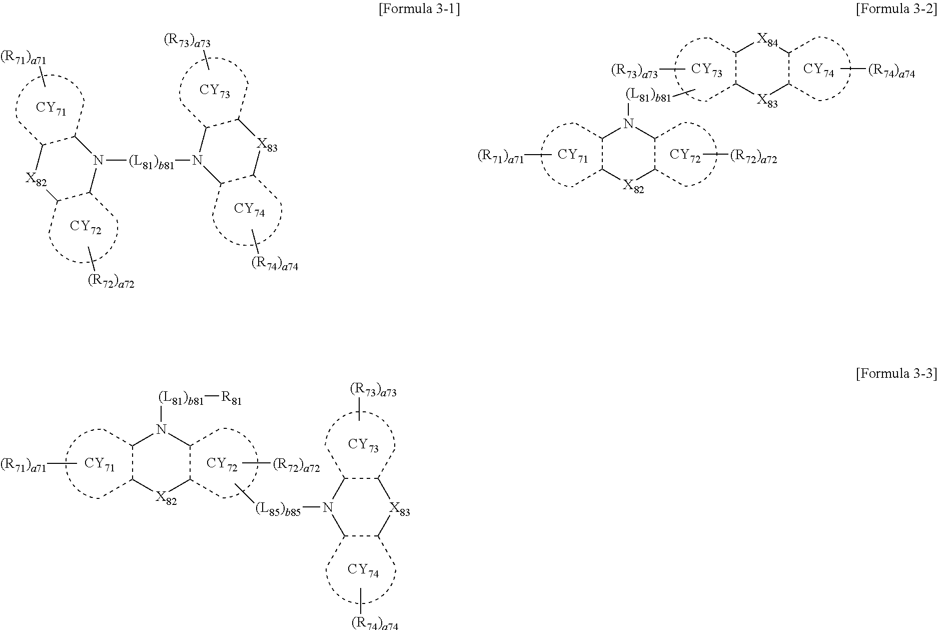

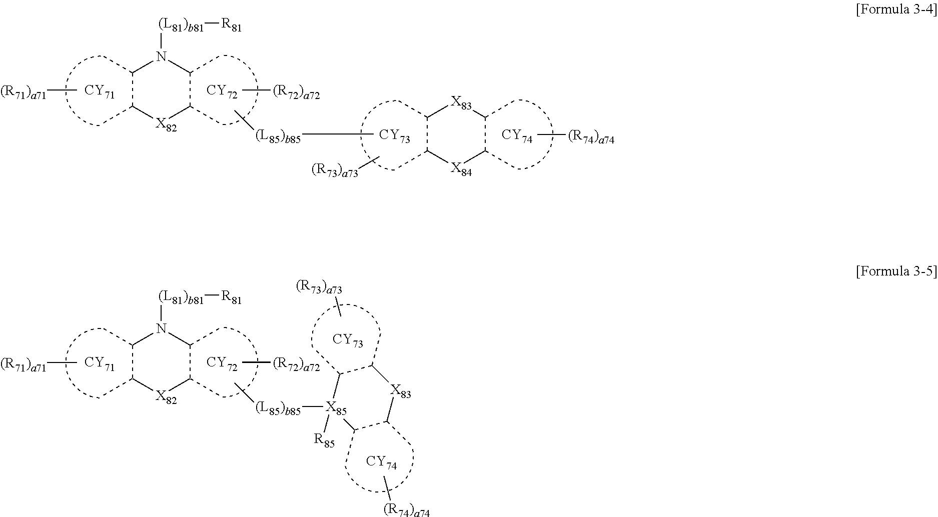

In Formulae 3-1 to 3-5,
ring CY₇₁ to ring CY₇₄ may each independently be a π electron-rich C₃-C₆₀ cyclic group or a pyridine group,
X₈₂ may be a single bond, O, S, N—[(L₈₂)_{b82}-R₈₂], C(R₈₂ₐ)(R_{82b}), or Si(R₈₂ₐ)(R_{82b}),
X₈₃ may be a single bond, O, S, N—[(L₈₃)_{b83}-R₈₃], C(R₈₃ₐ)(R_{83b}), or Si(R₈₃ₐ)(R_{83b}),
X₈₄ may be O, S, N—[(L₈₄)_{b84}-R₈₄], C(R₈₄ₐ)(R_{84b}), or Si(R₈₄ₐ)(R_{84b}),
X₈₅ may be C or Si,
L₈₁ to L₈₅ may each independently be a single bond, *—C(Q₄)(Q₅)-*′, *—Si(Q₄)(Q₅)-*′, a π electron-rich C₃-C₆₀ cyclic group that is unsubstituted or substituted with at least one R₁₀ₐ or a pyridine group that is unsubstituted or substituted with at least one R₁₀ₐ, wherein Q₄ and Q₅ may each independently be the same as described in connection with Q₁,
b81 to b85 may each independently be an integer from 1 to 5,
R₇₁ to R₇₄, R₈₁ to R₈₅, R₈₂ₐ, R_{82b}, R₈₃ₐ, R_{83b}, R₈₄ₐ, and R_{84b} may each independently be the same as described in connection with R₁,
a71 to a74 may each independently be an integer from 0 to 20, and
R₁₀ₐ may be as described in the specification.

In an embodiment, the third compound may not be CBP or mCBP:

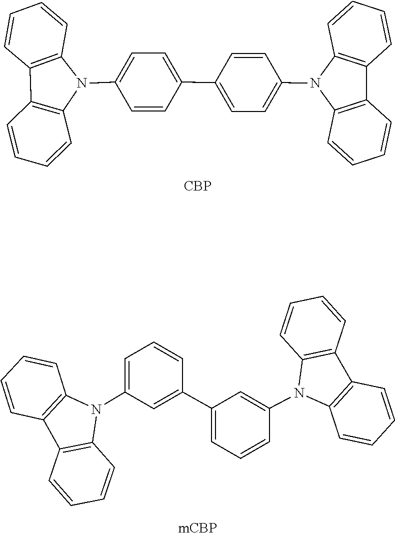 [SMILES: c1ccc2c(c1)c1ccccc1n2-c1ccc(-c2ccc(-n3c4ccccc4c4ccccc43)cc2)cc1 ; "CBP" ; c1cc(-c2cccc(-n3c4ccccc4c4ccccc43)c2)cc(-n2c3ccccc3c3ccccc32)c1]

In an embodiment, a difference between a triplet energy level (eV) and a singlet energy level (eV) of the fourth compound may be in a range of about 0 eV to about 0.5 eV. For example, the difference between the triplet energy level (eV) and the singlet energy level (eV) of the fourth compound may be in a range of about 0 eV to about 0.3 eV.

In an embodiment, the fourth compound may be a compound including at least one cyclic group including boron (B) and nitrogen (N) as ring-forming atoms.

For example, the fourth compound may be a C₈-C₆₀ polycyclic group-containing compound including at least two cyclic groups that are condensed with each other while sharing boron (B).

In an embodiment, the fourth compound may include a condensed ring in which at least one third ring may be condensed with at least one fourth ring,

the third ring may be a cyclopentane group, a cyclohexane group, a cycloheptane group, a cyclooctane group, a cyclopentene group, a cyclohexene group, a cycloheptene group, a cyclooctene group, an adamantane group, a norbornene group, a norbornane group, a bicyclo[1.1.1]pentane group, a bicyclo[2.1.1]hexane group, a bicyclo[2.2.2]octane group, a benzene group, a pyridine group, a pyrimidine group, a pyridazine group, a pyrazine group, or a triazine group, and

the fourth ring may be a 1,2-azaborinine group, a 1,3-azaborinine group, a 1,4-azaborinine group, a 1,2-dihydro-1,2-azaborinine group, a 1,4-oxaborinine group, a 1,4-thiaborinine group, or a 1,4-dihydroborinine group.

In an embodiment, the fourth compound may include a compound represented by Formula 502, a compound represented by Formula 503, or any combination thereof:

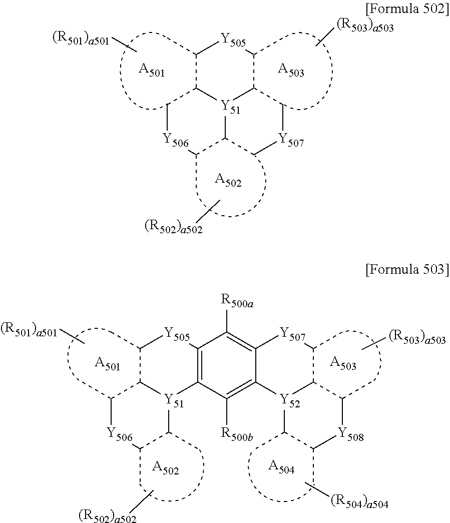

In Formulae 502 and 503,
ring A₅₀₁ to ring A₅₀₄ may each independently be a C₃-C₆₀ carbocyclic group or a C₁-C₆₀ heterocyclic group,
Y₅₀₅ may be O, S, N(R₅₀₅), B(R₅₀₅), C(R₅₀₅ₐ)(R_{505b}), or Si(R₅₀₅ₐ)(R_{505b}),
Y₅₀₆ may be O, S, N(R₅₀₆), B(R₅₀₆), C(R₅₀₆ₐ)(R_{506b}), or Si(R₅₀₆ₐ)(R_{506b}),
Y₅₀₇ may be O, S, N(R₅₀₇), B(R₅₀₇), C(R₅₀₇ₐ)(R_{507b}), or Si(R₅₀₇ₐ)(R_{507b}),
Y₅₀₈ may be O, S, N(R₅₀₈), B(R₅₀₈), C(R₅₀₈ₐ)(R_{508b}), or Si(R₅₀₈ₐ)(R_{508b}),
Y₅₁ and Y₅₂ may each independently be B, P(═O), or S(═O),
R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} may each independently be the same as described in connection with R₁, and
a501 to a504 may each independently be an integer from 0 to 20.

In an embodiment, the light-emitting device may satisfy at least one of Conditions 11 to 14:
[Condition 11]
LUMO energy level (eV) of third compound>LUMO energy level (eV) of organometallic compound represented by Formula 1;
[Condition 12]
LUMO energy level (eV) of organometallic compound represented by Formula 1>LUMO energy level (eV) of second compound;
[Condition 13]
HOMO energy level (eV) of organometallic compound represented by Formula 1>HOMO energy level (eV) of third compound; and
[Condition 14]
HOMO energy level (eV) of third compound>HOMO energy level (eV) of second compound

A HOMO energy level and a LUMO energy level of each of the organometallic compound represented by Formula 1, the second compound, and the third compound may each be a negative value, and may be measured according to a method of the related art.

In an embodiment, an absolute value of a difference between a LUMO energy level of the organometallic compound represented by Formula 1 and a LUMO energy level of the second compound may be in a range of about 0.1 eV to about 1.0 eV, and/or the absolute value of a difference between the LUMO energy level of the organometallic compound represented by Formula 1 and the LUMO energy level of the third compound may be about 0.1 eV to about 1.0 eV.

In an embodiment, an absolute value of a difference between a HOMO energy level of the organometallic compound represented by Formula 1 and a HOMO energy level of the second compound may be less than or equal to about 1.25 eV (for example, about 0.2 eV to about 1.25 eV), and/or the absolute value of a difference between the HOMO energy level of the organometallic compound represented by Formula 1 and the HOMO energy level of the third compound may be less than or equal to about 1.25 eV (for example, about 0.2 eV to about 1.25 eV).

When the relationships between LUMO energy level and HOMO energy level satisfy the conditions as described above, the balance between holes and electrons injected into the emission layer may be achieved.

The light-emitting device may have a structure of a first embodiment or a second embodiment.

### First Embodiment

According to a first embodiment, an emission layer may include the organometallic compound and a host, wherein the organometallic compound and the host may be different from each other, and the emission layer may emit phosphorescence or fluorescence emitted from the organometallic compound. Phosphorescence or fluorescence emitted from the organometallic compound may be blue light.

For example, according to the first embodiment, the organometallic compound may be a dopant (or an emitter). In an embodiment, the organometallic compound may be a phosphorescent dopant (or a phosphorescent emitter).

The emission layer may further include an auxiliary dopant that is different from each of the organometallic compound and the host. The auxiliary dopant may effectively transfer energy to the organometallic compound, which may be a dopant, and thus improve luminescence efficiency from the organometallic compound.

In an embodiment, the auxiliary dopant may be a compound emitting delayed fluorescence. The auxiliary dopant may be a compound including at least one cyclic group including boron (B) and nitrogen (N) as ring-forming atoms. The auxiliary dopant in the first embodiment may include, for example, the fourth compound represented by Formula 502 or Formula 503.

### Second Embodiment

According to a second embodiment, an emission layer may include the organometallic compound, a host, and a dopant (or an emitter), wherein the organometallic compound, the host, and the dopant may be different from each other, and the emission layer may emit phosphorescence or fluorescence (for example, delayed fluorescence) emitted from the dopant.

In an embodiment, the organometallic compound in the second embodiment may not be a dopant, and may rather serve as an auxiliary dopant that transfers energy to a dopant (or an emitter).

In another embodiment, the organometallic compound in the second embodiment may serve as a dopant, and may also serve as an auxiliary dopant that transfers energy to a dopant.

Phosphorescence or fluorescence emitted from the dopant in the second embodiment may be blue phosphorescence or blue fluorescence (for example, blue delayed fluorescence).

The dopant in the second embodiment may be a phosphorescent dopant material (for example, the organometallic compound represented by Formula 1, an organometallic compound represented by Formula 401, or any combination thereof) or any fluorescent dopant material (for example, a compound represented by Formula 501, a compound represented by Formula 502, a compound represented by Formula 503, or any combination thereof).

In the first embodiment and the second embodiment, the blue light may have a maximum emission wavelength in a range of about 390 nm to about 500 nm. For example, the blue light in the first embodiment and the second embodiment may be a blue light having a maximum emission wavelength in a range of about 410 nm to about 490 nm. For example, the blue light in the first embodiment and the second embodiment may be a blue light having a maximum emission wavelength in a range of about 430 nm to about 480 nm. For example, the blue light in the first embodiment and the second embodiment may be a blue light having a maximum emission wavelength in a range of about 440 nm to about 475 nm. For example, the blue light in the first embodiment and the second embodiment may be a blue light having a maximum emission wavelength in a range of about 455 nm to about 470 nm.

The host in the first embodiment and the second embodiment may be any host material (for example, a compound represented by Formula 301, a compound represented by Formula 301-1, a compound represented by Formula 301-2, or any combination thereof).

The host in the first embodiment and the second embodiment may be the second compound, the third compound, or any combination thereof.

In an embodiment, the light-emitting device may further include a capping layer outside the first electrode and/or outside the second electrode.

For example, the light-emitting device may further include at least one of a first capping layer outside the first electrode and a second capping layer outside the second electrode.

At least one of the first capping layer and the second capping layer may include the organometallic compound represented by Formula 1. According to an embodiment, the light-emitting device may further include the first capping layer outside the first electrode, the first capping layer may include the organometallic compound represented by Formula 1. According to another embodiment, the light-emitting device may further include the second capping layer outside the second electrode, the second capping layer may include the organometallic compound represented by Formula 1. According to another embodiment, the light-emitting device may further include the first capping layer outside the first electrode and the second capping layer outside the second electrode, at least one of the first capping layer and the second capping layer may include the organometallic compound represented by Formula 1. The first capping layer and/or the second capping layer may each be the same as described herein.

In an embodiment, the light-emitting device may include:
a first capping layer outside the first electrode and including the organometallic compound represented by Formula 1;
a second capping layer outside the second electrode and including the organometallic compound represented by Formula 1; or
both the first capping layer and the second capping layer.

The expression “(interlayer and/or a capping layer) includes an organometallic compound represented by Formula 1” as used herein may be to mean that the (interlayer and/or the capping layer) may include one kind of organometallic compound represented by Formula 1 or two or more different kinds of organometallic compounds, each represented by Formula 1.

In an embodiment, the interlayer and/or the capping layer may include Compound BD1 only as the organometallic compound represented by Formula 1. Compound BD1 may be included in the emission layer of the light-emitting device.

In another embodiment, the interlayer may include, as the organometallic compound represented by Formula 1, Compound BD1 and Compound BD2. Compound BD1 and Compound BD2 may be included in an identical layer (for example, both Compound BD1 and Compound BD2 may be included in the emission layer), or may be included in different layers (for example, Compound BD1 may be included in the emission layer, and Compound BD2 may be included in the electron transport region).

The term “interlayer” as used herein refers to a single layer and/or all layers between the first electrode and the second electrode of the light-emitting device.

According to embodiments, an electronic apparatus may include: the light-emitting device, and a thin-film transistor electrically connected to the light-emitting device. For example, the thin-film transistor may include a source electrode and a drain electrode, and the first electrode of light-emitting device may be electrically connected to the source electrode or the drain electrode. The electronic apparatus may further include a color filter, a color conversion layer, a touch screen layer, a polarizing layer, or any combination thereof. Further details on the electronic apparatus may be the same as described herein.

According to embodiments, an electronic equipment may include the light-emitting device and may be a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall including multiple displays tiled together, a theater screen, a stadium screen, a phototherapy device, or a signboard.

According to embodiments, an organometallic compound may be represented by Formula 1 and may satisfy both Conditions A and B. Formula 1 may be the same as described herein.

Synthesis methods of the organometallic compound represented by Formula 1 may be recognizable by one of ordinary skill in the art by referring to the Synthesis Examples and/or Examples provided below.

### Description of Formulae

According to embodiments, the organometallic compound may be represented by Formula 1 and may satisfy Conditions A and B:

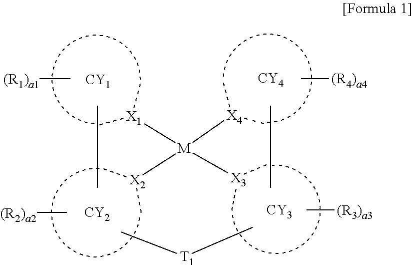

[Condition A]
in Formula 1, a moiety represented by

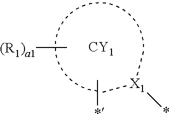

may be a moiety represented by Formula 1-1 or Formula 1-2; and

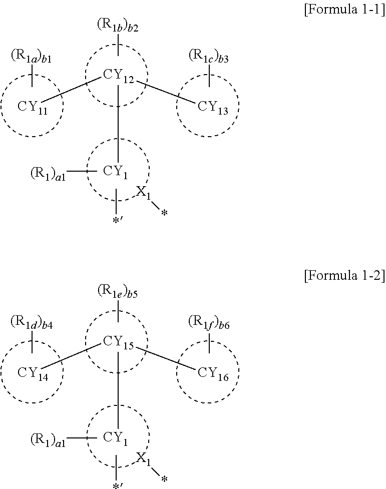

[Condition B]
at least one of R₂ in the number of a2 may each independently be deuterium, a methyl group, an ethyl group, a propyl group, a methyl group that is substituted with at least one deuterium, an ethyl group that is substituted with at least one deuterium, or a propyl group that is substituted with at least one deuterium.

In Formulae 1, 1-1, and 1-2,
M may be platinum (Pt), palladium (Pd), gold (Au), silver (Ag), nickel (Ni), or copper(Cu),
X₁ to X₄ may each independently be carbon (C) or nitrogen(N),
T₁ may be a single bond, O, N(Z₁), or C(Z₁)(Z₂),
ring CY₁ to ring CY₄ and ring CY₁₁ to ring CY₁₆ may each independently be a C₃-C₆₀ carbocyclic group or a C₁-C₆₀ heterocyclic group,
Z₁, Z₂, R₁ to R₄, and R₁ₐ to R_{1f} may each independently be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a plurality of R₁ₐ may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1b} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R₁ may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1d} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R₁ₑ may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1f} may optionally be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a1 to a4 and b1 to b6 may each independently be an integer from 0 to 20,
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ may each independently be:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof,
* indicates a binding site to M in Formula 1, and
*′ indicates a binding site to ring CY₂ in Formula 1.

In an embodiment, in Formula 1, at least one of a bond between X₁ and M, a bond between X₂ and M, a bond between X₃ and M, and a bond between X₄ and M may each independently be a coordinate bond.

In an embodiment, in Formula 1, X₁ may be a carbon atom of a carbene moiety.

In an embodiment, in Formula 1, at least one of X₁ to X₄ may each be N. For example, X₄ may be N.

In an embodiment, in Formula 1, T₁ may be a single bond, O, N(Z₁), or C(Z₁)(Z₂), wherein Z₁ and Z₂ may be:
hydrogen or deuterium; or
a methyl group, an ethyl group, a propyl group, a phenyl group, a biphenyl group, a terphenyl group, a naphthyl group, a pyridinyl group, a pyrimidinyl group, or a triazinyl group, each unsubstituted or substituted with at least one deuterium.

In an embodiment, Z₁ and Z₂ may not be bonded to each other.

For example, in Formula 1, T₁ may be O.

In an embodiment, ring CY₁ to ring CY₄ and ring CY₁₁ to ring CY₁₆ may each independently be:
a C₂-C₈ monocyclic group; or
a C₄-C₂₀ polycyclic group in which two or three C₂-C₈ monocyclic groups are condensed with each other.

The term “C₂-C₈ monocyclic group” as recited above may refer to a non-condensed ring group, and may be, for example, a cyclopentadiene group, a pyrrole group, a pyrazole group, an imidazole group, a triazole group, an oxazole group, an isooxazole group, a thiazole group, an isothiazole group, an oxadiazole group, a thiadiazole group, a cyclohexadiene group, a benzene group, a pyridine group, a pyrimidine group, a pyrazine group, a pyridazine group, a triazine group, a cycloheptadiene group, or a cyclooctadiene group.

In an embodiment, ring CY₁ may be a nitrogen-containing C₁-C₆₀ heterocyclic group. For example, ring CY₁ may include a nitrogen-containing 5-membered ring. As another example, ring CY₁ may be a condensed ring including a 5-membered ring and a 6-membered ring. In an embodiment, ring CY₁ may be an X₁-containing 5-membered ring, an X₁-containing 5-membered ring condensed with at least one 6-membered ring, or an X₁-containing 6-membered ring.

In an embodiment, ring CY₁ in Formula 1 may be an X₁-containing 5-membered ring or an X₁-containing 5-membered ring condensed with at least one 6-membered ring, wherein
the X₁-containing 5-membered ring may be a pyrrole group, a pyrazole group, an imidazole group, a triazole group, an oxazole group, an isooxazole group, a thiazole group, an isothiazole group, an oxadiazole group, or a thiadiazole group, and
the X₁-containing 6-membered ring or the 6-membered ring that may be optionally condensed with the X₁-containing 5-membered ring may be a benzene group, a pyridine group, or a pyrimidine group.

For example, ring CY₁ may be an imidazole group, a triazole group, a benzimidazole group, a naphthoimidazole group, or an imidazopyridine group.

In an embodiment, in Formula 1-1, ring CY₁₁ to ring CY₁₃ may be identical to each other.

In an embodiment, in Formula 1-2, ring CY₁₄ to ring CY₁₆ may be identical to each other.

In an embodiment, ring CY₁₁ to ring CY₁₆ may each include a benzene group. For example, ring CY₁₁ to ring CY₁₆ may each be a benzene group or a condensed ring in which a cyclopentadiene group, a pyrrole group, a pyrazole group, an imidazole group, a triazole group, an oxazole group, an isooxazole group, a thiazole group, an isothiazole group, an oxadiazole group, a thiadiazole group, a cyclohexadiene group, a benzene group, a pyridine group, a pyrimidine group, a pyrazine group, a pyridazine group, a triazine group, a cycloheptadiene group, or a cyclooctadiene group may be condensed with a benzene group.

In an embodiment, ring CY₁₁ to ring CY₁₆ may each be a benzene group,
a plurality of R₁ₐ may optionally be bonded to each other to form a cyclopentadiene group, a pyrrole group, a pyrazole group, an imidazole group, a triazole group, an oxazole group, an isooxazole group, a thiazole group, an isothiazole group, an oxadiazole group, a thiadiazole group, a cyclohexadiene group, a benzene group, a pyridine group, a pyrimidine group, a pyrazine group, a pyridazine group, a triazine group, a cycloheptadiene group, or a cyclooctadiene group, each unsubstituted or substituted with at least one R₁₀ₐ, and
a plurality of R_{1c} may optionally be bonded to each other to form a cyclopentadiene group, a pyrrole group, a pyrazole group, an imidazole group, a triazole group, an oxazole group, an isooxazole group, a thiazole group, an isothiazole group, an oxadiazole group, a thiadiazole group, a cyclohexadiene group, a benzene group, a pyridine group, a pyrimidine group, a pyrazine group, a pyridazine group, a triazine group, a cycloheptadiene group, or a cyclooctadiene group, each unsubstituted or substituted with at least one R₁₀ₐ.

In an embodiment, in Formula 1-2, a ring formed to be surrounded by CY₁-CY₁₄—CY₁₅—CY₁₆ may be a 9-membered ring. The 9-membered ring formed to be surrounded by CY₁—CY₁₄—CY₁₅—CY₁₆ may be a C₉ carbocyclic group.

In an embodiment, in Formula 1, a moiety represented by

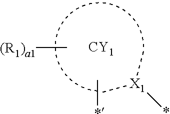

may be a moiety represented by one of Formulae 1A to 1C:

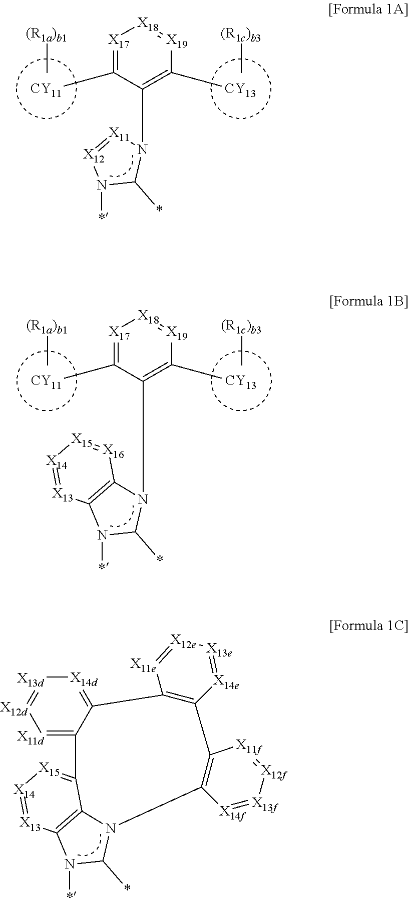

In Formulae 1A, 1B, and 1C,

X₁₁ may be N or C(R₁₁), X₁₂ may be N or C(R₁₂), X₁₃ may be N or C(R₁₃), X₁₄ may be N or C(R₁₄), X₁₅ may be N or C(R₁₅), X₁₆ may be N or C(R₁₆), X₁₇ may be N or C(R₁₇), X₁₈ may be N or C(R₁₈), X₁₉ may be N or C(R₁₉), X_{11d} may be N or C(R_{11d}), X_{12d} may be N or C(R_{12d}), X_{13d} may be N or C(R_{13d}), X_{14d} may be N or C(R_{14d}), X₁₁ₑ may be N or C(R₁₁ₑ), X₁₂ₑ may be N or C(R₁₂ₑ), X₁₃ₑ may be N or C(R₁₃ₑ), X₁₄ₑ may be N or C(R₁₄ₑ), X_{11f} may be N or C(R_{11f}), X_{12f} may be N or C(R_{12f}), X_{13f} may be N or C(R_{13f}), and X_{14f} may be N or C(R_{14f}),
R₁₁ to R₁₆ may each independently be the same as described in connection with R₁ in Formula 1,
R₁₇ to R₁₉ may each independently be the same as described in connection with R_{1b} in Formula 1-1,
R_{11d} to R_{14d} may each independently be the same as described in connection with R_{1d} in Formula 1-2,
R₁₁ₑ to R₁₄ₑ may each independently be the same as described in connection with R₁ₑ in Formula 1-2,
R_{11f} to R_{14f} may each independently be the same as described in connection with R_{1f} in Formula 1-2, and
b1 and b3 may each independently be an integer from 0 to 20.

In an embodiment, in Formulae 1A and 1B,
X₁₈ may be C(R₁₈), and
R₁₈ may be a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, or any combination thereof.

For example, R₁₈ may be a tert-butyl group.

In an embodiment, the organometallic compound represented by Formula 1 may satisfy at least one of Conditions 1 to 3:
[Condition 1]

in Formula 1-1, a plurality of R₁ₐ may be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ;
[Condition 2]
in Formula 1-1, at least one R_{1b} may be a tert-butyl group; and
[Condition 3]
in Formula 1-1, a plurality of R_{1c} may be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

In an embodiment, the organometallic compound represented by Formula 1 may satisfy at least one of Conditions 1A to 3A:
[Condition 1A]
in Formula 1-1, a plurality of R₁ₐ may be bonded to each other to form a cyclopentadiene group, a pyrrole group, a pyrazole group, an imidazole group, a triazole group, an oxazole group, an isooxazole group, a thiazole group, an isothiazole group, an oxadiazole group, a thiadiazole group, a cyclohexadiene group, a benzene group, a pyridine group, a pyrimidine group, a pyrazine group, a pyridazine group, a triazine group, a cycloheptadiene group, or a cyclooctadiene group, each unsubstituted or substituted with at least one R₁₀ₐ;
[Condition 2A]
in Formulae 1A and 1B, X₁₈ may be C(R₁₈), and R₁₈ may be a tert-butyl group; and
[Condition 3A]
in Formula 1-1, a plurality of R_{1c} may be bonded to each other to form a cyclopentadiene group, a pyrrole group, a pyrazole group, an imidazole group, a triazole group, an oxazole group, an isooxazole group, a thiazole group, an isothiazole group, an oxadiazole group, a thiadiazole group, a cyclohexadiene group, a benzene group, a pyridine group, a pyrimidine group, a pyrazine group, a pyridazine group, a triazine group, a cycloheptadiene group, or a cyclooctadiene group, each unsubstituted or substituted with at least one R₁₀ₐ.

In an embodiment, in Formulae 1-1, 1A, and 1B at least one R₁ₐ may be deuterium; or a plurality of R₁ₐ may be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

For example, in Formulae 1-1, 1A, and 1B, one, two, three, four, or five R₁ₐ may each be deuterium; or a plurality of R₁ₐ may be bonded to each other to form a cyclopentadiene group, a cyclohexadiene group, or a cycloheptadiene group, each unsubstituted or substituted with at least one R₁₀ₐ.

In an embodiment, in Formulae 1-1, 1A, and 1B, at least one R_{1c} may be a tert-butyl group, or a plurality of R_{1c} may be bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

For example, in Formulae 1-1, 1A, and 1B, one, two, three, four, or five R_{1c} may each be a tert-butyl group; or a plurality of R_{1c} may be bonded to each other to form a cyclopentadiene group, a cyclohexadiene group, or a cycloheptadiene group, each unsubstituted or substituted with at least one R₁₀ₐ.

In an embodiment, in Formulae 1, 1-1, 1-2, 1A, 1B, and 1C, a plurality of R₁ may not be directly bonded to each other; a plurality of R₂ may not be directly bonded to each other; a plurality of R₃ may not be directly bonded to each other; a plurality of R₄ may not be directly bonded to each other; a plurality of R_{1d} may not be directly bonded to each other; a plurality of R₁ₑ may not be directly bonded to each other; a plurality of R_{1f} may not be directly bonded to each other; R₁₁ and R₁₂ may not be directly bonded to each other; R₁₃ and R₁₄ may not be directly bonded to each other; R₁₄ and R₁₅ may not be directly bonded to each other; and R₁₅ and R₁₆ may not be directly bonded to each other.

An example of a compound in which a plurality of R₁ₐ in Formula 1-1 are bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ may include Compound BD23:

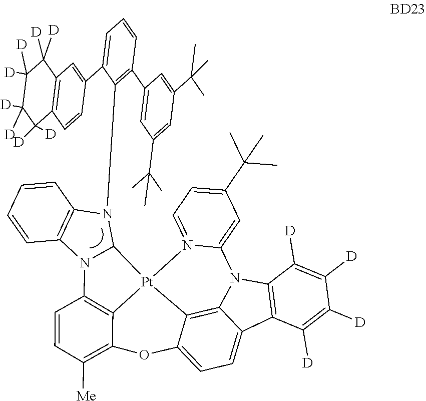

An example of a compound in which a plurality of R_{1c} in Formula 1-1 are bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ may include Compound BD21:

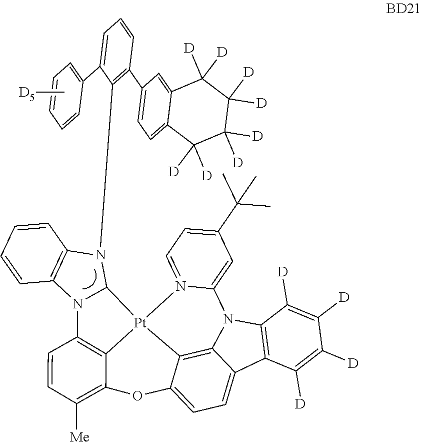

An example of a compound in which a plurality of R₁ₐ in Formula 1-1 are bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ, and in which a plurality of R_{1c} in Formula 1-1 are bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ may include Compound BD24:

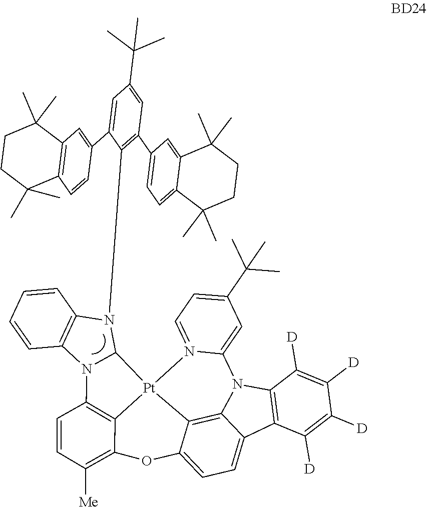

In an embodiment, in Formula 1A and 1B, a moiety represented by

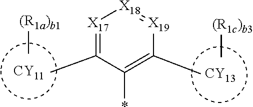

may be a moiety represented by Formula AS:

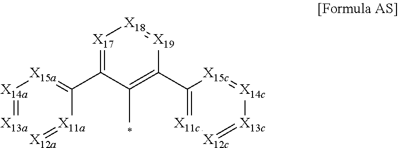

In Formula AS,
X₁₇, X₁₈, and X₁₉ may each be the same as defined in Formulae 1A and 1B,
X₁₁ₐ may be N or C(R₁₁ₐ), X₁₂ₐ may be N or C(R₁₂ₐ), X₁₃ₐ may be N or C(R₁₃ₐ), X₁₄ₐ may be N or C(R₁₄ₐ), X₁₅a may be N or C(R₁₅ₐ), X_{11c} may be N or C(R_{11c}), X_{12c} may be N or C(R_{12c}), X_{13c} may be N or C(R_{13c}), X_{14c} may be N or C(R_{14c}), and X_{15c} may be N or C(R_{15c}),
R₁₁ₐ to R₁₅ₐ may each independently be the same as described in connection with R₁ₐ in Formula 1-1,
R_{11c} to R_{15c} may each independently be the same as described in connection with R_{1c} in Formula 1-1,
R₁₁ₐ and R₁₂ₐ, R₁₂ₐ and R₁₃ₐ, R₁₃ₐ and R₁₄ₐ, and R₁₄ₐ and R₁₅ₐ may each be optionally bonded to each other to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
R_{11c} and R_{12c}, R_{12c} and R_{13c}, R_{13c} and R_{14c}, and R_{14c} and R_{15c} may each be optionally bonded to each other to form a C₃-C₆₀ carbocyclic group that is unsubstituted or substituted with at least one R₁₀ₐ or a C₁-C₆₀ heterocyclic group that is unsubstituted or substituted with at least one R₁₀ₐ, and
* indicates a binding site to ring CY₁ in Formula 1.

In an embodiment, a moiety represented by Formula AS may be a moiety represented by Formula AS1:

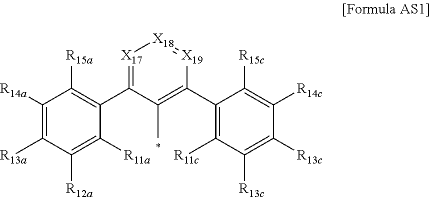

In Formula AS1,
X₁₇, X₁₈, and X₁₉ may each be the same as defined in Formulae 1A and 1B,
R₁₁ₐ to R₁₅ₐ may each independently be the same as described in connection with R₁ₐ in Formula 1-1,
R_{11c} to R_{15c} may each independently be the same as described in connection with R_{1c} in Formula 1-1,
R₁₃ₐ and R₁₄ₐ may be optionally bonded to each other to form a C₂-C₈ monocyclic group that is unsubstituted or substituted with at least one R₁₀ₐ, and
R_{13c} and R_{14c} may be optionally bonded to each other to form a C₂-C₈ monocyclic group that is unsubstituted or substituted with at least one R₁₀ₐ.

In an embodiment, in Formula AS1, R₁₃ₐ, R₁₄ₐ, R_{12c}, R_{13c}, and R_{14c} may each independently be a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, or any combination thereof.

In an embodiment, in Formula AS1, at least one of R₁₁ₐ to R₁₅ₐ may each independently be deuterium or a C₁-C₆₀ alkyl group that is substituted with deuterium, and at least one of R_{11c} to R_{15c} may be a tert-butyl group.

In an embodiment, in Formula 1C,
X₁₃ₑ may be C(R₁₃ₑ), and R₁₃ₑ may be a phenyl group that is substituted with at least one of deuterium and a tert-butyl group;
X_{14f} may be C(R_{14f}), and R_{14f} may be a phenyl group that is substituted with at least one of deuterium and a tert-butyl group; or
X₁₃ₑ may be C(R₁₃ₑ), X_{14f} may be C(R_{14f}), and R₁₃ₑ and R_{14f} may each independently be a phenyl group that is substituted with at least one of deuterium and a tert-butyl group.

For example, R₁₃ₑ and R_{14f} may each independently be a group represented by

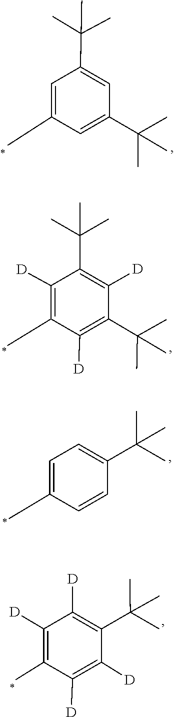

wherein * indicates a binding site to a neighboring atom.

In an embodiment, ring CY₂ may be a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinaphthofuran group, an azadinaphthothiophene group, an azadibenzocarbazole group, an azadibenzofluorene group, or an azadinaphthosilole group.

In an embodiment, in Formula 1, a moiety represented by

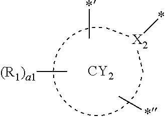

may be a moiety represented by Formula 2-1:

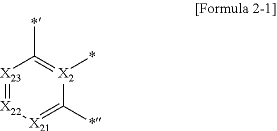

In Formula 2-1,
X₂₁ may be N or C(R₂₁), X₂₂ may be N or C(R₂₂), X₂₃ may be N or C(R₂₃), and X₂ is the same as defined in Formula 1,
R₂₁ to R₂₃ may each independently be the same as described in connection with R₂ in Formula 1,
at least one of R₂₁ and R₂₂ may each independently be deuterium, a methyl group, an ethyl group, a propyl group, a methyl group that is substituted with at least one deuterium, an ethyl group that is substituted with at least one deuterium, or a propyl group that is substituted with at least one deuterium,
* indicates a binding site to M in Formula 1,
*′ indicates a binding site to ring CY₁ in Formula 1, and
*″ indicates a binding site to T₁ in Formula 1.

In an embodiment, in Formula 1, ring CY₃ may be:
a C₂-C₈ monocyclic group; or
a C₄-C₂₀ polycyclic group in which two or three C₂-C₈ monocyclic groups are condensed with each other.

In an embodiment, in Formula 1, ring CY₃ may be a benzene group, a pyridine group, a pyrimidine group, a naphthalene group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

In an embodiment, in Formula 1, a moiety represented by

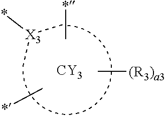

may be a moiety represented by one of Formulae 3A to 3F:

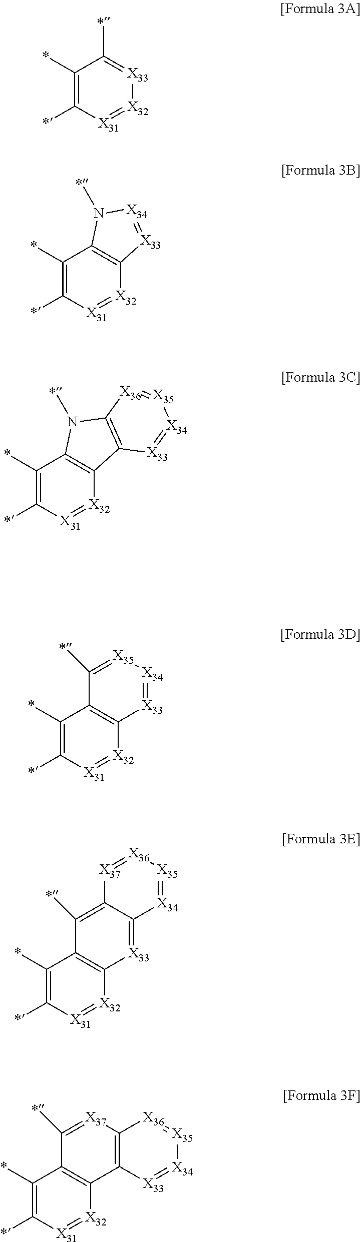

In Formulae 3A to 3F,
X₃₁ may be N or C(R₃₁), X₃₂ may be N or C(R₃₂), X₃₃ may be N or C(R₃₃), X₃₄ may be N or C(R₃₄), X₃₅ may be N or C(R₃₅), X₃₆ may be N or C(R₃₆), and X₃₇ may be N or C(R₃₇),
R₃₁ to R₃₇ may each independently be the same as described in connection with R₃ in Formula 1,
* indicates a binding site to M in Formula 1,
*′ indicates a binding site to T₁ in Formula 1, and
*″ indicates a binding site to ring CY₄ in Formula 1.

In an embodiment, in Formulae 3A to 3F, at least one of X₃₁ to X₃₇ may each be N.

In an embodiment, in Formula 3A to 3F, at least one of R₃₁ to R₃₇ may be deuterium.

In an embodiment, in Formula 1, ring CY₄ may be a benzene group, a pyridine group, a pyrimidine group, a naphthalene group, a dibenzofuran group, a dibenzothiophene group, a carbazole group, a fluorene group, a dibenzosilole group, an azadibenzofuran group, an azadibenzothiophene group, an azacarbazole group, an azafluorene group, or an azadibenzosilole group.

In an embodiment, in Formula 1, a moiety represented by

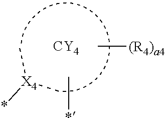

may be a moiety represented by Formula 4-1:

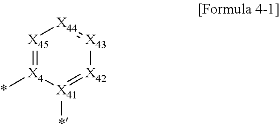

In Formula 4-1,
X₄₁ may be N or C, X₄₂ may be N or C(R₄₂), X₄₃ may be N or C(R₄₃), X₄₄ may be N or C(R₄₄), and X₄₅ may be N or C(R₄₅),
R₄₂ to R₄₅ may each independently be the same as described in connection with R₄ in Formula 1, and X₄ is the same as defined in Formula 1,
* indicates a binding site to M in Formula 1, and
*′ indicates a binding site to ring CY₃ in Formula 1.

In an embodiment, in Formula 4-1, at least one of R₄₂ to R₄₅ may each independently be a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, or any combination thereof. For example, R₄₃ may be a tert-butyl group.

In an embodiment, the organometallic compound represented by Formula 1 may satisfy Condition B-1:
[Condition B-1]
in Formula 1, at least one of R₂ in the number of a2 may each independently be deuterium, a methyl group, an ethyl group, a propyl group, a methyl group that is substituted with at least one deuterium, an ethyl group that is substituted with at least one deuterium, or a propyl group that is substituted with at least one deuterium.

In an embodiment, the organometallic compound represented by Formula 1 may satisfy Condition B-2:
[Condition B-2]
in Formula 1, at least one of R₂ in the number of a2 may each independently be deuterium, a methyl group, an ethyl group, a methyl group that is substituted with at least one deuterium, or an ethyl group that is substituted with at least one deuterium.

In an embodiment, the organometallic compound represented by Formula 1 may satisfy Condition B-3:
[Condition B-3]
in Formula 1, at least one of R₂ in the number of a2 may each independently be —CH₃, —CH₂D, —CHD₂, or —CD₃.

Conditions B-1, B-2, and B-3 may be satisfied for the organometallic compound represented by Formula 1 corresponding to an embodiment where, in Condition A, a moiety represented by

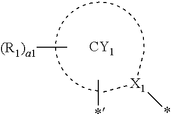

in Formula 1 may be a moiety represented by Formula 1-1.

In an embodiment, the organometallic compound represented by Formula 1 may include at least one deuterium atom.

In an embodiment, the organometallic compound represented by Formula 1 may satisfy both Conditions A and B. For example, the organometallic compound represented by Formula 1 is clearly different from a compound that does not satisfy any of Conditions A and B, satisfies Condition A and does not satisfy Condition B, or does not satisfy Condition A and satisfies Condition B.

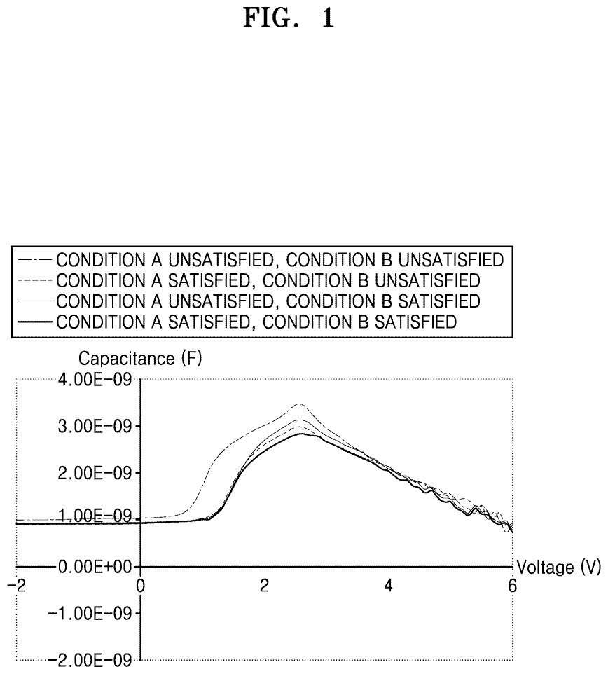

FIG. 1 is a graph showing the results of measuring an amount of charge (for example, a corresponding capacitance thereto) of a light-emitting device including an organometallic compound according to the structure of the organometallic compound.

Referring to FIG. 1, when measuring capacitance by applying a voltage to a light-emitting device (for example, including the second compound to the fourth compound) including a blue phosphorescent dopant (or sensitizer) that does not satisfy both Conditions A and B, injection of holes may be relatively fast in a low-voltage region. As a result, a hump may occur in the low-voltage region, resulting in an increase in the capacitance and the amount of charge. In this regard, the amount of charge may be calculated according to Equation 1 of Evaluation Example 1 to be described below. When the capacitance and the amount of charge increase, RC delay may occur at high scanning rates.

Therefore, in order to provide a light-emitting device having low capacitance and a low amount of charge, a condition in which there is an increase in a negative giant surface potential (negative GSP) effect that slows down injection of holes increases may be considered. Negative GSP may move a region where a hump occurs to a high voltage region by slowing down injection of holes, and may lower the maximum value of capacitance (Cₘₐₓ).

Referring to FIG. 1, when measuring capacitance by applying a voltage to a light-emitting device (for example, including the second compound to the fourth compound) including a blue phosphorescent dopant (or sensitizer) that satisfies Condition A and does not satisfy Condition B, or including a blue phosphorescent dopant (or sensitizer) that does not satisfy Condition A and satisfies Condition B, the negative GSP effect may occur.

As the blue phosphorescent dopant (or sensitizer), the light-emitting device (for example, including the second compound to the fourth compound) including the organometallic compound represented by Formula 1 that satisfies both Conditions A and B exhibits a large negative GSP effect, which not only moves the region where the hump occurs to a high voltage region, but also may effectively lower the maximum value of capacitance (Cₘₐₓ). Therefore, the organometallic compound represented by Formula 1 that satisfies both Conditions A and B may improve both the capacitance and amount of charge of the light-emitting device. As a result, the possibility of RC delay in an electronic apparatus including the light-emitting device may be effectively reduced, thereby improving display quality. For example, embodiments may determine conditions of the structure of a blue phosphorescent dopant (or sensitizer) for improving the capacitance and amount of charge of a light-emitting device.

### Examples of Compounds

In an embodiment, the organometallic compound represented by Formula 1 may be one of Compounds BD1 to BD27.

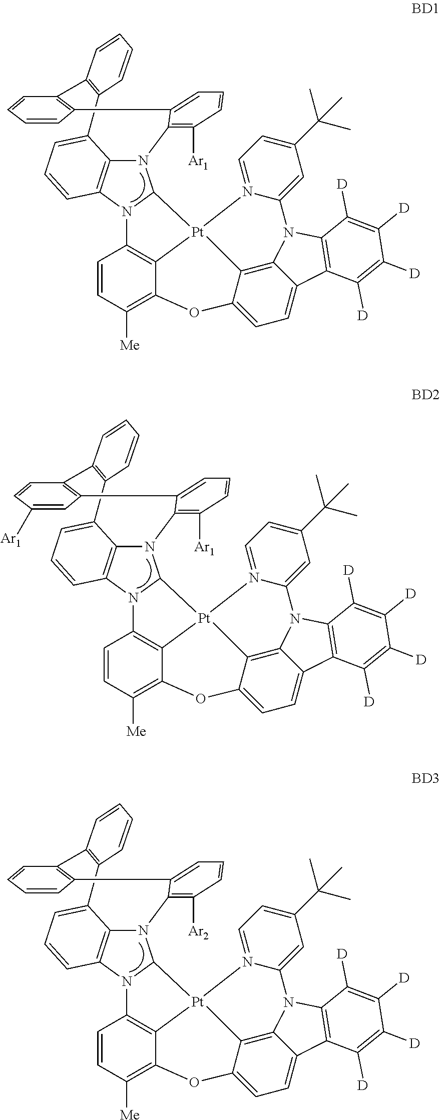

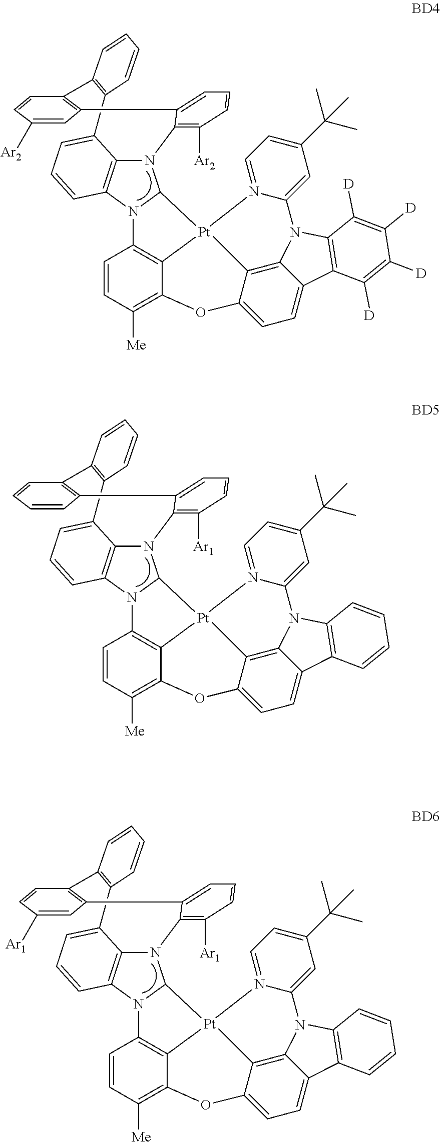

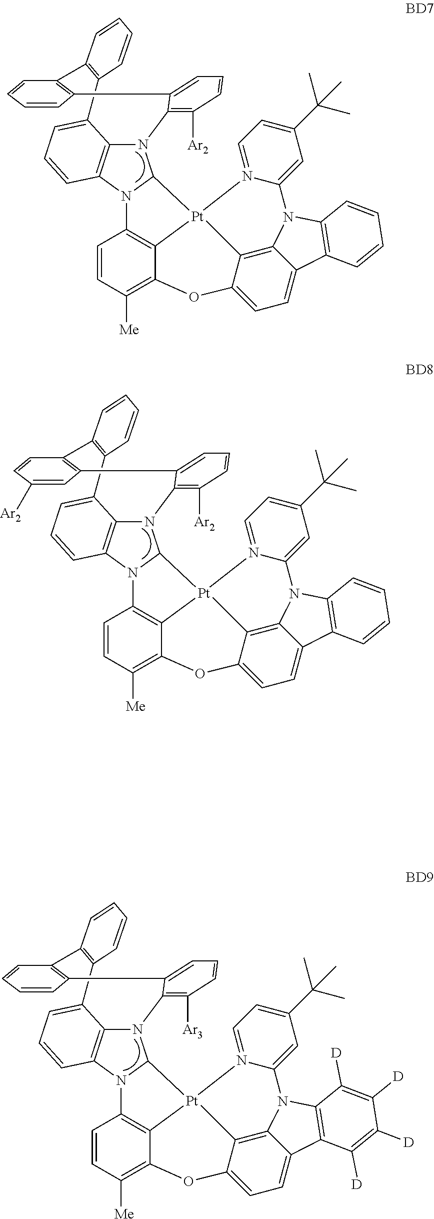

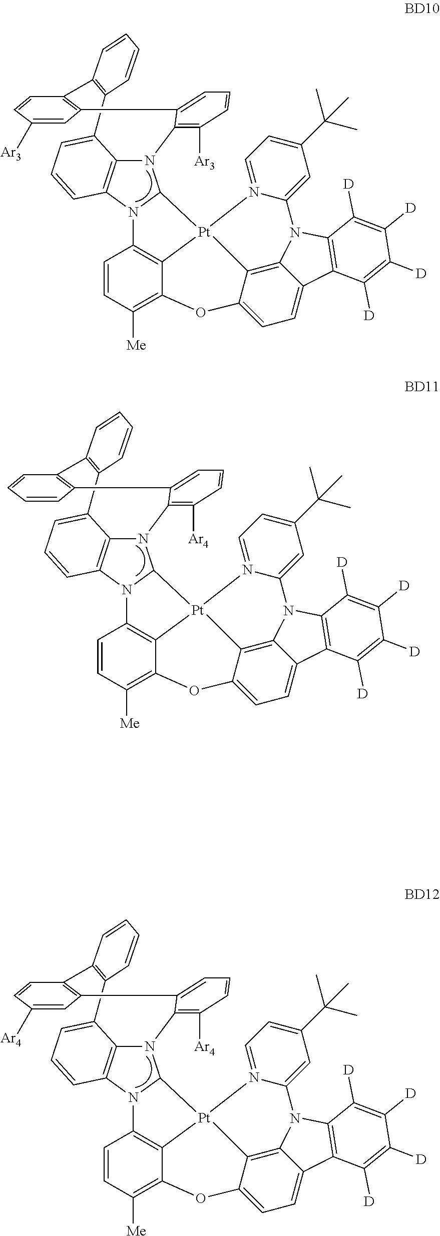

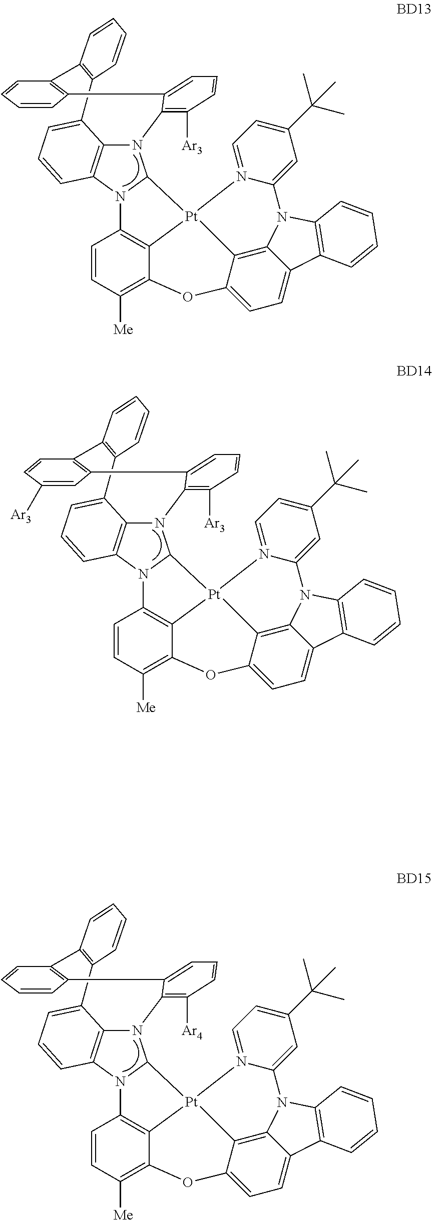

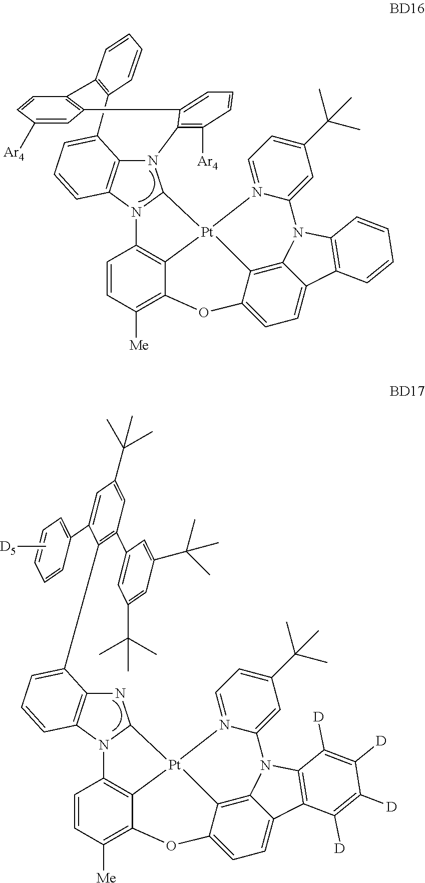

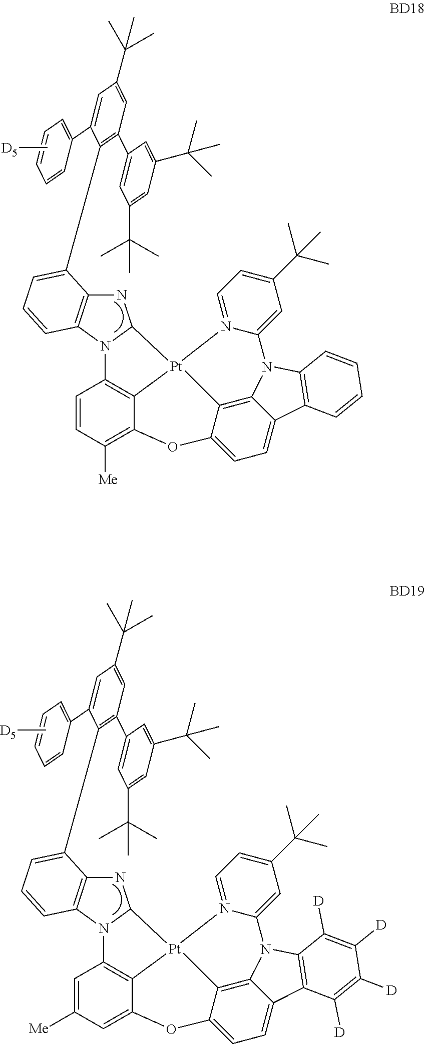

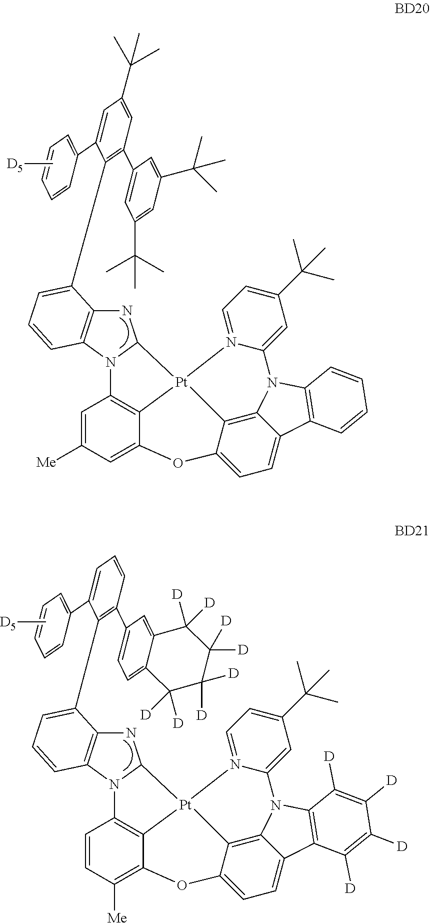

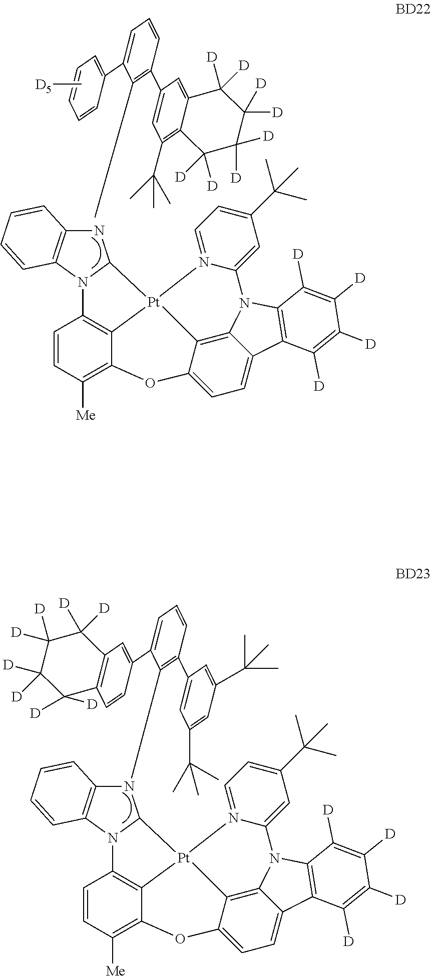

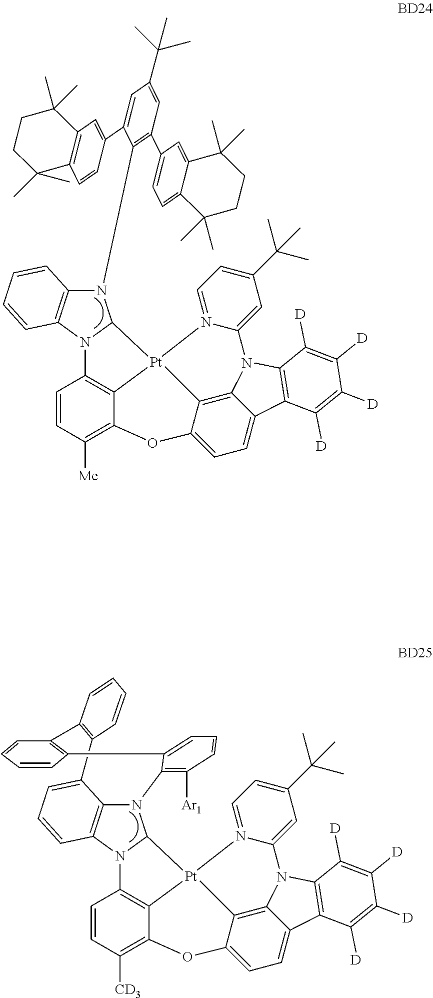

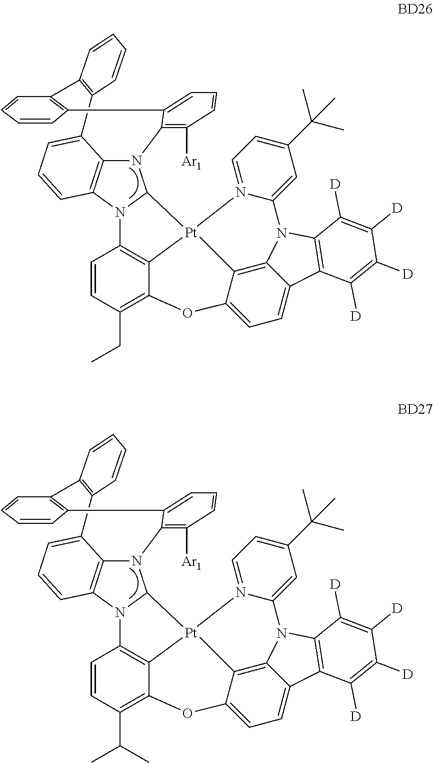

In Compounds BD1 to BD16 and BD25 to BD27,

Ar₁ may be a group represented by

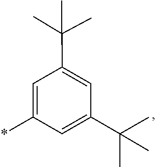 [SMILES: *c1cc(C(C)(C)C)cc(C(C)(C)C)c1]

Ar₂ may be a group represented by

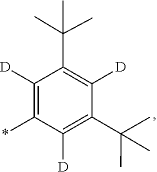 [SMILES: *c1c([2H])c(C(C)(C)C)c([2H])c(C(C)(C)C)c1[2H]]

Ar₃ may be a group represented by

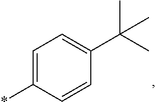 [SMILES: *c1ccc(C(C)(C)C)cc1]

Ar₄ may be a group represented by

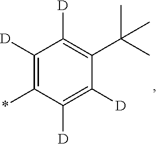 [SMILES: *c1c([2H])c([2H])c(C(C)(C)C)c([2H])c1[2H]]

and
* in Ar₁ to Ar₄ indicates a binding site to a neighboring atom.

In an embodiment, the second compound may be one of Compounds ETH1 to ETH 100.

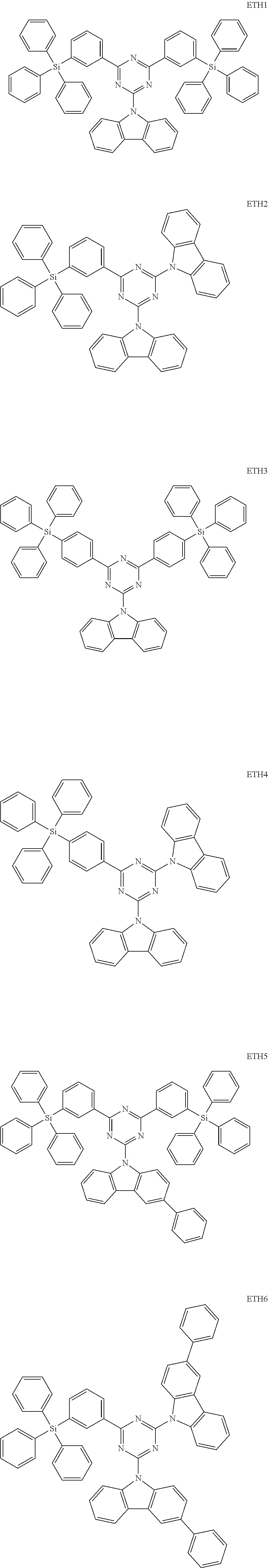

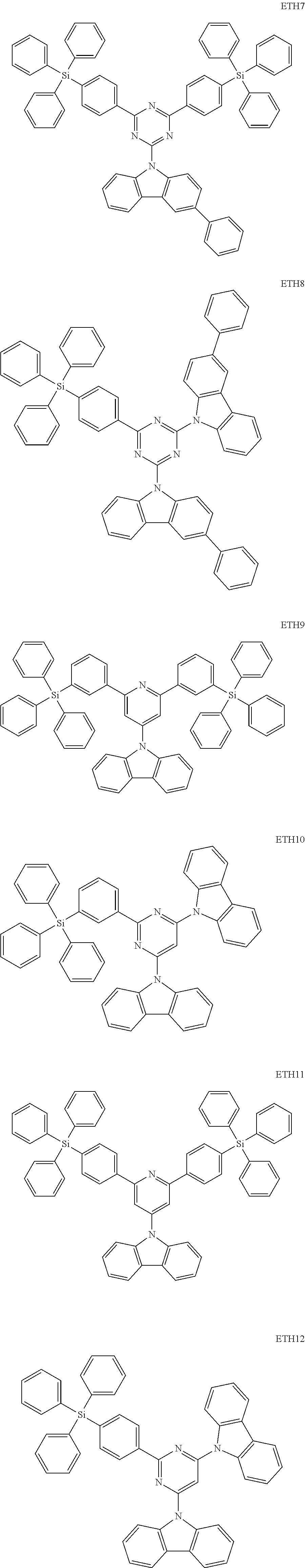

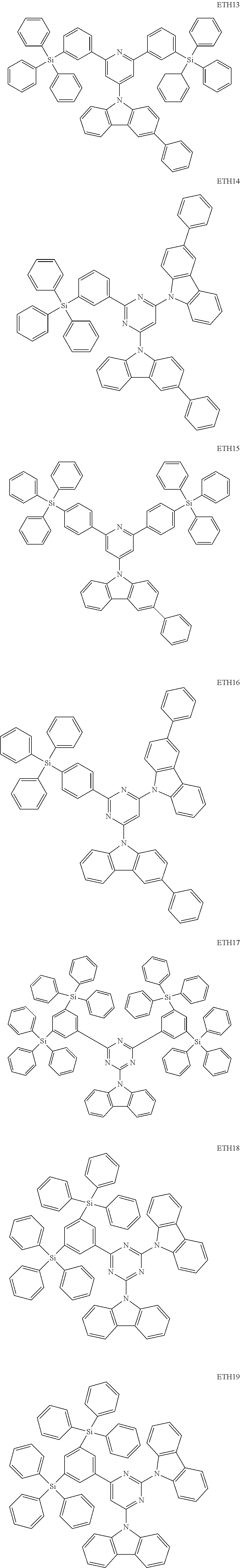

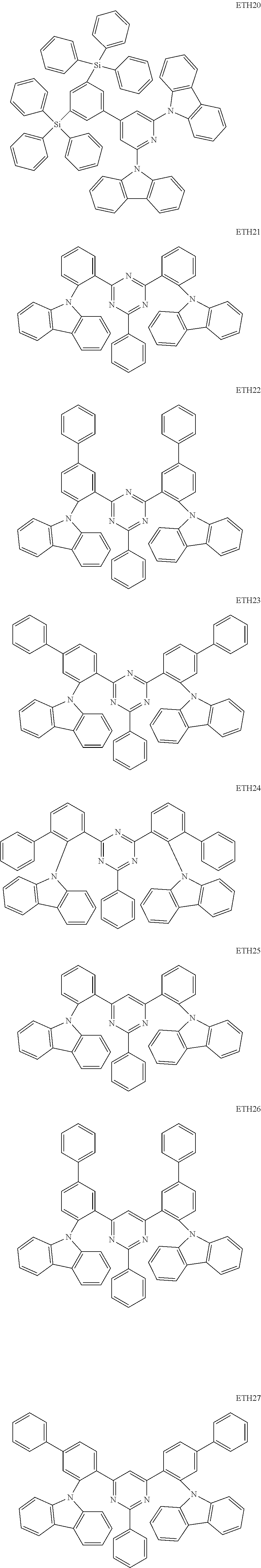

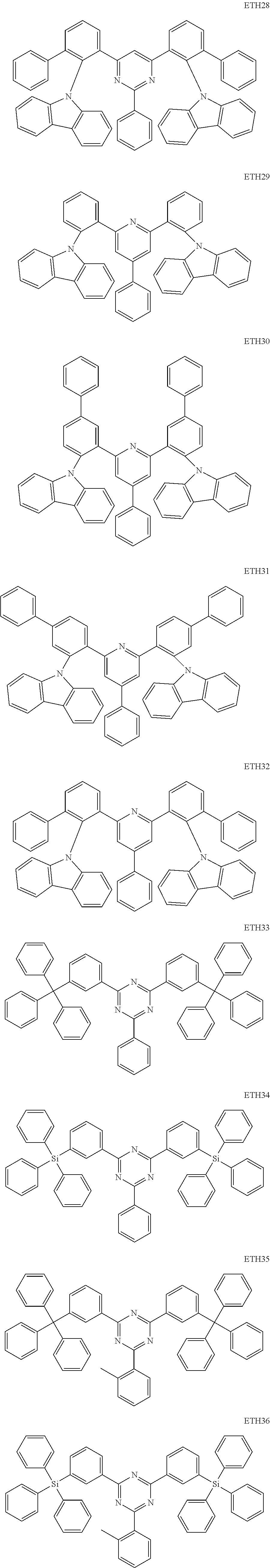

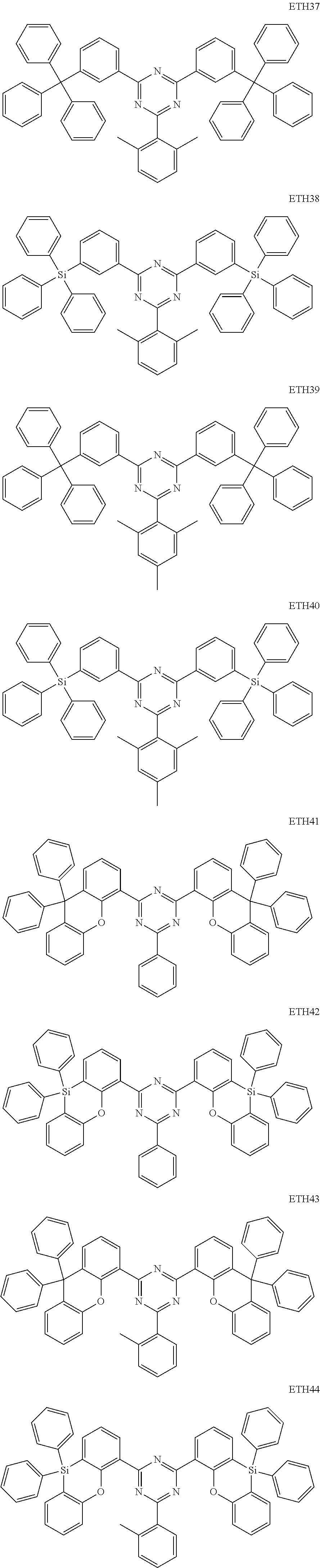

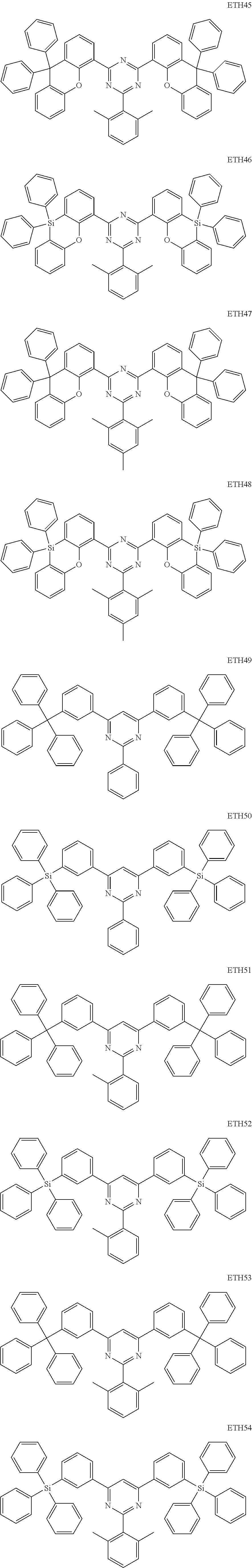

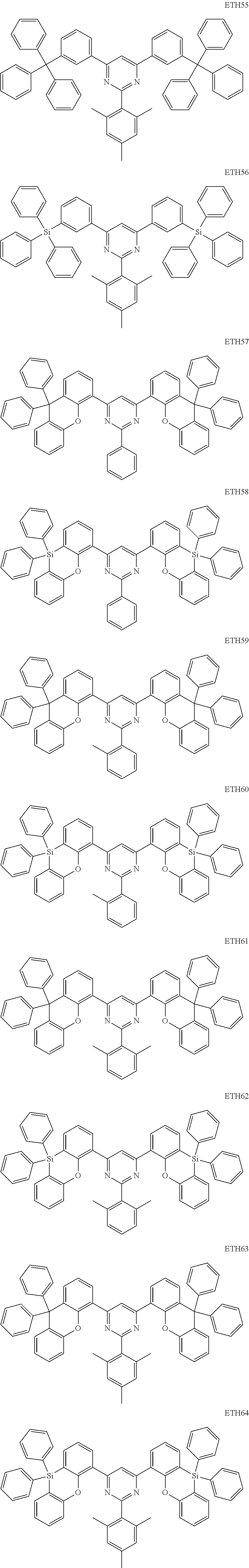

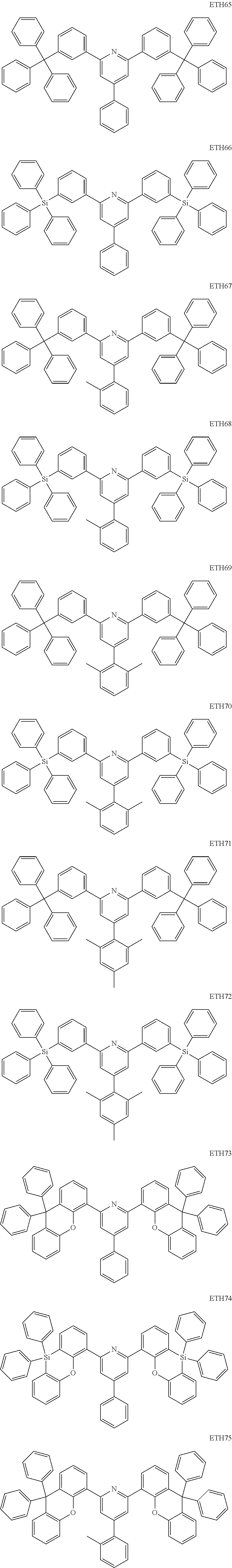

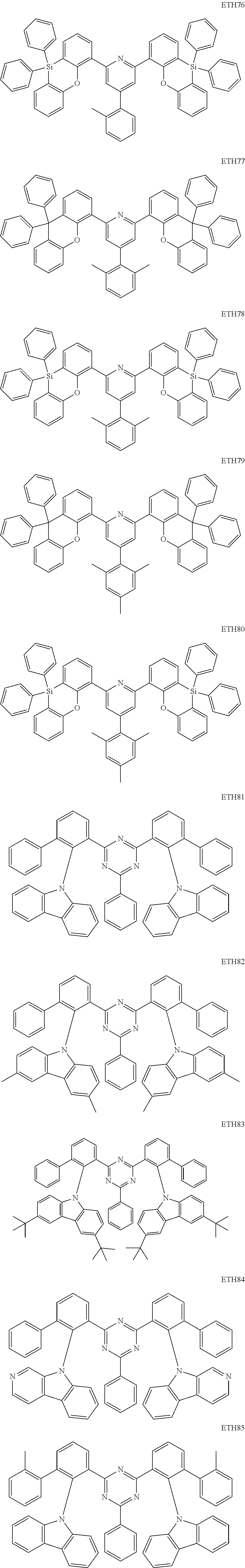

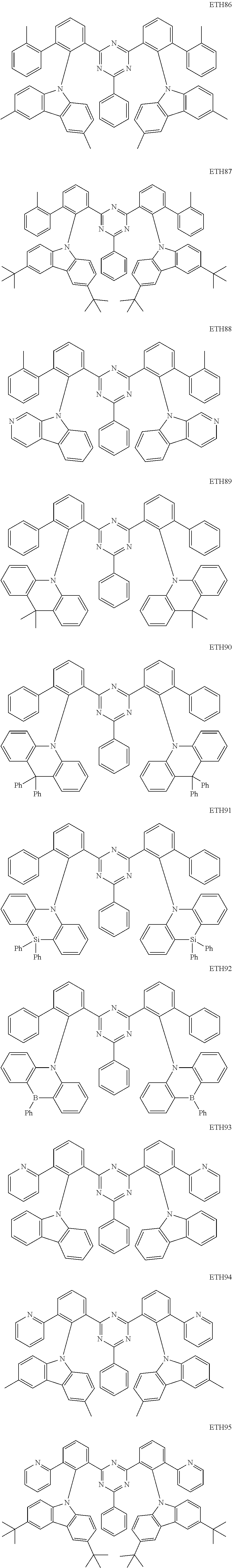

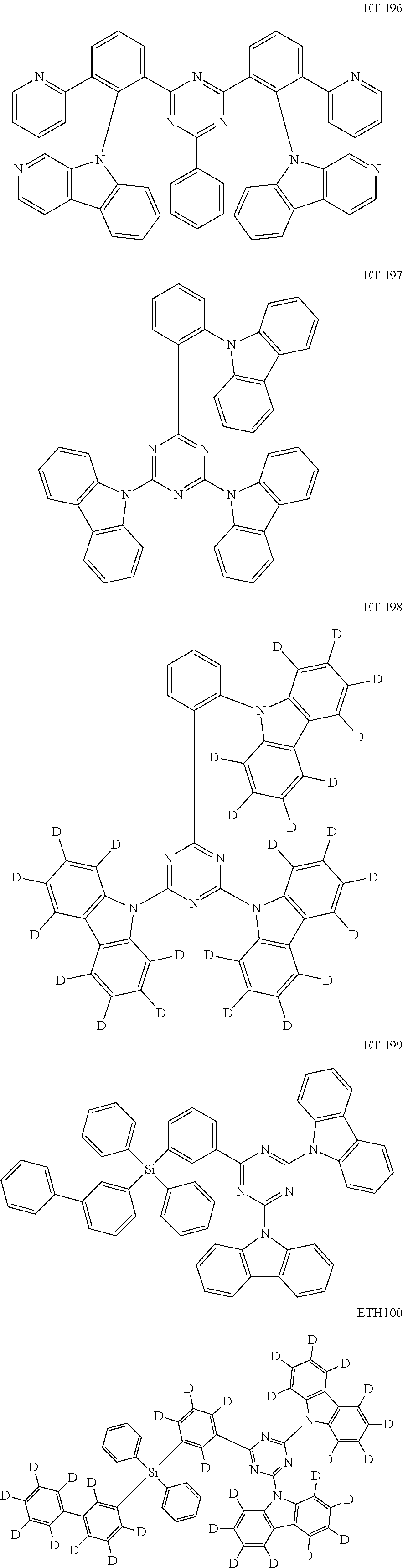

In an embodiment, the third compound may be one of Compounds HTH1 to HTH46.

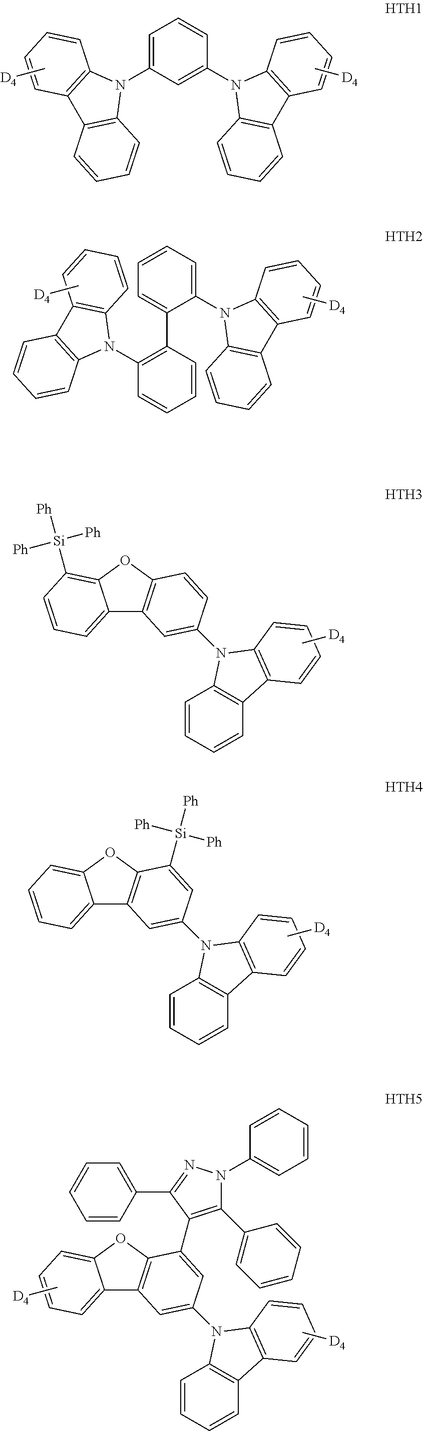

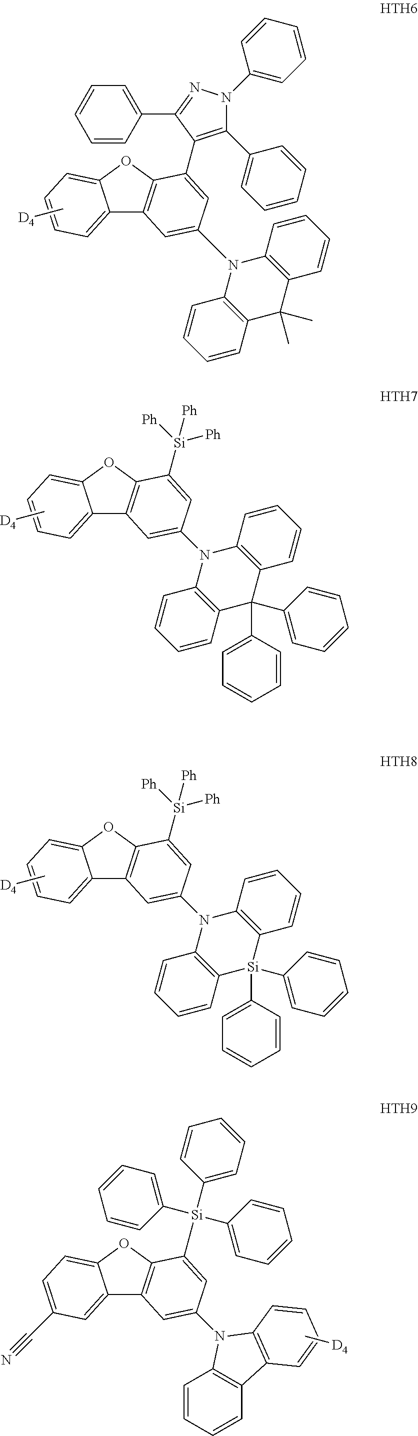

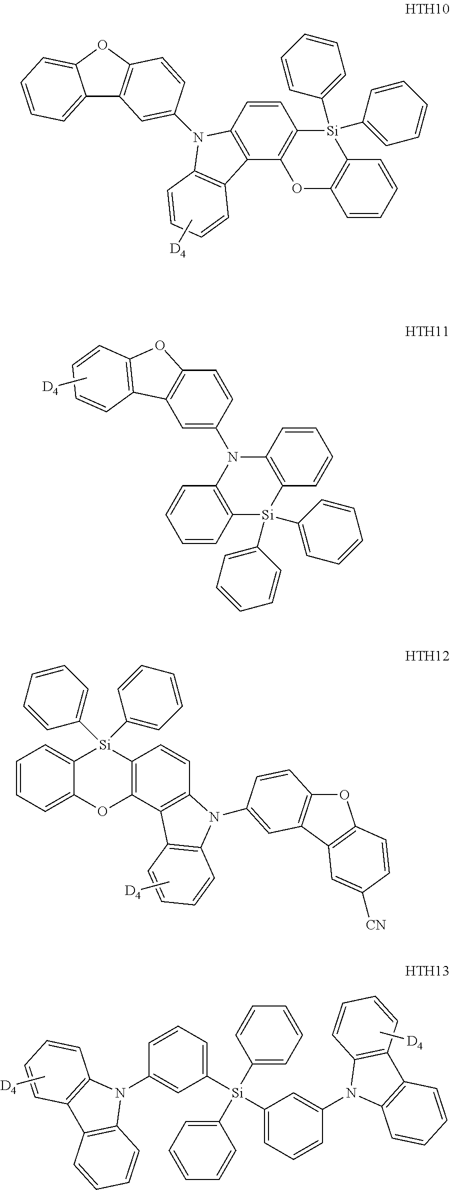

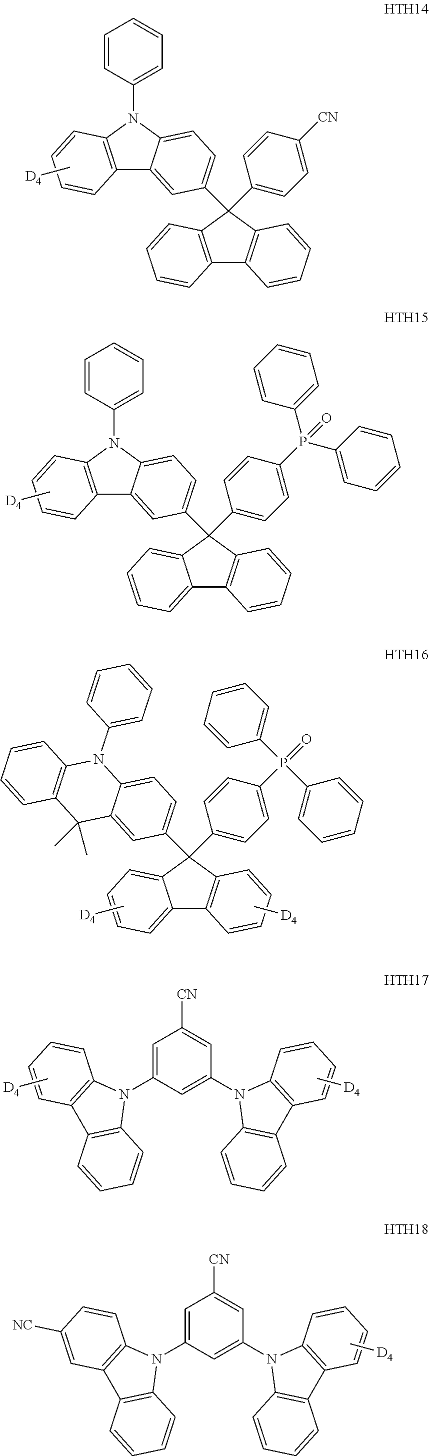

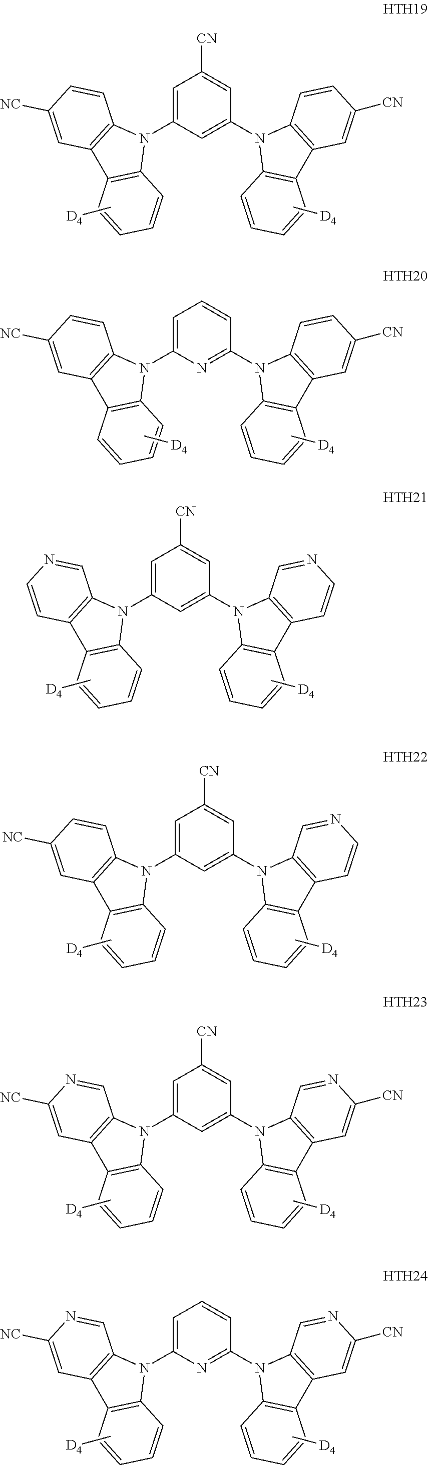

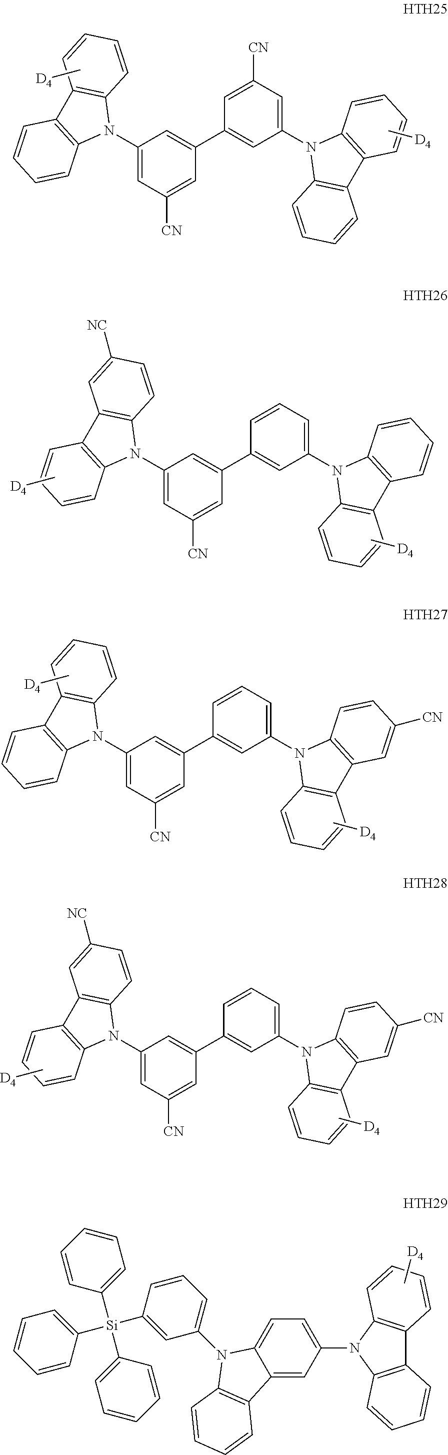

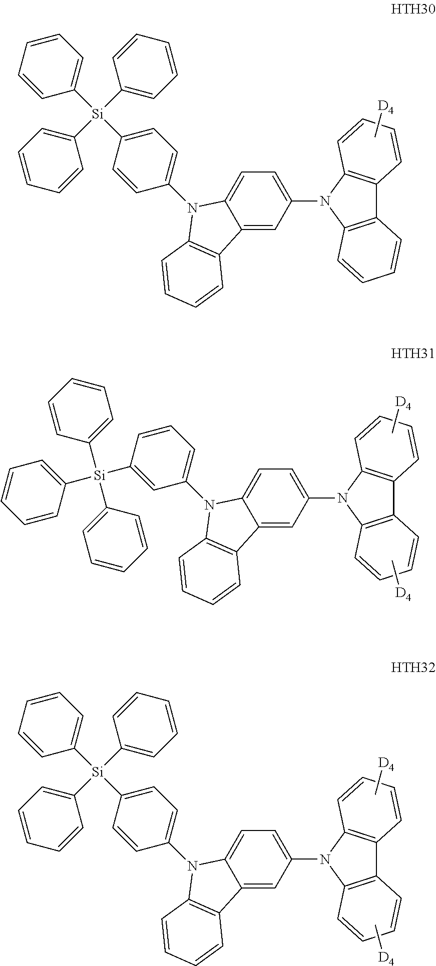

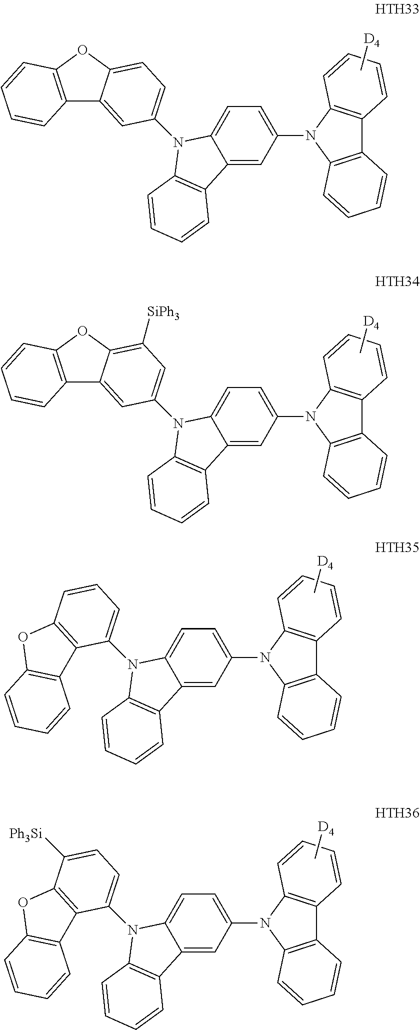

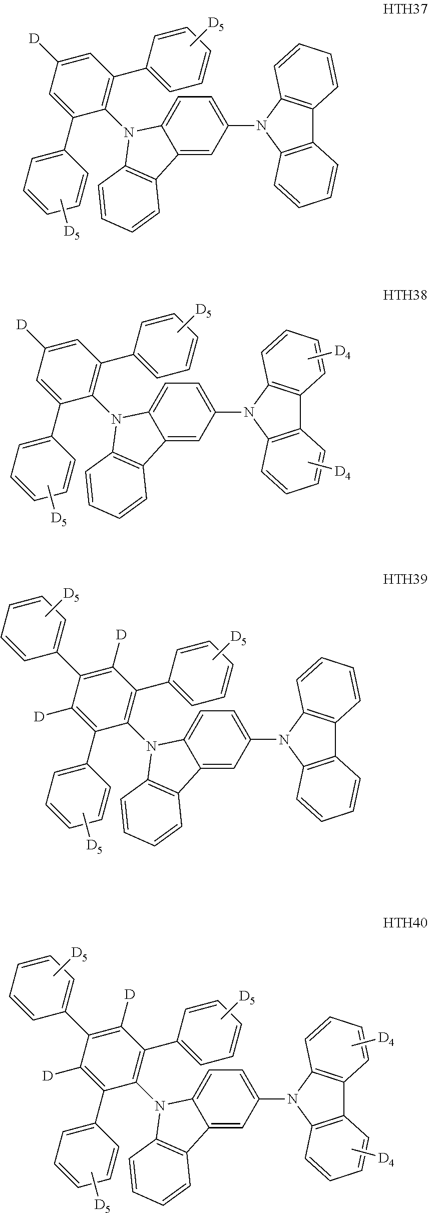

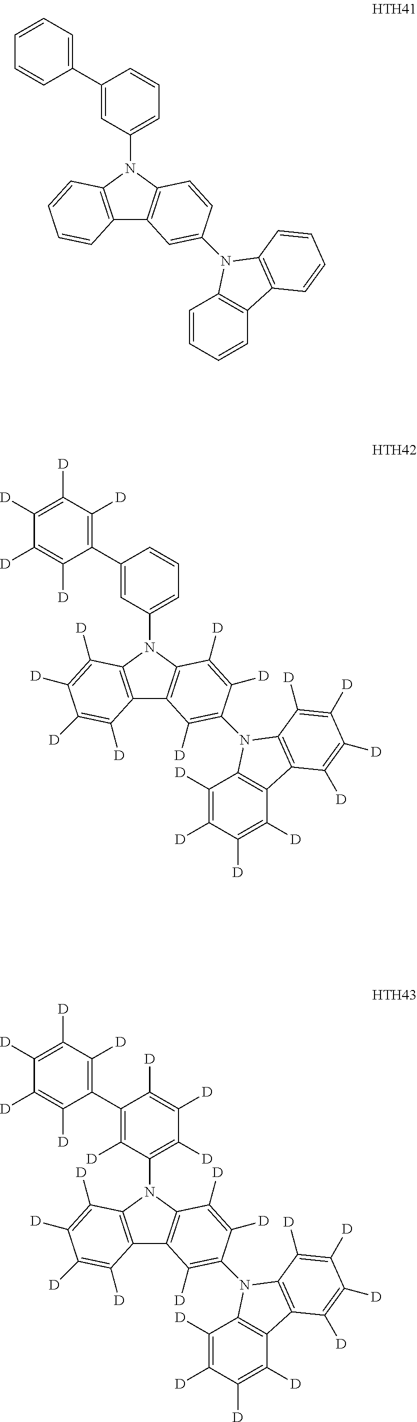 [SMILES: c1ccc(-c2cccc(-n3c4ccccc4c4cc(-n5c6ccccc6c6ccccc65)ccc43)c2)cc1 ; [2H]c1c([2H])c([2H])c(-c2cccc(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2)c([2H])c1[2H] ; [2H]c1c([2H])c([2H])c(-c2c([2H])c([2H])c([2H])c(-n3c4c([2H])c([2H])c([2H])c([2H])c4c4c([2H])c(-n5c6c([2H])c([2H])c([2H])c([2H])c6c6c([2H])c([2H])c([2H])c([2H])c65)c([2H])c([2H])c43)c2[2H])c([2H])c1[2H]]

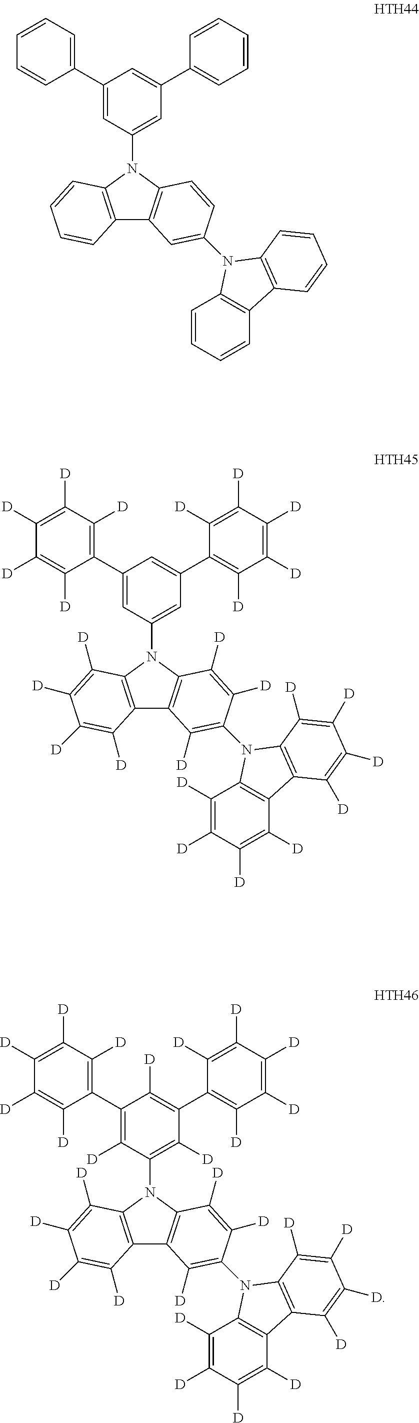

In an embodiment, the fourth compound may be one of Compounds DFD1 to DFD30.

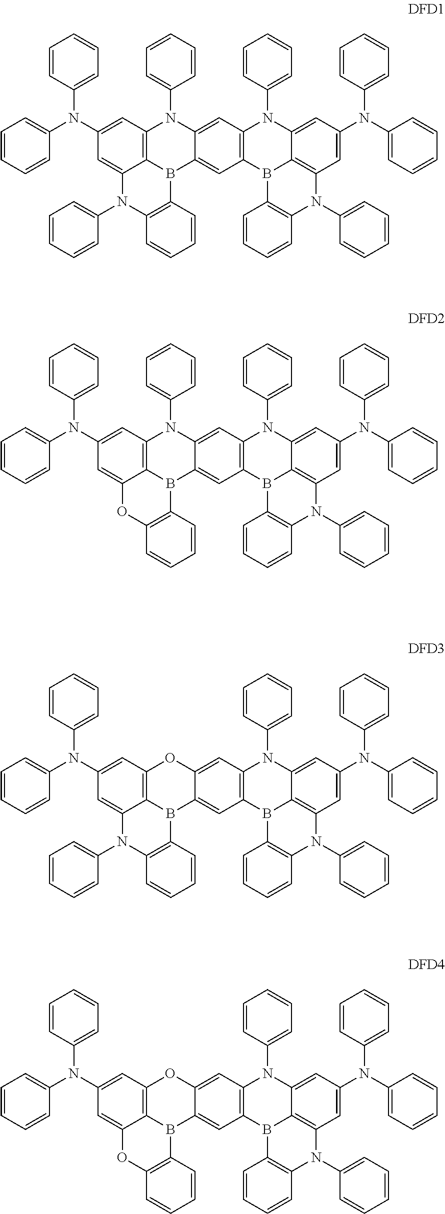

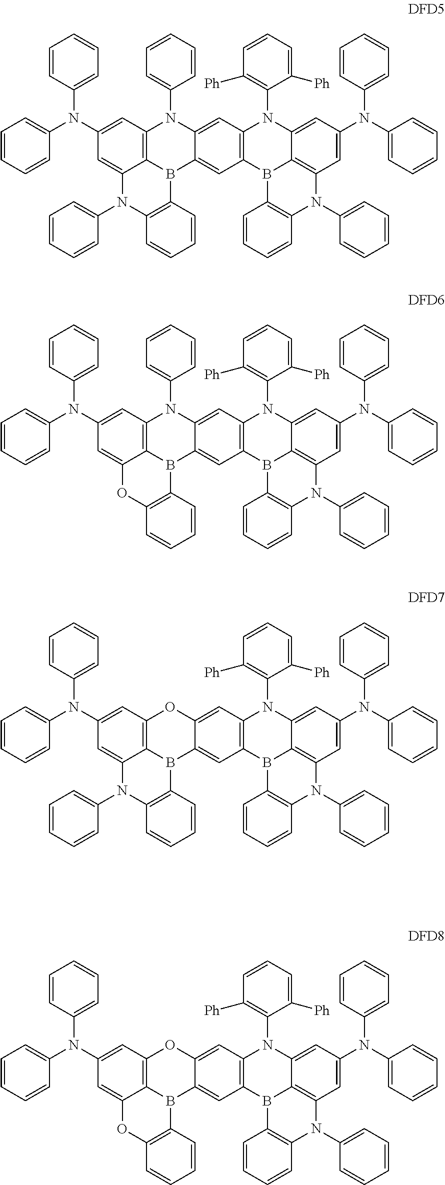

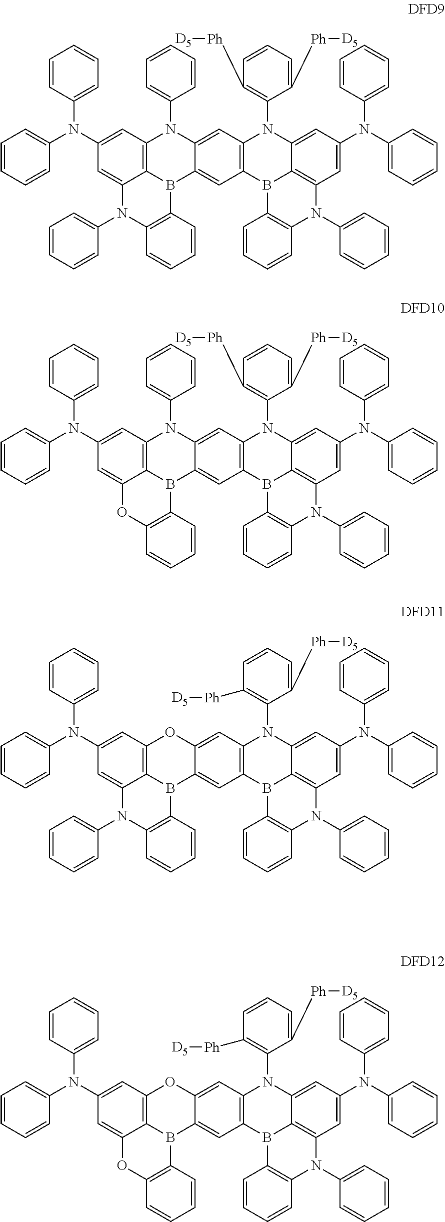

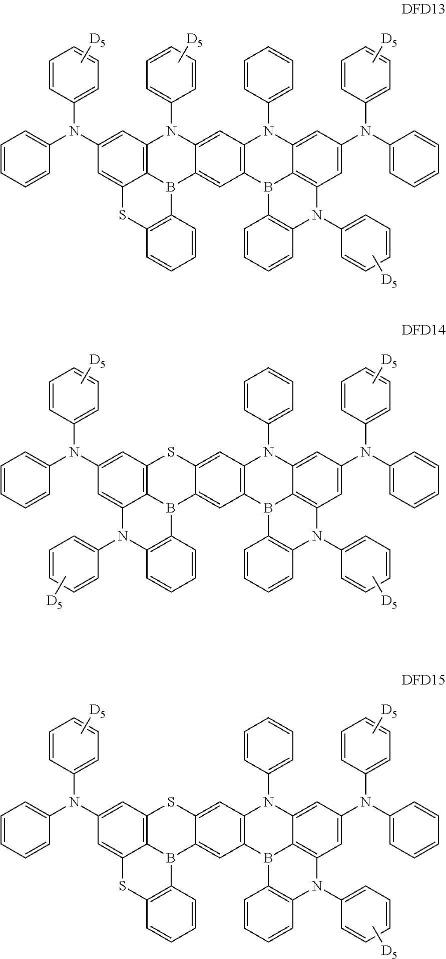

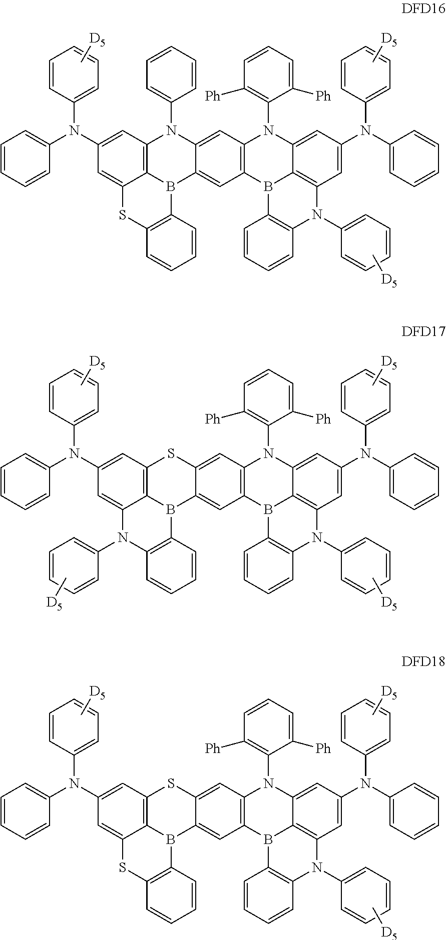

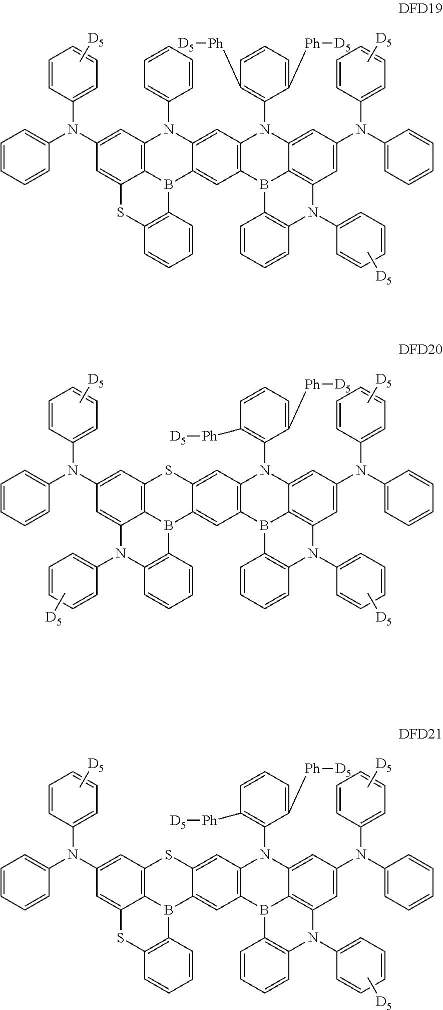

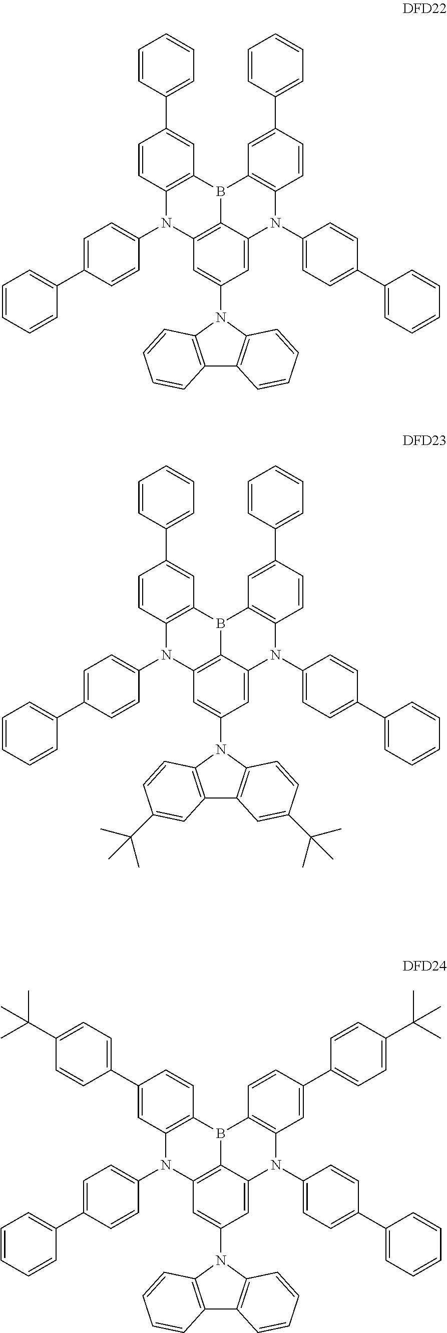 [SMILES: c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1 ; CC(C)(C)c1ccc2c(c1)c1cc(C(C)(C)C)ccc1n2-c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; CC(C)(C)c1ccc(-c2ccc3c(c2)N(c2ccc(-c4ccccc4)cc2)c2cc(-n4c5ccccc5c5ccccc54)cc4c2B3c2ccc(-c3ccc(C(C)(C)C)cc3)cc2N4c2ccc(-c3ccccc3)cc2)cc1]

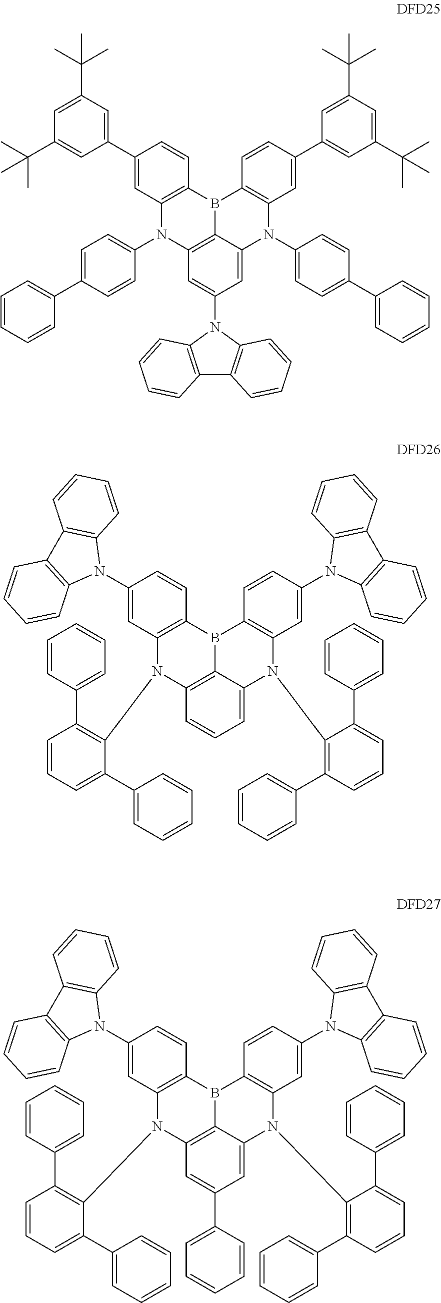 [SMILES: CC(C)(C)c1cc(-c2ccc3c(c2)N(c2ccc(-c4ccccc4)cc2)c2cc(-n4c5ccccc5c5ccccc54)cc4c2B3c2ccc(-c3cc(C(C)(C)C)cc(C(C)(C)C)c3)cc2N4c2ccc(-c3ccccc3)cc2)cc(C(C)(C)C)c1 ; c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cccc2c43)cc1 ; c1ccc(-c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)cc1]

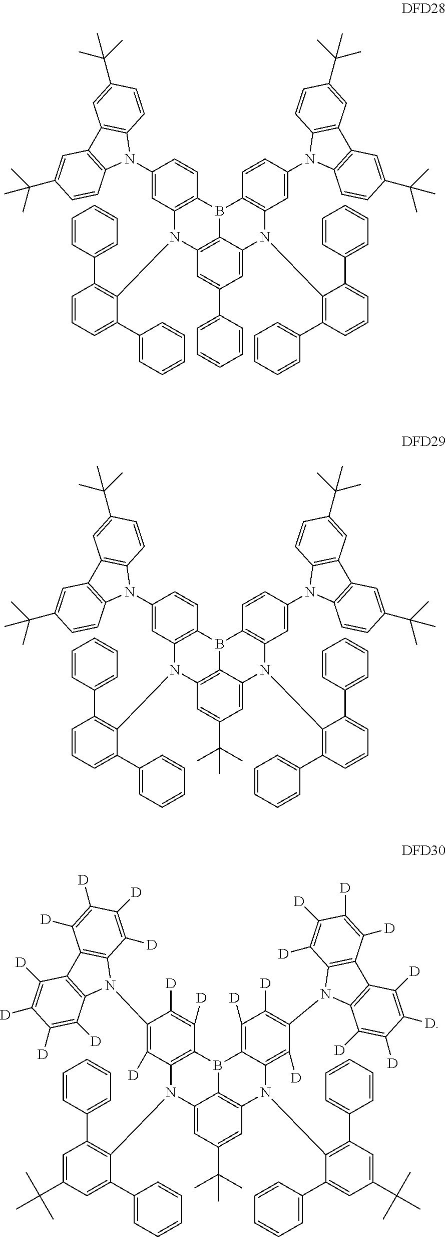

In Compounds ETH1 to ETH100, HTH1 to HTH46, and DFD1 to DFD30, Me represents a methyl group, Ph represents a phenyl group, D represents deuterium, D₄ represents substitution with four deuterium atoms, and D₅ represents substitution with five deuterium atoms. For example, a group represented by -Ph-D₅ and a group represented by

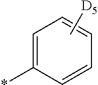

may each be identical to a group represented by

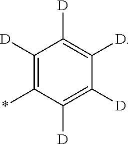

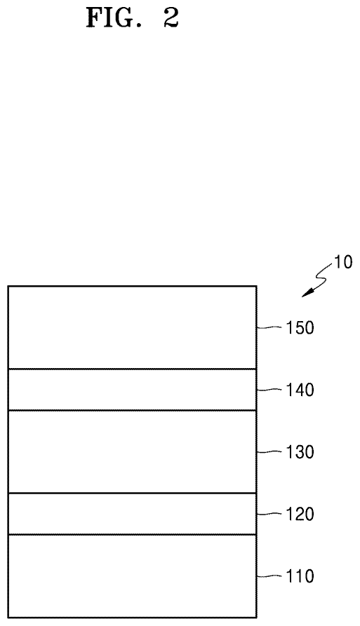

### [Description of FIG. 2]

FIG. 2 is a schematic cross-sectional view of a light-emitting device 10 according to an embodiment. The light-emitting device 10 may include a first electrode 110, an interlayer, and a second electrode 150. The interlayer may include a hole transport region 120, an emission layer 130, and an electron transport region 140.

Hereinafter, the structure and manufacturing method of the light-emitting device 10 according to an embodiment are described with reference to FIG. 2.

### [First Electrode 110]

In FIG. 2, a substrate may be further included under the first electrode 110 or on the second electrode 150. In an embodiment, the substrate may be a glass substrate or a plastic substrate. In an embodiment, the substrate may be a flexible substrate. For example, the substrate may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by depositing or sputtering a material for forming the first electrode 110 on the substrate. When the first electrode 110 is an anode, a high-work function material that facilitates injection of holes may be used as a material for forming the first electrode 110.

The first electrode 110 may be a reflective electrode, a semi-transmissive electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. When the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a structure consisting of a single layer or a structure including multiple layers. In an embodiment, the first electrode 110 may have a three-layer structure of ITO/Ag/ITO.

### [Interlayer]

The interlayer may be disposed above the first electrode 110. The interlayer may include the hole transport region 120, the emission layer 130, and the electron transport region 140.

The interlayer may include various organic materials, a metal-containing compound such as an organometallic compound, an inorganic material such as quantum dots, etc.

In an embodiment, the interlayer may include at least two emitting units stacked between the first electrode 110 and the second electrode 150 and at least one charge generation layer between adjacent units among the two or more emitting units. When the interlayer includes the at least two emitting units and the at least one charge generation layer as described above, the light-emitting device 10 may be a tandem light-emitting device.

### [Hole Transport Region 120]

The hole transport region 120 may have a structure consisting of a layer consisting of a single material, a structure consisting of a layer including different materials, or a structure including multiple layers including different materials.

The hole transport region 120 may include a hole injection layer, a hole transport layer, an emission auxiliary layer, an electron blocking layer, or any combination thereof.

In an embodiment, the hole transport region 120 may have a multilayer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the layers of each structure may be stacked from the first electrode 110 in its respective stated order, but the structure of the hole transport region 120 is not limited thereto.

In an embodiment, the hole transport region 120 may include a compound represented by Formula 201, a compound represented by Formula 202, or any combination thereof:

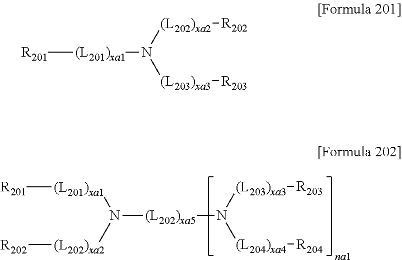

In Formulae 201 and 202,
L₂₀₁ to L₂₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
L₂₀₅ may be *—O—*′, *—S—*′, *—N(Q₂₀₁)-*′, a C₁-C₂₀ alkylene group that is unsubstituted or substituted with at least one R₁₀ₐ, a C₂-C₂₀ alkenylene group that is unsubstituted or substituted with at least one R₁₀ₐ, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
R₂₀₁ and R₂₀₂ may optionally be linked to each other via a single bond, a C₁-C₅alkylene group that is unsubstituted or substituted with at least one R₁₀ₐ, or a C₂-C₅ alkenylene group that is unsubstituted or substituted with at least one R₁₀ₐ to form a C₈-C₆₀ polycyclic group (for example, a carbazole group) that is unsubstituted or substituted with at least one R₁₀ₐ (for example, Compound HT16),
R₂₀₃ and R₂₀₄ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ to form a C₈-C₆₀ polycyclic group that is unsubstituted or substituted with at least one R₁₀ₐ, and

na1 may be an integer from 1 to 4.

In an embodiment, the compound represented by Formula 201 and the compound represented by Formula 202 may each independently include at least one of groups represented by Formulae CY201 to CY217:

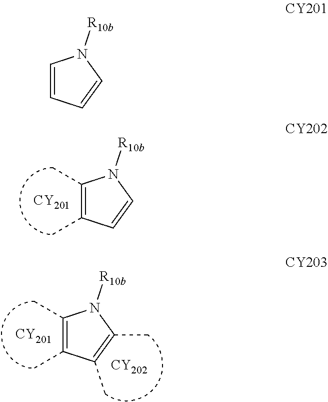

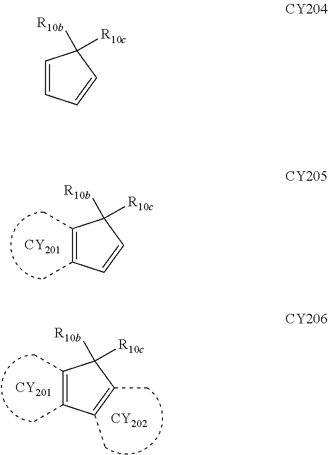

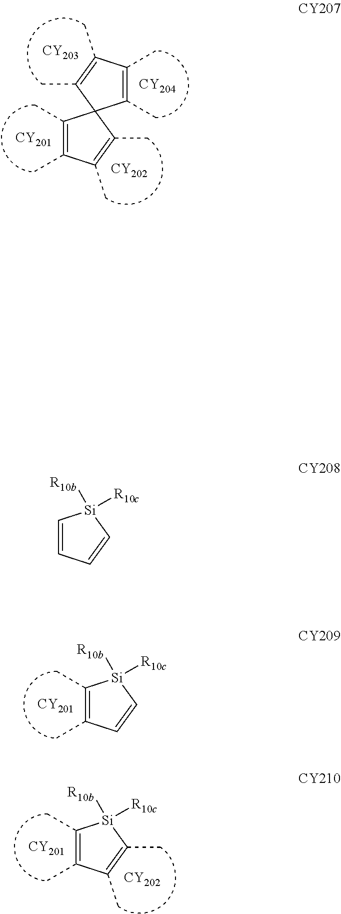

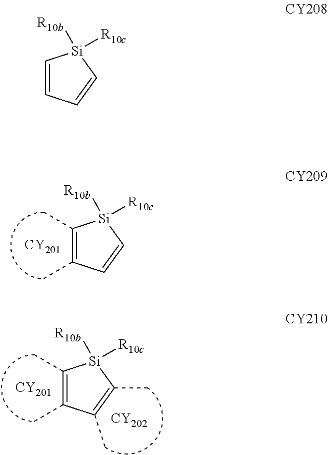

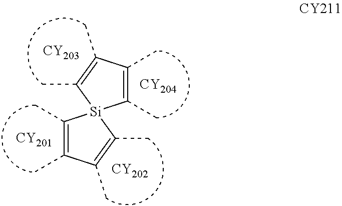

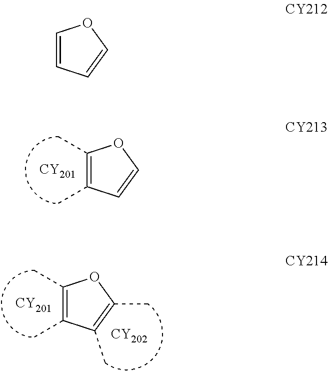

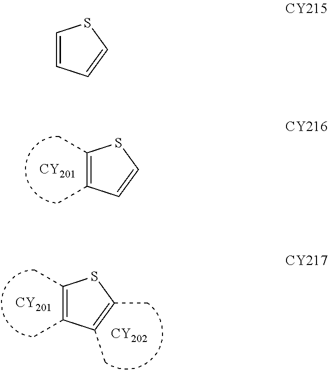

In Formulae CY201 to CY217, R_{10b} and R_{10c} may each independently be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described herein.

In an embodiment, in Formulae CY201 to CY 217, ring CY₂₀₁ to ring CY₂₀₄ may each independently be a benzene group, a naphthalene group, a phenanthrene group, or an anthracene group.

In an embodiment, the compound represented by Formula 201 and the compound represented by Formula 202 may include at least one of groups represented by Formulae CY201 to CY203.

In an embodiment, the compound represented by Formula 201 may include at least one of groups represented by Formulae CY201 to CY203 and at least one of groups represented by Formulae CY204 to CY217.

In an embodiment, in Formula 201, xa1 may be 1, R₂₀₁ may be a group represented by one of Formulae CY201 to CY203, xa2 may be 0, and R₂₀₂ may be a group represented by one of Formulae CY204 to CY207.

In an embodiment, the compound represented by Formula 201 and the compound represented by Formula 202 may each not include groups represented by Formulae CY201 to CY203.

In an embodiment, the compound represented by Formula 201 and the compound represented by Formula 202 may each not include groups represented by Formulae CY201 to CY203, and may each independently include at least one of groups represented by Formulae CY204 to CY217.

In an embodiment, the compound represented by Formula 201 and the compound represented by Formula 202 may each not include groups represented by Formulae CY201 to CY217.

In an embodiment, the hole transport region may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzene sulfonic acid (PANI/DBSA), poly(3,4-ethylene dioxythiophene)/poly(4-styrene sulfonate) (PEDOT/PSS), polyaniline/camphor sulfonic acid (PANI/CSA), polyaniline/poly(4-styrene sulfonate) (PANI/PSS), or any combination thereof:

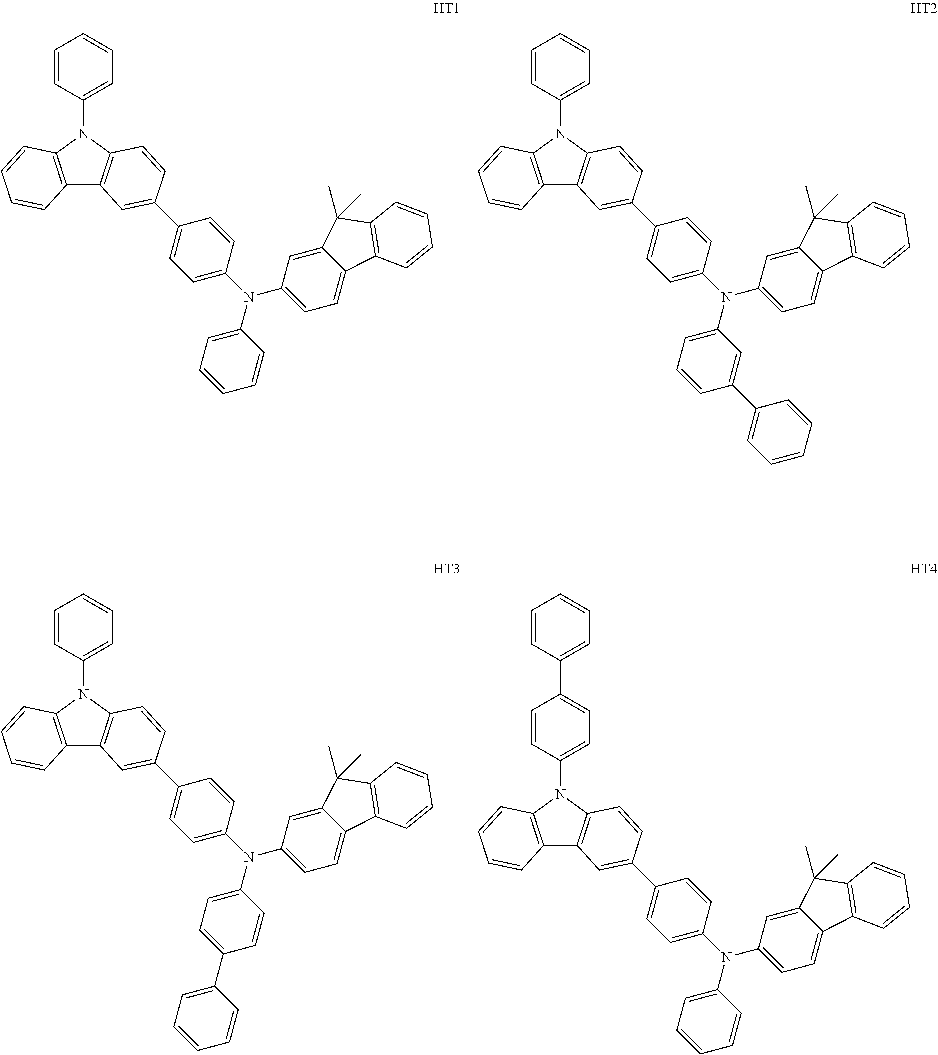 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

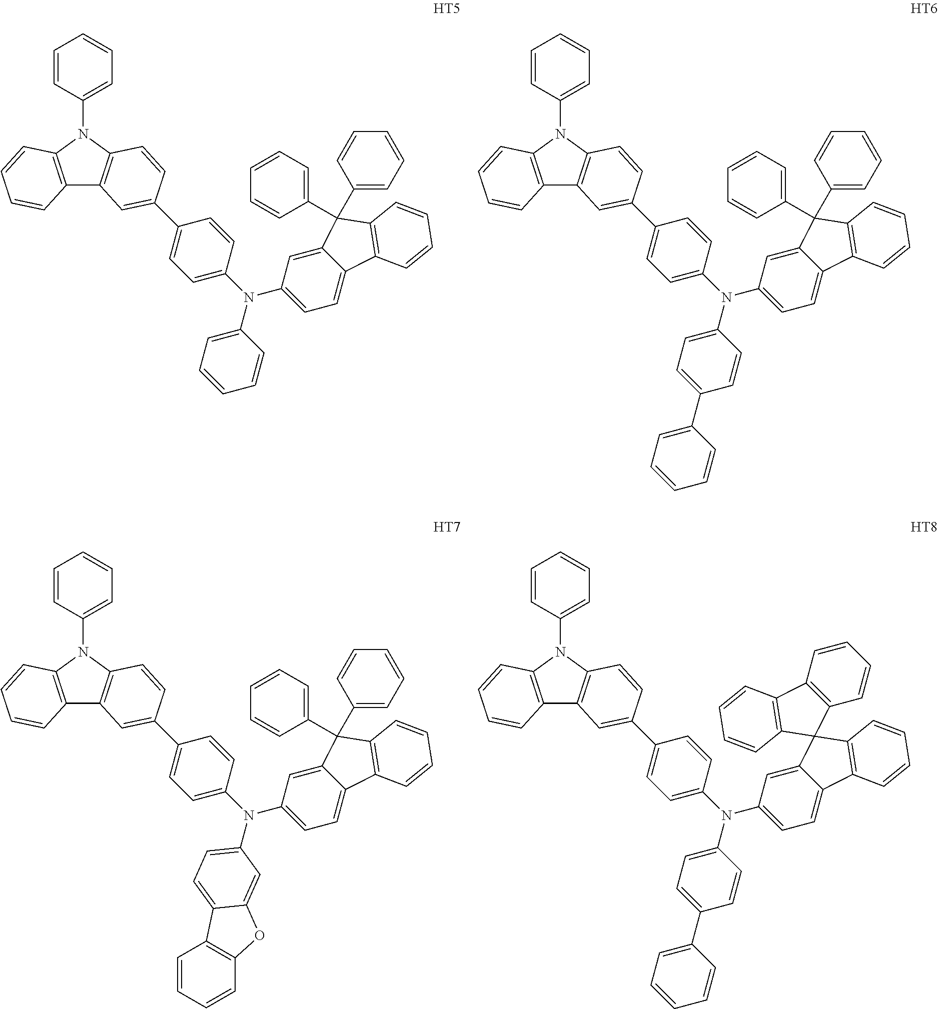 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

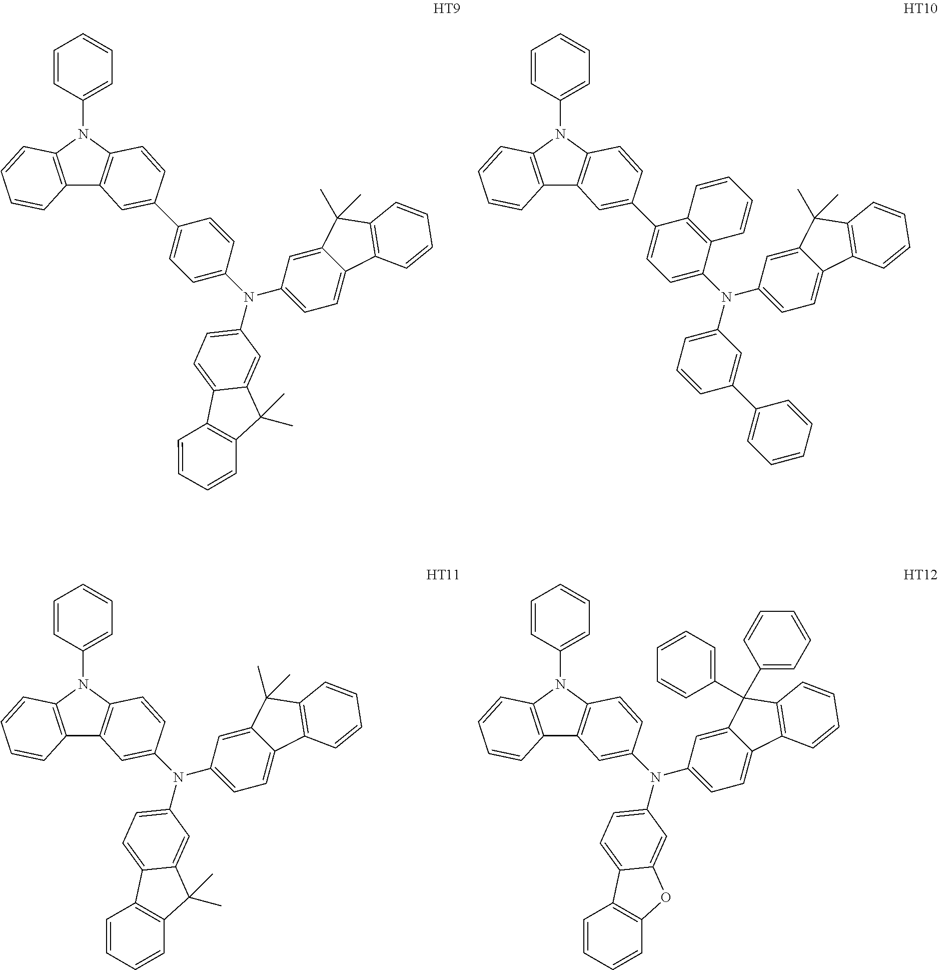 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

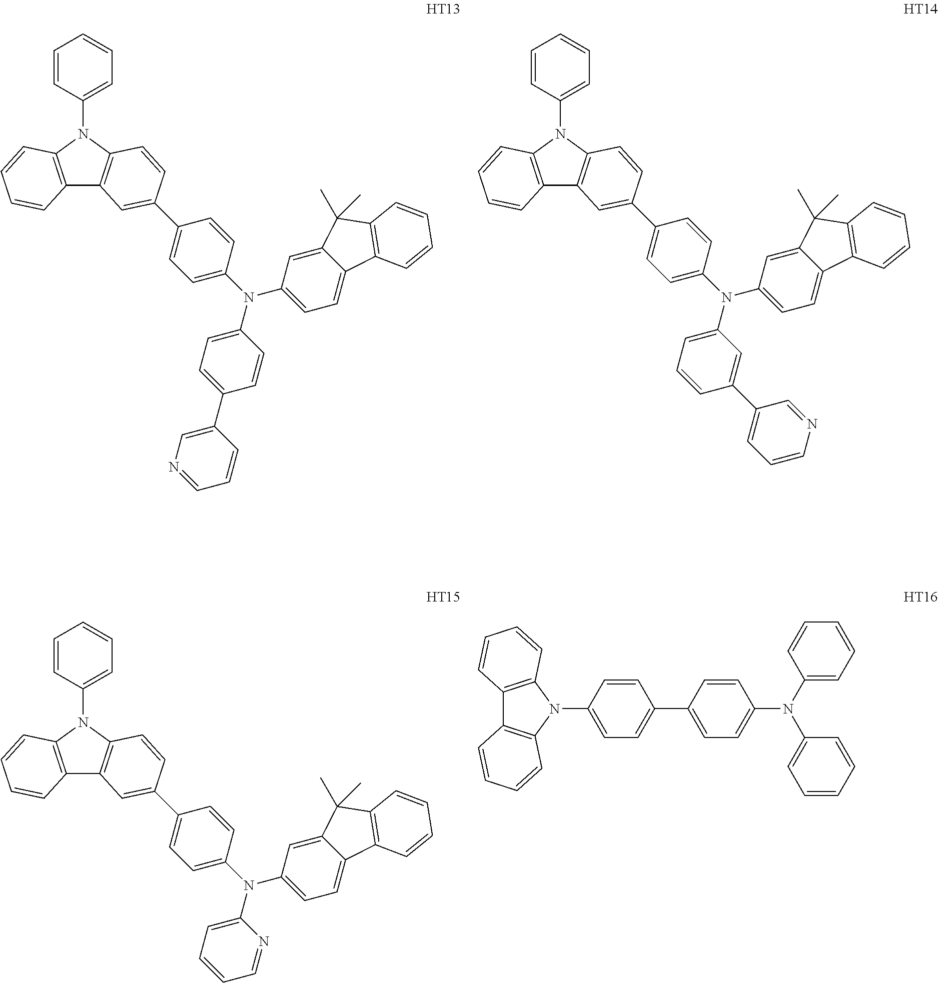 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

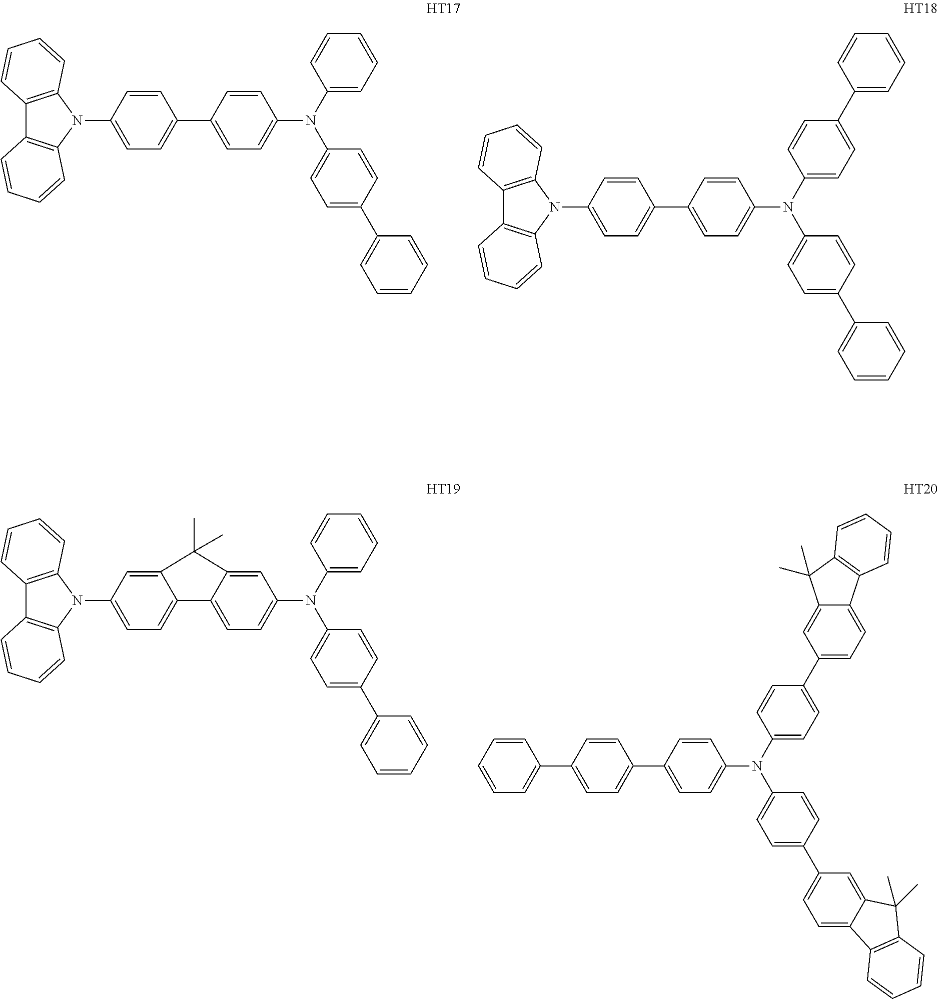 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

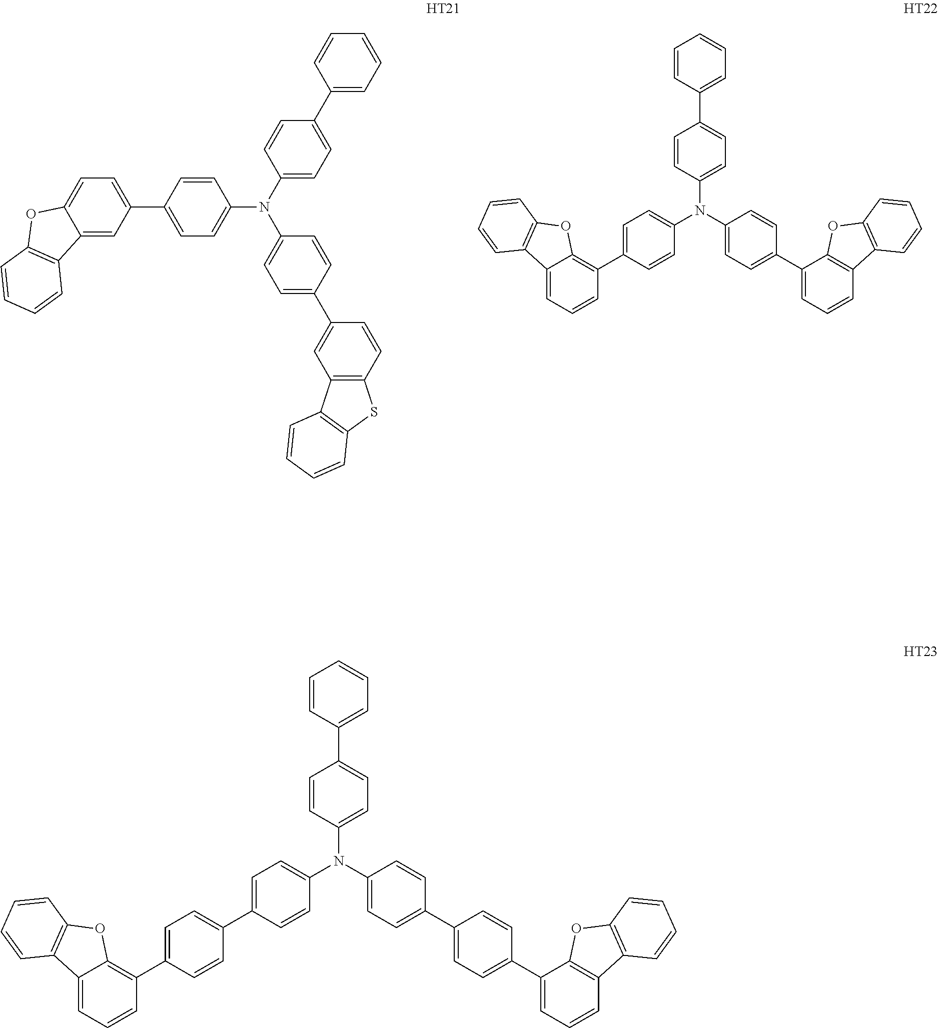 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

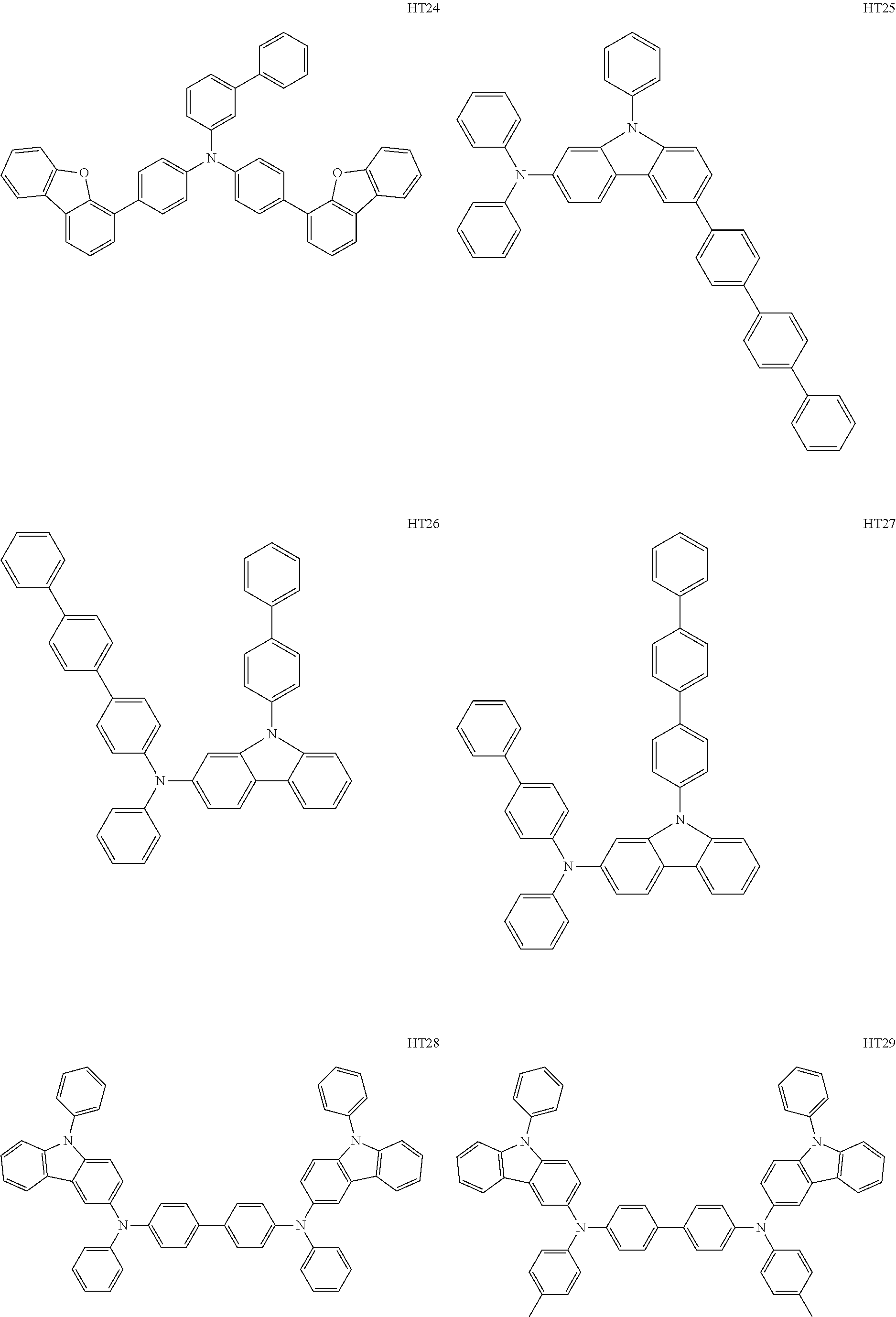

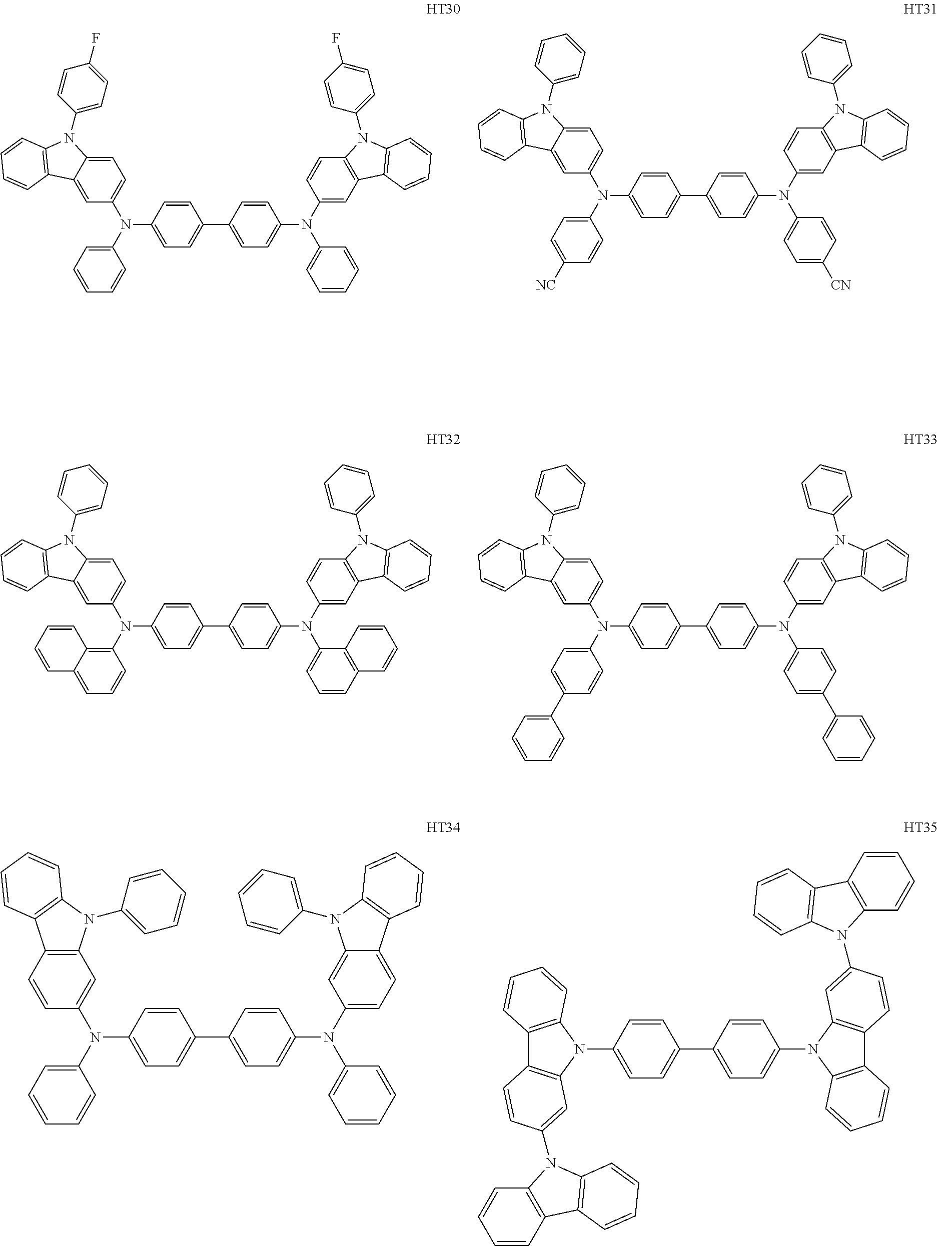

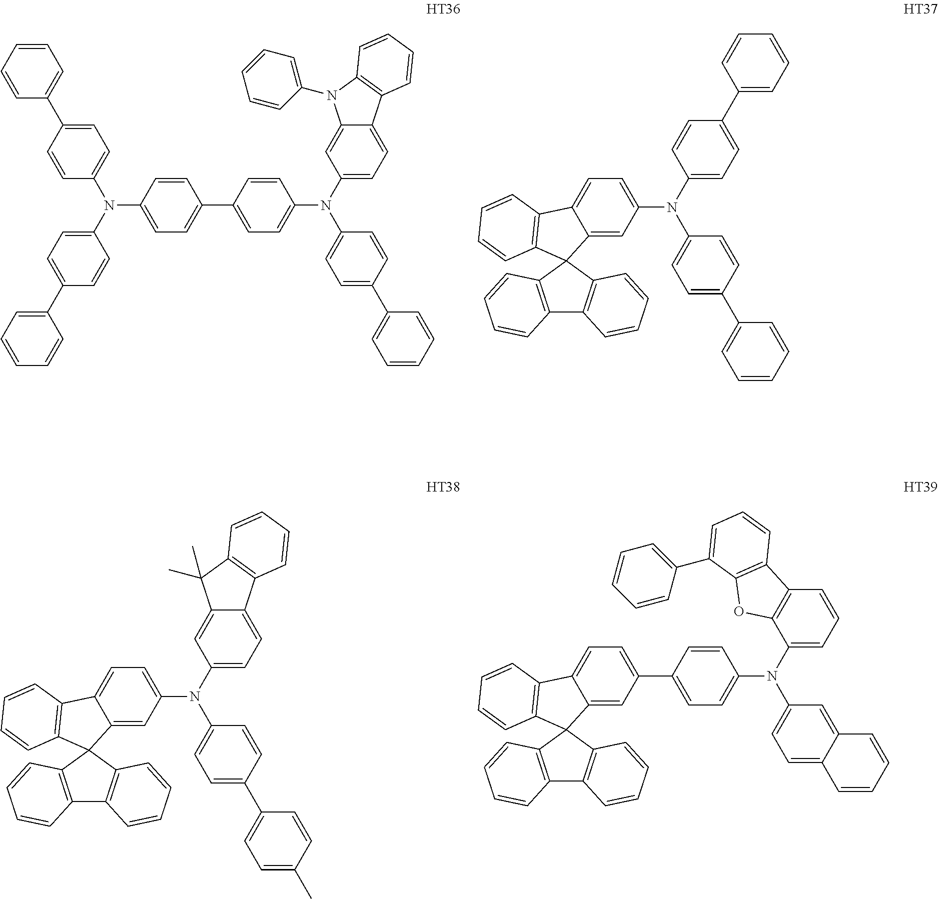 [SMILES: c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1]

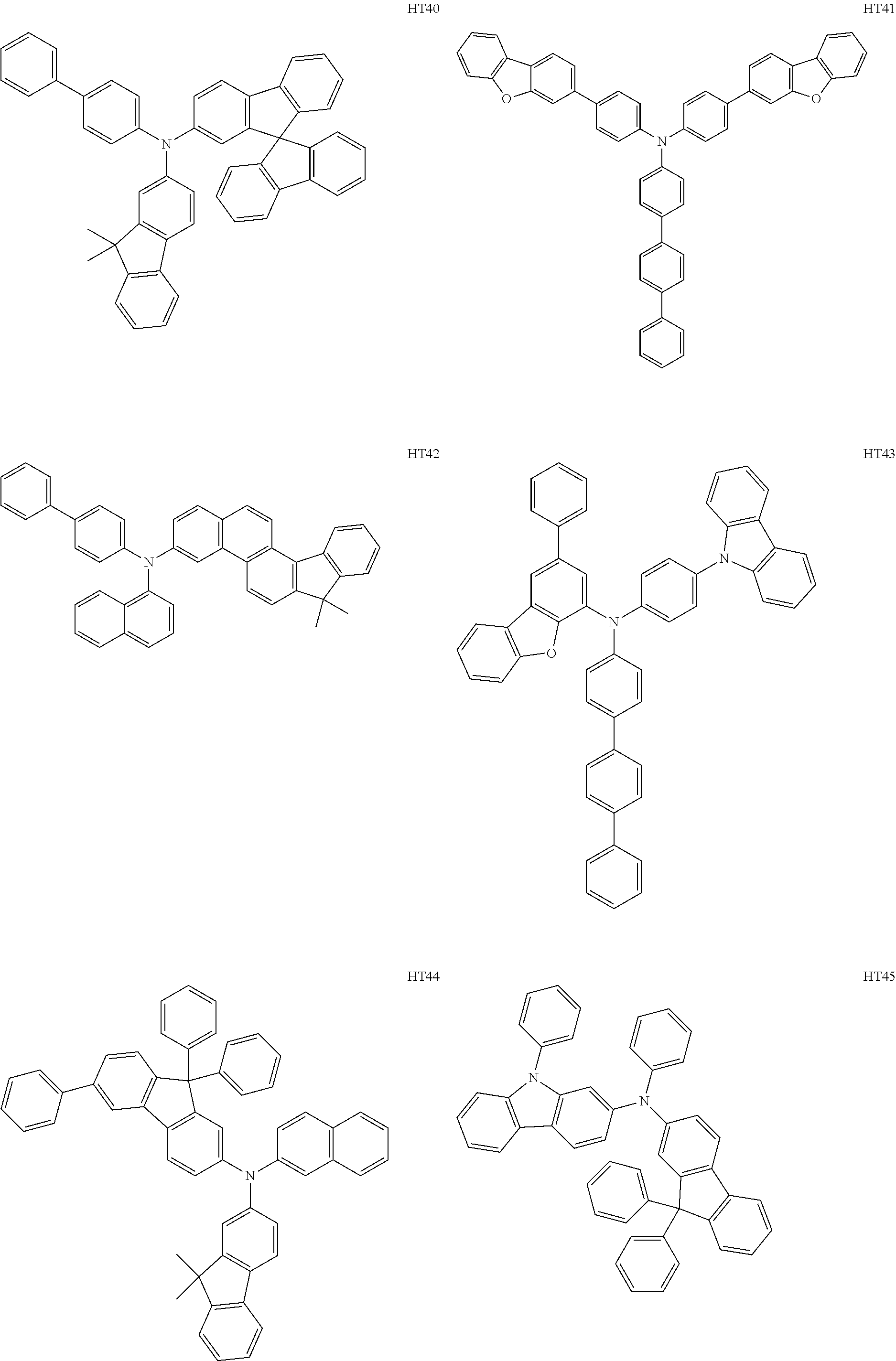

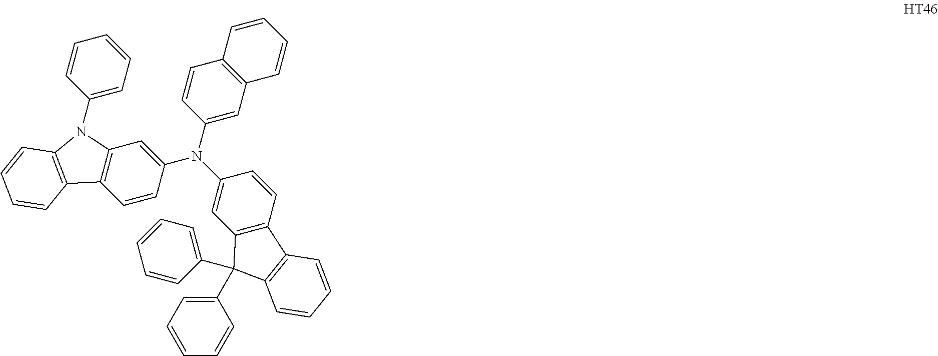 [SMILES: c1ccc(-n2c3ccccc3c3ccc(N(c4ccc5c(c4)C(c4ccccc4)(c4ccccc4)c4ccccc4-5)c4ccc5ccccc5c4)cc32)cc1]

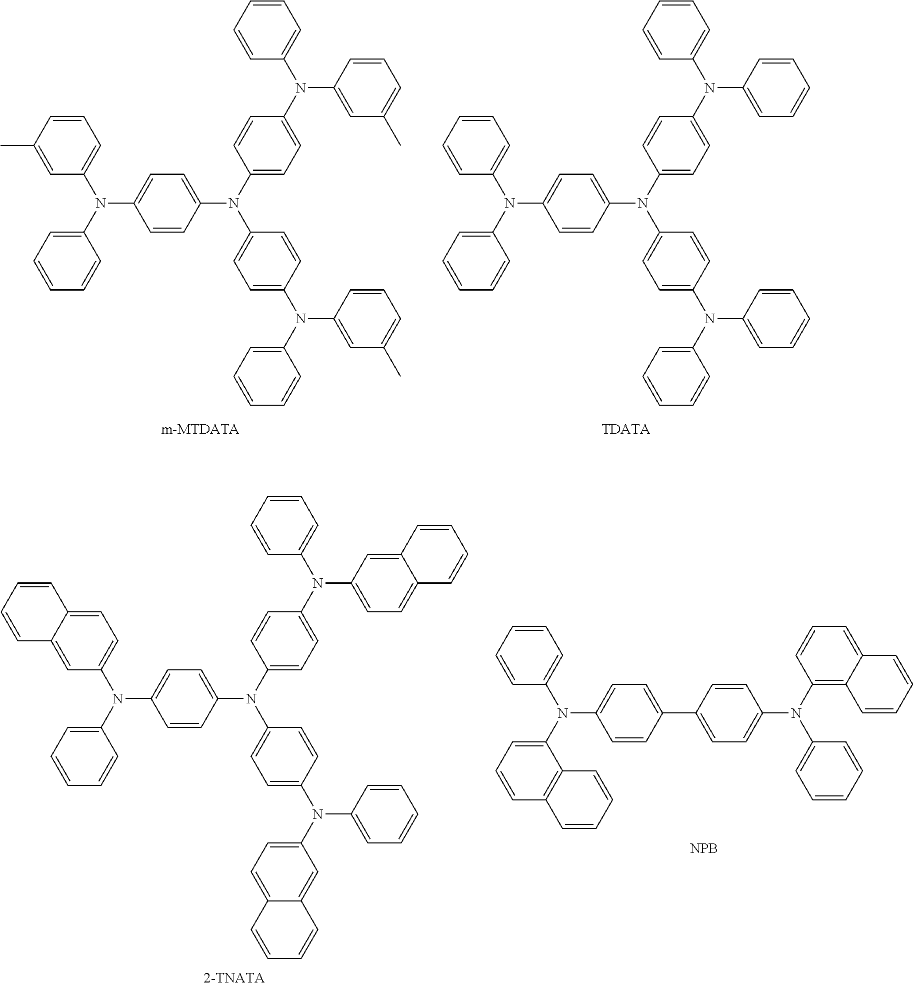

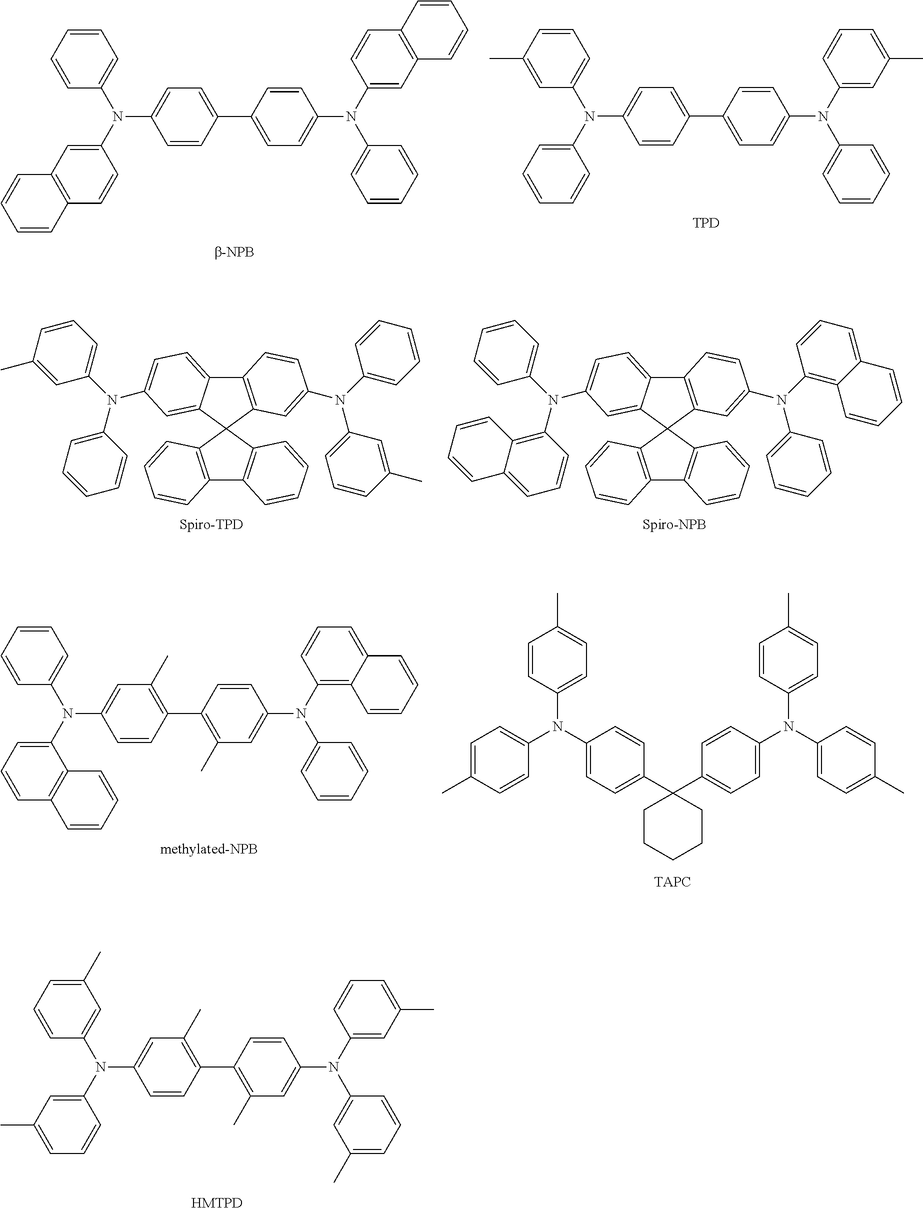

A thickness of the hole transport region 120 may be in a range of about 50 Δ to about 10,000 Δ. For example, the thickness of the hole transport region 120 may be in a range of about 100 Δ to about 4,000 Δ. When the hole transport region 120 includes a hole injection layer, a hole transport layer, or any combination thereof, a thickness of the hole injection layer may be in a range of about 100 Δ to about 9,000 Δ, and a thickness of the hole transport layer may be in a range of about 50 Δ to about 2,000 Δ. For example, the thickness of the hole injection layer may be in a range of about 100 Δ to about 1,000 Δ. For example, the thickness of the hole transport layer may be in a range of about 100 Δ to about 1,500 Δ. When the thicknesses of the hole transport region, the hole injection layer, and the hole transport layer are within the ranges described above, satisfactory hole transporting characteristics may be obtained without a substantial increase in driving voltage.

The emission auxiliary layer may serve to increase light emission efficiency by compensating for an optical resonance distance according to the wavelength of light emitted by the emission layer. The electron blocking layer may serve to prevent electron leakage from the emission layer to the hole transport region. Materials that may be included in the hole transport region may be included in the emission auxiliary layer and the electron blocking layer.

[p-Dopant]

The hole transport region 120 may further include, in addition to the aforementioned materials, a charge-generation material for the improvement of conductive properties. The charge-generation material may be uniformly or non-uniformly dispersed in the hole transport region (for example, in the form of a single layer consisting of a charge-generation material).

The charge-generation material may be, for example, a p-dopant.

For example, the lowest unoccupied molecular orbital (LUMO) energy level of the p-dopant may be less than or equal to about −3.5 eV.

In an embodiment, the p-dopant may include a quinone derivative, a cyano group-containing compound, a compound including an element EL1 and an element EL2, or any combination thereof.

Examples of a quinone derivative may include TCNQ and F4-TCNQ.

Examples of a cyano group-containing compound may include HAT-CN and a compound represented by Formula 221.

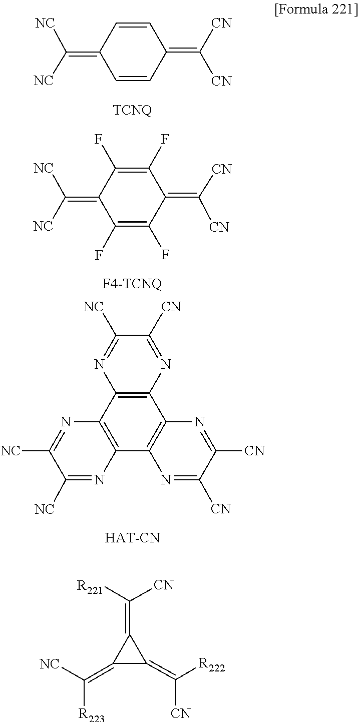

In Formula 221,
R₂₂₁ to R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, the element EL1 may be a metal, a metalloid, or any combination thereof, and the element EL2 may be a non-metal, a metalloid, or any combination thereof.

Examples of a metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of a metalloid may include silicon (Si), antimony (Sb), and tellurium (Te).

Examples of a non-metal may include oxygen (O) and a halogen (for example, F, Cl, Br, I, etc.).

Examples of a compound including element EL1 and element EL2 may include a metal oxide, a metal halide (for example, a metal fluoride, a metal chloride, a metal bromide, a metal iodide, etc.), a metalloid halide (for example, a metalloid fluoride, a metalloid chloride, a metalloid bromide, a metalloid iodide, etc.), a metal telluride, or any combination thereof.

Examples of a metal oxide may include a tungsten oxide (for example, WO, W₂O₃, WO₂, WO₃, W₂O₅, etc.), a vanadium oxide (for example, VO, V₂O₃, VO₂, V₂O₅, etc.), a molybdenum oxide (for example, MoO, Mo₂O₃, MoO₂, MoO₃, Mo₂O₅, etc.), a rhenium oxide (for example, ReO₃, etc.), etc.

Examples of a metal halide may include an alkali metal halide, an alkaline earth metal halide, a transition metal halide, a post-transition metal halide, and a lanthanide metal halide.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, Kl, RbI, and CsI.

Examples of an alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, and BaI₂.

Examples of a transition metal halide may include a titanium halide (for example, TiF₄, TiCl₄, TiBr₄, TiI₄, etc.), a zirconium halide (for example, ZrF₄, ZrCl₄, ZrBr₄, ZrI₄, etc.), a hafnium halide (for example, HfF₄, HfCl₄, HfBr₄, HfI₄, etc.), a vanadium halide (for example, VF₃, VCl₃, VBr₃, VI₃, etc.), a niobium halide (for example, NbF₃, NbCl₃, NbBr₃, NbI₃, etc.), a tantalum halide (for example, TaF₃, TaCl₃, TaBr₃, TaI₃, etc.), a chromium halide (for example, CrF₃, CrCl₃, CrBr₃, CrI₃, etc.), a molybdenum halide (for example, MoF₃, MoCl₃, MoBr₃, MoI₃, etc.), a tungsten halide (for example, WF₃, WCl₃, WBr₃, WI₃, etc.), a manganese halide (for example, MnF₂, MnCl₂, MnBr₂, MnI₂, etc.), a technetium halide (for example, TcF₂, TcCl₂, TcBr₂, TcI₂, etc.), a rhenium halide (for example, ReF₂, ReCl₂, ReBr₂, ReI₂, etc.), an iron halide (for example, FeF₂, FeCl₂, FeBr₂, FeI₂, etc.), a ruthenium halide (for example, RuF₂, RuCl₂, RuBr₂, RuI₂, etc.), an osmium halide (for example, OsF₂, OSCl₂, OsBr₂, OSI₂, etc.), a cobalt halide (for example, CoF₂, CoCl₂, CoBr₂, CoI₂, etc.), a rhodium halide (for example, RhF₂, RhCl₂, RhBr₂, RhI₂, etc.), an iridium halide (for example, IrF₂, IrCl₂, IrBr₂, IrI₂, etc.), a nickel halide (for example, NiF₂, NiCl₂, NiBr₂, NiI₂, etc.), a palladium halide (for example, PdF₂, PdCl₂, PdBr₂, PdI₂, etc.), a platinum halide (for example, PtF₂, PtCl₂, PtBr₂, PtI₂, etc.), a copper halide (for example, CuF, CuCl, CuBr, CuI, etc.), a silver halide (for example, AgF, AgCl, AgBr, AgI, etc.), and a gold halide (for example, AuF, AuCl, AuBr, AuI, etc.).

Examples of a post-transition metal halide may include a zinc halide (for example, ZnF₂, ZnCl₂, ZnBr₂, ZnI₂, etc.), an indium halide (for example, InI₃, etc.), a tin halide (for example, SnI₂, etc.), etc.

Examples of a lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, etc.

Examples of a metalloid halide may include an antimony halide (for example, SbCl₅, etc.).

Examples of a metal telluride may include an alkali metal telluride (for example, Li₂Te, Na₂Te, K₂Te, Rb₂Te, Cs₂Te, etc.), an alkaline earth metal telluride (for example, BeTe, MgTe, CaTe, SrTe, BaTe, etc.), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (for example, ZnTe, etc.), and a lanthanide metal telluride (for example, LaTe, CeTe, PrTe, NdTe, PmTe, EuTe, GdTe, TbTe, DyTe, HoTe, ErTe, TmTe, YbTe, LuTe, etc.).

### [Emission Layer 130]

When the light-emitting device 10 is a full-color light-emitting device, the emission layer 130 may be patterned into a red emission layer, a green emission layer, and/or a blue emission layer, according to a subpixel. In an embodiment, the emission layer 130 may have a stacked structure of two or more layers of a red emission layer, a green emission layer, and a blue emission layer, in which the two or more layers may contact each other or may be separated from each other, to emit white light. In embodiments, the emission layer 130 may include two or more materials of a red light-emitting material, a green light-emitting material, and a blue light-emitting material, in which the two or more materials may be mixed with each other in a single layer, to emit white light.

The emission layer 130 may include a host and a dopant. The dopant may include a phosphorescent dopant, a fluorescent dopant, or any combination thereof.

An amount of the dopant in the emission layer 130 may be in a range of about 0.01 parts by weight to about 15 parts by weight, based on 100 parts by weight of the host.

In an embodiment, the emission layer 130 may include a quantum dot.

The emission layer 130 may include a delayed fluorescence material. The delayed fluorescence material may serve as a host or as a dopant in the emission layer.

A thickness of the emission layer 130 may be in a range of about 100 Å to about 1,000 Å. For example, the thickness of the emission layer 130 may be in a range of about 200 Å to about 600 Å. When the thickness of the emission layer is within the range described above, excellent luminescence characteristics may be obtained without a substantial increase in driving voltage.

### [Host]

In an embodiment, the host may include a compound represented by Formula 301:

[Ar₃₀₁]_{xb11}-[(L₃₀₁)_{xb1}-R₃₀₁]_{xb21} [Formula 301]

In Formula 301,
Ar₃₀₁ and L₃₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be the same as described in connection with Q₁.

In an embodiment, in Formula 301, when xb11 is 2 or more, two or more of Ar₃₀₁ may be linked to each other via a single bond.

In an embodiment, the host may include a compound represented by Formula 301-1, a compound represented by Formula 301-2, or any combination thereof:

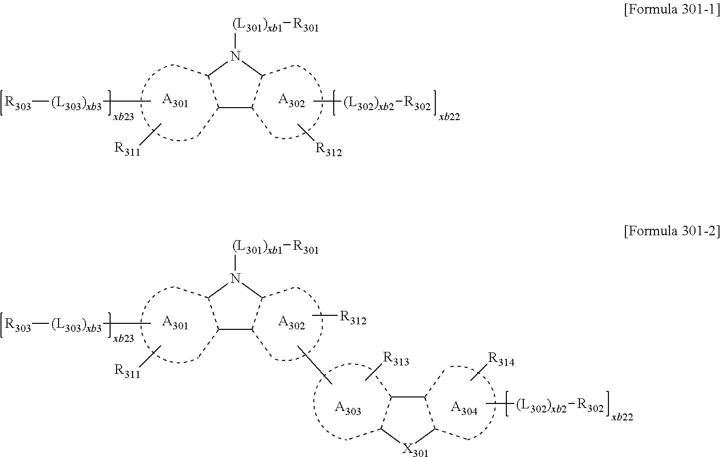

In Formula 301-1 and 301-2,
ring A₃₀₁ to ring A₃₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅), xb22 and xb23 may each independently be 0, 1, or 2,
L₃₀₁, xb1, and R₃₀₁ may each be the same as described in the specification,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described in connection with R₃₀₁.

In an embodiment, the host may include an alkali earth metal complex, a post-transition metal complex, or any combination thereof. In an embodiment, the host may include a Be complex (for example, Compound H55), an Mg complex, a Zn complex, or any combination thereof.

In an embodiment, the host may include one of Compounds H1 to H128, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN); 4,4′-bis(N-carbazolyl)-1,1′-biphenyl (CBP), 1,3-di(carbazol-9-yl)benzene (mCP), 1,3,5-tri(carbazol-9-yl)benzene (TCP), or any combination thereof:

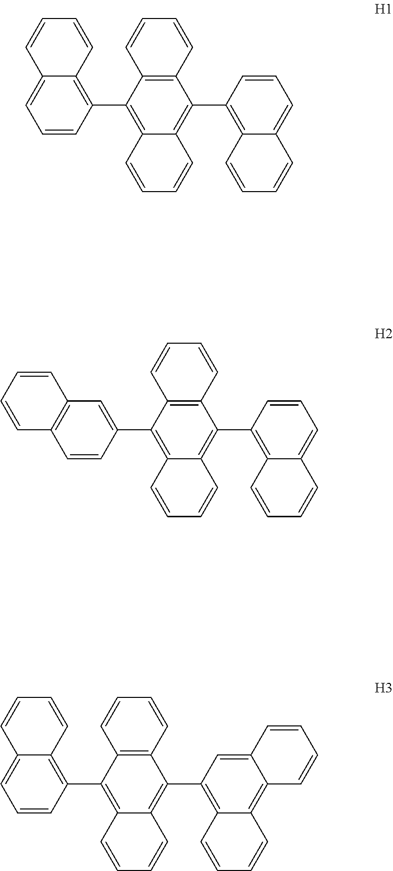

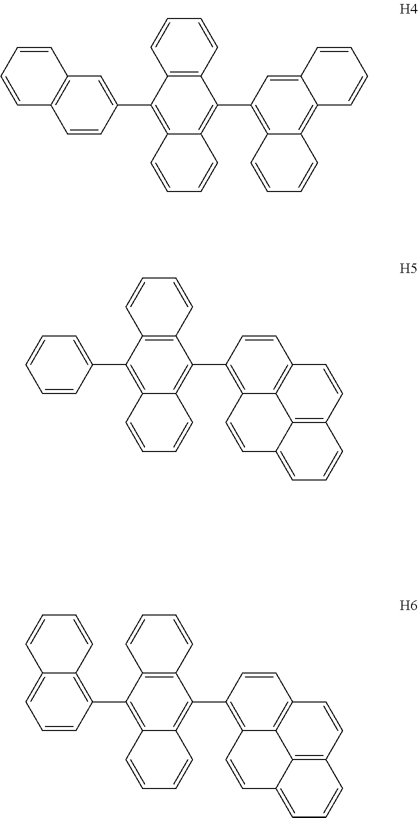

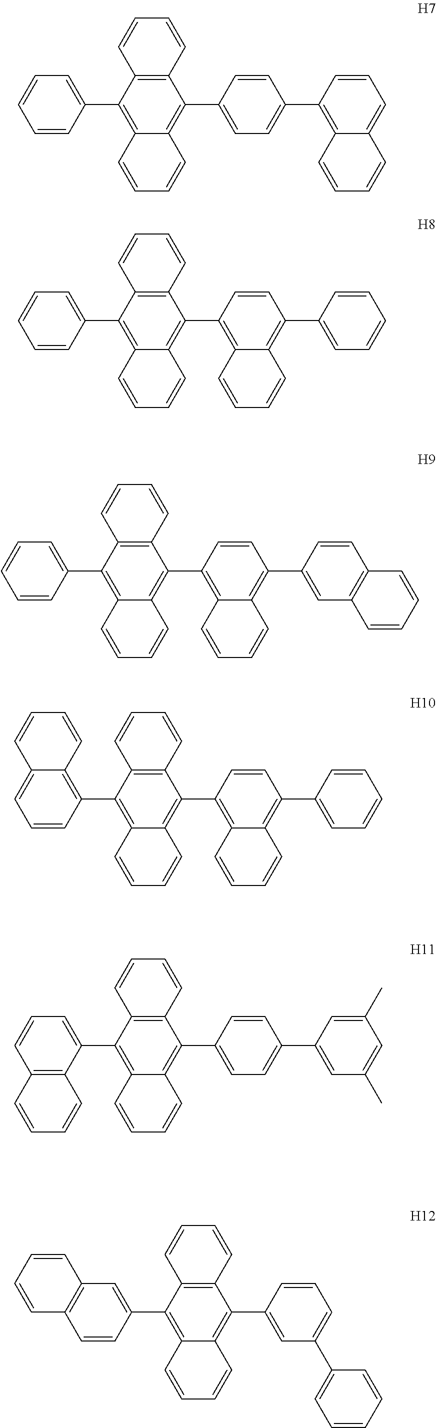

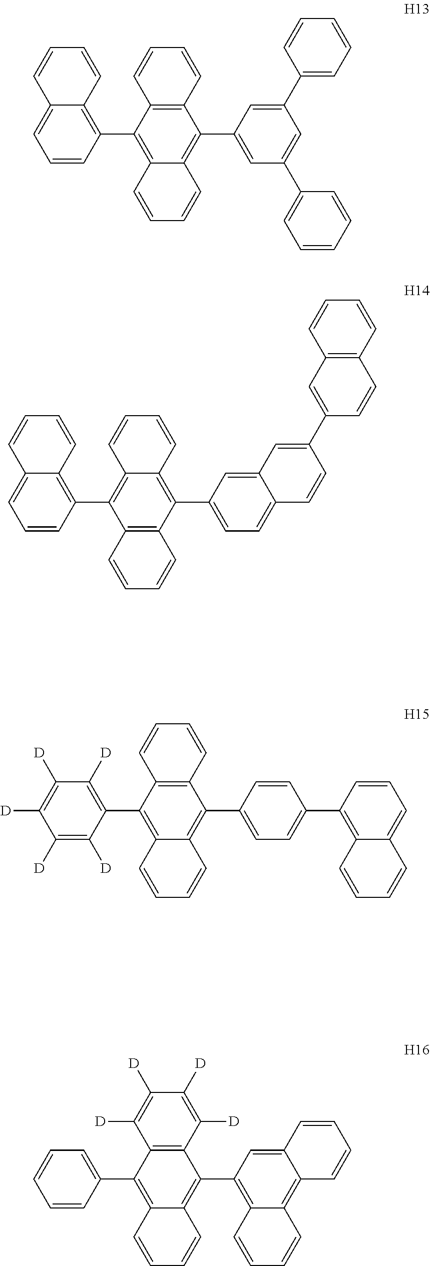

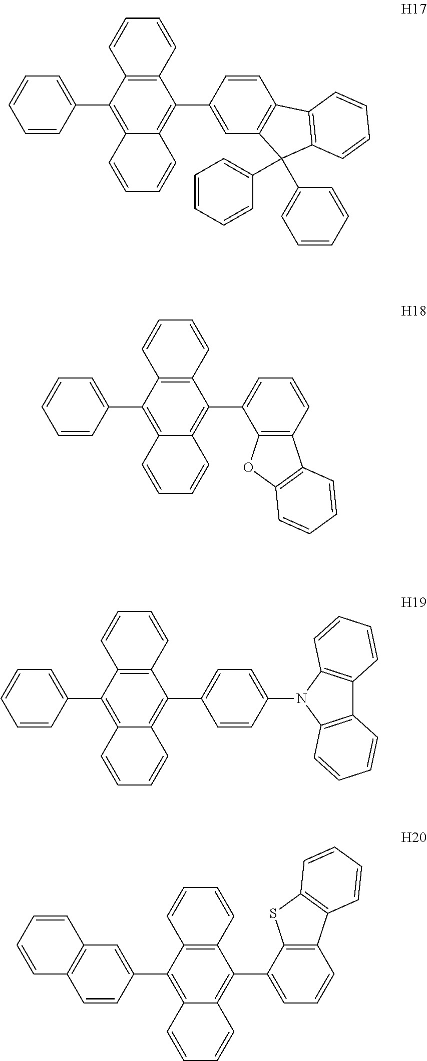

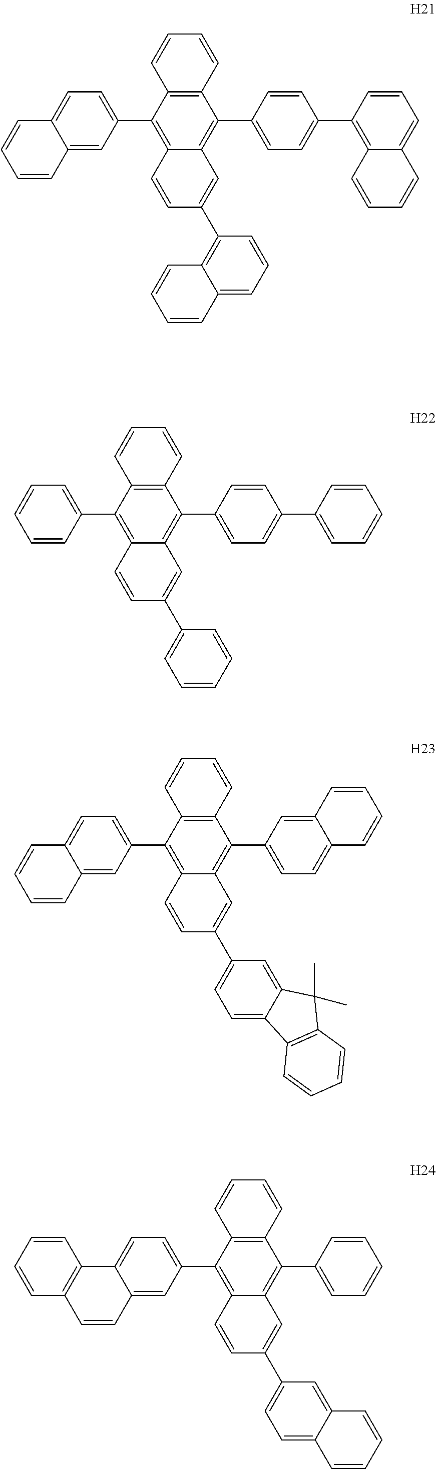

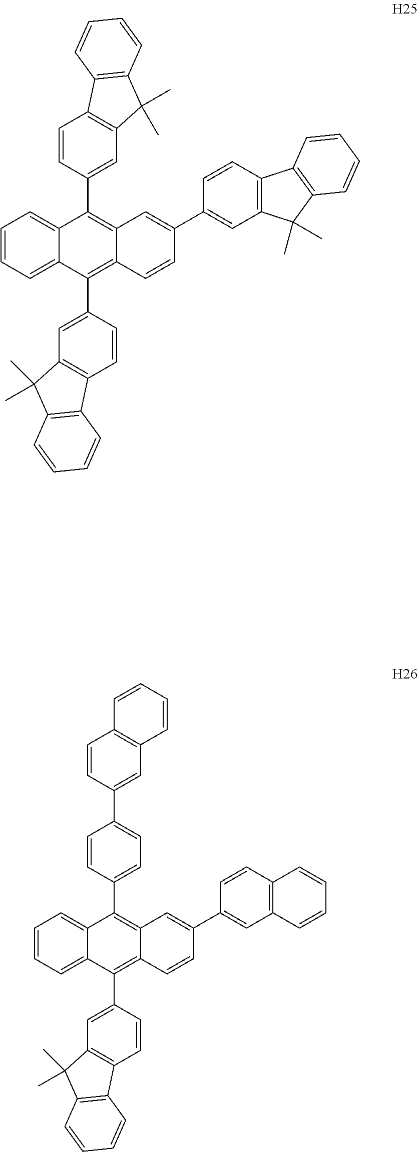

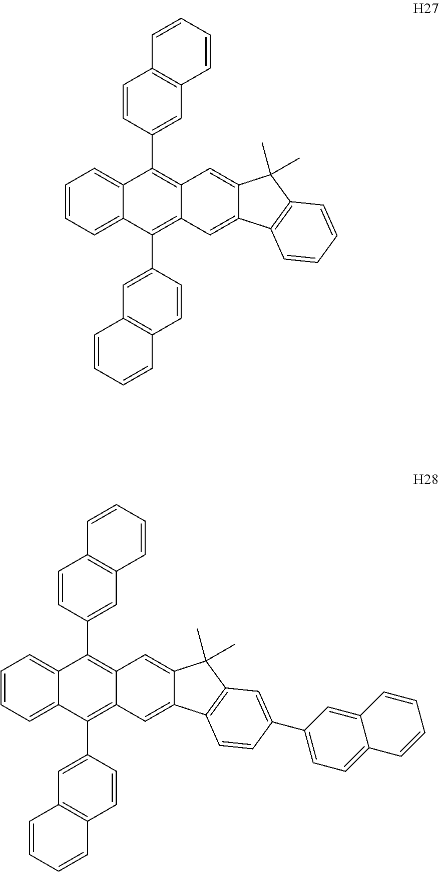

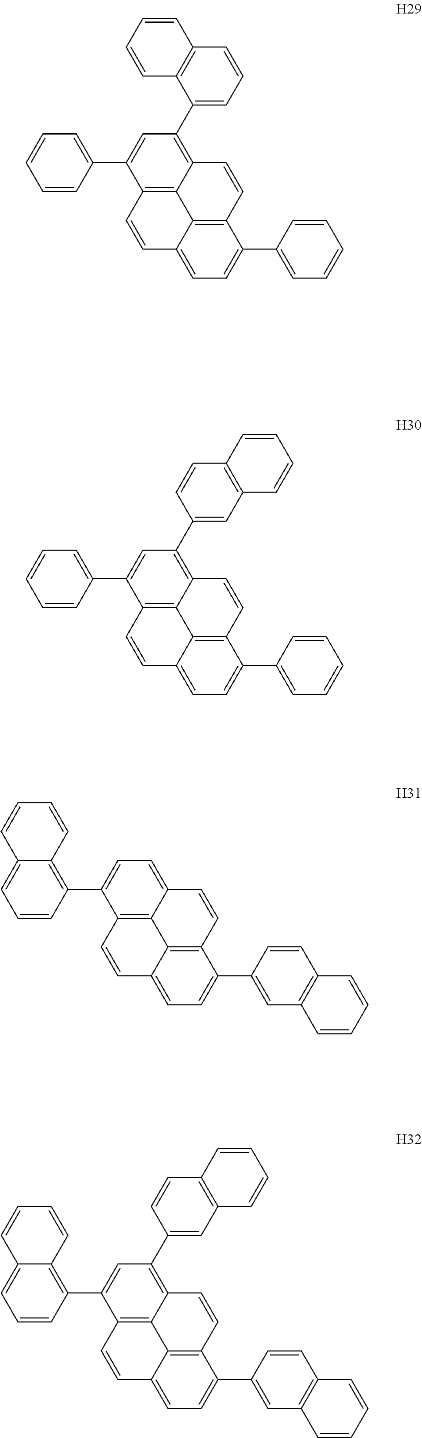

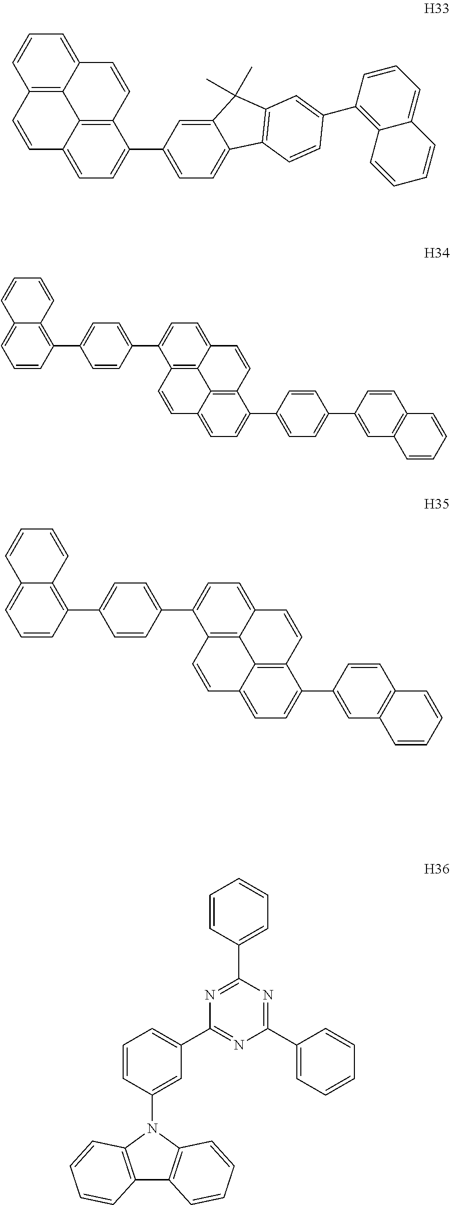

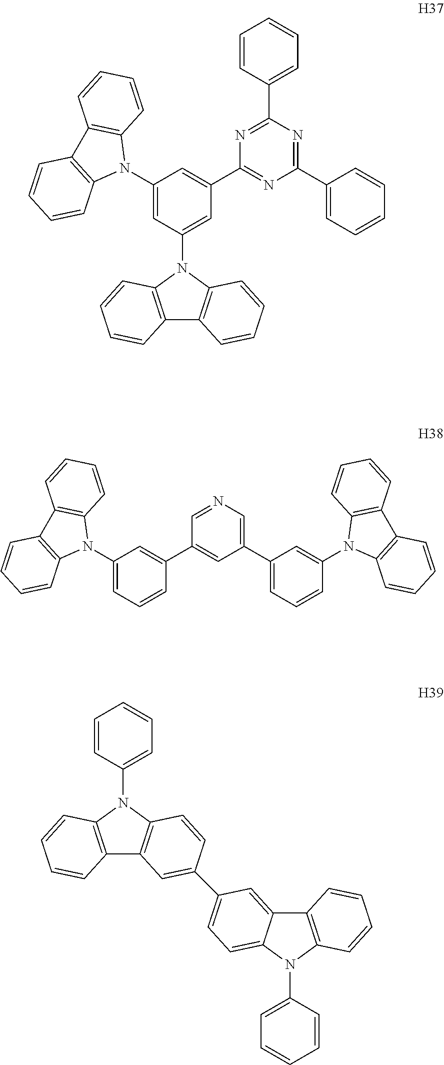 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

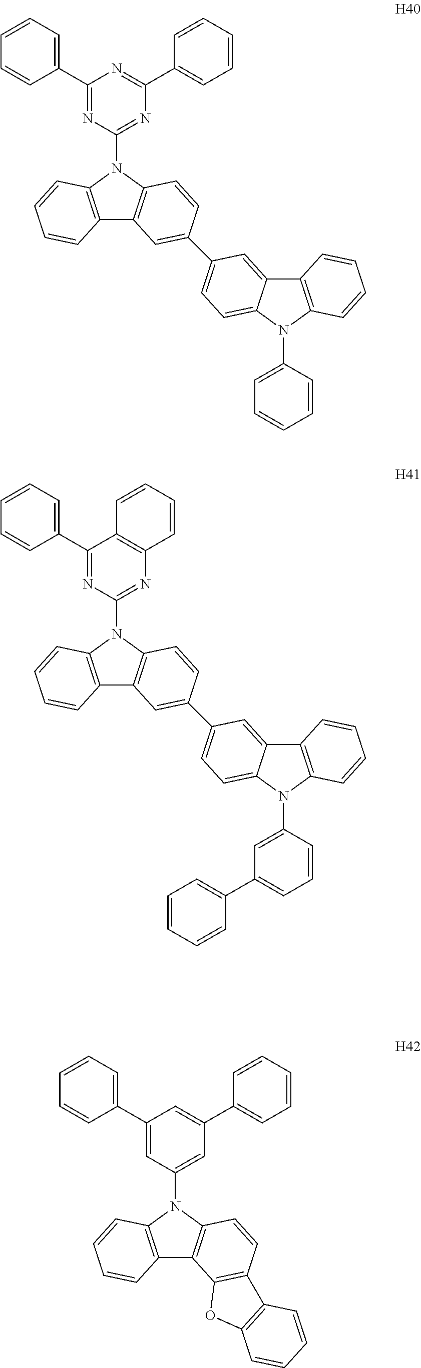 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

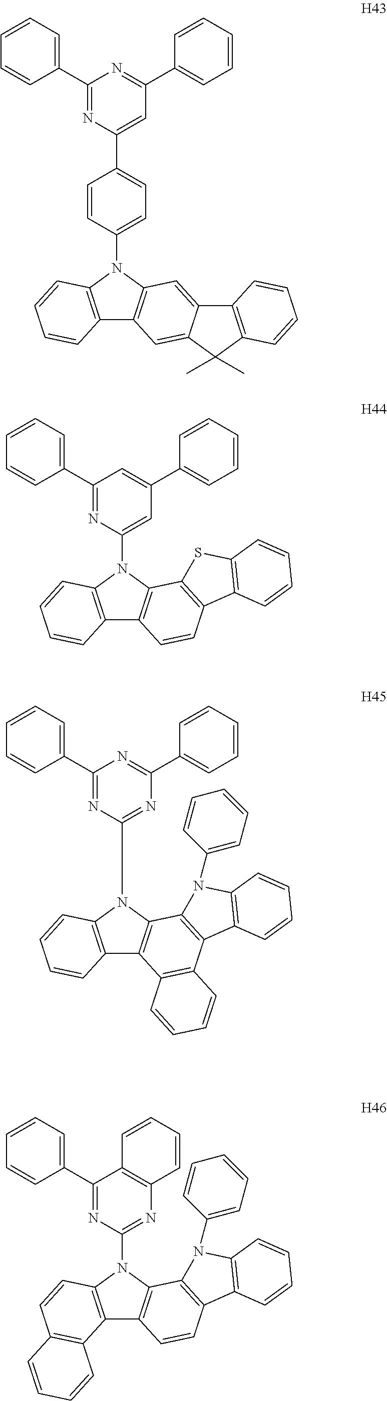 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

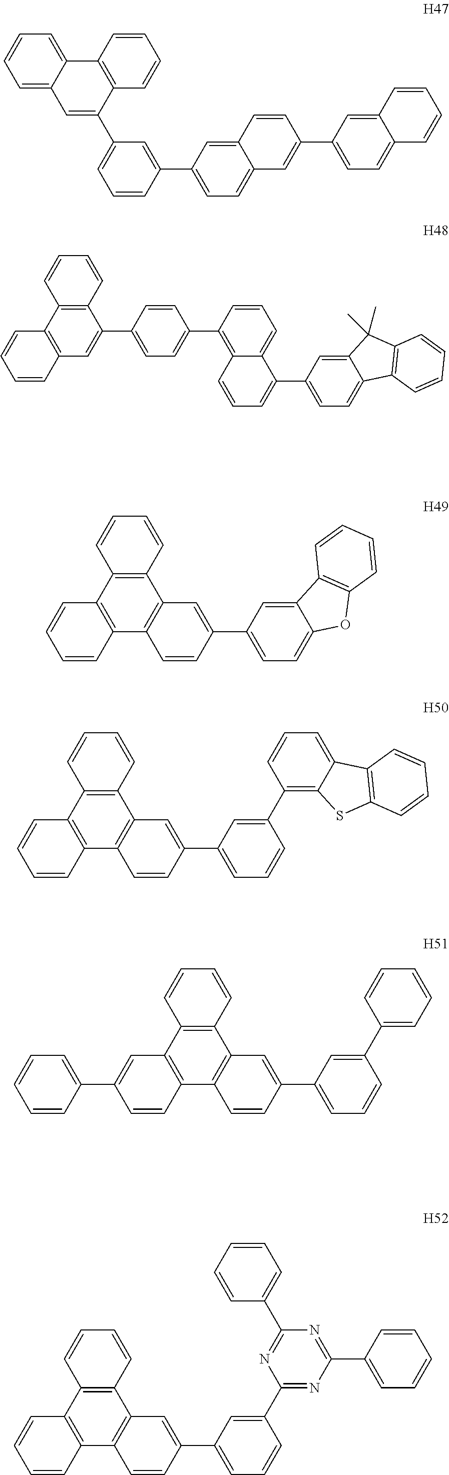

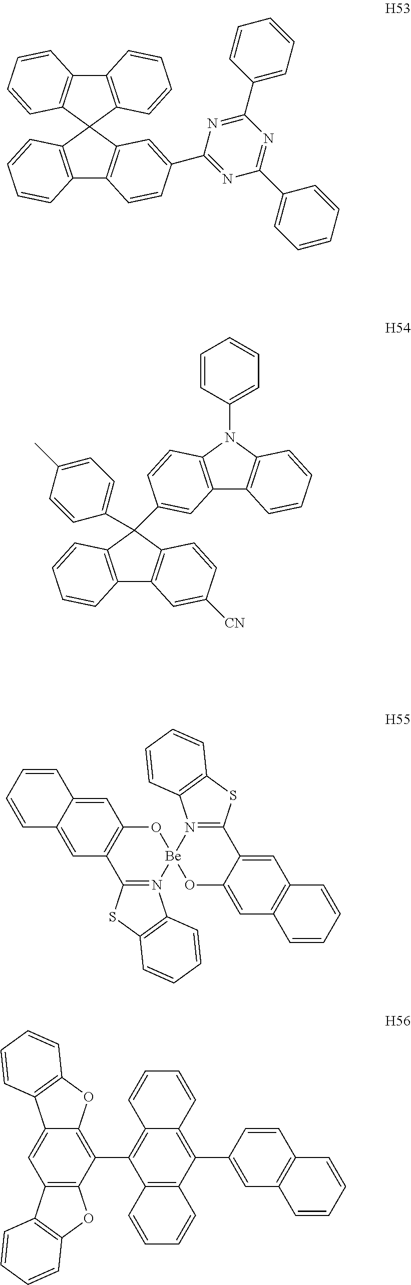

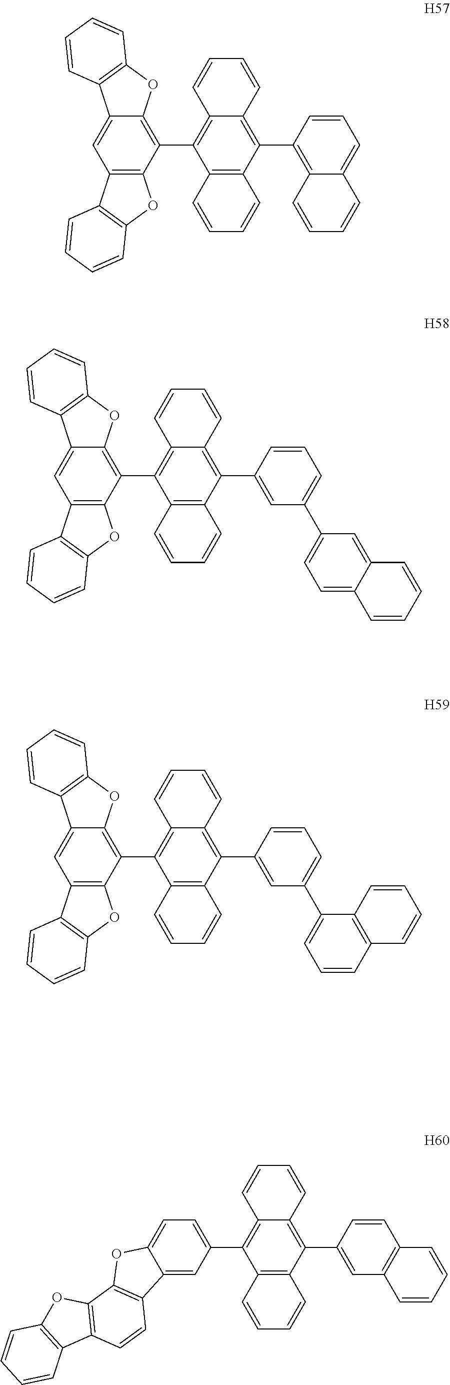 [SMILES: c1ccc2c(-c3c4ccccc4c(-c4c5oc6ccccc6c5cc5c4oc4ccccc45)c4ccccc34)cccc2c1 ; c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1]

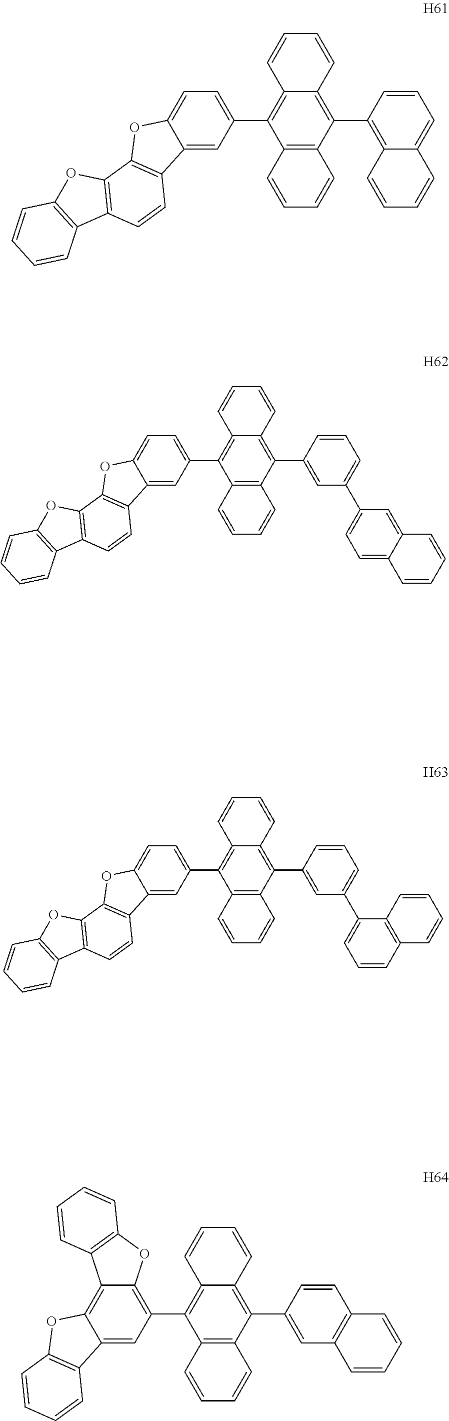 [SMILES: c1ccc2c(-c3c4ccccc4c(-c4ccc5oc6c(ccc7c8ccccc8oc76)c5c4)c4ccccc34)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1]

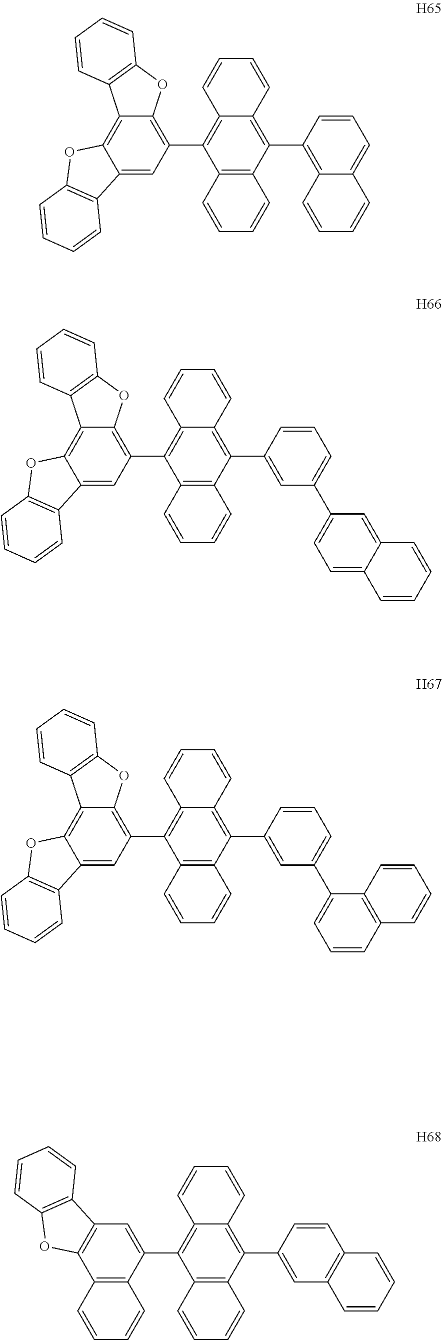 [SMILES: c1ccc2c(-c3c4ccccc4c(-c4cc5c6ccccc6oc5c5c4oc4ccccc45)c4ccccc34)cccc2c1 ; c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1]

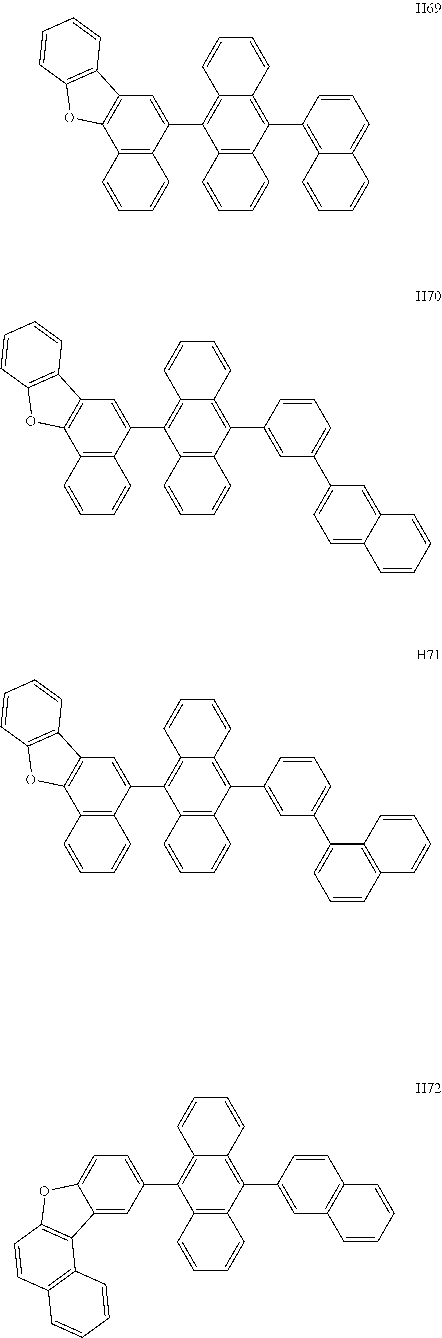 [SMILES: c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1]

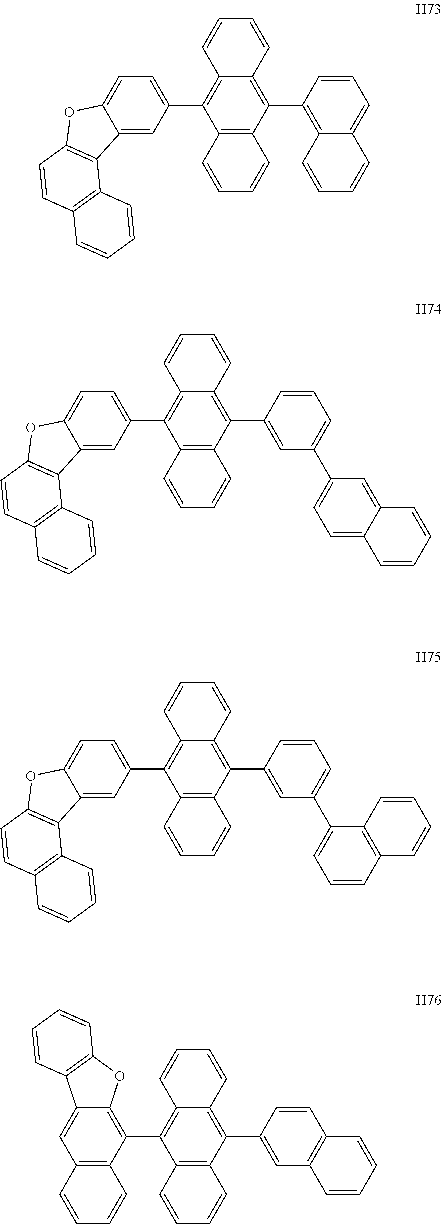 [SMILES: c1ccc2c(-c3c4ccccc4c(-c4ccc5oc6ccc7ccccc7c6c5c4)c4ccccc34)cccc2c1 ; c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1]

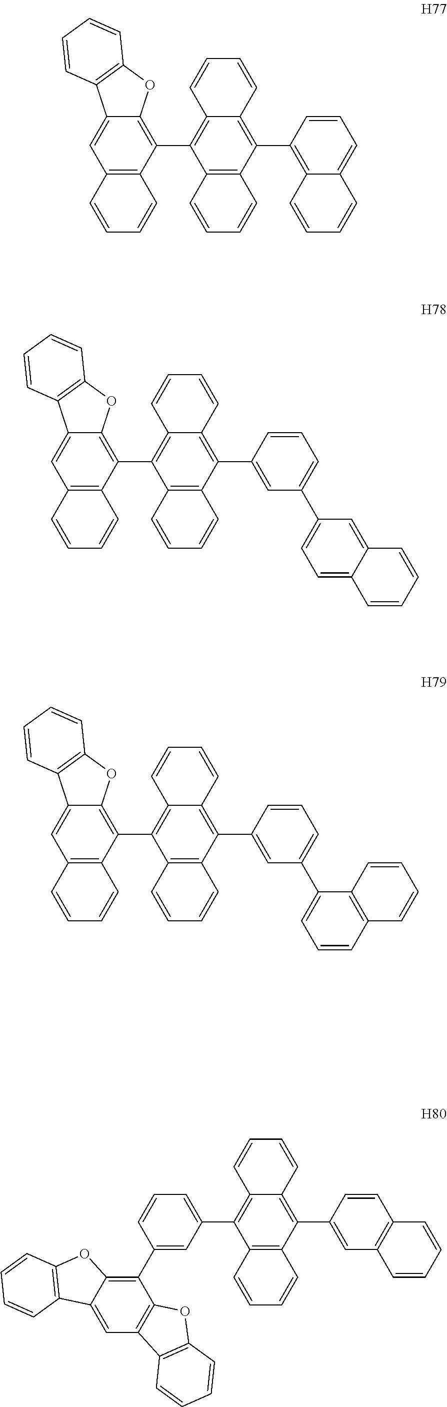 [SMILES: c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1]

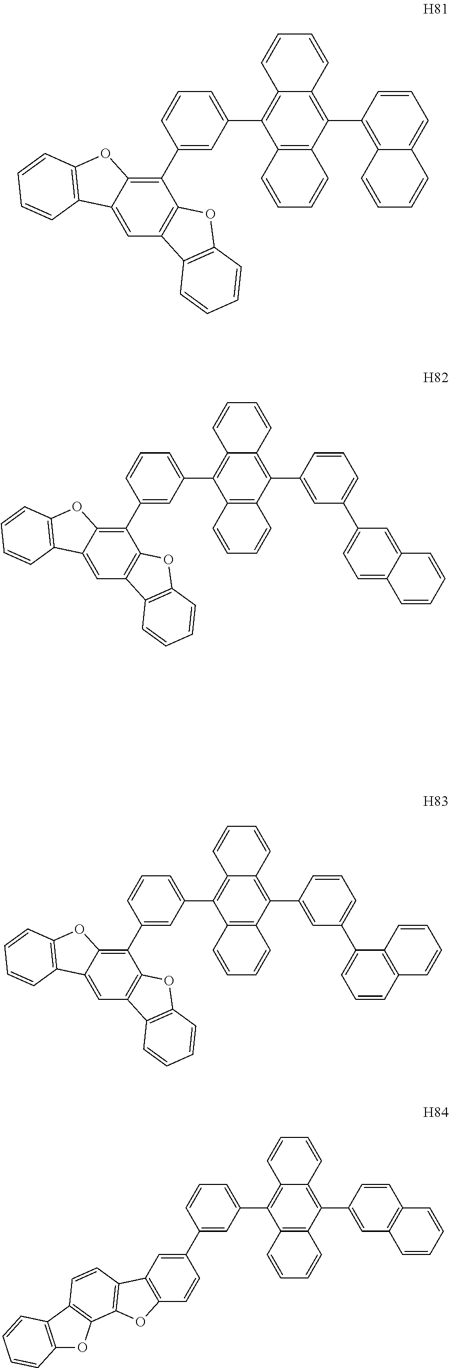 [SMILES: c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1]

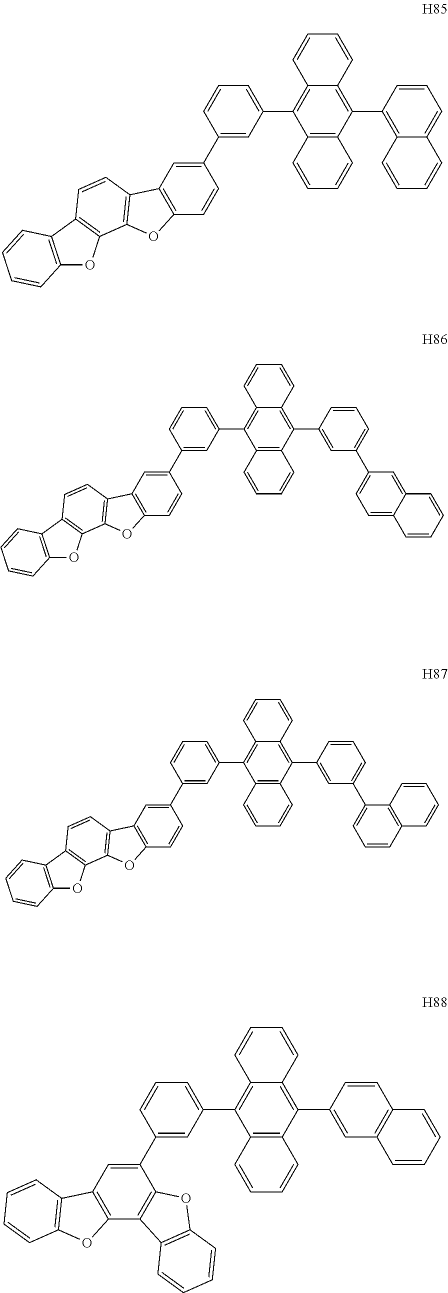 [SMILES: c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1]

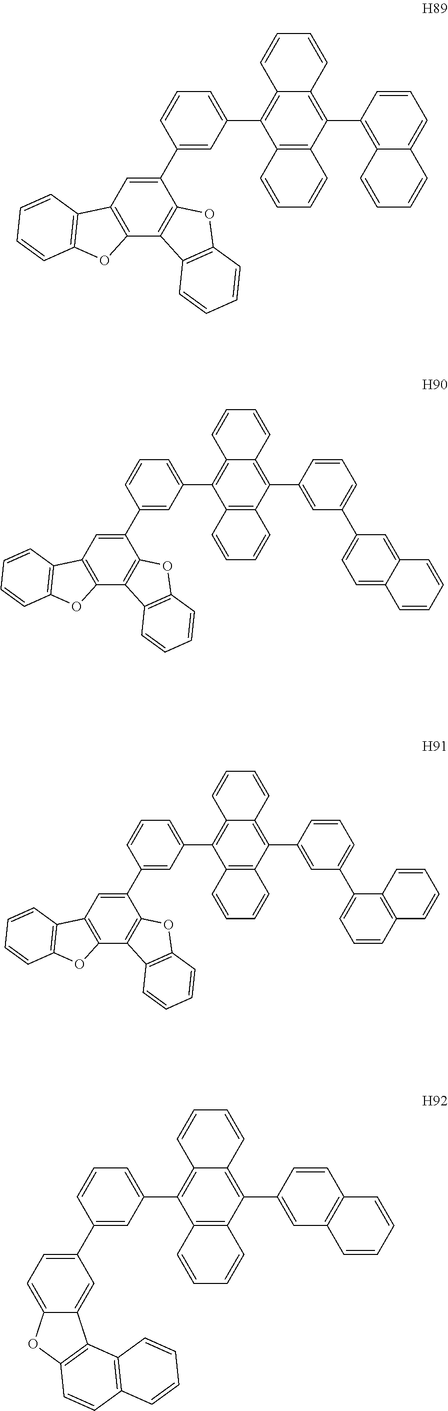 [SMILES: c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1]

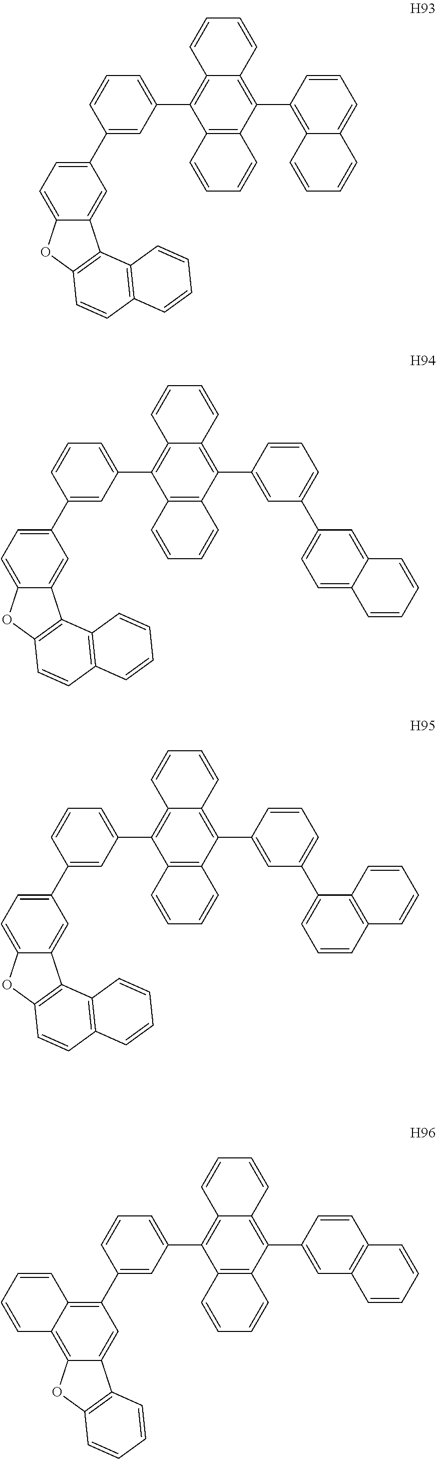 [SMILES: c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1]

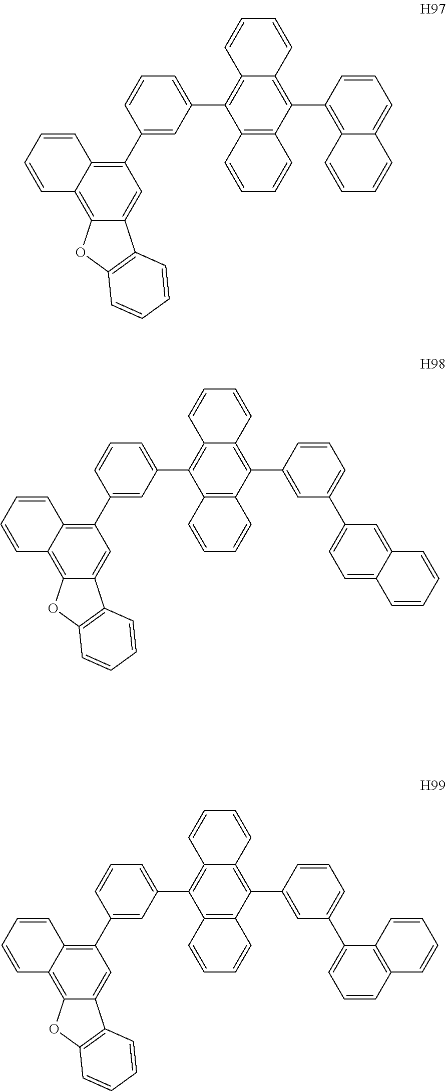 [SMILES: c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

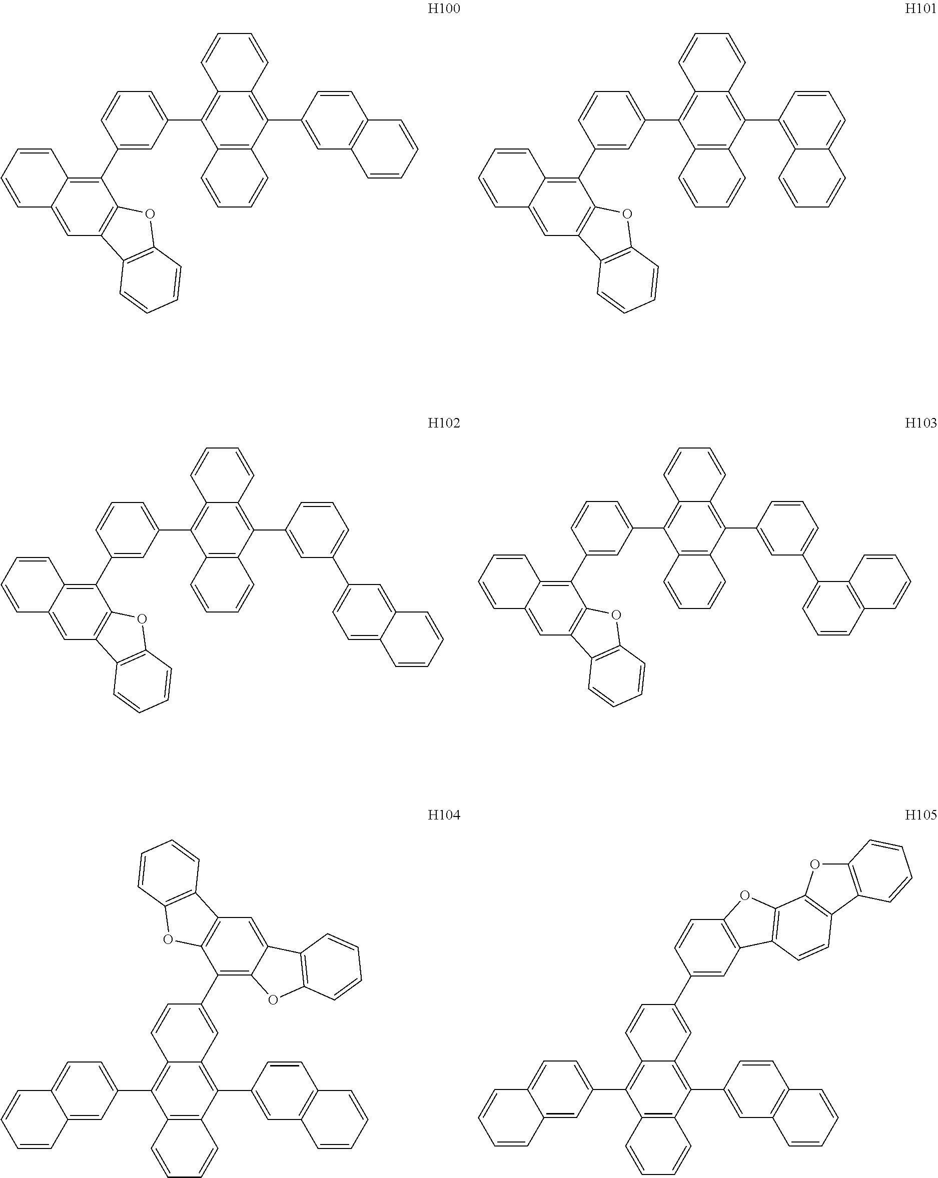

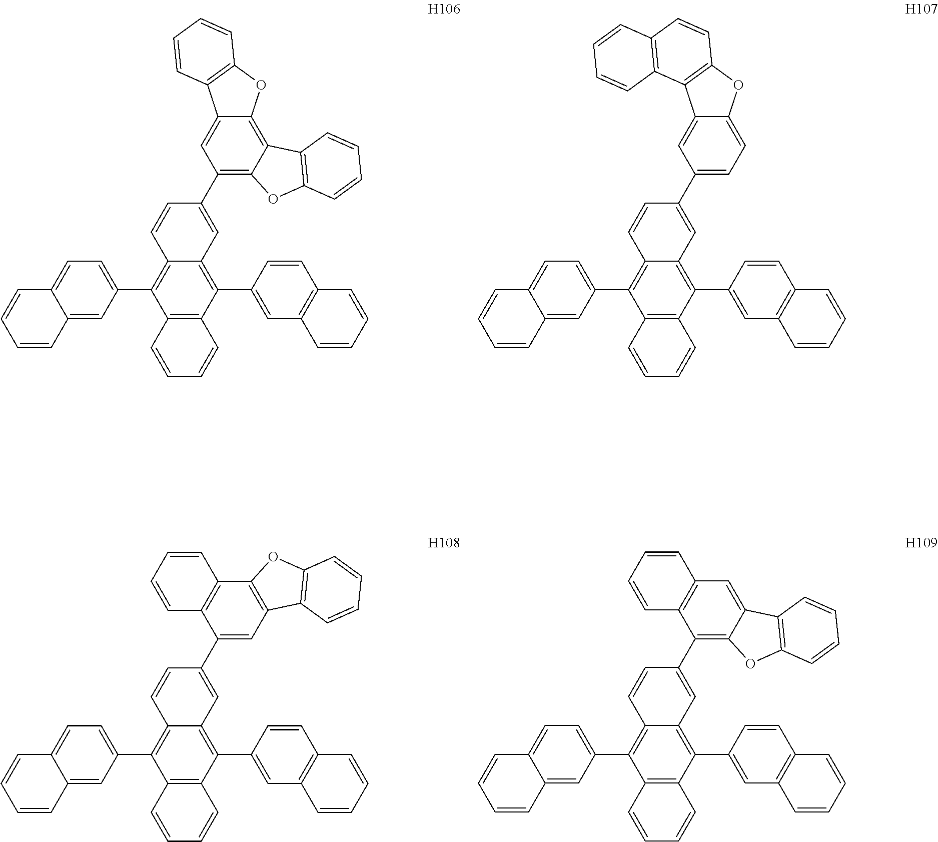 [SMILES: c1ccc2cc(-c3c4ccccc4c(-c4ccc5ccccc5c4)c4cc(-c5cc6c7ccccc7oc6c6c5oc5ccccc56)ccc34)ccc2c1 ; c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1]

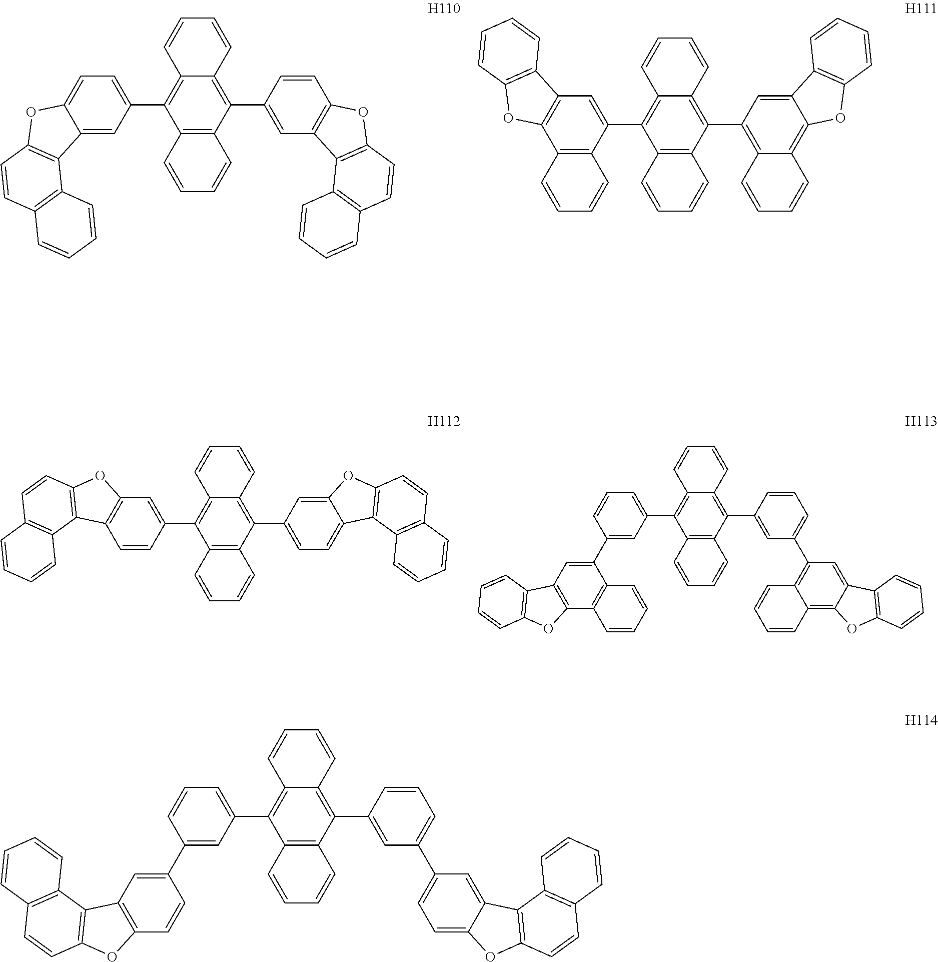

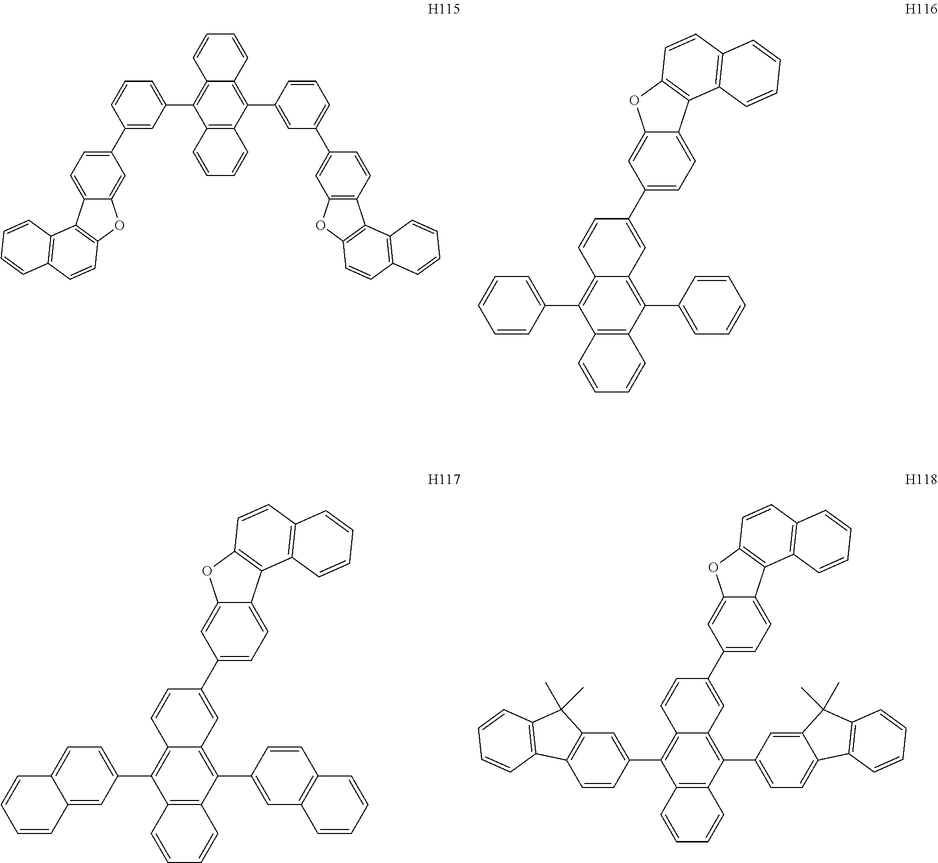 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

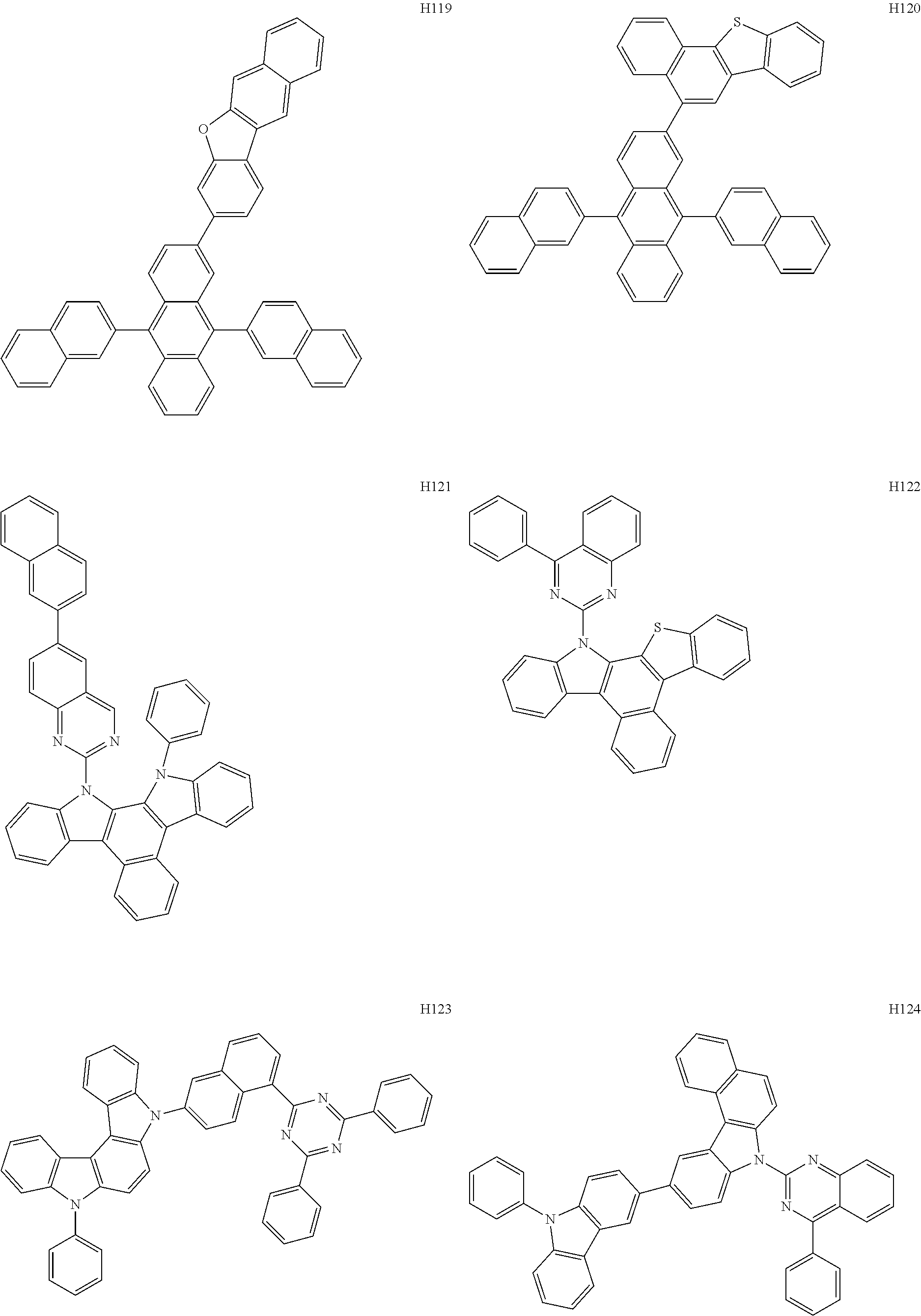

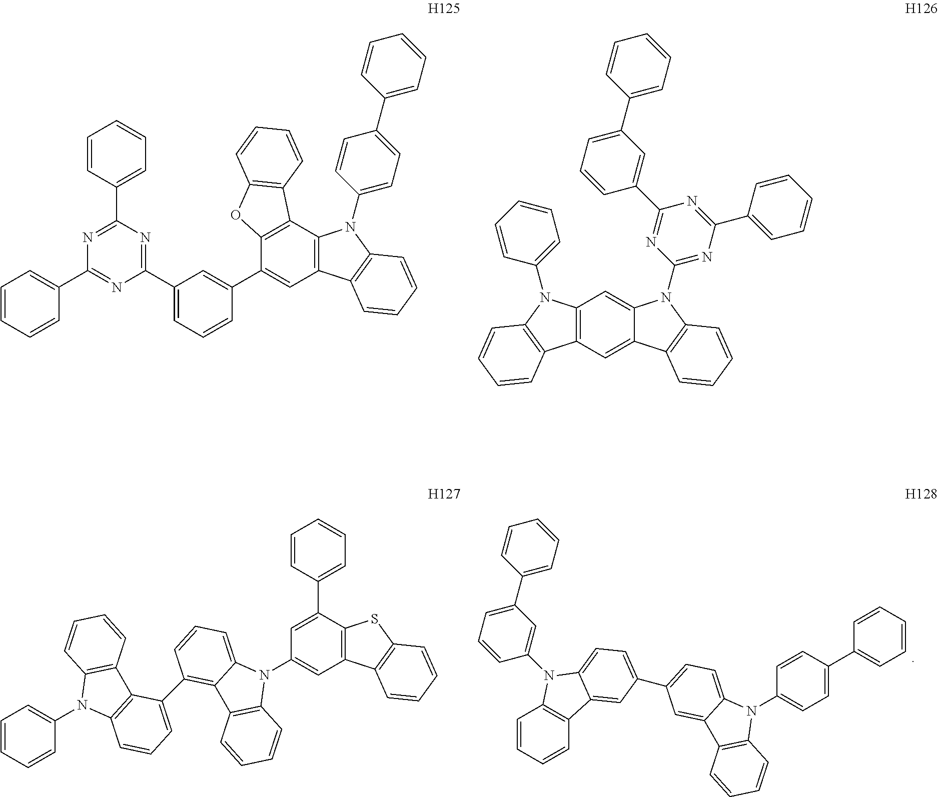 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### [Phosphorescent Dopant]

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

M(L₄₀₁)_{xc1}(L₄₀₂)_{xc2} [Formula 401]

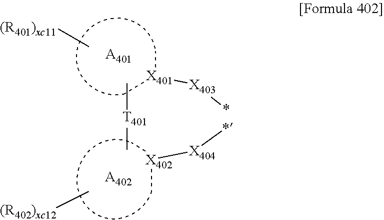

In Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein when xc1 is 2 or more, two or more of L₄₀₁ may be identical to or different from each other,
L₄₀₂ may be an organic ligand, and xc2 may be 0, 1, 2, 3, or 4, wherein when xc2 is 2 or more, two or more of L₄₀₂ may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁)=C(Q₄₁₂)-*′, *—C(Q₄₁)=*′, or *═C═*′,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁3)(Q₄₁₄),
Q₄₁₁ to Q₄₁₄ may each independently be the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group that is unsubstituted or substituted with at least one R₁₀ₐ, a C₁-C₂₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described in connection with Q₁,
xc11 and xc12 may each independently be an integer from 0 to 10, and
* and *′ in Formula 402 each indicate a binding site to M in Formula 401.

For example, in Formula 402, X₄₀₁ may be nitrogen and X₄₀₂ may be carbon, or X₄₀₁ and X₄₀₂ may each be nitrogen.

In an embodiment, in Formula 401, when xc1 is 2 or more, two ring A₄₀₁ among two or more of L₄₀₁ may be optionally linked together via T₄₀₂, which is a linking group, and two ring A₄₀₂ may be optionally linked together via T₄₀₃, which is a linking group (see Compounds PD1 to PD4 and PD7). T₄₀₂ and T₄₀₃ may each independently be the same as described in connection with T₄₀₁.

In Formula 401, L₄₀₂ may be an organic ligand. In an embodiment, L₄₀₂ may include a halogen group, a diketone group (for example, an acetylacetonate group), a carboxylic acid group (for example, a picolinate group), —C(═O), an isonitrile group, a —CN group, a phosphorus group (for example, a phosphine group, a phosphite group, etc.), or any combination thereof.

In an embodiment, the phosphorescent dopant may include, for example, one of Compounds PD1 to PD39, or any combination thereof:

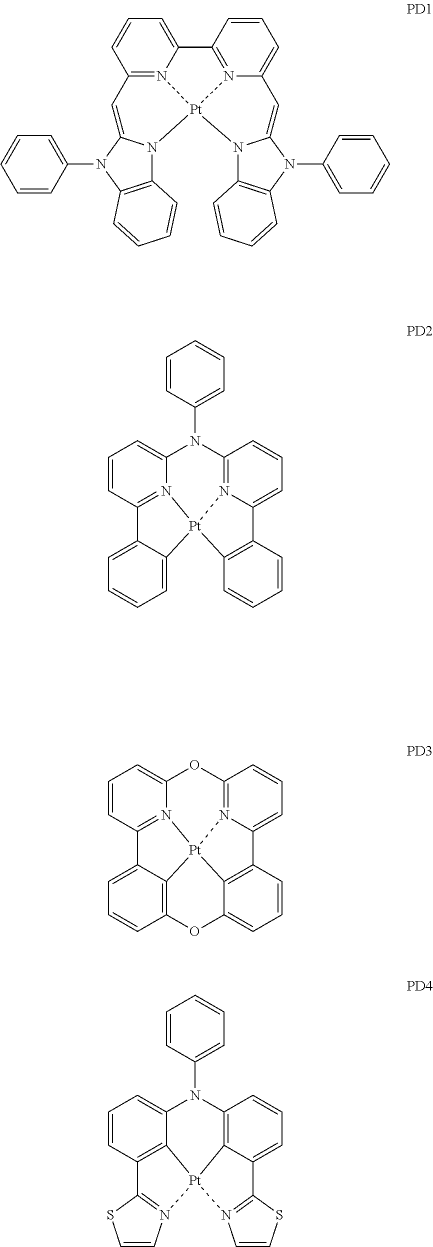

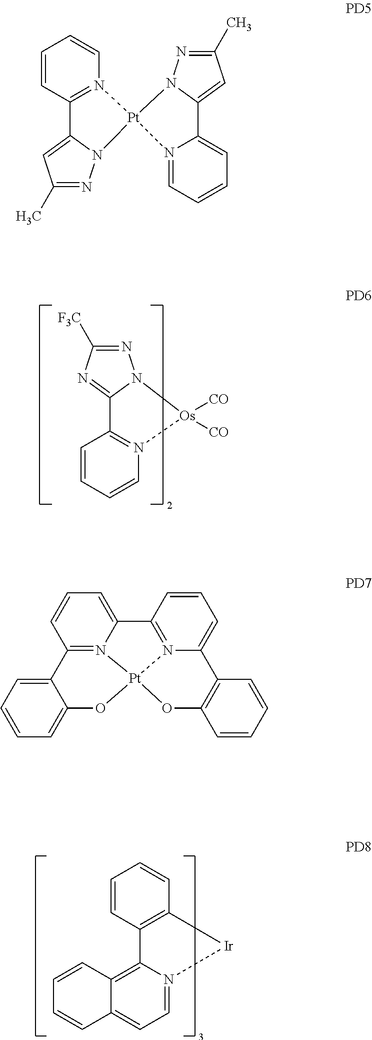

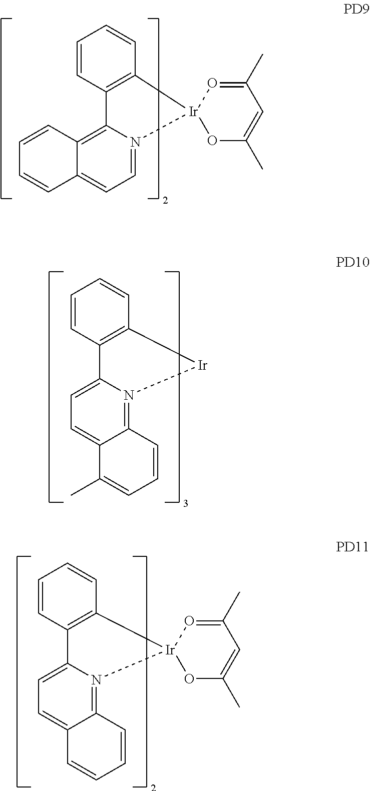

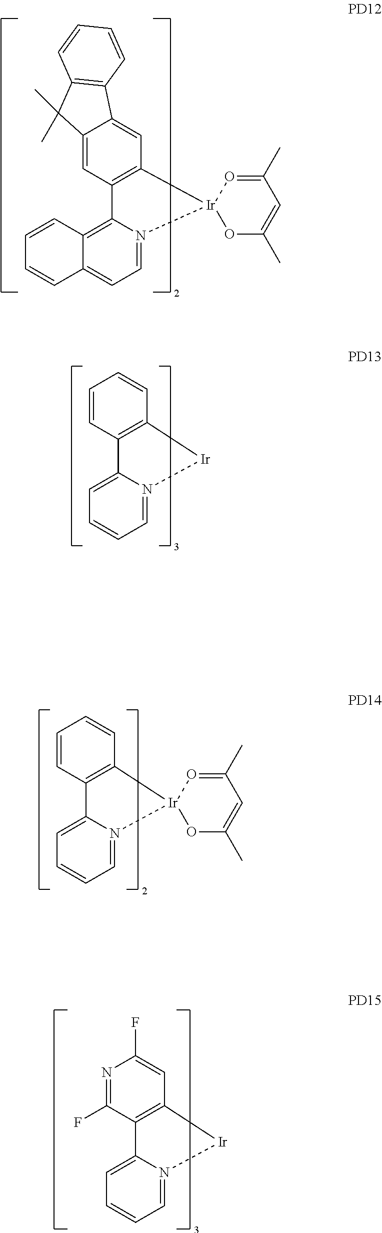

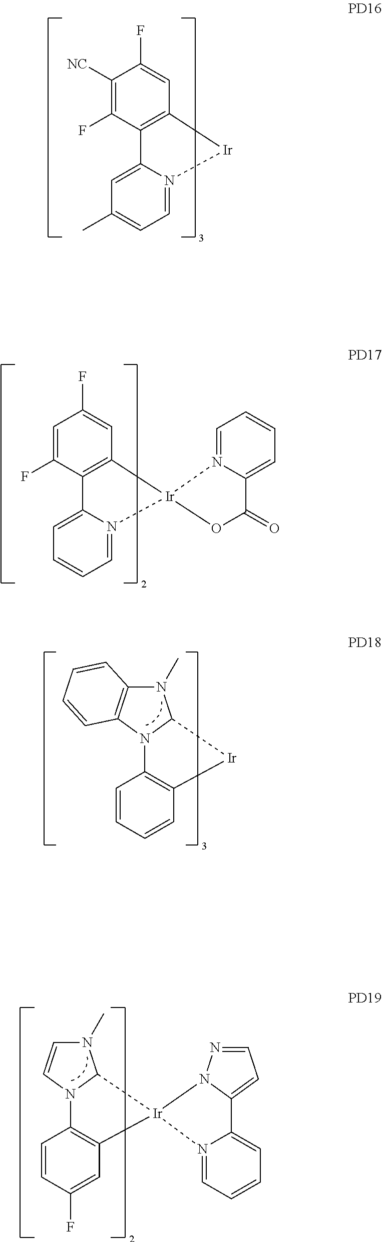

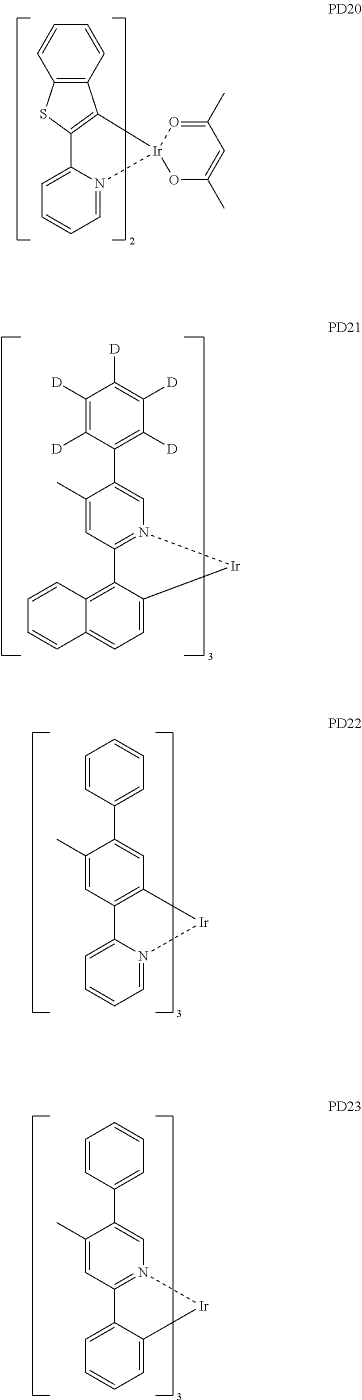

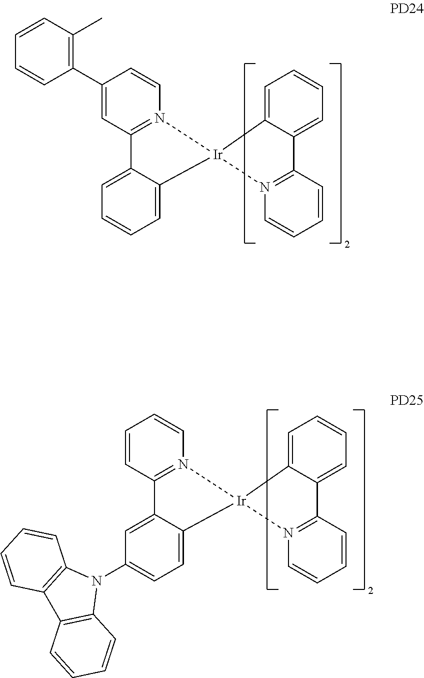

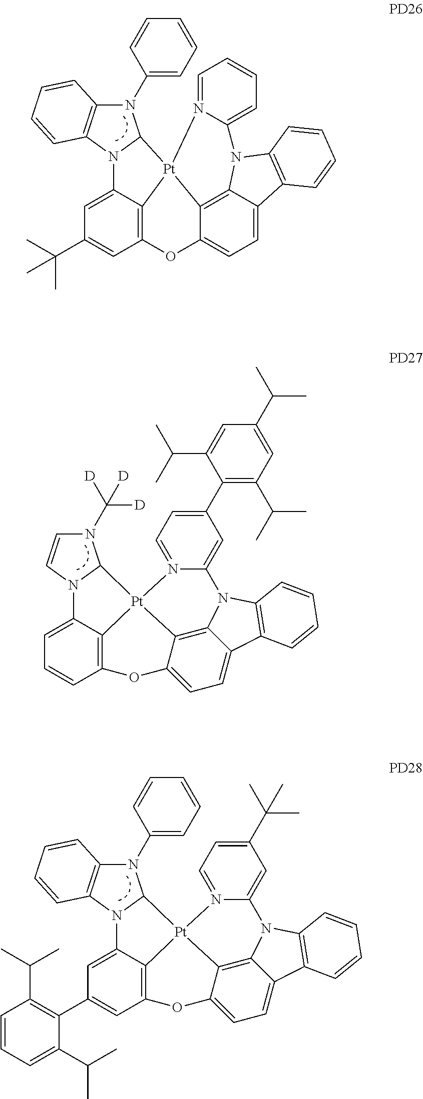

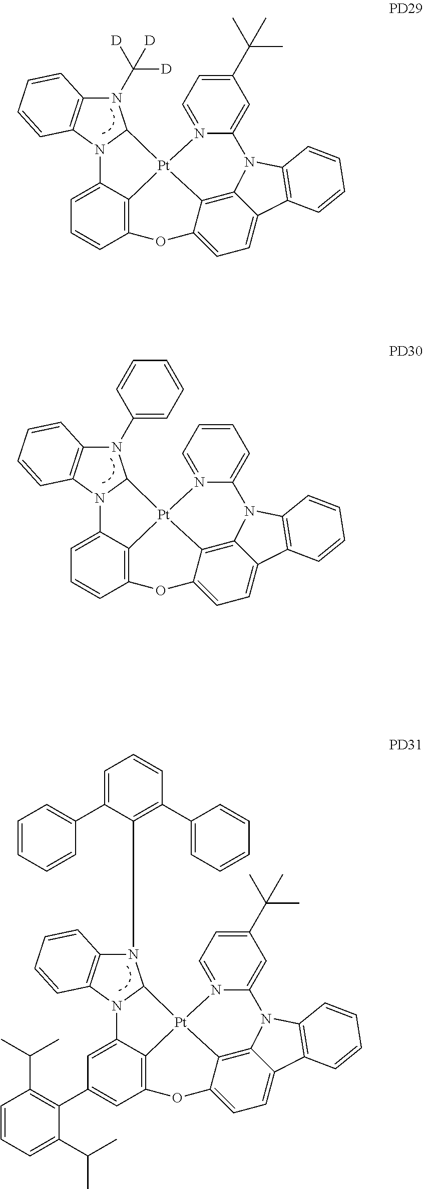

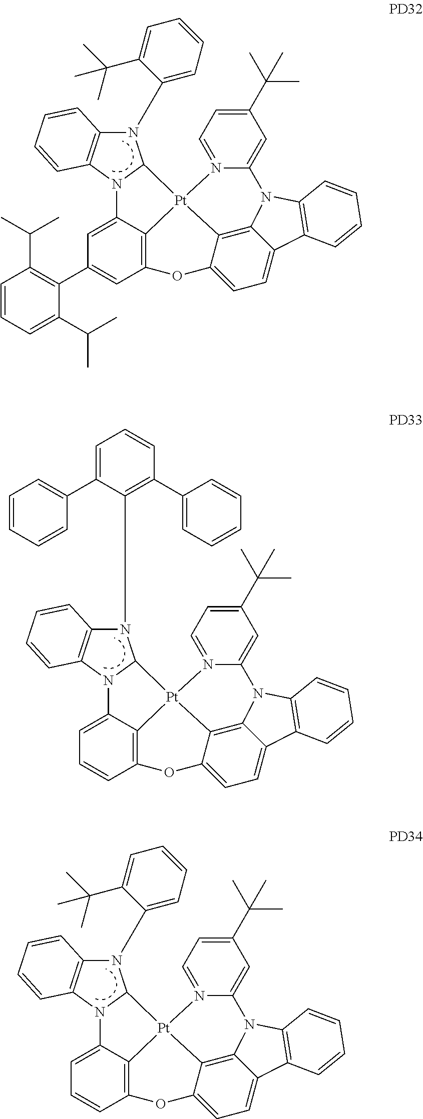

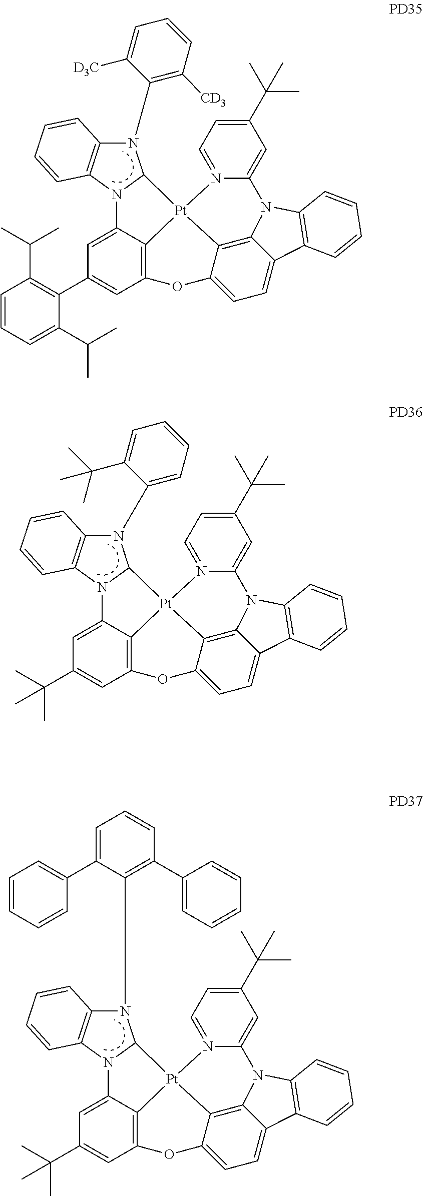

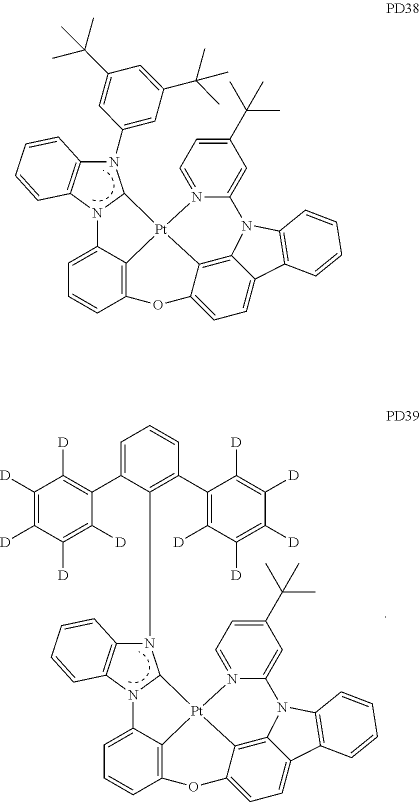

### [Fluorescent Dopant]

The fluorescent dopant may include an amine group-containing compound, a styryl group-containing compound, or any combination thereof.

In an embodiment, the fluorescent dopant may include a compound represented by Formula 501:

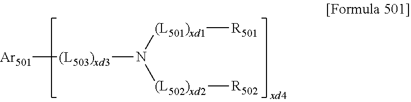

In Formula 501,
Ar₅₀₁, L₅₀₁ to L₅₀₃, R₅₀₁, and R₅₀₂ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xd1 to xd3 may each independently be 0, 1, 2, or 3, and
xd4 may be 1, 2, 3, 4, 5, or 6.

In an embodiment, in Formula 501, Ar₅₀₁ may be a condensed cyclic group (for example, an anthracene group, a chrysene group, a pyrene group, etc.) in which three or more monocyclic groups are condensed together.

In an embodiment, in Formula 501, xd4 may be 2.

In an embodiment, the fluorescent dopant may include one of Compounds FD1 to FD37, DPVBi, DPAVBi, or any combination thereof:

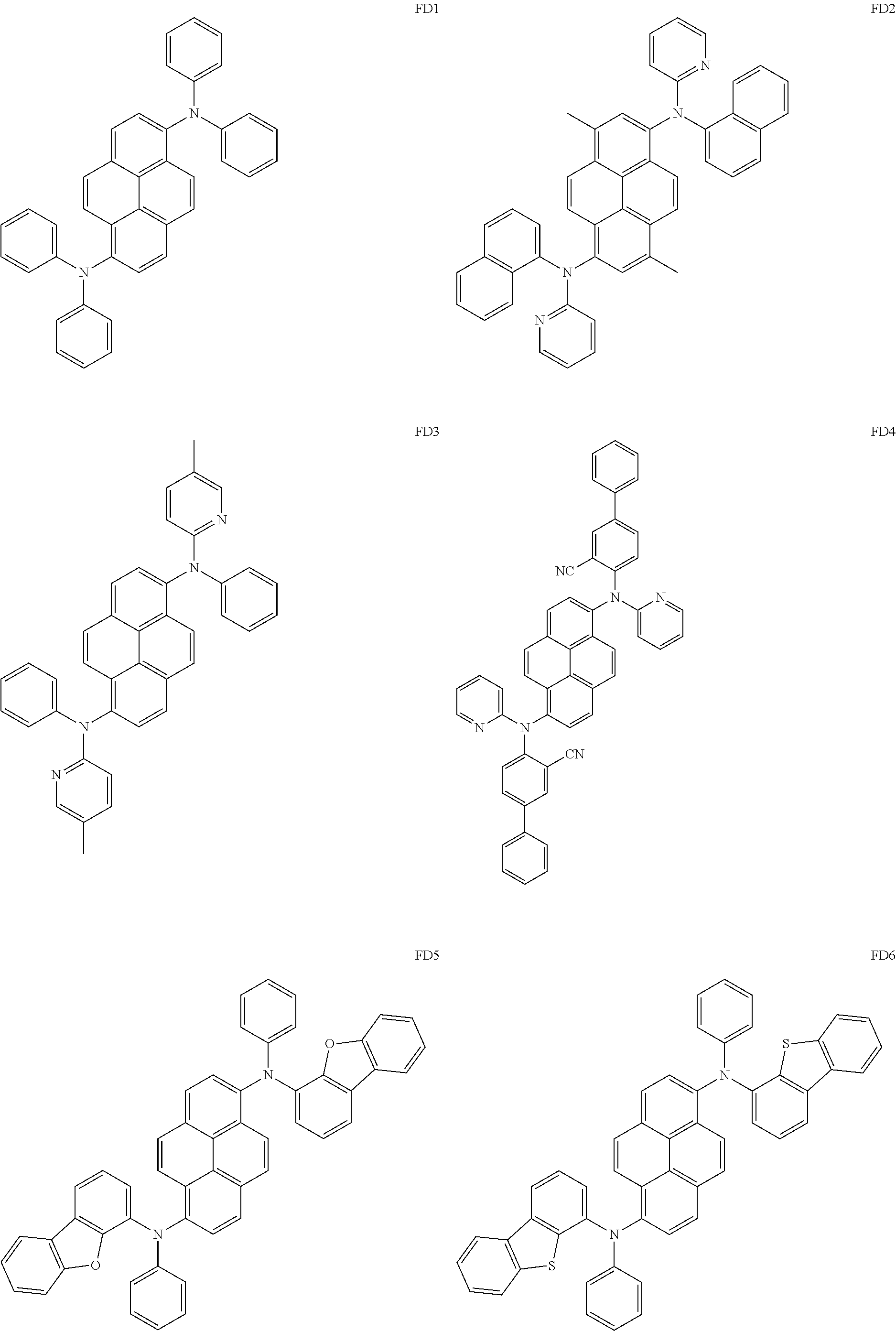

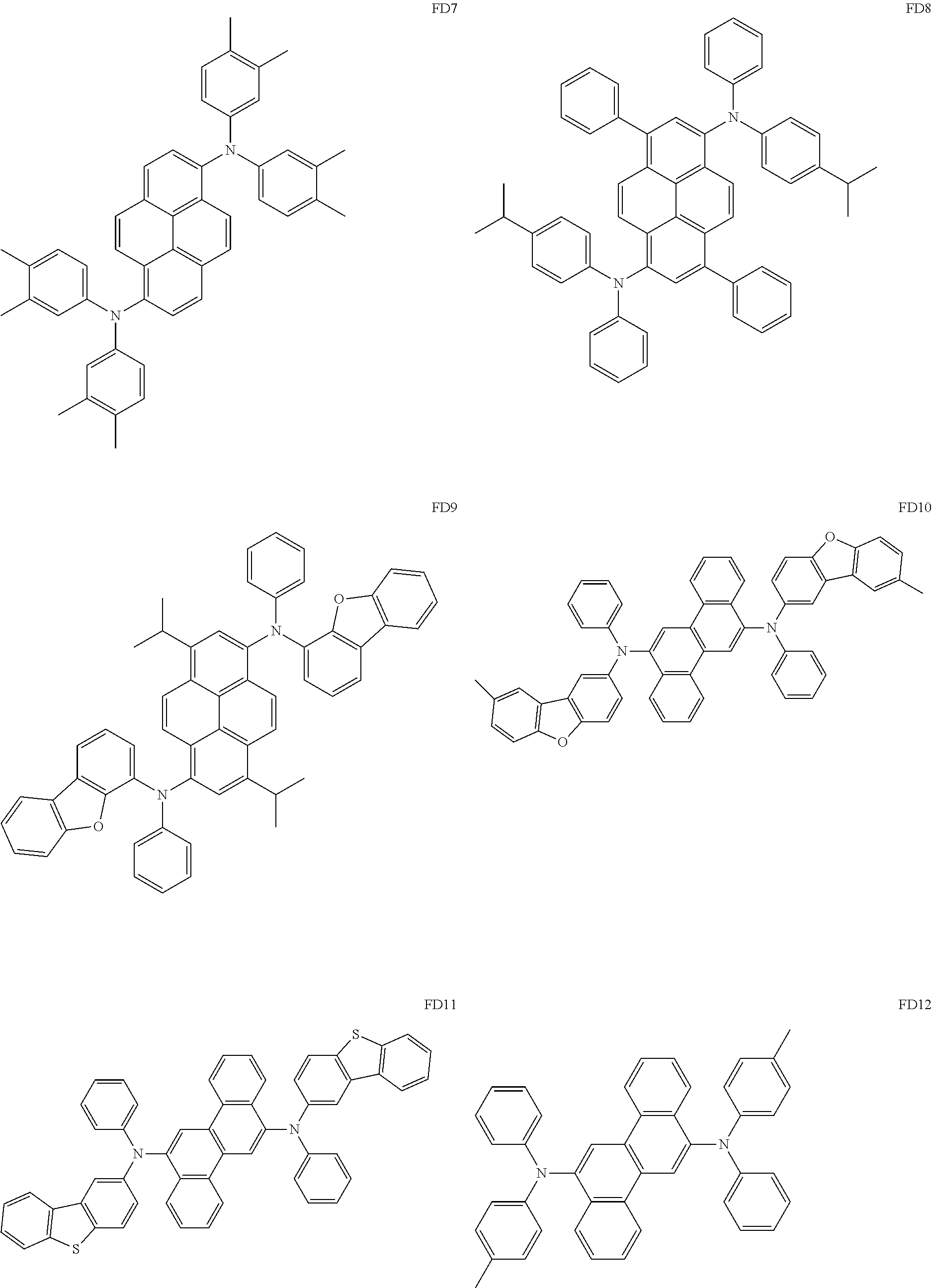

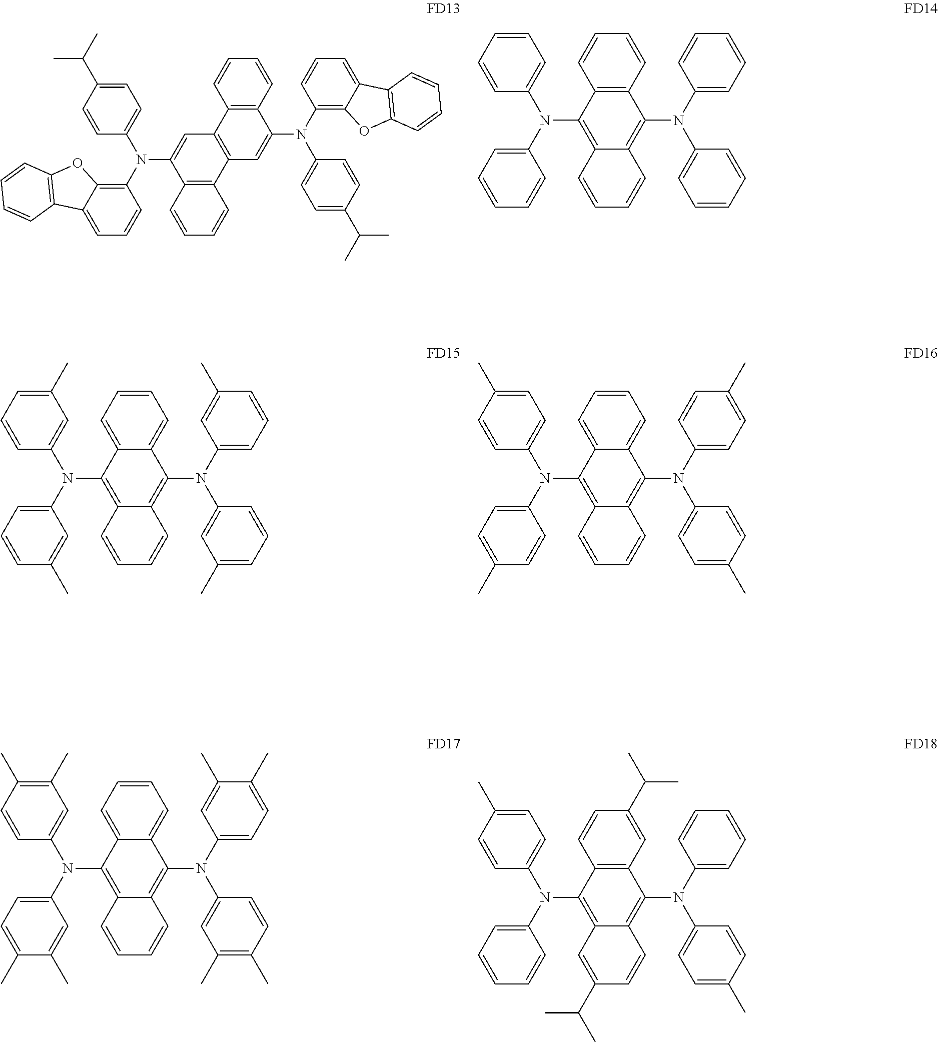

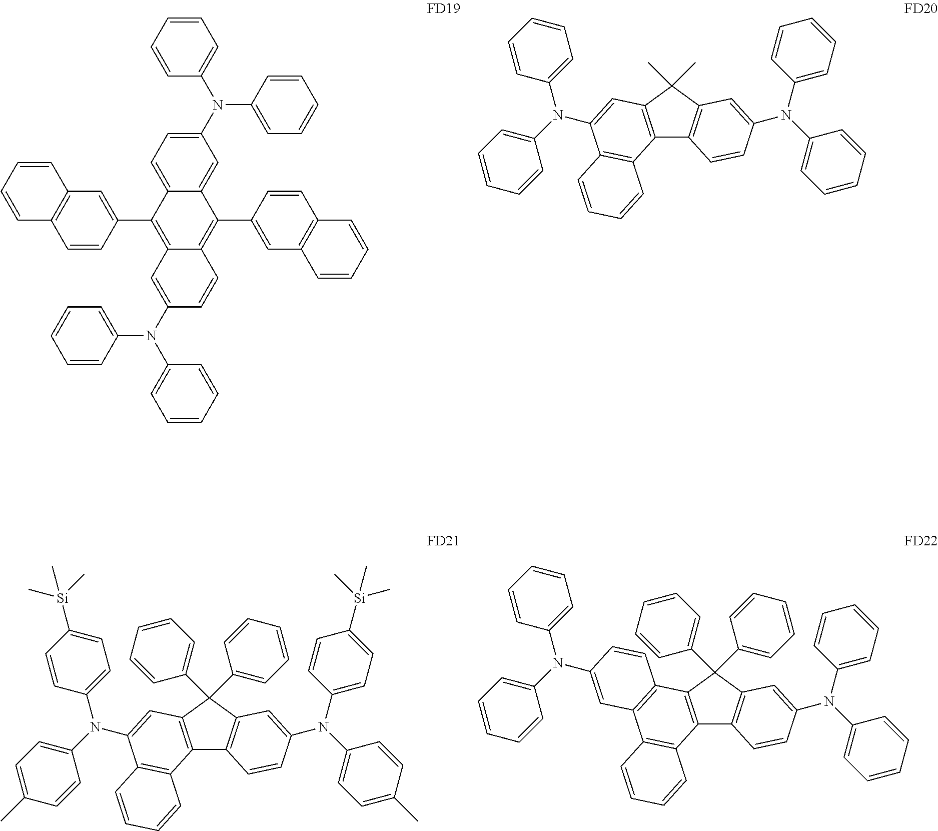

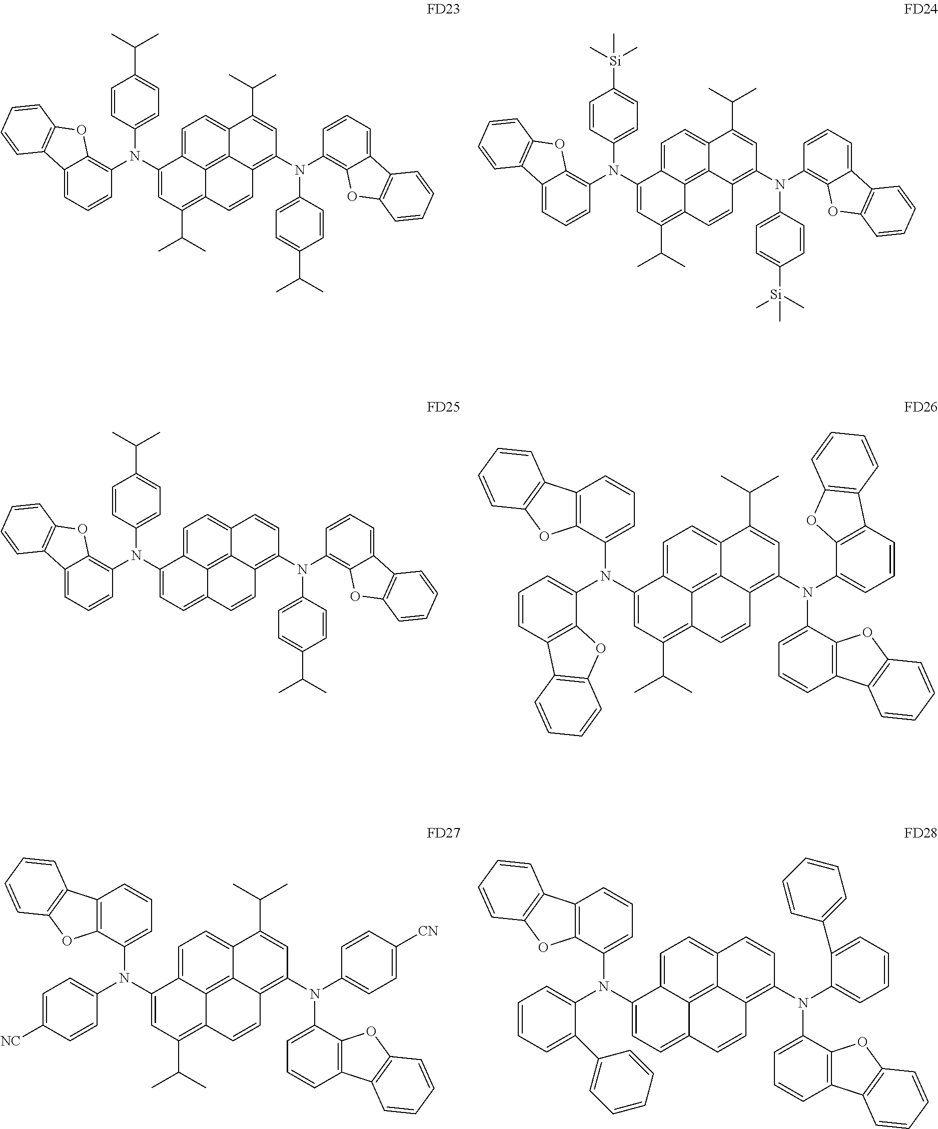

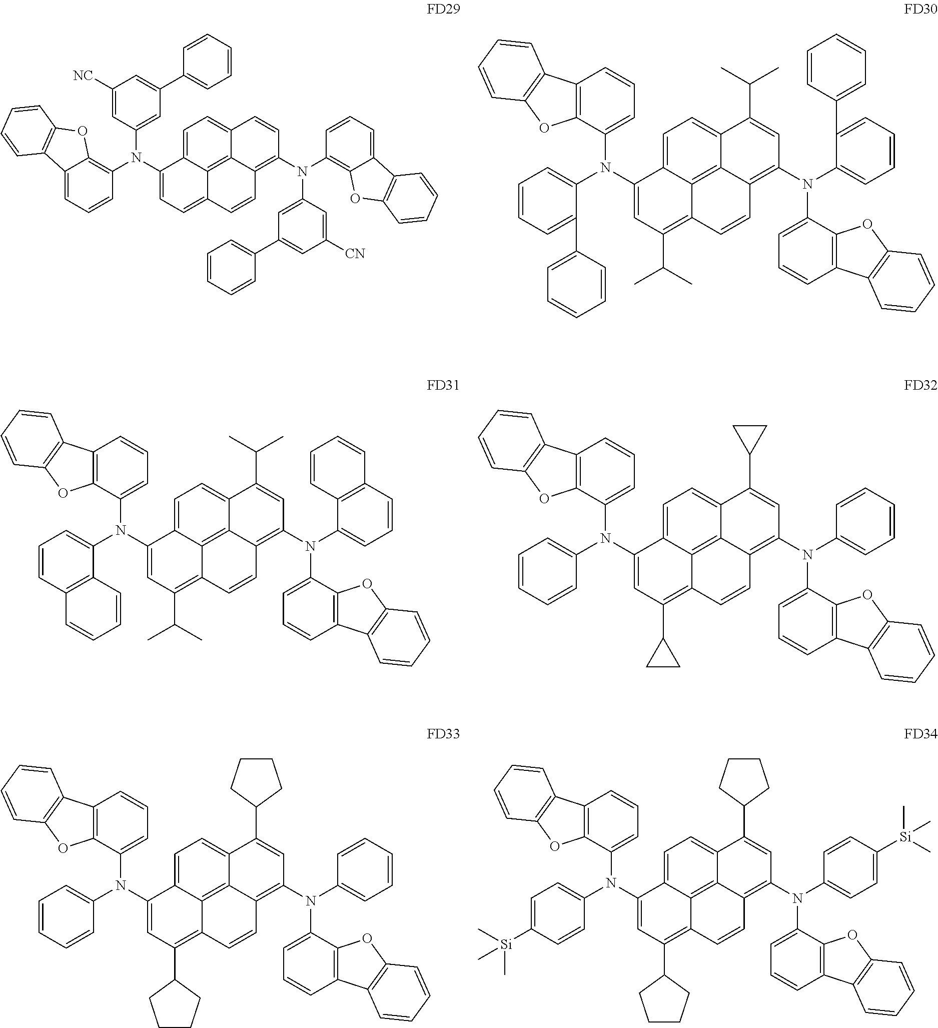

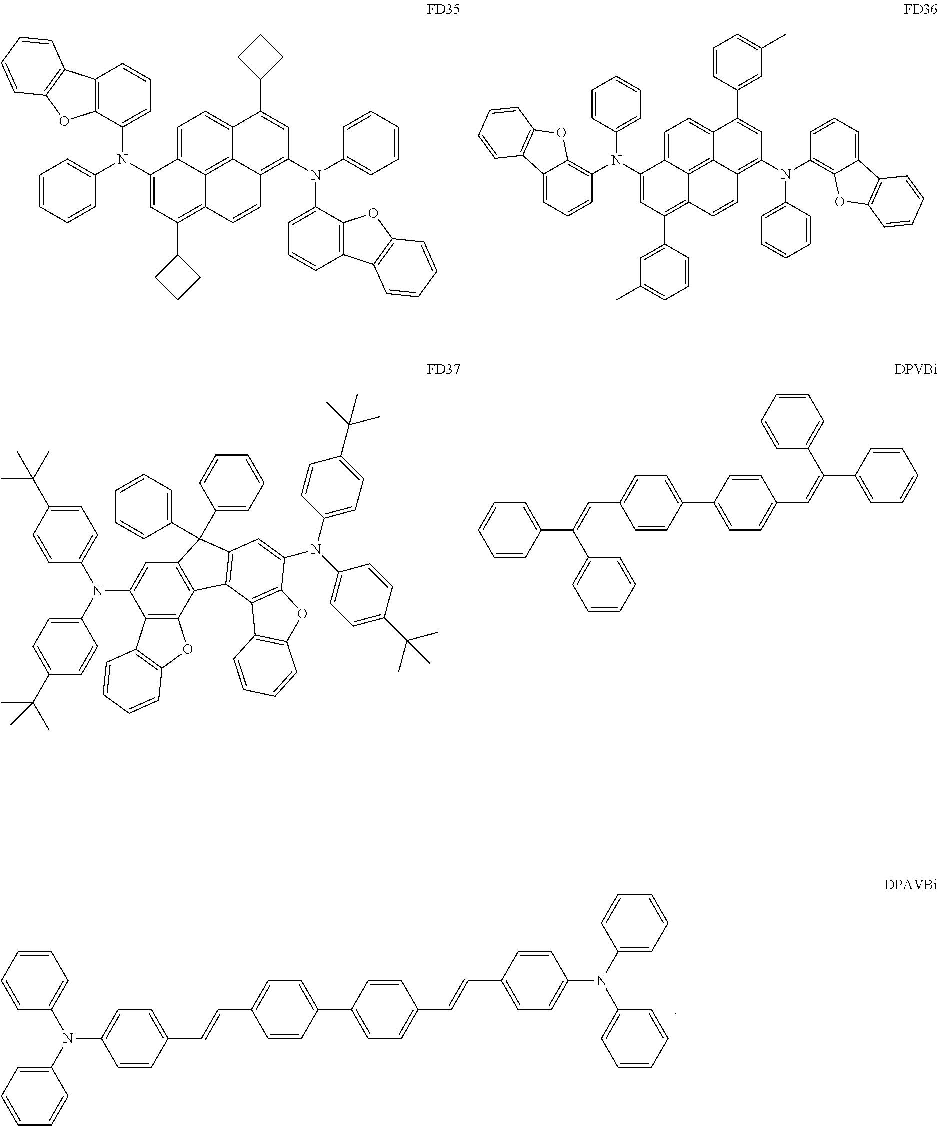

### [Delayed Fluorescence Material]

The emission layer may include a delayed fluorescence material.

In an embodiment, the delayed fluorescence material may be selected from compounds capable of emitting delayed fluorescence based on a delayed fluorescence emission mechanism.

The delayed fluorescence material included in the emission layer may serve as a host or as a dopant depending on the types of other materials included in the emission layer.

In an embodiment, a difference between a triplet energy level (eV) of the delayed fluorescence material and a singlet energy level (eV) of the delayed fluorescence material may be in a range of about 0 eV to about 0.5 eV. When a difference between a triplet energy level (eV) of the delayed fluorescence material and a singlet energy level (eV) of the delayed fluorescence material is within the above range, up-conversion from the triplet state to the singlet state of the delayed fluorescence materials may effectively occur, and thus, the light-emitting device 10 may have improved luminescence efficiency.

In an embodiment, the delayed fluorescence material may include: a material including at least one electron donor (for example, a π electron-rich C₃-C₆₀ cyclic group such as a carbazole group) and at least one electron acceptor (for example, a sulfoxide group, a cyano group, a π electron-deficient nitrogen-containing C₁-C₆₀ cyclic group, and the like); or a material including a C₈-C₆₀ polycyclic group including at least two cyclic groups that are condensed with each other while sharing boron (B).

In an embodiment, the delayed fluorescence material may include, for example, at least one of Compounds DF1 to DF14:

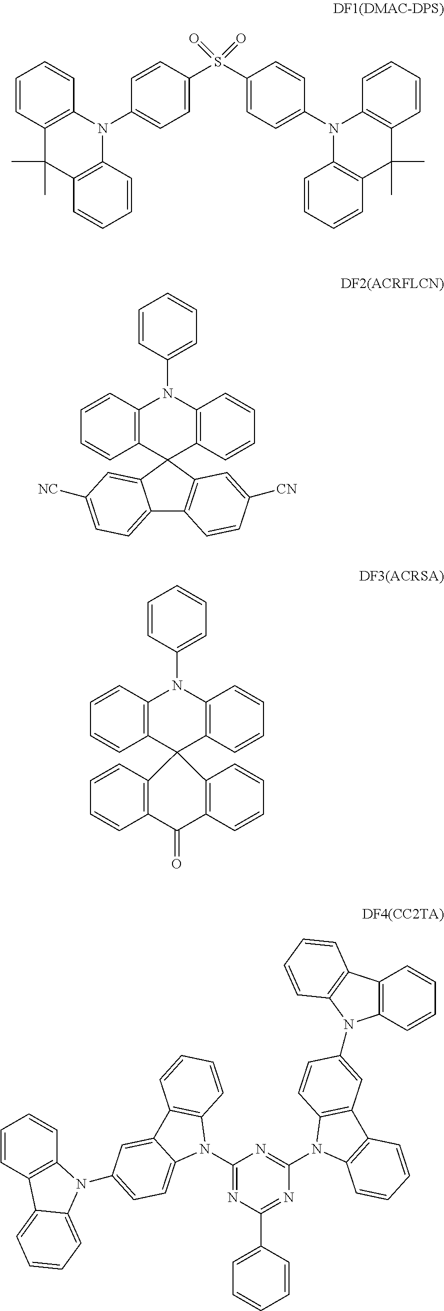

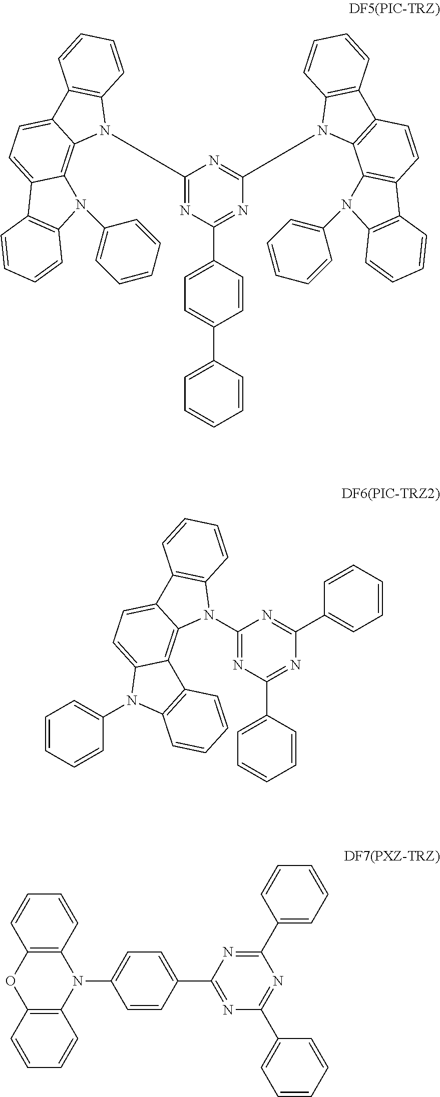 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

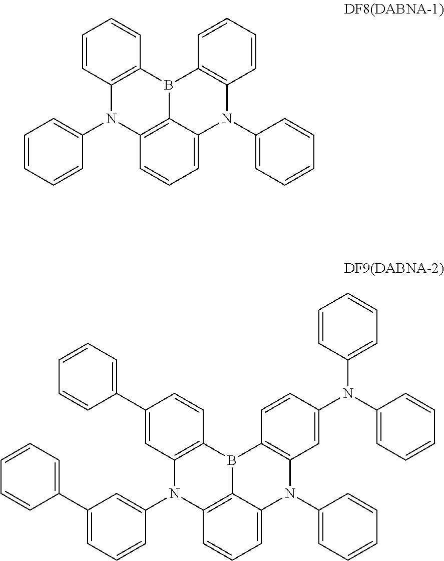 [SMILES: c1ccc(N2c3ccccc3B3c4ccccc4N(c4ccccc4)c4cccc2c43)cc1 ; c1ccc(-c2cccc(N3c4cc(-c5ccccc5)ccc4B4c5ccc(N(c6ccccc6)c6ccccc6)cc5N(c5ccccc5)c5cccc3c54)c2)cc1]

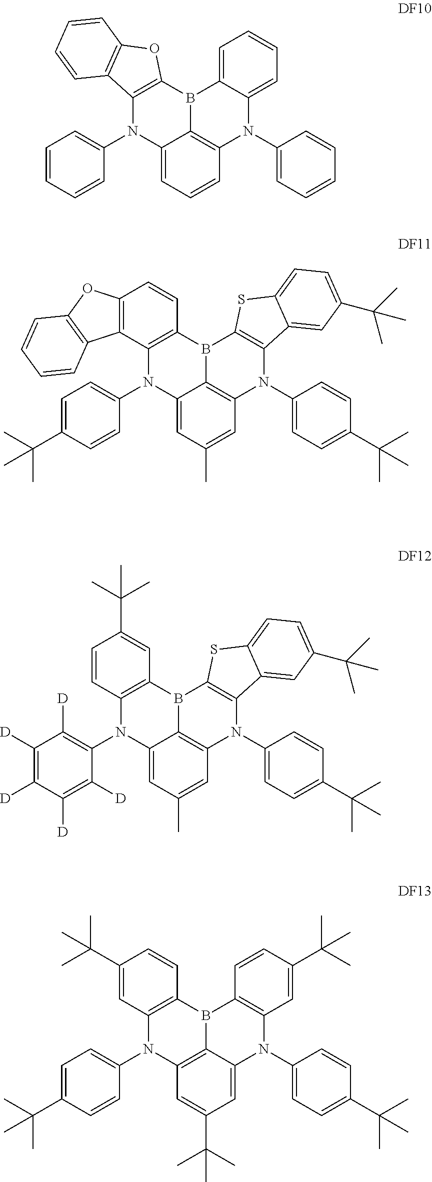

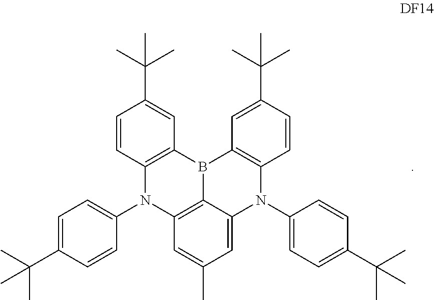 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### [Quantum Dot]

The emission layer 130 may include a quantum dot.

In the specification, a quantum dot may be a crystal of a semiconductor compound. Quantum dots may emit light of various emission wavelengths according to a size of the crystal. Quantum dots may also emit light of various emission wavelengths by adjusting the ratio of elements constituting the quantum dots.

A diameter of the quantum dots may be, for example, in a range of about 1 nm to about 10 nm.

The quantum dot may be synthesized by a wet chemical process, a metal organic chemical vapor deposition process, a molecular beam epitaxy process, or any process similar thereto.

The wet chemical process is a method that includes mixing a precursor material with an organic solvent and growing quantum dot particle crystals. When the crystal grows, the organic solvent naturally serves as a dispersant coordinated on the surface of the quantum dot crystal and controls the growth of the crystal so that the growth of quantum dot particles may be controlled through a process which costs less, and may be more readily performed than vapor deposition methods, such as metal organic chemical vapor deposition (MOCVD) or molecular beam epitaxy (MBE).

The quantum dot may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound, such as CdZnSeS, CdZnSeTe, CdZnSTe, CdHgSeS, CdHgSeTe, CdHgSTe, HgZnSeS, HgZnSeTe, or HgZnSTe; or any combination thereof.

Examples of a Group III-V semiconductor compound may include: a binary compound, such as GaN, GaP, GaAs, GaSb, AlN, AlP, AlAs, AlSb, InN, InP, InAs, or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; or any combination thereof. In an embodiment, the Group III-V semiconductor compound may further include a Group II element. Examples of a Group III-V semiconductor compound further including the Group II element may include InZnP, InGaZnP, and InAlZnP.

Examples of a Group III-VI semiconductor compound may include: a binary compound, such as GaS, Ga₂S₃, GaSe, Ga₂Se₃, GaTe, InS, InSe, In₂S₃, In₂Se₃, InTe, etc.; a ternary compound, such as InGaS₃, InGaSe₃, etc.; or any combination thereof.

Examples of a Group I-III-VI semiconductor compound may include: a ternary compound, such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, AgAlO₂, etc.; a quaternary compound, such as AgInGaS₂, AgInGaSe₂, etc.; or any combination thereof.

Examples of a Group IV-VI semiconductor compound may include: a binary compound, such as SnS, SnSe, SnTe, PbS, PbSe, or PbTe; a ternary compound, such as SnSeS, SnSeTe, SnSTe, PbSeS, PbSeTe, PbSTe, SnPbS, SnPbSe, or SnPbTe; a quaternary compound, such as SnPbSSe, SnPbSeTe, or SnPbSTe; or any combination thereof.

Examples of a Group IV element or compound may include: a single element, such as Si, Ge, etc.; a binary compound, such as SiC, SiGe, etc.; or any combination thereof.

Each element included in a compound, such as a binary compound, a ternary compound, or a quaternary compound, may be present at a uniform concentration or non-uniform concentration in a particle. In an embodiment, the formulae above refers to types of elements included in the compound, wherein the element ratios in the compound may vary. For example, AgInGaS₂ may refer to AgInₓGa₁₋ₓS₂ (wherein x is a real number between 0 and 1).

In an embodiment, the quantum dot may have a single structure in which the concentration of each element in the quantum dot is uniform, or the quantum dot may have a core-shell structure. In an embodiment, in case that the quantum dot has a core-shell structure, a material included in the core and a material included in the shell may be different from each other.

The shell of the quantum dot may serve as a protective layer that prevents chemical denaturation of the core to maintain semiconductor characteristics, and/or may serve as a charging layer that imparts electrophoretic characteristics to the quantum dot. The shell may be a single layer or a multilayer. An interface between the core and the shell may have a concentration gradient in which the concentration of a material that is present in the shell decreases toward the core.

Examples of a shell of the quantum dot may include a metal oxide, a non-metal oxide, a semiconductor compound, or any combination thereof. Examples of a metal oxide, or a non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, etc.; a ternary compound, such as MgAl₂O₄, CoFe₂O₄, NiFe₂O₄, CoMn₂O₄, etc.; or any combination thereof.

Examples of a semiconductor compound may include a Group III-VI semiconductor compound, a Group II-VI semiconductor compound, a Group III-V semiconductor compound, a Group I-III-VI semiconductor compound, a Group IV-VI semiconductor compound, or any combination thereof, as described herein. For example, a semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

The quantum dot may have a full width at half maximum (FWHM) of an emission wavelength spectrum of less than or equal to about 45 nm. For example, the quantum dot may have an FWHM of an emission wavelength spectrum less than or equal to about 40 nm. For example, the quantum dot may have an FWHM of an emission wavelength spectrum less than or equal to about 30 nm. When the FWHM of an emission wavelength of the quantum dot is within any of these ranges, the quantum dot may have improved color purity and/or improved color reproducibility. Light emitted through the quantum dot may be emitted in all directions, a wide viewing angle may be improved.

In an embodiment, the quantum dot may be in a spherical form, a pyramidal form, a multi-arm form, or a cubic form, or the quantum dot may be in the form of nanoparticles, nanotubes, nanowires, nanofibers, or nanoplate particles.

Since the energy band gap may be controlled by adjusting the size of the quantum dots or the ratio of elements in the quantum dot compound, light of various wavelengths may be obtained from the quantum dot-containing emission layer. Therefore, by using the aforementioned quantum dots (using quantum dots of different sizes or having different element ratios in the quantum dot compound), a light-emitting device emitting light of various wavelengths may be implemented. In an embodiment, the size of the quantum dots or the ratio of elements in the quantum dot compound may be selected to emit red light, green light, and/or blue light. In an embodiment, the size of the quantum dots may be configured to emit white light by a combination of light of various colors.

### [Electron Transport Region 140]

The electron transport region 140 may have a structure consisting of a layer including a single material, a structure consisting of a layer including different materials, or a structure including multiple layers including different materials.

The electron transport region 140 may include a buffer layer, a hole blocking layer, an electron control layer, an electron transport layer, an electron injection layer, or any combination thereof.

In an embodiment, the electron transport region 140 may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the layers for each structure may be sequentially stacked from the emission layer 130 in its respective stated order, but the structure of the electron transport region 140 is not limited thereto.

The electron transport region 140 (for example, the buffer layer, the hole blocking layer, the electron control layer, or the electron transport layer in the electron transport region) may include a metal-free compound including at least one π electron-deficient nitrogen-containing C₁-C₆₀ cyclic group.

In an embodiment, the electron transport region 140 may include a compound represented by Formula 601.

[Ar₆₀₁]ₓₑ₁₁-[(L₆₀₁)ₓₑ₁-R₆₀₁]ₓₑ₂₁ [Formula 601]

In Formula 601,

Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group that is unsubstituted or substituted with at least one R₁₀ₐ.

In an embodiment, in Formula 601, when xe11 is 2 or more, two or more of Ar₆₀₁ may be linked together via a single bond.

In an embodiment, in Formula 601, Ar₆₀₁ may be an anthracene group that is unsubstituted or substituted with at least one R₁₀ₐ.

In an embodiment, the electron transport region 140 may include a compound represented by Formula 601-1:

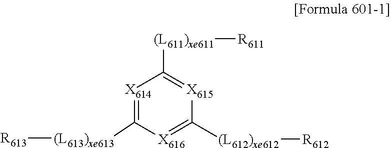

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

In an embodiment, in Formulae 601 and 601-1, xe1 and xe611 to xe613 may each independently be 0, 1, or 2.

In an embodiment, the electron transport region 140 may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

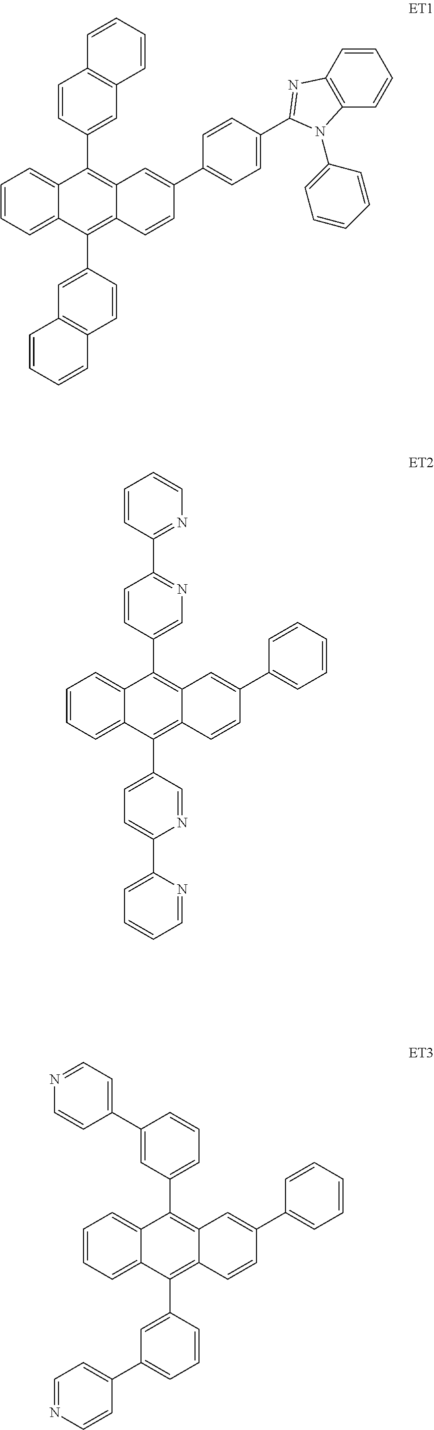 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

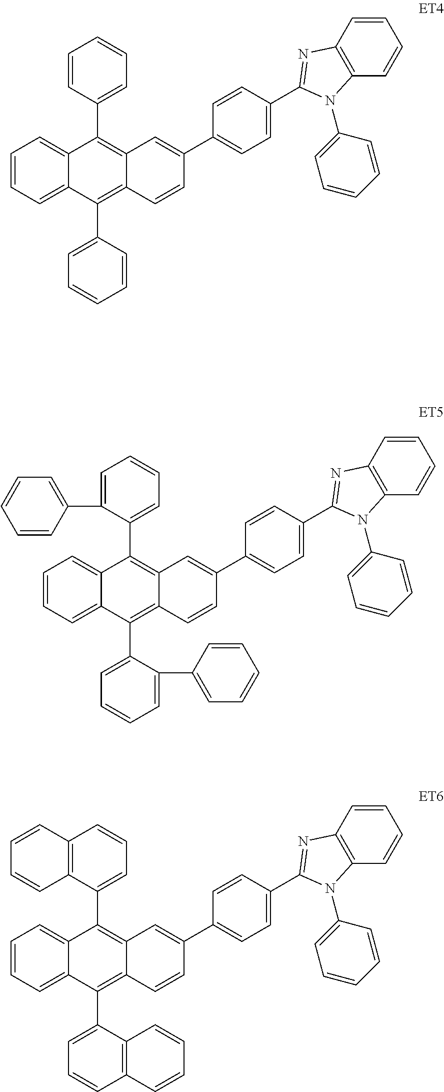 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

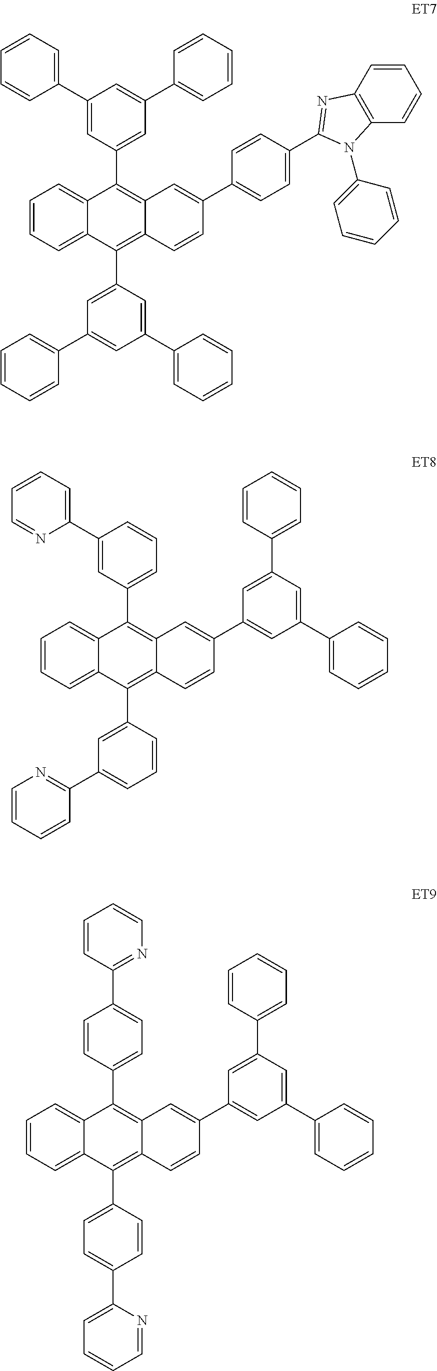 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

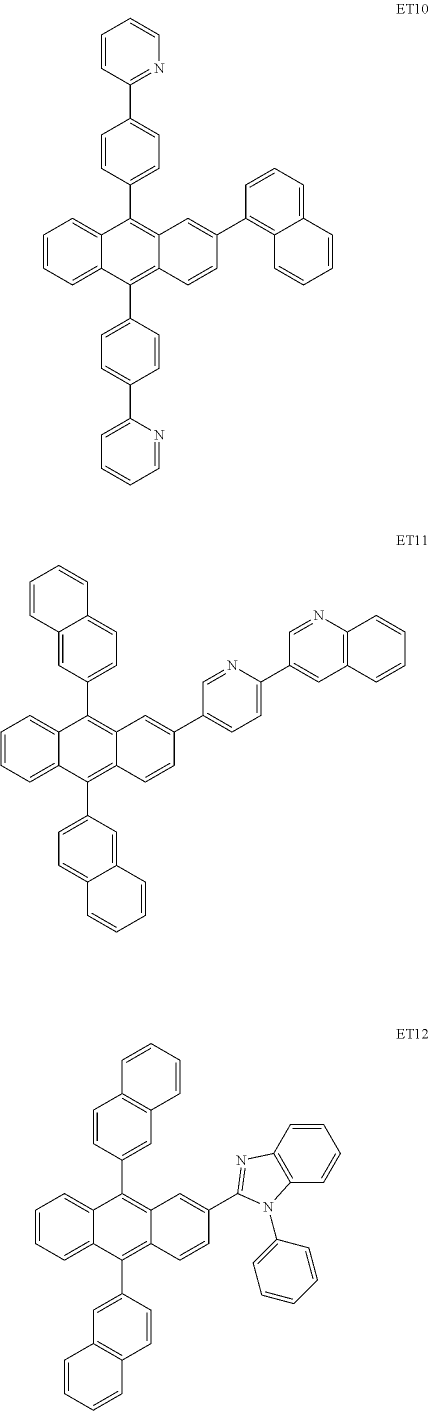 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

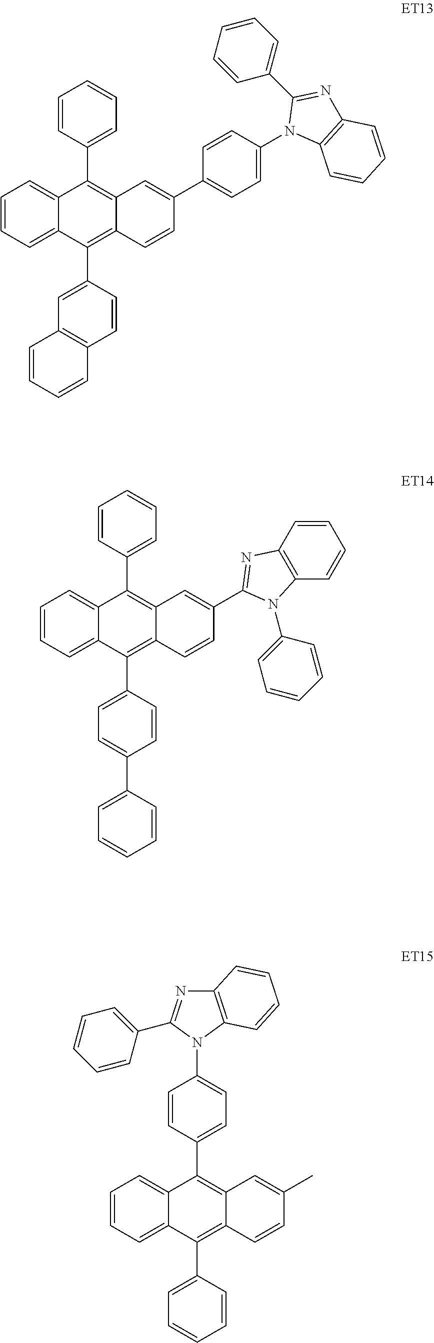 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

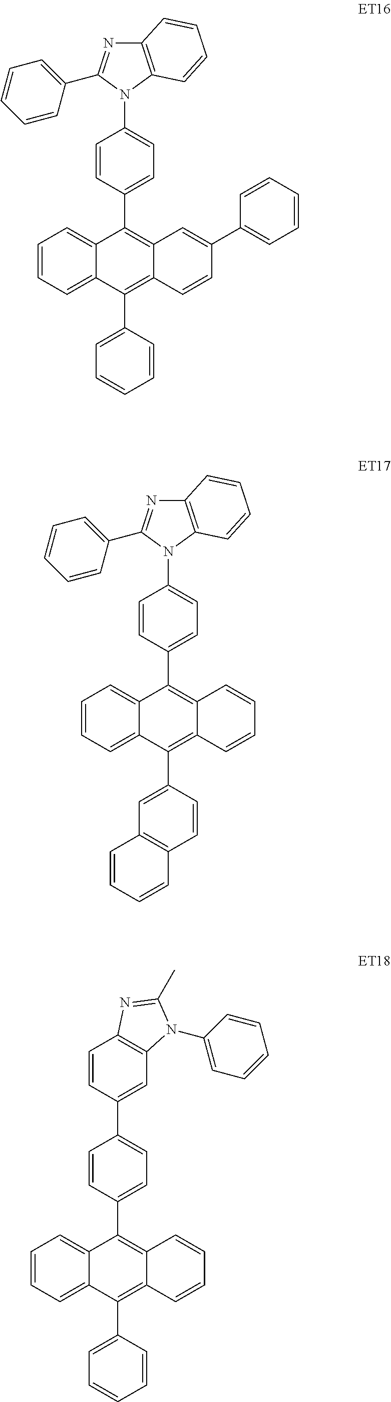 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

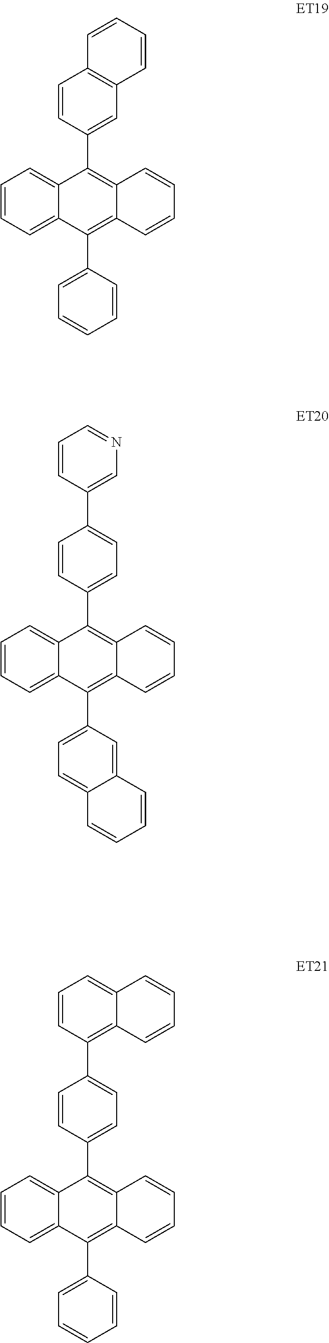

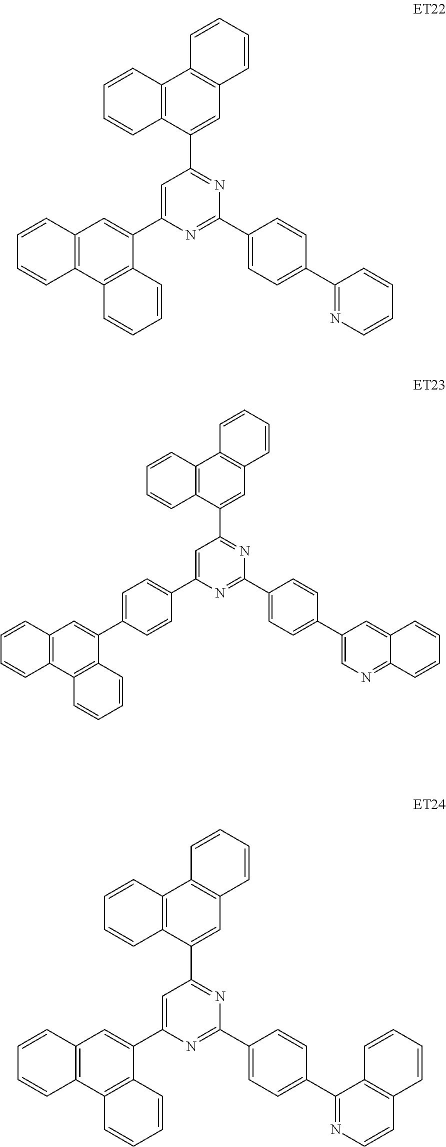 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

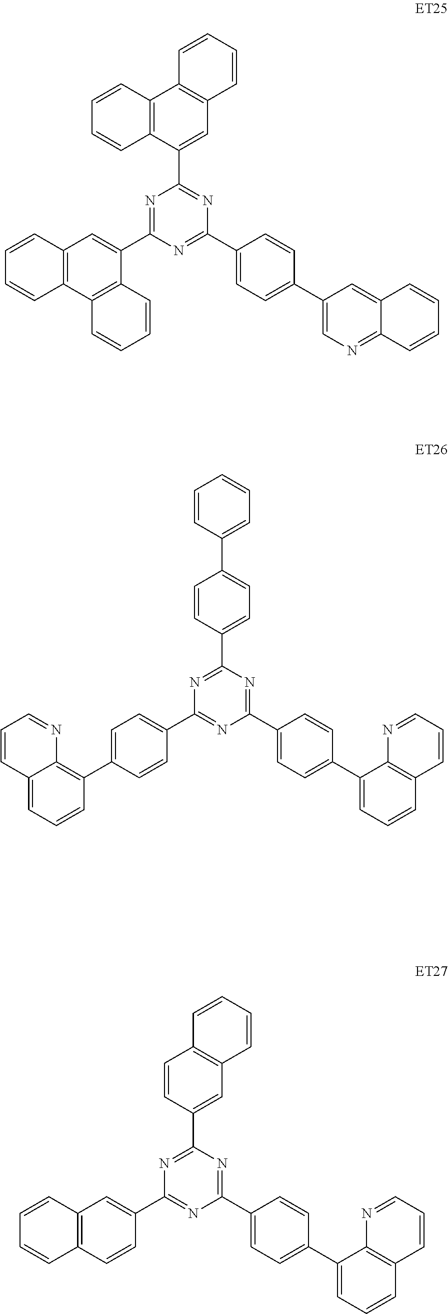 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

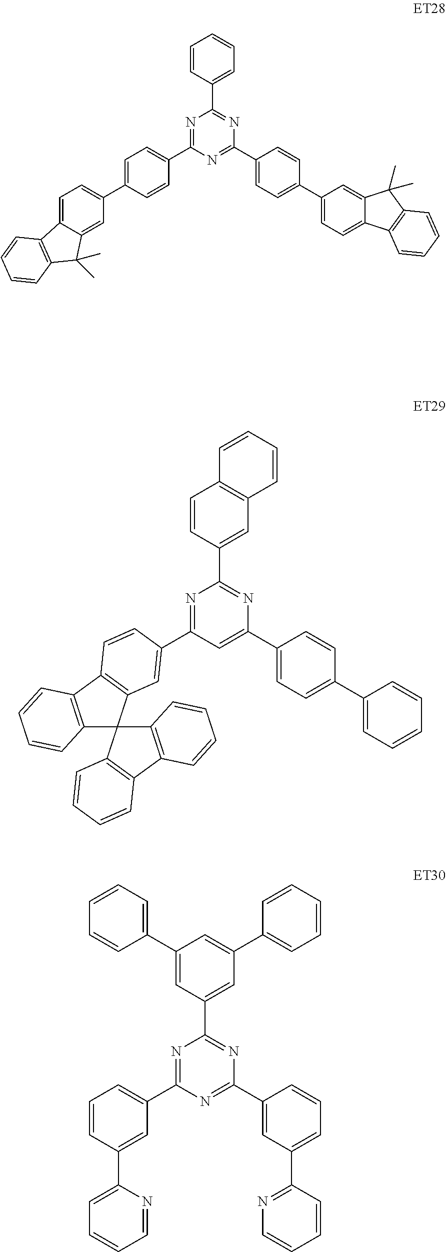 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

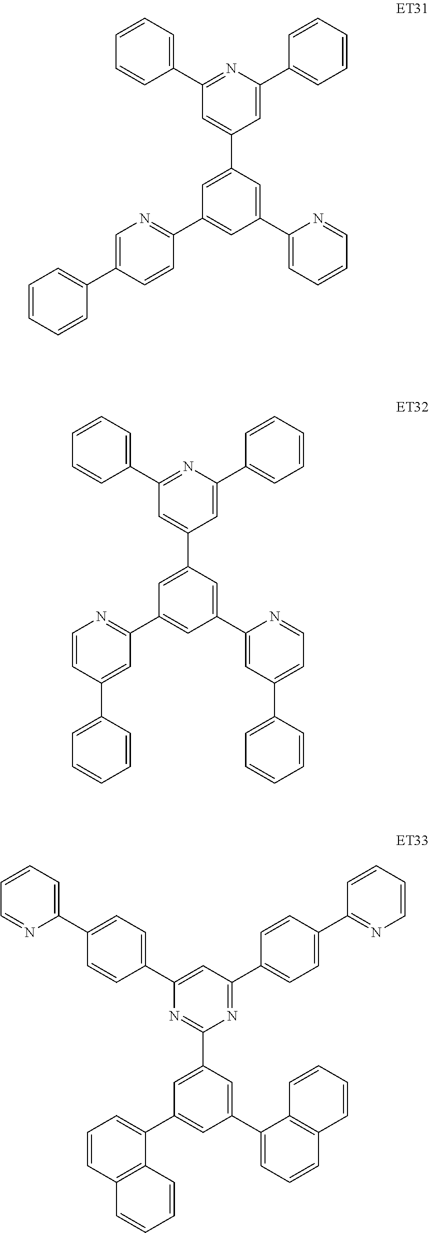 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

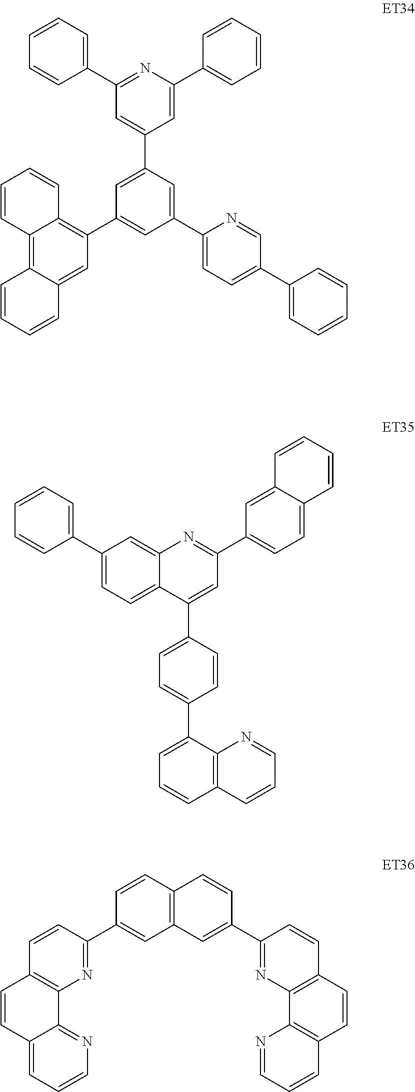 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

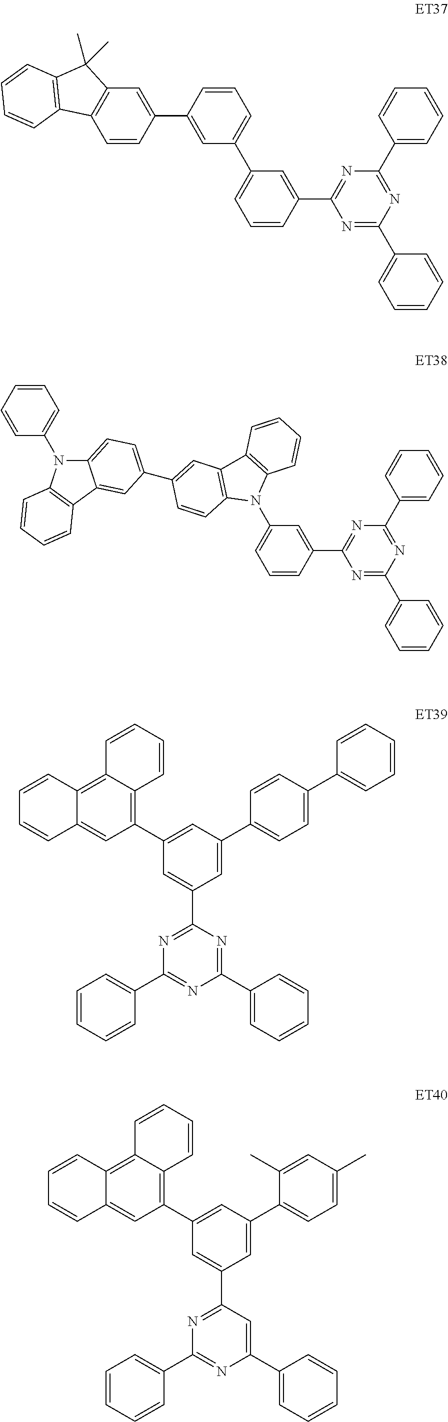 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

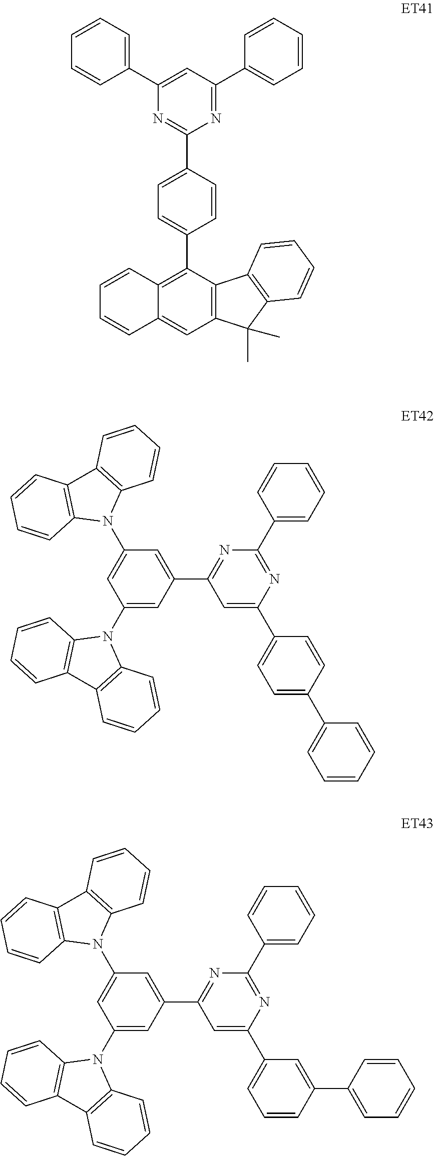 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

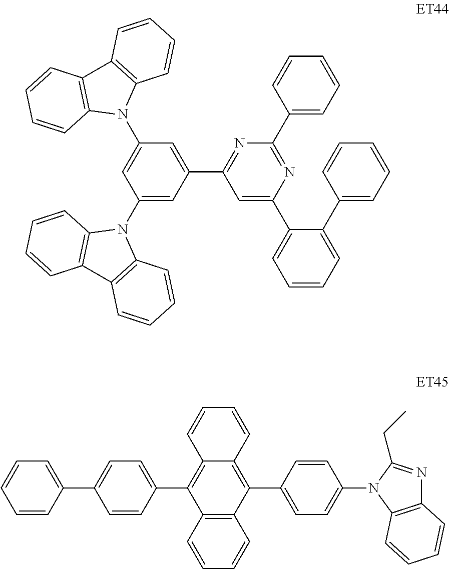 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

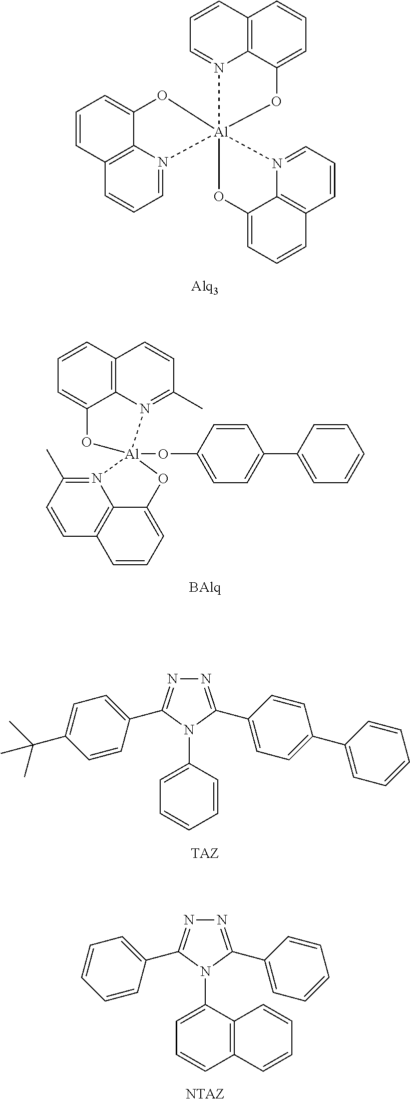

A thickness of the electron transport region 140 may be in a range of about 100 Å to about 5,000 Å. For example, the thickness of the electron transport region may be in a range of about 160 Å to about 4,000 Å. When the electron transport region 140 includes a buffer layer, a hole blocking layer, an electron control layer, an electron transport layer, or any combination thereof, a thickness of the buffer layer, the hole blocking layer, or the electron control layer may each independently be in a range of about 20 Å to about 1,000 Å and a thickness of the electron transport layer may be about 100 Å to about 1,000 Å. For example, the thickness of the buffer layer, the hole blocking layer, or the electron control layer may each independently be in a range of about 30 Å to about 300 Å. For example, the thickness of the electron transport layer may be in a range of about 150 Å to about 500 Å. When the thickness of the buffer layer, the hole blocking layer, the electron control layer, the electron transport layer, and/or the electron transport region are within these ranges, satisfactory electron transporting characteristics may be obtained without a substantial increase in driving voltage.

The electron transport region 140 (for example, an electron transport layer in the electron transport region) may further include, in addition to the aforementioned materials, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion.

A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or Compound ET-D2:

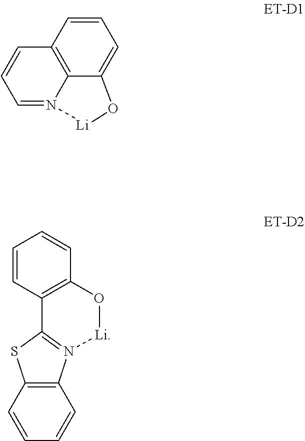

The electron transport region 140 may include an electron injection layer that facilitates injection of electrons from the second electrode 150. The electron injection layer may contact (e.g., directly connect) the second electrode 150.

The electron injection layer may have a structure consisting of a layer consisting of a single material, a structure consisting of a layer including different materials, or a structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, iodides, etc.), or tellurides of the alkali metal, the alkaline earth metal, and the rare earth metal, or any combination thereof.

The alkali metal-containing compound may include: an alkali metal oxide, such as Li₂O, Cs₂O, or K₂O; an alkali metal halide, such as LiF, NaF, CsF, KF, LiI, NaI, CsI, or Kl; or any combination thereof. The alkaline earth metal-containing compound may include an alkaline earth metal compound, such as BaO, SrO, CaO, BaₓSr₁₋ₓO (x is a real number satisfying 0<x<1), or BaₓCa₁₋ₓO (x is a real number satisfying 0<x<1). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include: an alkali metal ion, an alkaline earth metal ion, or a rare earth metal ion; and a ligand bonded to the metal ion (for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof).

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (for example, a compound represented by Formula 601).

In an embodiment, the electron injection layer may consist of an alkali metal-containing compound (for example, alkali metal halide); or the electron injection layer may consist of an alkali metal-containing compound (for example, alkali metal halide), and an alkali metal, an alkaline earth metal, a rare earth metal, or any combination thereof. In an embodiment, the electron injection layer may be a Kl:Yb co-deposited layer, an RbI:Yb co-deposited layer, a LiF:Yb co-deposited layer, or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. When the thickness of the electron injection layer is within any of the ranges as described above, satisfactory electron injection characteristics may be obtained without a substantial increase in driving voltage.

### [Second Electrode 150]

The second electrode 150 may be disposed above the electron transport region 140. The second electrode 150 may be a cathode, which is an electron injection electrode. When the second electrode 150 is a cathode, a material for forming the second electrode 150 may include a material having a low-work function, such as a metal, an alloy, an electrically conductive compound, or any combination thereof.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layer structure or a multilayer structure.

[Capping layer]

The light-emitting device 10 may include a first capping layer outside the first electrode 110, and/or the second capping layer outside the second electrode 150. For example, the light-emitting device 10 may have a structure in which the first capping layer, the first electrode 110, the interlayer, and the second electrode 150 are stacked in this stated order, a structure in which the first electrode 110, the interlayer, the second electrode 150, and the second capping layer are stacked in this stated order, or a structure in which the first capping layer, the first electrode 110, the interlayer, the second electrode 150, and the second capping layer are stacked in this stated order.

Light generated in the emission layer 130 of the light-emitting device 10 may pass through the first electrode 110, which may be a semi-transmissive electrode or a transmissive electrode, and through the first capping layer to the outside. Light generated in the emission layer 130 of the light-emitting device 10 may pass through the second electrode 150, which may be a semi-transmissive electrode or a transmissive electrode, and through the second capping layer to the outside.

The first capping layer and the second capping layer may each increase external emission efficiency according to the principle of constructive interference. Accordingly, the light extraction efficiency of the light-emitting device 10 is increased, such that the luminescence efficiency of the light-emitting device 10 may be increased.

The first capping layer and the second capping layer may each include a material having a refractive index greater than or equal to about 1.2 (with respect to a wavelength of about 460 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may each optionally be substituted with a substituent including O, N, S, Se, Si, F, Cl, Br, I, or any combination thereof. In an embodiment, at least one of the first capping layer and the second capping layer may each independently include an amine group-containing compound.

In an embodiment, at least one of the first capping layer and the second capping layer may each independently include a compound represented by Formula 201, a compound represented by Formula 202, or any combination thereof.

In an embodiment, at least one of the first capping layer and the second capping layer may each independently include one of Compounds HT28 to HT33, one of Compounds CP1 to CP6, β-NPB, or any combination thereof:

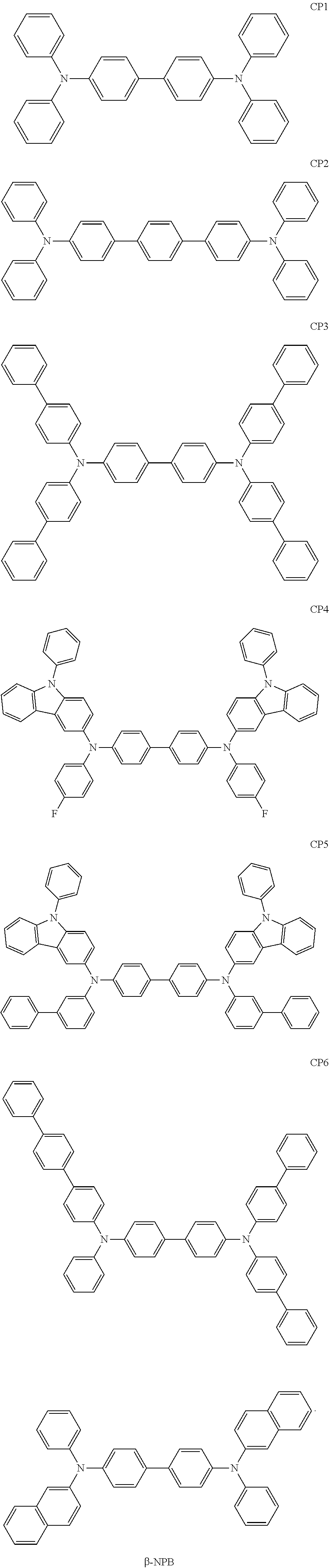

### [Film]

The electronic apparatus may further include a film. The film may be, for example, an optical member (or a light control means) (for example, a color filter, a color conversion member, a capping layer, a light extraction efficiency enhancement layer, a selective light absorbing layer, a polarizing layer, a quantum dot-containing layer, or like), a light-blocking member (for example, a light reflective layer, a light absorbing layer, or the like), a protective member (for example, an insulating layer, a dielectric layer, or the like).

### [Electronic Apparatus]

The light-emitting device 10 may be included in various electronic apparatuses. In an embodiment, an electronic apparatus including the light-emitting device 10 may be a display apparatus or an authentication apparatus.

The electronic apparatus (for example, a display apparatus) may further include, in addition to the light-emitting device 10, a color filter, a color conversion layer, or a color filter and a color conversion layer. The color filter and/or the color conversion layer may be disposed in at least one direction in which light emitted from the light-emitting device 10 travels. For example, the light emitted from the light-emitting device 10 may be blue light or white light. The light-emitting device 10 may be a light-emitting device as described herein. In an embodiment, the color conversion layer may include quantum dots. The quantum dots may be, for example, the quantum dots as described herein.

The electronic apparatus may include a first substrate. The first substrate may include subpixels, the color filter may include color filter areas respectively corresponding to the subpixels, and the color conversion layer may include color conversion areas respectively corresponding to the subpixels.

A pixel-defining film may be arranged between the subpixels to define each subpixel.

The color filter may further include color filter areas and light-shielding patterns arranged between the color filter areas, and the color conversion layer may further include color conversion areas and light-shielding patterns arranged between the color conversion areas.

The color filter areas (or the color conversion areas) may include a first area emitting first color light, a second area emitting second color light, and/or a third area emitting third color light, wherein the first color light, the second color light, and/or the third color light may have different maximum emission wavelengths from one another. In an embodiment, the first color light may be red light, the second color light may be green light, and the third color light may be blue light. In an embodiment, the color filter areas (or the color conversion areas) may include quantum dots. In an embodiment, the first area may include red quantum dots, the second area may include green quantum dots, and the third area may not include quantum dots. The quantum dots may be the quantum dots as described herein. The first area, the second area, and/or the third area may each further include a scatterer.

In an embodiment, the light-emitting device 10 may emit first light, the first area may absorb the first light to emit first-first color light, the second area may absorb the first light to emit second-first color light, and the third area may absorb the first light to emit third-first color light. In an embodiment, the first-first color light, the second-first color light, and the third-first color light may have different maximum emission wavelengths from one another. In an embodiment, the first light may be blue light, the first-first color light may be red light, the second-first color light may be green light, and the third-first color light may be blue light.

The electronic apparatus may further include a thin-film transistor, in addition to the light-emitting device 10. The thin-film transistor may include a source electrode, a drain electrode, and an active layer, wherein any one of the source electrode and the drain electrode may be electrically connected to any one of the first electrode and the second electrode of the light-emitting device.

The thin-film transistor may further include a gate electrode, a gate insulating film, and the like.

The active layer may include crystalline silicon, amorphous silicon, an organic semiconductor, an oxide semiconductor, and the like.

The electronic apparatus may further include a sealing portion for sealing the light-emitting device. The sealing portion may be arranged between the color filter and/or the color conversion layer and the light-emitting device. The sealing portion may allow light from the light-emitting device to be extracted to the outside, and may prevent ambient air and/or moisture from penetrating into the light-emitting device. The sealing portion may be a sealing substrate that includes a transparent glass substrate or a plastic substrate. The sealing portion may be a thin-film encapsulation layer that includes at least one layer of an organic layer and/or an inorganic layer. When the sealing portion is a thin film encapsulation layer, the electronic apparatus may be flexible.

Various functional layers may be further included on the sealing portion, in addition to the color filter and/or the color conversion layer, according to the use of the electronic apparatus. Examples of a functional layers may include a touch screen layer and a polarizing layer. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (for example, fingertips, pupils, etc.).

The authentication apparatus may further include, in addition to the light-emitting device as described above, a biometric information collector.

The electronic apparatus may be applied to various displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

### [Electronic Equipment]

The light-emitting device 10 may be included in various electronic equipment.

For example, an electronic equipment that includes the light-emitting device 10 may be a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall including multiple displays tiled together, a theater screen, or a stadium screen, a phototherapy device, or a signboard.

Because the light-emitting device 10 has improved color purity, improved luminescence efficiency, improved lifespan, etc., the electronic equipment including the light-emitting device 10 may have high luminance, high resolution, and low power consumption.

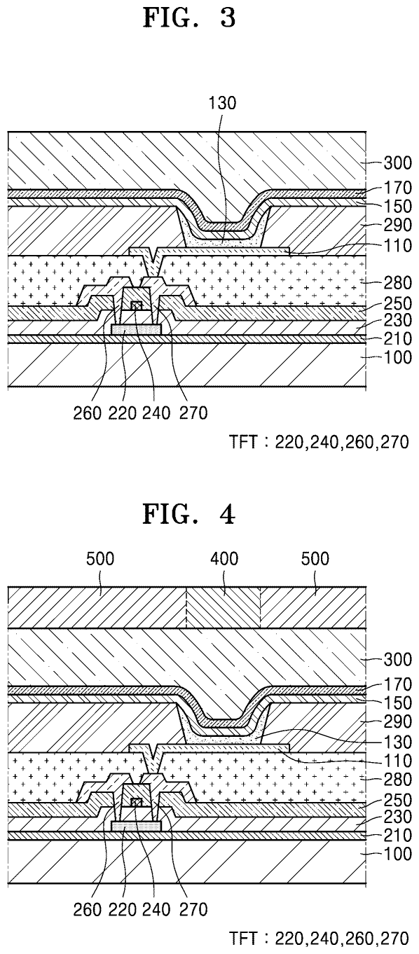

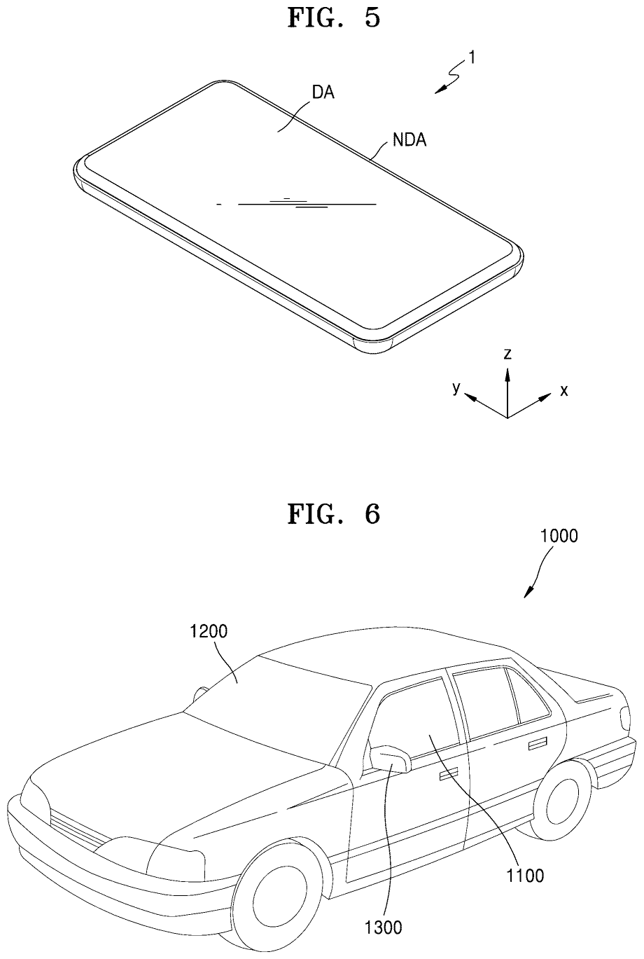

### [Description of FIGS. 3 and 4]

FIG. 3 is a schematic cross-sectional view of an electronic apparatus according to an embodiment.

The electronic apparatus in FIG. 3 may include a substrate 100, a thin-film transistor (TFT), a light-emitting device, and an encapsulation portion 300.

The substrate 100 may be a flexible substrate, a glass substrate, or a metal substrate. A buffer layer 210 may be disposed on the substrate 100. The buffer layer 210 may prevent penetration of impurities through the substrate 100 and may provide a flat surface on the substrate 100.

The TFT may be disposed on the buffer layer 210. The TFT may include an active layer 220, a gate electrode 240, a source electrode 260, and a drain electrode 270.

The active layer 220 may include an inorganic semiconductor, such as silicon or polysilicon, an organic semiconductor, or an oxide semiconductor, and may include a source region, a drain region, and a channel region.

A gate insulating film 230 for insulating the active layer 220 from the gate electrode 240 may be disposed on the active layer 220, and the gate electrode 240 may be disposed on the gate insulating film 230.

An interlayer insulating film 250 may be disposed on the gate electrode 240. The interlayer insulating film 250 may be located between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be disposed on the interlayer insulating film 250. The interlayer insulating film 250 and the gate insulating film 230 may be formed to expose the source region and the drain region of the active layer 220, and the source electrode 260 and the drain electrode 270 may respectively contact the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. A light-emitting device may be provided on the passivation layer 280. The light-emitting device may include the first electrode 110, the interlayer, and the second electrode 150.

The first electrode 110 may be disposed on the passivation layer 280. The passivation layer 280 may not completely cover the drain electrode 270 and may expose a portion of the drain electrode 270. The first electrode 110 may be electrically connected to the exposed portion of the drain electrode 270.

A pixel-defining film 290 including an insulating material may be disposed on the first electrode 110. The pixel-defining film 290 may expose a certain region of the first electrode 110, and the interlayer may be formed in the exposed region of the first electrode 110. The pixel-defining film 290 may be a polyimide-based organic film or a polyacrylic organic film. Although not shown in FIG. 3, at least some layers of the interlayer may extend to the upper portion of the pixel-defining film 290 and may be provided in the form of a common layer.

The second electrode 150 may be disposed on the interlayer, and a capping layer 170 may be further included on the second electrode 150. The capping layer 170 may be formed to cover the second electrode 150.

The encapsulation portion 300 may be disposed on the capping layer 170. The encapsulation portion 300 may be disposed on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE), or the like), or any combination thereof; or any combination of the inorganic film and the organic film.

FIG. 4 is a schematic cross-sectional view of an electronic apparatus according to another embodiment.

The electronic apparatus in FIG. 4 may differ from the electronic apparatus in FIG. 3, at least in that a light-shielding pattern 500 and a functional region 400 are further included on the encapsulation portion 300. The functional region 400 may be a color filter area, a color conversion area, or a combination of the color filter area and the color conversion area. In an embodiment, the light-emitting device included in the electronic apparatus in FIG. 4 may be a tandem light-emitting device.

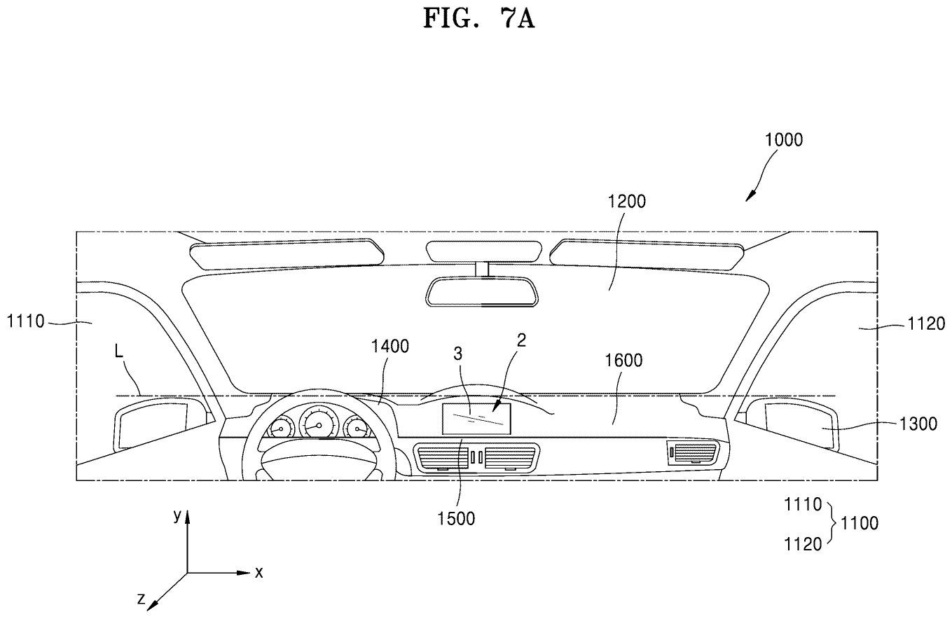

### [Description of FIG. 5]

FIG. 5 is a schematic perspective view of electronic equipment 1 including a light-emitting device, according to an embodiment. The electronic equipment 1 which may be an apparatus that displays a moving image or a still image, may not only be a portable electronic device, such as a mobile phone, a smartphone, a tablet computer, a mobile communication terminal, an electronic notebook, an electronic book, a portable multimedia player (PMP), a navigation device, or an ultra-mobile PC (UMPC), but may also be various products, such as a television, a laptop, a monitor, a billboard, or an Internet of things (IOT). The electronic equipment 1 may be such a product above or any part thereof.

The electronic equipment 1 may be a wearable device, such as a smart watch, a watch phone, a glasses-type display, or a head mounted display (HMD), or a part of the wearable device. However, embodiments are not limited thereto.

In an embodiment, the electronic equipment 1 may be a dashboard of a vehicle, a center information display (ClD) arranged on a center fascia or dashboard of a vehicle, a room mirror display instead of a side-view mirror of a vehicle, an entertainment display for a back seat of a vehicle, or a display arranged on the back of a front seat of a vehicle, a head up display (HUD) installed on the front of a vehicle or projected on a front window glass, or a computer generated hologram augmented reality head up display (CGH AR HUD). FIG. 5 illustrates an embodiment in which the electronic equipment 1 is a smartphone for convenience of explanation.

The electronic equipment 1 may include a display area DA and a non-display area NDA outside the display area DA. The electronic equipment 1 may implement an image through a two-dimensional array of pixels that are arranged in the display area DA.

The non-display area NDA may be an area that does not display an image, and may surround (e.g., entirely surround) the display area DA. A driver for providing electrical signals or power to display devices arranged on the display area DA may be arranged in the non-display area (NDA). A pad, which is an area to which an electronic element or a printed circuit board may be electrically connected, may be arranged in the non-display area NDA.

In the electronic equipment 1, a length in an x-axis direction and a length in a y-axis direction may be different from each other. In an embodiment, as shown in FIG. 5, a length in the x-axis direction may be less than a length in the y-axis direction. In an embodiment, a length in the x-axis direction may be the same as a length in the y-axis direction. In an embodiment, a length in the x-axis direction may be greater than a length in the y-axis direction.

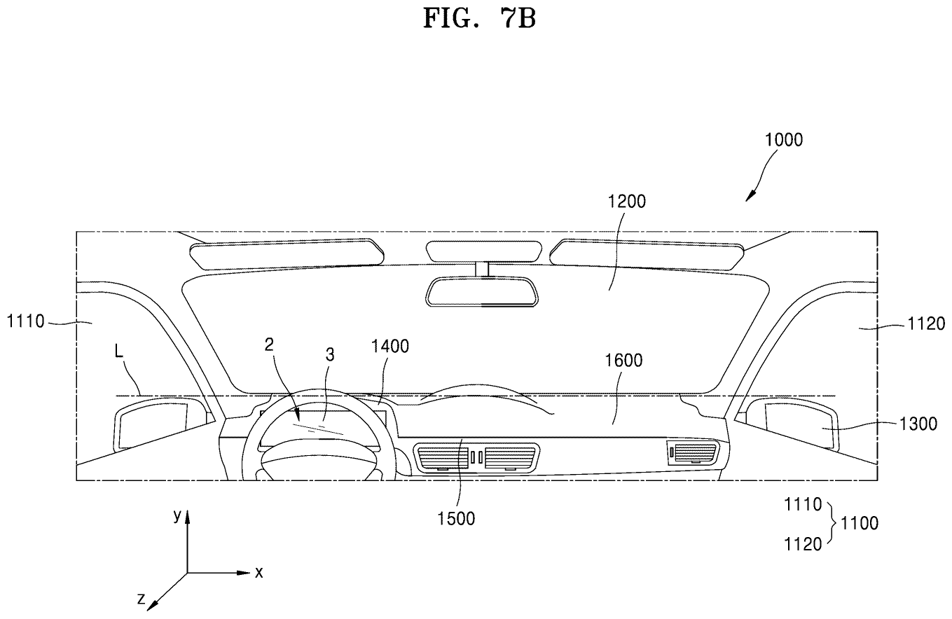

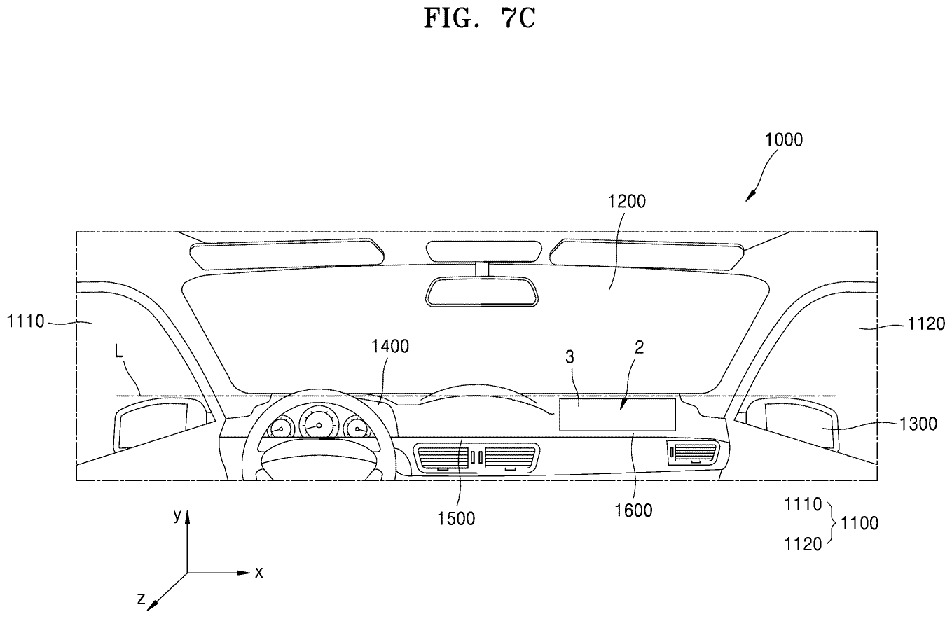

### [Descriptions of FIGS. 6 and 7A to 7C]

FIG. 6 is a schematic perspective view of an exterior of a vehicle 1000 as an electronic equipment including a light-emitting device, according to an embodiment. FIGS. 7A to 7C are each a schematic diagram of an interior of the vehicle 1000 according to embodiments.

Referring to FIGS. 6 and 7A to 7C, embodiments of the vehicle 1000 may include various apparatuses for moving a subject to be transported, such as a person, an object, or an animal, from a departure point to a destination point. Examples of the vehicle 1000 may include a vehicle traveling on a road or track, a vessel moving over the sea or river, an airplane flying in the sky using the action of air, and the like.

The vehicle 1000 may travel on a road or a track. The vehicle 1000 may move in a selectable direction according to the rotation of at least one wheel. Examples of the vehicle 1000 may include a three-wheeled or four-wheeled vehicle, a construction machine, a two-wheeled vehicle, a prime mover device, a bicycle, and a train running on a track.

The vehicle 1000 may include a vehicle body having an interior and an exterior, and a chassis that is a portion excluding the body in which mechanical apparatuses necessary for driving are installed. The exterior of the vehicle body may include a front panel, a bonnet, a roof panel, a rear panel, a trunk, a pillar provided at a boundary between doors, and the like. The chassis of the vehicle 1000 may include a power generating device, a power transmitting device, a driving device, a steering device, a braking device, a suspension device, a transmission device, a fuel device, front and rear wheels, left and right wheels, and the like.

The vehicle 1000 may include a side window glass 1100, a front window glass 1200, a side-view mirror 1300, a cluster 1400, a center fascia 1500, a passenger seat dashboard 1600, and a display apparatus 2.

The side window glass 1100 and the front window glass 1200 may be partitioned by a pillar arranged between the side window glass 1100 and the front window glass 1200.

The side window glass 1100 may be installed on a side of the vehicle 1000. In an embodiment, the side window glass 1100 may be installed on a door of the vehicle 1000. Multiple side window glasses 1100 may be provided and may face each other. In an embodiment, the side window glass 1100 may include a first side window glass 1110 and a second side window glass 1120. In an embodiment, the first side window glass 1110 may be arranged adjacent to the cluster 1400 and the second side window glass 1120 may be arranged adjacent to the passenger seat dashboard 1600.

In an embodiment, the side window glasses 1100 may be spaced apart from each other in an x direction or a −x direction. In an embodiment, the first side window glass 1110 and the second side window glass 1120 may be spaced apart from each other in the x direction or the −x direction. For example, a virtual straight line L connecting the side window glasses 1100 may extend in the x direction or the −x direction. In an embodiment, a virtual straight line L connecting the first side window glass 1110 and the second side window glass 1120 to each other may extend in the x direction or the −x direction.

The front window glass 1200 may be installed in front of the vehicle 1000. The front window glass 1200 may be arranged between the side window glasses 1100 facing each other.

The side-view mirror 1300 may provide a rear view of the vehicle 1000. The side-view mirror 1300 may be installed on the exterior of the vehicle body. In an embodiment, multiple side-view mirrors 1300 may be provided. One of the side-view mirrors 1300 may be arranged outside the first side window glass 1110. Another one of the side-view mirrors 1300 may be arranged outside the second side window glass 1120.

The cluster 1400 may be arranged in front of the steering wheel. The cluster 1400 may include a tachometer, a speedometer, a coolant thermometer, a fuel gauge turn indicator, a high beam indicator, a warning light, a seat belt warning light, an odometer, a tachograph, an automatic shift selector indicator light, a door open warning light, an engine oil warning light, and/or a low fuel warning light.

The center fascia 1500 may include a control panel on which buttons for adjusting an audio device, an air conditioning device, and a seat heater may be disposed. The center fascia 1500 may be arranged on one side of the cluster 1400.

The passenger seat dashboard 1600 may be spaced apart from the cluster 1400 with the center fascia 1500 arranged therebetween. In an embodiment, the cluster 1400 may be arranged to correspond to a driver seat (not shown), and the passenger seat dashboard 1600 may be arranged to correspond to a passenger seat (not shown). In an embodiment, the cluster 1400 may be adjacent to the first side window glass 1110, and the passenger seat dashboard 1600 may be adjacent to the second side window glass 1120.

In an embodiment, the display apparatus 2 may include a display panel 3, and the display panel 3 may display an image. The display apparatus 2 may be arranged inside the vehicle 1000. In an embodiment, the display apparatus 2 may be arranged between the side window glasses 1100 facing each other. The display apparatus 2 may be arranged on at least one of the cluster 1400, the center fascia 1500, and the passenger seat dashboard 1600.

The display apparatus 2 may include an organic light-emitting display device, an inorganic electroluminescent (EL) display device, a quantum dot display device, and the like. Hereinafter, as the display apparatus 2 according to an embodiment, a light-emitting display apparatus including the light-emitting device according will be described as an example. However, various types of display devices as described herein may be used in embodiments.

Referring to FIG. 7A, the display apparatus 2 may be disposed on the center fascia 1500. In an embodiment, the display apparatus 2 may display navigation information. In an embodiment, the display apparatus 2 may display information regarding audio settings, video settings, or vehicle settings.

Referring to FIG. 7B, the display apparatus 2 may be disposed on the cluster 1400. In an embodiment, the cluster 1400 may display driving information and the like through the display apparatus 2. For example, the cluster 1400 may digitally implement driving information. The digital cluster 1400 may display vehicle information and driving information as images. In an embodiment, a needle and a gauge of a tachometer and various warning light icons may be displayed by a digital signal.

Referring to FIG. 7C, the display apparatus 2 may be disposed on the passenger seat dashboard 1600. The display apparatus 2 may be embedded in the passenger seat dashboard 1600 or arranged on the passenger seat dashboard 1600. In an embodiment, the display apparatus 2 arranged on the passenger seat dashboard 1600 may display an image related to information displayed on the cluster 1400 and/or information displayed on the center fascia 1500. In an embodiment, the display apparatus 2 arranged on the passenger seat dashboard 1600 may display information that is different from information displayed on the cluster 1400 and/or information displayed on the center fascia 1500.

### [Manufacturing Method]

The layers included in the hole transport region 120, the emission layer 130, and the layers included in the electron transport region 140 may be formed in a selected region by using various methods such as vacuum deposition, spin coating, casting, a Langmuir-Blodgett (LB) method, ink-jet printing, laser-printing, and laser-induced thermal imaging (LITI).

When the layers included in the hole transport region 120, the emission layer 130, and the layers included in the electron transport region 140 are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on a material to be included in a layer to be formed and the structure of a layer to be formed.

### [Definitions of Terms]

The term “C₃-C₆₀ carbocyclic group” as used herein may be a cyclic group consisting of carbon atoms as the only ring-forming atoms and having 3 to 60 carbon atoms.

The term “C₁-C₆₀ heterocyclic group” as used herein may be a cyclic group that has 1 to 60 carbon atoms and may further include, in addition to carbon atoms, at least one heteroatom as a ring-forming atom.

The C₃-C₆₀ carbocyclic group and the C₁-C₆₀ heterocyclic group may each be a monocyclic group consisting of one ring or a polycyclic group in which two or more rings are condensed with each other. For example, the C₁-C₆₀ heterocyclic group may have 3 to 61 ring-forming atoms.

The term “cyclic group” as used herein may be a C₃-C₆₀ carbocyclic group or a C₁-C₆₀ heterocyclic group.

The term “π electron-rich C₃-C₆₀ cyclic group” as used herein may be a cyclic group that has 3 to 60 carbon atoms and may not include *—N═*′ as a ring-forming moiety.

The term “π electron-deficient nitrogen-containing C₁-C₆₀ cyclic group” as used herein may be a heterocyclic group that has 1 to 60 carbon atoms and may include *—N═*′ as a ring-forming moiety.

In an embodiment,
the C₃-C₆₀ carbocyclic group may be a T1 group or a group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which two or more T2 groups are condensed with each other, or a group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, a xanthene group, etc.).

A π electron-rich C₃-C₆₀ cyclic group may be a T1 group, a group in which two or more T1 groups are condensed with each other, a T3 group, a group in which two or more T3 groups are condensed with each other, or a group in which at least one T3 group and at least one T1 group are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.).

A π electron-deficient nitrogen-containing C₁-C₆₀ cyclic group may be a T4 group, a group in which two or more T4 groups are condensed with each other, a group in which at least one T4 group and at least one T1 group are condensed with each other, a group in which at least one T4 group and at least one T3 group are condensed with each other, or a group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.).

The T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group.

The T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

The T3 group may be a furan group, a thiophene group, a 1H-pyrrole group, a silole group, or a borole group.

The T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group,” “C₃-C₆₀ carbocyclic group,” “C₁-C₆₀ heterocyclic group,” “π electron-rich C₃-C₆₀ cyclic group,” or “π electron-deficient nitrogen-containing C₁-C₆₀ cyclic group,” as used herein, refer to a monovalent or polyvalent group (for example, a divalent group, a trivalent group, a tetravalent group, or the like) that is condensed with (e.g., combined together with) a cyclic group according to the structure of a formula for which the corresponding term is used.

In an embodiment, a “benzene group” may be a benzo group, a phenyl group, a phenylene group, or the like, which may be readily understood by those of ordinary skill in the art according to the structure of a formula including the “benzene group.”

Examples of a monovalent C₃-C₆₀ carbocyclic group or a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Examples of the divalent C₃-C₆₀ carbocyclic group or a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched aliphatic hydrocarbon monovalent group that has 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group.

The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of the C₂-C₆₀ alkyl group, and examples thereof may include an ethenyl group, a propenyl group, and a butenyl group.

The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group and a propynyl group.

The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —O(A₁₀₁) (wherein A₁₀₁ may be a C₁-C₆₀ alkyl group), and examples thereof may include a methoxy group, an ethoxy group, and an isopropyloxy group.

The term “C₃-C₁₀ cycloalkyl group” as used herein may be a monovalent saturated hydrocarbon cyclic group that has 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group.

The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group that has 1 to 10 carbon atoms and further includes, in addition to the carbon atoms, at least one heteroatom as a ring-forming atom, and examples thereof may include a 1,2,3,4-oxatriazolidinyl group, a tetrahydrofuranyl group, and a tetrahydrothiophenyl group.

The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has 3 to 10 carbon atoms, at least one carbon-carbon double bond in the cyclic structure thereof, and no aromaticity, and examples thereof may include a cyclopentenyl group, a cyclohexenyl group, and a cycloheptenyl group.

The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group that has 1 to 10 carbon atoms, further includes, in addition to the carbon atoms, at least one heteroatom as a ring-forming atom, and has at least one double bond in the cyclic structure thereof. Examples of a C₁-C₁₀ heterocycloalkenyl group may include a 4,5-dihydro-1,2,3,4-oxatriazolyl group, a 2,3-dihydrofuranyl group, and a 2,3-dihydrothiophenyl group.

The term “C₁-C₁₀ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system of 6 to 60 carbon atoms.

The term “C₆-C₆₀ arylene group” as used herein may be a divalent group having a carbocyclic aromatic system of 6 to 60 carbon atoms.

Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group.

When the C₆-C₆₀ aryl group and the C₆-C₆₀ arylene group each include two or more rings, the respective two or more rings may be condensed with each other.

The term “C₁-C₆₀ heteroaryl group” as used herein may be a monovalent group having a heterocyclic aromatic system that has 1 to 60 carbon atoms and further includes, in addition to the carbon atoms, at least one heteroatom as a ring-forming atom.

The term “C₁-C₆₀ heteroarylene group” as used herein may be a divalent group having a heterocyclic aromatic system that has 1 to 60 carbon atoms and further includes, in addition to the carbon atoms, at least one heteroatom as a ring-forming atom.

Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group.

When the C₁-C₆₀ heteroaryl group and the C₁-C₆₀ heteroarylene group each include two or more rings, the respective two or more rings may be condensed with each other.

The term “monovalent non-aromatic condensed polycyclic group” as used herein may be a monovalent group having two or more rings condensed with each other, only carbon atoms (for example, eight to sixty carbon atoms) as ring-forming atoms, and no aromaticity in its molecular structure when considered as a whole. Examples of a monovalent non-aromatic condensed polycyclic group may include an indenyl group, a fluorenyl group, a spiro-bifluorenyl group, a benzofluorenyl group, an indenophenanthrenyl group, and an indeno anthracenyl group.

The term “divalent non-aromatic condensed polycyclic group” as used herein may be a divalent group having a same structure as the monovalent non-aromatic condensed polycyclic group.

The term “monovalent non-aromatic condensed heteropolycyclic group” as used herein may be a monovalent group that has two or more rings condensed with each other, further includes, in addition to carbon atoms (for example, one to sixty carbon atoms), at least one heteroatom as a ring-forming atom, and has no aromaticity in its molecular structure when considered as a whole. Examples of a monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group.

The term “divalent non-aromatic condensed heteropolycyclic group” as used herein may be a divalent group having a same structure as the monovalent non-aromatic condensed heteropolycyclic group.

The term “C₆-C₆₀ aryloxy group” as used herein may be a group represented by —O(A₁₀₂) (wherein A₁₀₂ may be a C₆-C₆₀ aryl group).

The term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by -(A₁₀₄)(A₁₀₅) (wherein A₁₀₄ may be a C₁-C₅₄ alkylene group, and A₁₀₅ may be a C₆-C₅₉ aryl group).

The term “C₂-C₆₀ heteroarylalkyl group” as used herein may be a group represented by -(A₁₀₆)(A₁₀₇) (wherein A₁₀₆ may be a C₁-C₅₉ alkylene group, and A₁₀₇ may be a C₁-C₅₉ heteroaryl group).

In the specification, the group term “R₁₀ₐ” may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, the groups Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein may be any atom other than a carbon atom or a hydrogen atom. Examples of a heteroatom may include O, S, N, P, Si, B, Ge, Se, or any combination thereof.

The term “transition metal” as used herein may include hafnium (Hf), tantalum (Ta), tungsten (W), rhenium (Re), osmium (Os), iridium (Ir), platinum (Pt), and gold (Au).

Throughout the specification, “D” refers to deuterium, “Ph” refers to a phenyl group, “Me” refers to a methyl group, “Et” refers to an ethyl group, “tert-Bu,” “^{t}Bu,” or “Bu^{t}” each refer to a tert-butyl group, and “OMe” refers to a methoxy group.

The term “biphenyl group” as used herein may be a “phenyl group that is substituted with a phenyl group.” For example, the “biphenyl group” may be a substituted phenyl group having a C₆-C₆₀ aryl group as a substituent.

The term “terphenyl group” as used herein may be a “phenyl group substituted with a biphenyl group.” For example, the term “terphenyl group” may be a substituted phenyl group wherein the substituent is a C₆-C₆₀ aryl group substituted with a C₆-C₆₀ aryl group, and a substituted phenyl group wherein two substituents are present, and each substituent is a C₆-C₆₀ aryl group.

The symbols *, *′, and *″ as used herein, unless defined otherwise, each refer to a binding site to a neighboring atom in a corresponding formula or moiety.

In the specification, the x-axis, y-axis, and z-axis are not limited to three axes in an orthogonal coordinate system (e.g., a Cartesian coordinate system), and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Hereinafter, organometallic compounds according to embodiments and light-emitting devices according to embodiments are described in detail with reference to the following Synthesis Examples and Examples.

### Synthesis Example 1 (Synthesis of Compound BD1)

### Synthesis of Intermediate I-1-1

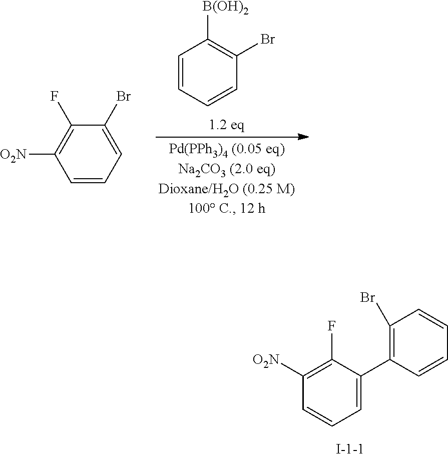 [SMILES: O=[N+]([O-])c1cccc(Br)c1F ; OB(O)c1ccccc1Br ; O=[N+]([O-])c1cccc(-c2ccccc2Br)c1F]

1-bromo-2-fluoro-3-nitro benzene 55 g (1.0 eq.), 2-bromophenylboronic acid (1.2 eq.), tetrakis(triphenylphosphine)palladium(0) (Pd(PPh₃)₄) (0.05 eq.), and sodium carbonate (2.0 eq.) were suspended in 0.25 M mixed solution of 800 ml of dioxane (that is, 1,4-dioxane) and 200 ml of distilled water and heated to 100° C. for 12 hours in an N₂ atmosphere. After cooling the mixture to room temperature (r.t.), distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-1-1 (yield: 97%).

### Synthesis of Intermediate I-1-2

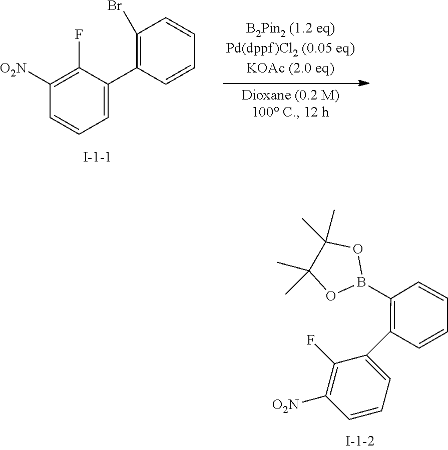 [SMILES: O=[N+]([O-])c1cccc(-c2ccccc2Br)c1F ; CC1(C)OB(c2ccccc2-c2cccc([N+](=O)[O-])c2F)OC1(C)C]

Intermediate I-1-1 (1.0 eq.), bis(pinacolato)diboron (B₂Pin₂) (1.2 eq.), [1,1′-bis(diphenylphosphino)ferrocene]dichloropalladium (II) (Pd(dppf)Cl₂) (0.05 eq.), and potassium acetate (KOAc) (2.0 eq.) were suspended in 0.2 M dioxane and heated to 100° C. for 12 hours in an N₂ atmosphere. After cooling the mixture to room temperature (r.t.), distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-1-2 (yield: 77%).

### Synthesis of Intermediate I-1-3

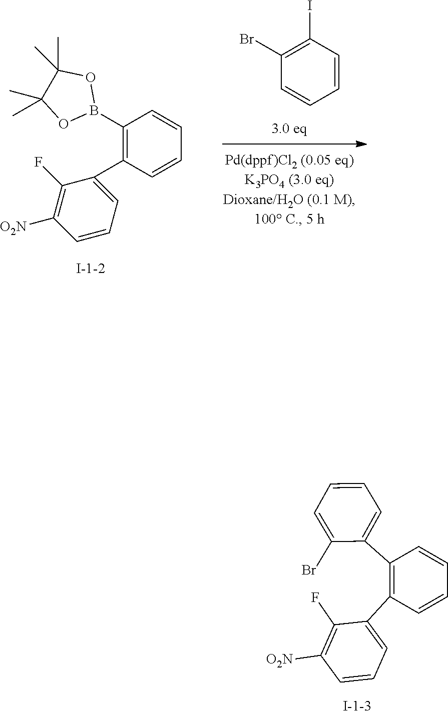 [SMILES: CC1(C)OB(c2ccccc2-c2cccc([N+](=O)[O-])c2F)OC1(C)C ; Brc1ccccc1I ; O=[N+]([O-])c1cccc(-c2ccccc2-c2ccccc2Br)c1F]

Intermediate I-1-2 (1.0 eq.), 1-bromo-2-iodobenzene (3.0 eq.), Pd(dppf)C₁₂ (0.05 eq.), and tripotassium phosphate (K₃PO₄) (3.0 eq.) were suspended in 0.1 M mixed solution of 400 ml of dioxane and 100 ml of distilled water and heated to 100° C. for 5 hours in an N₂ atmosphere. After cooling the mixture to room temperature (r.t.), distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-1-3 (yield: 74%).

### Synthesis of Intermediate I-1-4

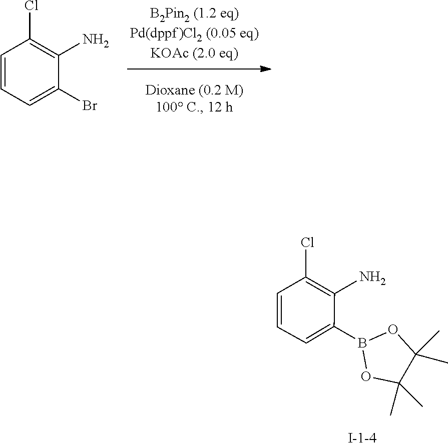 [SMILES: Nc1c(Cl)cccc1Br ; CC1(C)OB(c2cccc(Cl)c2N)OC1(C)C]

2-bromo-6-chloroaniline (1.0 eq.), B₂Pin₂ (1.2 eq.), Pd(dppf)C₁₂ (0.05 eq.), and KOAc (2.0 eq.) were suspended in 0.2 M dioxane and heated to 100° C. for 12 hours in an N₂ atmosphere. After cooling the mixture to room temperature (r.t.), distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-1-4 (yield: 77%).

### Synthesis of Intermediate I-1-5

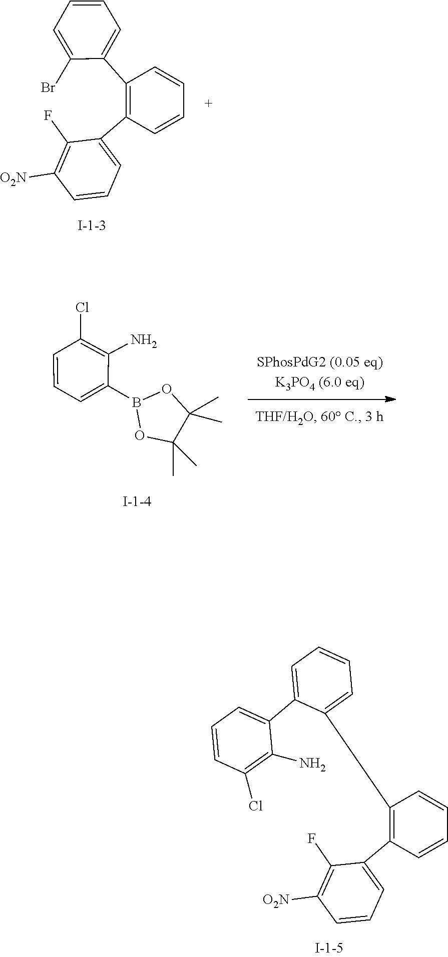 [SMILES: O=[N+]([O-])c1cccc(-c2ccccc2-c2ccccc2Br)c1F ; CC1(C)OB(c2cccc(Cl)c2N)OC1(C)C ; Nc1c(Cl)cccc1-c1ccccc1-c1ccccc1-c1cccc([N+](=O)[O-])c1F]

Intermediate I-1-3 (1.0 eq.), Intermediate I-1-4 (1.1 eq.), chloro(2-dicyclohexylphosphino-2′,6′-dimethoxy-1,1′-biphenyl)[2-(2′-amino-1,1′-biphenyl)]palladium(II) (Sphos Pd G2) (0.05 eq.), and K₃PO₄ (6.0 eq.) were suspended in a mixed solution of 400 ml of tetrahydrofuran (THF) and 100 ml of distilled water and heated to 60° C. for 3 hours in an N₂ atmosphere. After cooling the mixture to room temperature (r.t.), distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-1-5 (yield: 74%).

### Synthesis of Intermediate I-1-6

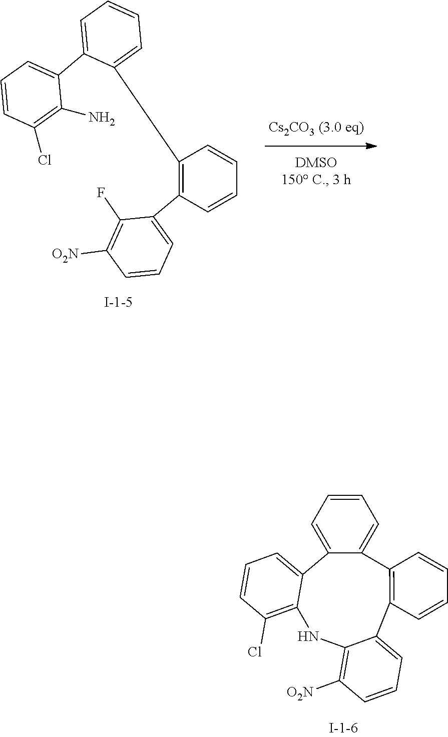 [SMILES: Nc1c(Cl)cccc1-c1ccccc1-c1ccccc1-c1cccc([N+](=O)[O-])c1F ; O=[N+]([O-])c1cccc2c1[nH]c1c(Cl)cccc1c1ccccc1c1ccccc21]

Intermediate I-1-5 (1.0 eq.) and cesium carbonate (3.0 eq.) were suspended in dimethyl sulfoxide (DMSO) and heated to 150° C. for 3 hours in an N₂ atmosphere. After cooling the mixture to room temperature (r.t.), distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-1-6 (yield: 73%).

### Synthesis of Intermediate I-1-7

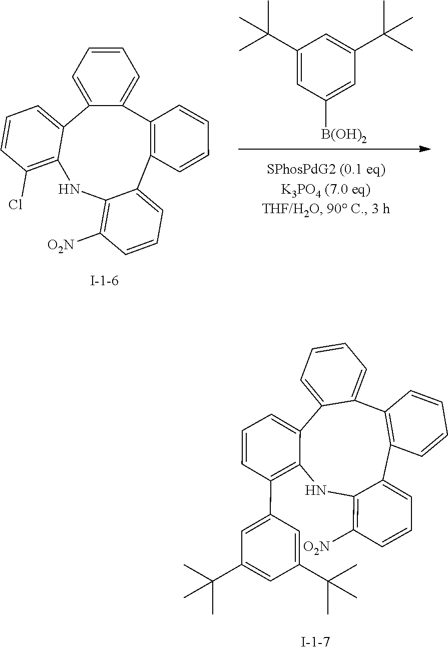 [SMILES: O=[N+]([O-])c1cccc2c1[nH]c1c(Cl)cccc1c1ccccc1c1ccccc21 ; CC(C)(C)c1cc(B(O)O)cc(C(C)(C)C)c1 ; CC(C)(C)c1cc(-c2cccc3c2[nH]c2c([N+](=O)[O-])cccc2c2ccccc2c2ccccc32)cc(C(C)(C)C)c1]

Intermediate I-1-6 (1.0 eq.), 3,5-di-tert-butylphenylboronic acid (1.2 eq.), Sphos Pd G2 (0.1 eq.), and K₃PO₄ (7.0 eq.) were suspended in a mixed solution of 150 ml of THF and 300 ml of distilled water and heated to 90° C. for 3 hours in an N₂ atmosphere. After cooling the mixture to room temperature (r.t.), distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-1-7 (yield: 98%).

### Synthesis of Intermediate I-1-8

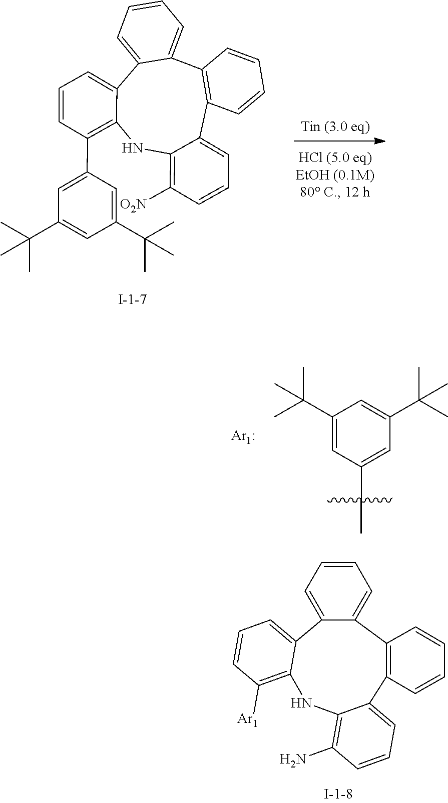

Intermediate I-1-7 (1.0 eq.) was dissolved in 0.1 M ethanol, and a 37% hydrochloric acid aqueous solution by mass fraction (5.0 eq.) was added dropwise thereto. Tin (3.0 eq.) was added to the reaction mixture and stirred at 80° C. for 12 hours by raising the temperature. When the reaction ended, the reaction result was cooled to room temperature and neutralized with a 1N sodium hydroxide solution, an organic layer was extracted by using methylene chloride and distilled water, and the extracted organic layer was dried with magnesium sulfate, to thereby obtain Intermediate I-1-8 (yield: 71%). The obtained Intermediate I-1-8 was used in the next reaction without additional purification.

### Synthesis of Intermediate I-1-9

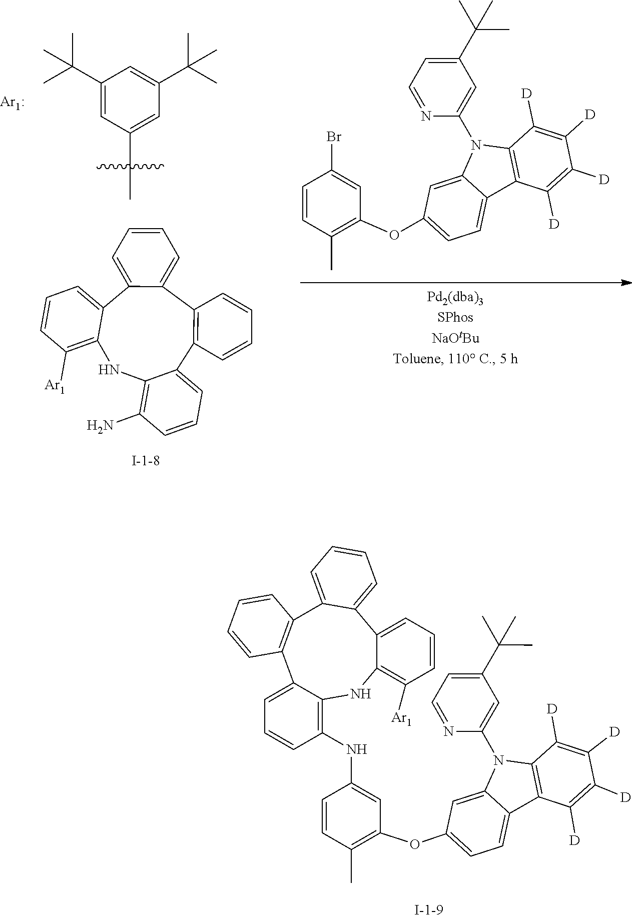

Intermediate I-1-8 (1.0 eq.), 2-(5-bromo-2-methylphenoxy)-9-(4-(tert-butyl)pyridine-2-yl)-9H-D₄-carbazole (1.1 eq.), tris(dibenzylideneacetone)dipalladium(0) (Pd₂(dba)₃) (0.05 eq.), 2-dicyclohexylphosphino-2′,6′-dimethoxybiphenyl (SPhos) (0.1 eq.), and sodium tertiary butoxide (NaOtBu) (2.0 eq.) were suspended in 250 ml of toluene and heated to 110° C. for 5 hours in an N₂ atmosphere. After the mixture was cooled to room temperature, an organic layer was extracted by using ethyl acetate and water and dried with magnesium sulfate. The result obtained therefrom was purified by column chromatography (ethyl acetate/hexane (volume ratio 10:90)) to obtain Intermediate I-1-9 (yield: 88%).

### Synthesis of Intermediate I-1-10

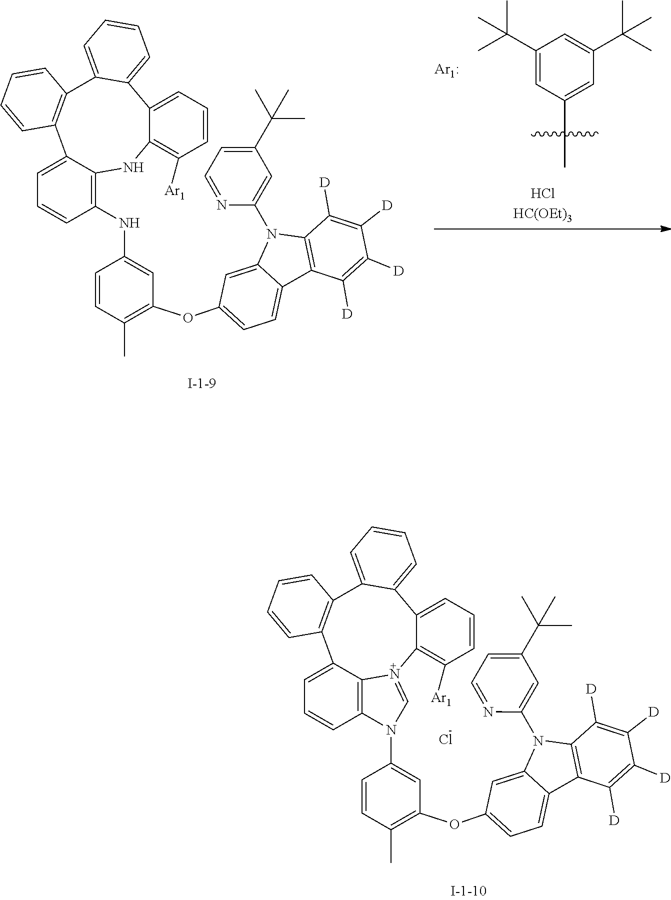

Intermediate I-1-9 (1.0 eq.) was dissolved in 25 ml of triethyl orthoformate (HC(OEt)₃) (50.0 eq.), and 5 ml of 12N hydrochloric acid (1.2 eq.) was added dropwise thereto. The reaction mixture was heated to 80° C. and stirred for 12 hours. When the reaction ended, the solvent was removed therefrom under reduced pressure, and an organic layer was extracted by using ethyl acetate and distilled water. The organic layer was dried with magnesium sulfate, and the result obtained therefrom was purified by column chromatography (methanol/methylene chloride (volume ratio 5:95)) to obtain Intermediate I-1-10 (yield: 82%).

### Synthesis of Compound BD1

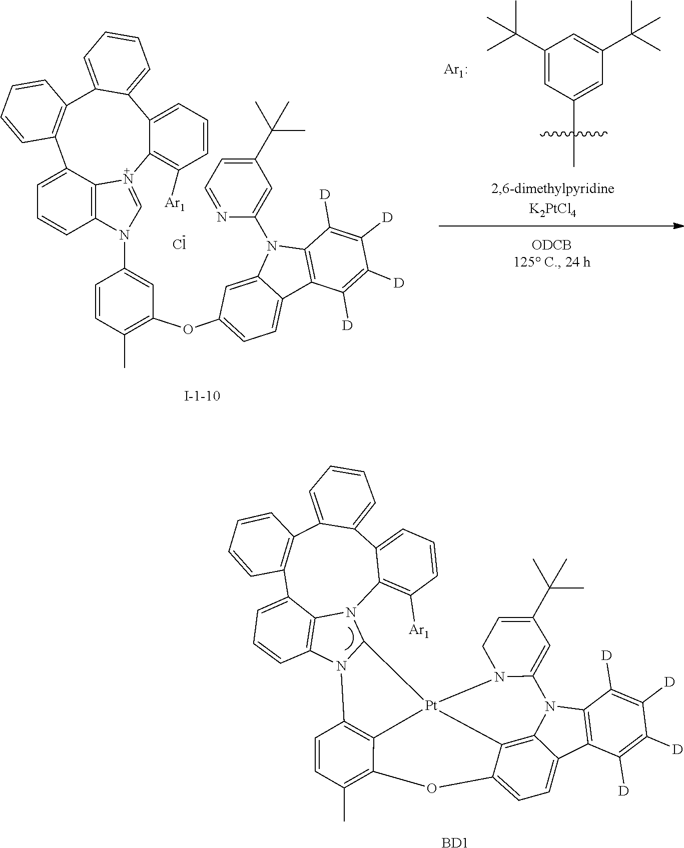

Intermediate I-1-10 (1.0 eq.), 2,6-dimethylpyridine (2.0 eq.), and potassium tetrachloroplatinate (K₂PtCl₄) (1.05 eq.) were suspended in 200 ml of orthodichlorobenzene (ODCB) and stirred at 125° C. for 24 hours by raising the temperature. When the reaction ended, the solvent was removed therefrom under reduced pressure, and an organic layer was extracted by using ethyl acetate and distilled water. The result obtained therefrom was dried with magnesium sulfate and purified by column chromatography (methylene chloride/hexane (volume ratio 50:50)) to obtain Compound BD1 (yield: 47%).

### Synthesis Example 2 (Synthesis of Compound BD3)

Compound BD3 was obtained (yield: 74%) in substantially the same manner as in Synthesis Example 1, except that 3,5-di-tert-butylphenylboronic acid-D₃ was used instead of 3,5-di-tert-butylphenylboronic acid in the synthesis of Intermediate I-1-7 in Synthesis Example 1.

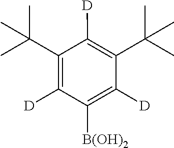 [SMILES: [2H]c1c(B(O)O)c([2H])c(C(C)(C)C)c([2H])c1C(C)(C)C]

### 3,5-di-tert-butylphenylboronic acid-D₃

### Synthesis Example 3 (Synthesis of Compound BD17)

### Synthesis of Intermediate I-17-1

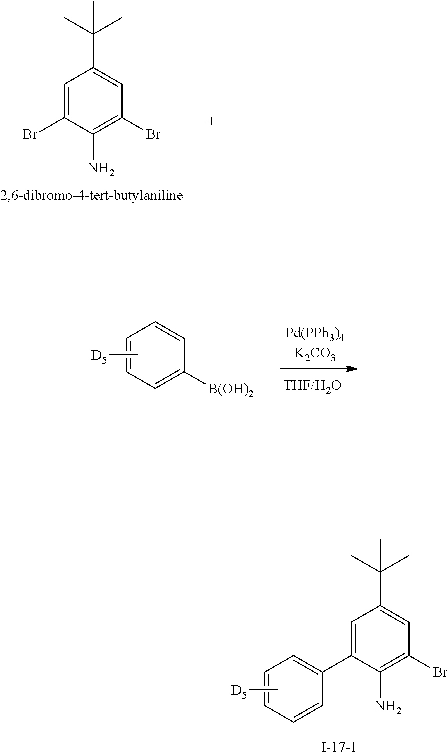

15 g of 2,6-dibro-4-tertiary butylaniline (1.0 eq.), phenyl-D₅-boronic acid (1.1 eq.), tetrakis(triphenylphosphine)palladium(0) (0.020 eq.), and potassium carbonate (2.0 eq.) were suspended in a mixed solution of 300 ml of THF and 100 ml of distilled water and heated to 80° C. for 24 hours in a nitrogen atmosphere. After cooling the mixture to room temperature, 300 ml of distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-17-1 (yield: 81%).

### Synthesis of Intermediate I-17-2

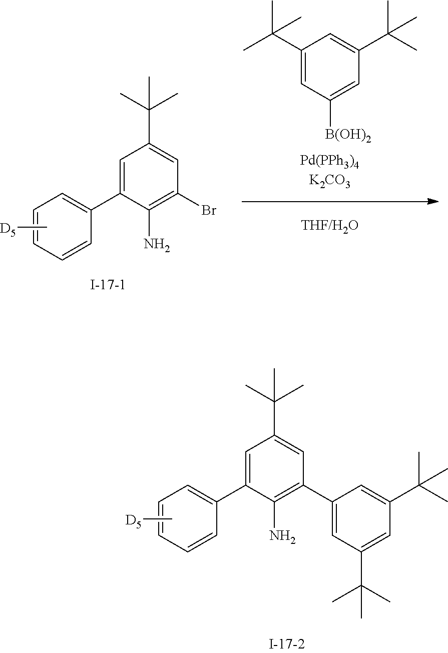

Intermediate I-17-1 (1.0 eq.), 3,5-ditertiarybutylphenylboronic acid (1.0 eq.), tetrakis(triphenylphosphine)palladium(0) (0.020 eq.), and potassium carbonate (2.0 eq.) were suspended in a mixed solution of 300 ml of THF and 100 ml of distilled water and heated to 80° C. for 24 hours in a nitrogen atmosphere. After cooling the mixture to room temperature, 250 ml of distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-17-2 (yield: 89%).

### Synthesis of Intermediate I-17-3

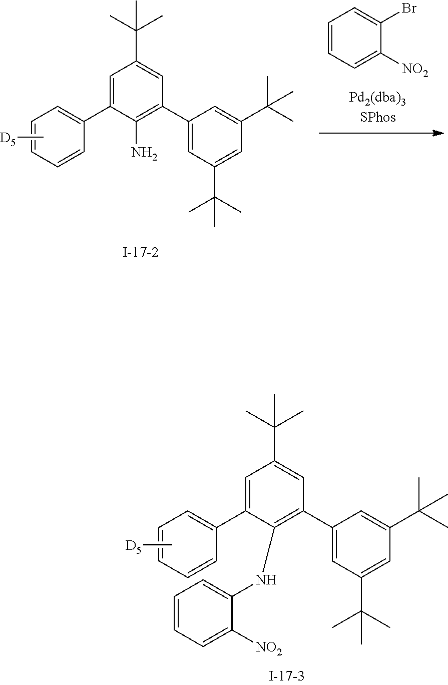

Intermediate I-17-2 (1.0 eq.), 1-bromo-2-nitrobenzene (1.1 eq.), Pd₂(dba)₃ (0.020 eq.), SPhos (0.040 eq.), and sodium tertiary butoxide (1.6 eq.) were suspended in a toluene solvent and heated to 120° C. for 12 hours in a nitrogen atmosphere. After cooling the mixture to room temperature, 300 ml of distilled water was added thereto, and an organic layer was extracted by using ethyl acetate. The extracted organic layer was washed with an aqueous solution of saturated sodium chloride and dried with magnesium sulfate. The result obtained therefrom was purified by column chromatography (ethyl acetate/hexane (volume ratio 5:95)) to obtain Intermediate I-17-3 (yield: 78%).

### Synthesis of Intermediate I-17-4

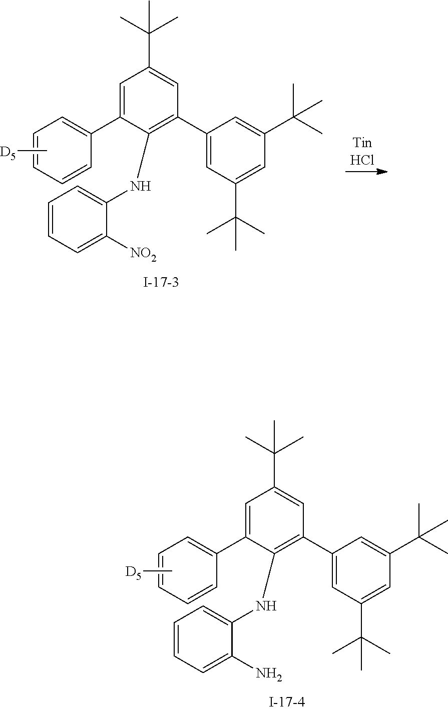

Intermediate I-17-3 (1.0 eq.) was dissolved in 300 ml of ethanol, and 3.2 ml of a 37% hydrochloric acid aqueous solution by mass fraction was added dropwise thereto. Tin (1.0 eq.) was added to the reaction mixture and stirred at 80° C. for 10 hours by raising the temperature. When the reaction ended, the reaction result was cooled to room temperature and neutralized with a 1N sodium hydroxide solution, an organic layer was extracted by using methylene chloride and distilled water, and the extracted organic layer was dried with magnesium sulfate, to thereby obtain Intermediate I-17-4 (yield: 75%). The obtained Intermediate I-17-4 was used in the next reaction without additional purification.

### Synthesis of Intermediate I-17-5

### 4-bromo-2-fluoro-1-methylbenzene

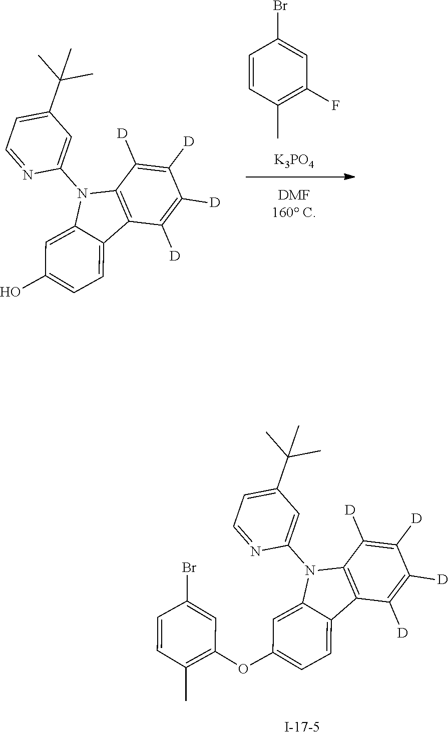

9-(4-(tert-butyl)pyridine-2-yl)-9H-carbazole-5,6,7,8-D₄-2-ol (1.0 eq.), 4-bromo-2-fluoro-1-methylbenzene (1.1 eq.), and potassium phosphate (2.0 eq.) were suspended in 100 ml of dimethylformamide and heated to 160° C. for 8 hours in a nitrogen atmosphere. After the mixture was cooled to room temperature, the solvent was removed by drying under reduced pressure, and an organic layer was extracted by using ethyl acetate and water and dried with magnesium sulfate. The result obtained therefrom was purified by column chromatography (ethyl acetate/hexane (volume ratio 10:90)) to obtain Intermediate I-17-5 (yield: 76%).

### Synthesis of Intermediate I-17-6

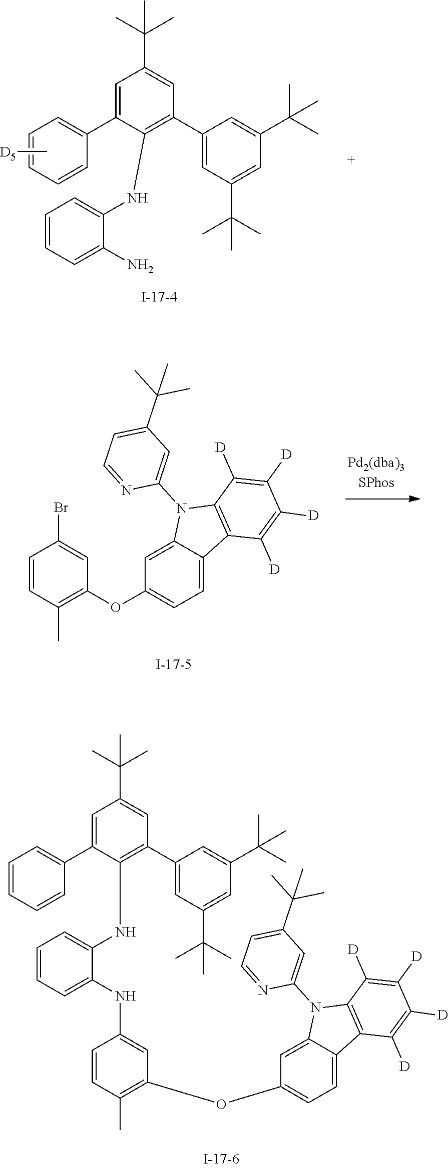

Intermediate I-17-4 (1.0 eq.), Intermediate I-17-5 (1.1 eq.), Pd₂(dba)₃ (0.050 eq.), SPhos (0.075 eq.), and sodium tertiary butoxide (2.0 eq.) were suspended in 100 ml of toluene and heated to 110° C. for 4 hours in a nitrogen atmosphere. After the mixture was cooled to room temperature, an organic layer was extracted by using ethyl acetate and water and dried with magnesium sulfate. The result obtained therefrom was purified by column chromatography (ethyl acetate/hexane (volume ratio 10:90)) to obtain Intermediate I-17-6 (yield: 59%).

### Synthesis of Intermediate I-17-7

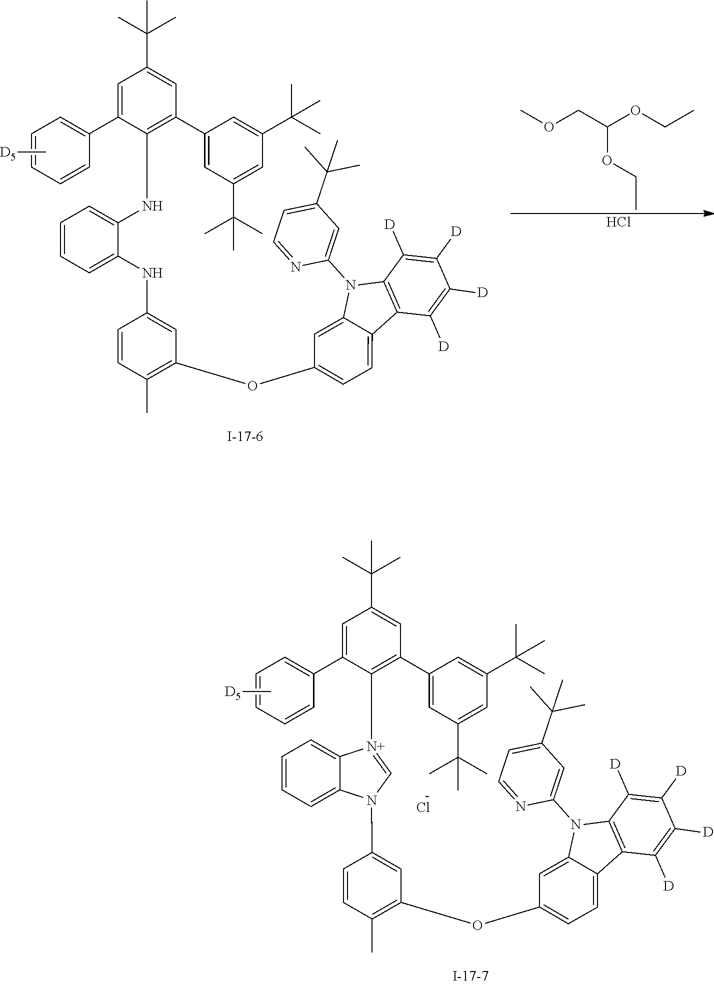

Intermediate I-17-6 (1.0 eq.) was dissolved in 40 ml of triethyl orthoformate (50 eq.), and 0.98 ml of 12N hydrochloric acid (1.2 eq.) was added dropwise thereto. The reaction mixture was heated to 80° C. and stirred for 12 hours. When the reaction ended, the solvent was removed therefrom under reduced pressure, and an organic layer was extracted by using ethyl acetate and distilled water. The organic layer was dried with magnesium sulfate, and the result obtained therefrom was purified by column chromatography (methanol/methylene chloride (volume ratio 5:95)) to obtain Intermediate I-17-7 (yield: 91%).

### Synthesis of Compound BD17

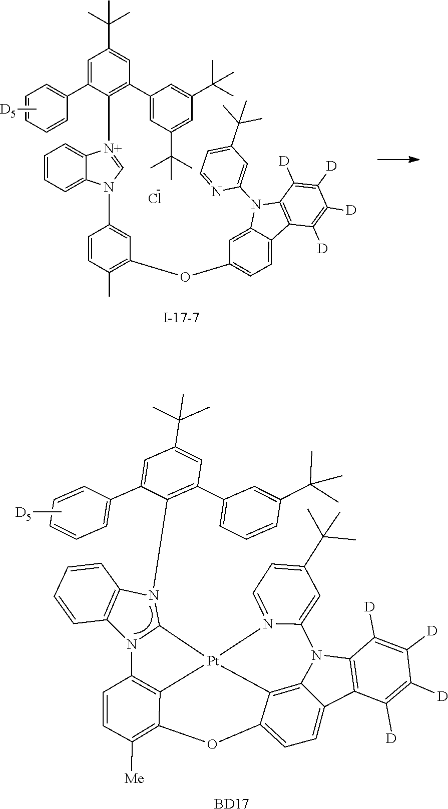

Intermediate I-17-7 (1.00 eq.), sodium acetate (3.00 eq.), and Pt(COD)C₁₂ (1.05 eq.) were suspended in 85 ml of 1,4-dioxane and stirred at 120° C. for 12 hours by raising the temperature. When the reaction ended, the solvent was removed therefrom under reduced pressure, and an organic layer was extracted by using ethyl acetate and distilled water. The result obtained therefrom was dried with magnesium sulfate and purified by column chromatography (methylene chloride/hexane (volume ratio 50:50)) to obtain Compound BD17 (yield: 39%).

### Synthesis Example 4 (Synthesis of Compound BD18)

Compound BD18 was obtained (yield: 45%) in substantially the same manner as in Synthesis Example 3, except that 9-(4-(tert-butyl)pyridine-2-yl)-9H-carbazole-5,6,7,8-2-ol was used instead of 9-(4-(tert-butyl)pyridine-2-yl)-9H-carbazole-5,6,7,8-D₄-2-ol in the synthesis of Intermediate I-17-5 in Synthesis Example 3.

### Synthesis Example 5 (Synthesis of Compound BD23)

### Synthesis of Intermediate I-23-1

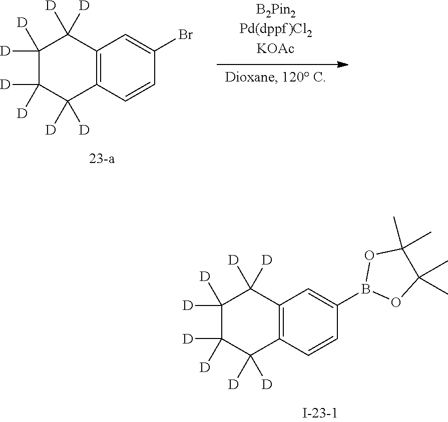 [SMILES: [2H]C1([2H])c2ccc(Br)cc2C([2H])([2H])C([2H])([2H])C1([2H])[2H] ; [2H]C1([2H])c2ccc(B3OC(C)(C)C(C)(C)O3)cc2C([2H])([2H])C([2H])([2H])C1([2H])[2H]]

Compound 23-a (1.0 eq.), B₂Pin₂ (1.2 eq.), Pd(dppf)C₁₂ (0.05 eq.), and KOAc (2.0 eq.) were suspended in 0.2 M dioxane and heated to 120° C. for 12 hours in an N₂ atmosphere. After cooling the mixture to room temperature (r.t.), distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-23-1 (yield: 76%).

### Synthesis of Intermediate I-23-2

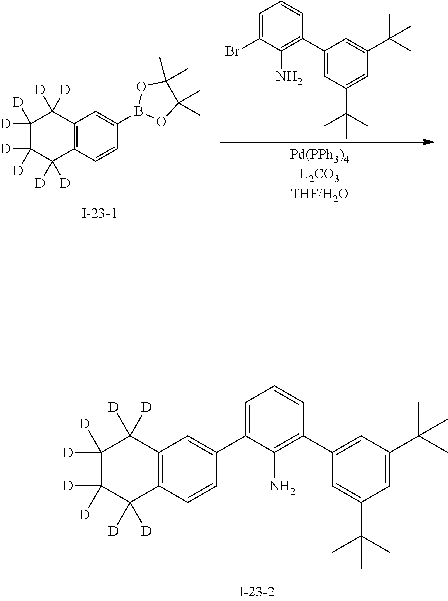 [SMILES: [2H]C1([2H])c2ccc(B3OC(C)(C)C(C)(C)O3)cc2C([2H])([2H])C([2H])([2H])C1([2H])[2H] ; CC(C)(C)c1cc(-c2cccc(Br)c2N)cc(C(C)(C)C)c1 ; [2H]C1([2H])c2ccc(-c3cccc(-c4cc(C(C)(C)C)cc(C(C)(C)C)c4)c3N)cc2C([2H])([2H])C([2H])([2H])C1([2H])[2H]]

12 g of Intermediate I-23-1 (1.0 eq.), 3-bromo-3′,5′-di-tert-butyl-[1,1′-biphenyl]-2-amine (1.1 eq.), tetrakis(triphenylphosphine)palladium(0) (0.020 eq.), and potassium carbonate (2.0 eq.) were suspended in a mixed solution of 300 ml of THF and 100 ml of distilled water and heated to 80° C. for 24 hours in a nitrogen atmosphere. After cooling the mixture to room temperature, 300 ml of distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-23-2 (yield: 81%).

### Synthesis of Intermediate I-23-3

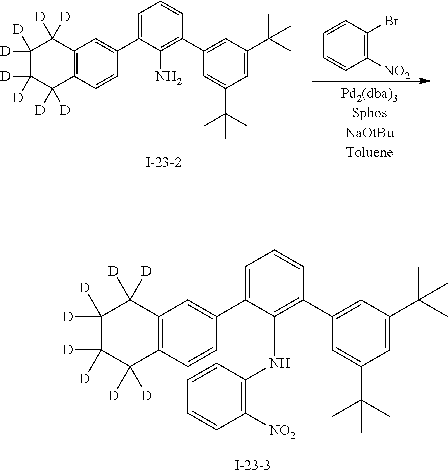

Intermediate I-23-2 (1.0 eq.), 1-bromo-2-nitrobenzene (1.1 eq.), Pd₂(dba)₃ (0.050 eq.), SPhos (0.075 eq.), and sodium tertiary butoxide (2.0 eq.) were suspended in 100 ml of toluene and heated to 110° C. for 4 hours in a nitrogen atmosphere. After the mixture was cooled to room temperature, an organic layer was extracted by using ethyl acetate and water and dried with magnesium sulfate. The result obtained therefrom was purified by column chromatography (ethyl acetate/hexane (volume ratio 10:90)) to obtain Intermediate I-23-3 (yield: 59%).

### Synthesis of Intermediate I-23-4

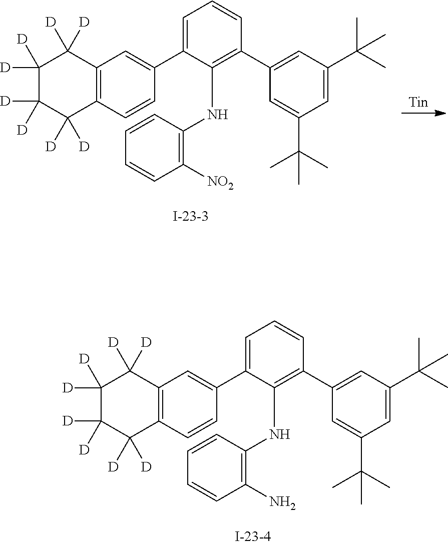 [SMILES: [2H]C1([2H])c2ccc(-c3cccc(-c4cc(C(C)(C)C)cc(C(C)(C)C)c4)c3Nc3ccccc3[N+](=O)[O-])cc2C([2H])([2H])C([2H])([2H])C1([2H])[2H] ; [2H]C1([2H])c2ccc(-c3cccc(-c4cc(C(C)(C)C)cc(C(C)(C)C)c4)c3Nc3ccccc3N)cc2C([2H])([2H])C([2H])([2H])C1([2H])[2H]]

Intermediate I-23-3 (1.0 eq.) was dissolved in 300 ml of ethanol, and 3.2 ml of a 37% hydrochloric acid aqueous solution by mass fraction was added dropwise thereto. Tin (1.0 eq.) was added to the reaction mixture and stirred at 80° C. for 10 hours by raising the temperature. When the reaction ended, the reaction result was cooled to room temperature and neutralized with a 1N sodium hydroxide solution, an organic layer was extracted by using methylene chloride and distilled water, and the extracted organic layer was dried with magnesium sulfate, to thereby obtain Intermediate I-23-4 (yield: 77%). The obtained Intermediate I-23-4 was used in the next reaction without additional purification.

### Synthesis of Intermediate I-23-5

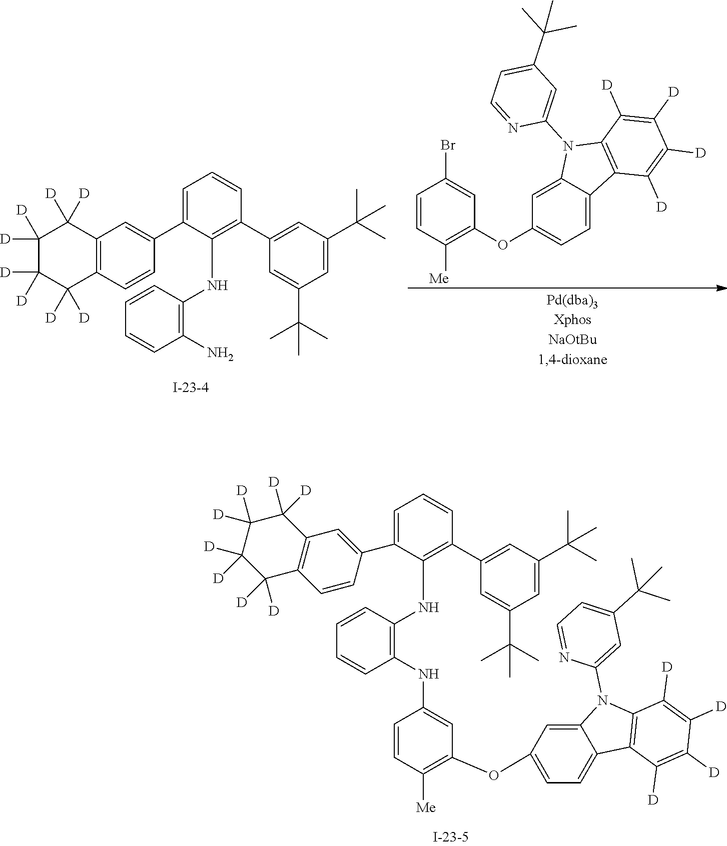

Intermediate I-23-4 (1.0 eq.), Intermediate I-17-5 (1.1 eq.), Pd₂(dba)₃ (0.050 eq.), XPhos (0.075 eq.), and sodium tertiary butoxide (2.0 eq.) were suspended in 100 ml of 1,4dioxane and heated to 110° C. for 4 hours in a nitrogen atmosphere. After the mixture was cooled to room temperature, an organic layer was extracted by using ethyl acetate and water and dried with magnesium sulfate. The result obtained therefrom was purified by column chromatography (ethyl acetate/hexane (volume ratio 10:90)) to obtain Intermediate I-23-5 (yield: 66%).

### Synthesis of Intermediate I-23-6

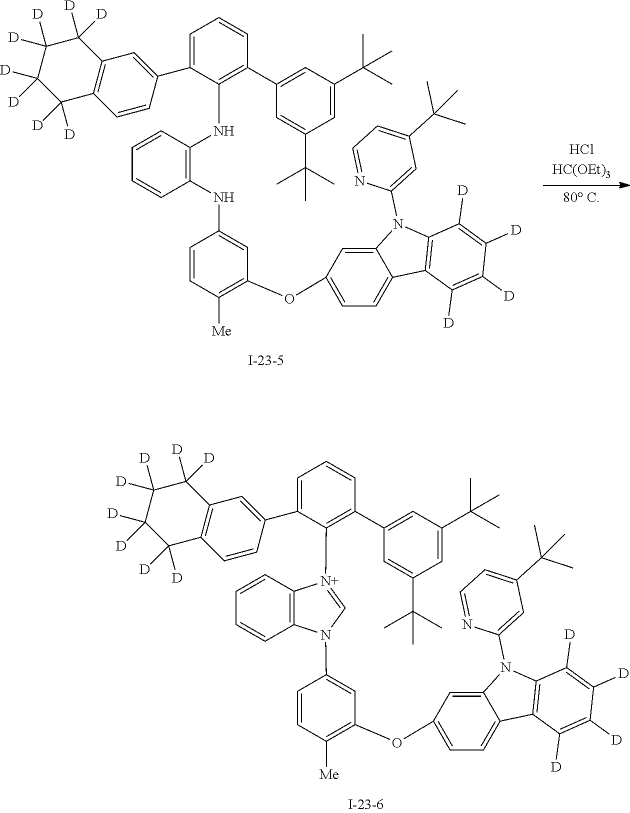 [SMILES: [2H]c1c([2H])c([2H])c2c(c1[2H])c1ccc(Oc3cc(Nc4ccccc4Nc4c(-c5cc(C(C)(C)C)cc(C(C)(C)C)c5)cccc4-c4ccc5c(c4)C([2H])([2H])C([2H])([2H])C([2H])([2H])C5([2H])[2H])ccc3C)cc1n2-c1cc(C(C)(C)C)ccn1 ; [2H]c1c([2H])c([2H])c2c(c1[2H])c1ccc(Oc3cc(-n4c[n+](-c5c(-c6cc(C(C)(C)C)cc(C(C)(C)C)c6)cccc5-c5ccc6c(c5)C([2H])([2H])C([2H])([2H])C([2H])([2H])C6([2H])[2H])c5ccccc54)ccc3C)cc1n2-c1cc(C(C)(C)C)ccn1]

Intermediate I-23-5 (1.0 eq.) was dissolved in 40 ml of triethyl orthoformate (50 eq.), and 0.98 ml of 12N hydrochloric acid (1.2 eq.) was added dropwise thereto. The reaction mixture was heated to 80° C. and stirred for 12 hours. When the reaction ended, the solvent was removed therefrom under reduced pressure, and an organic layer was extracted by using ethyl acetate and distilled water. The organic layer was dried with magnesium sulfate, and the result obtained therefrom was purified by column chromatography (methanol/methylene chloride (volume ratio 5:95)) to obtain Intermediate I-23-6 (yield: 90%).

### Synthesis of Compound BD23

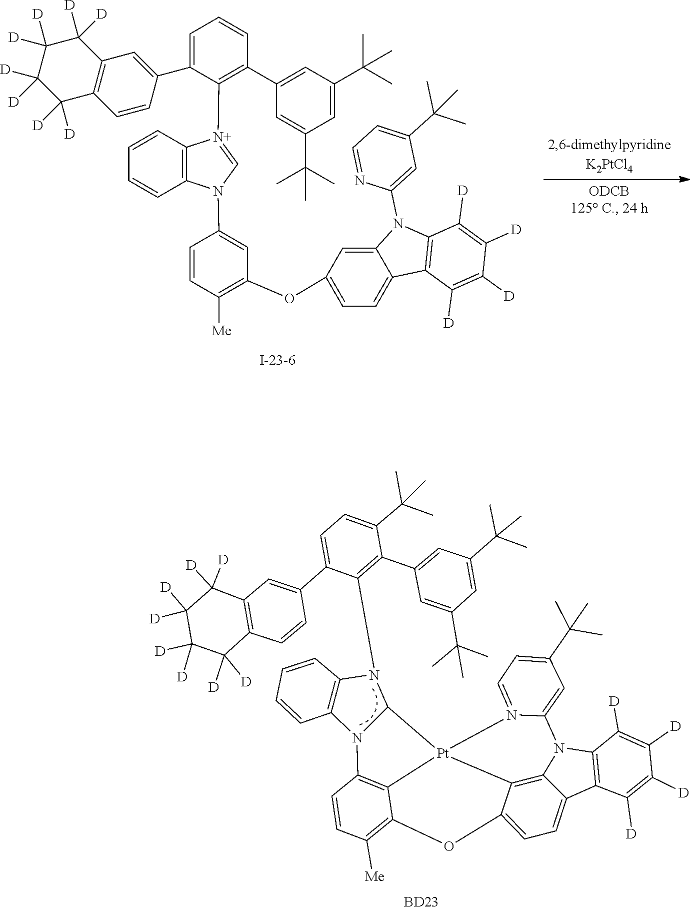

Intermediate I-23-6 (1.00 eq.), 2,6-dimethylpyridine (3.00 eq.), and potassium tetrachloroplatinate (K₂PtCl₄) (1.05 eq.) were suspended in 85 ml of ODCB and stirred at 125° C. for 24 hours by raising the temperature. When the reaction ended, the solvent was removed therefrom under reduced pressure, and an organic layer was extracted by using ethyl acetate and distilled water. The result obtained therefrom was dried with magnesium sulfate and purified by column chromatography (methylene chloride/hexane (volume ratio 50:50)) to obtain Compound BD23 (yield: 45%).

### Synthesis Example 6 (Synthesis of Compound BD24)

### Synthesis of Intermediate I-24-1

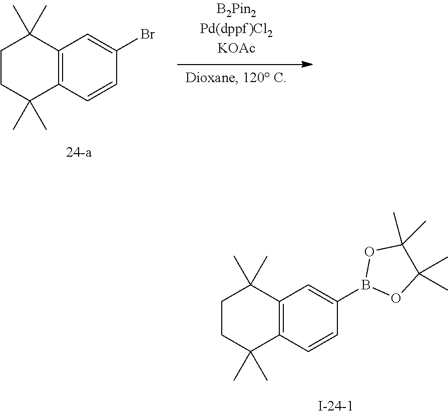 [SMILES: CC1(C)CCC(C)(C)c2cc(Br)ccc21 ; CC1(C)CCC(C)(C)c2cc(B3OC(C)(C)C(C)(C)O3)ccc21]

Compound 24-a (1.0 eq.), B₂Pin₂ (1.2 eq.), Pd(dppf)C₁₂ (0.05 eq.), and KOAc (2.0 eq.) were suspended in 0.2 M dioxane and heated to 120° C. for 12 hours in a N₂ atmosphere. After cooling the mixture to room temperature (r.t.), distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-24-1 (yield: 79%).

### Synthesis of Intermediate I-24-2

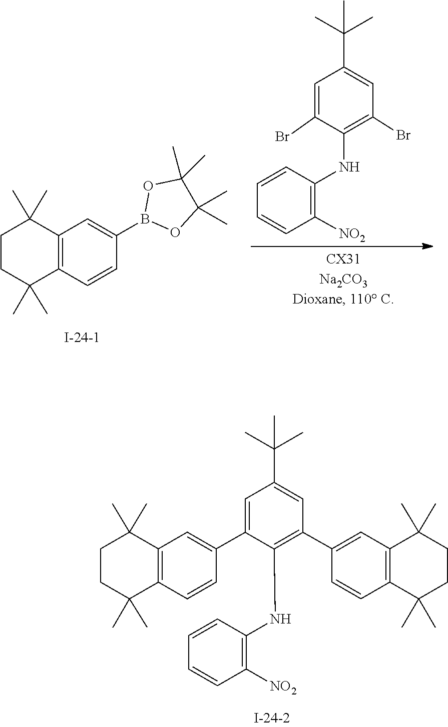

14 g of Intermediate I-24-1 (1.0 eq.), 2,6-dibromo-4-(tert-butyl)-N-(2-nitrophenyl)aniline (1.1 eq.), chlorophenylallyl[1,3-bis(2,6-diisopropylphenyl)imidazole-2-ylidene]palladium(II) (CX31) (0.020 eq.), and sodium carbonate (2.0 eq.) were suspended in a dioxane solution and heated to 110° C. for 24 hours in a nitrogen atmosphere. After cooling the mixture to room temperature, 300 ml of distilled water was added thereto, an organic layer was extracted by using ethyl acetate, and the extracted organic layer was washed with an aqueous solution of saturated sodium chloride and dried with magnesium sulfate. The result obtained therefrom was purified by column chromatography (methylene chloride/hexane (volume ratio 1:99)) to obtain intermediate I-24-2 (yield: 74%).

### Synthesis of Intermediate I-24-3

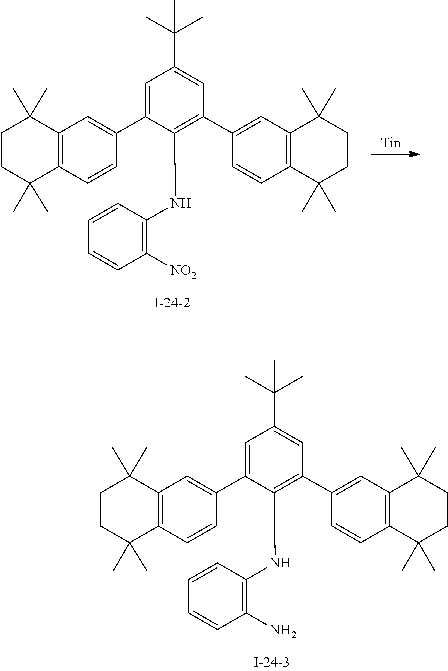 [SMILES: CC(C)(C)c1cc(-c2ccc3c(c2)C(C)(C)CCC3(C)C)c(Nc2ccccc2[N+](=O)[O-])c(-c2ccc3c(c2)C(C)(C)CCC3(C)C)c1 ; CC(C)(C)c1cc(-c2ccc3c(c2)C(C)(C)CCC3(C)C)c(Nc2ccccc2N)c(-c2ccc3c(c2)C(C)(C)CCC3(C)C)c1]

Intermediate I-24-2 (1.0 eq.) was dissolved in 300 ml of ethanol, and 3.2 ml of a 37% hydrochloric acid aqueous solution by mass fraction was added dropwise thereto. Tin (1.0 eq.) was added to the reaction mixture and stirred at 80° C. for 10 hours by raising the temperature. When the reaction ended, the reaction result was cooled to room temperature and neutralized with a 1N sodium hydroxide solution, an organic layer was extracted by using methylene chloride and distilled water, and the extracted organic layer was dried with magnesium sulfate, to thereby obtain Intermediate I-24-3 (yield: 71%). The obtained Intermediate I-24-3 was used in the next reaction without additional purification.

### Synthesis of Intermediate I-24-4

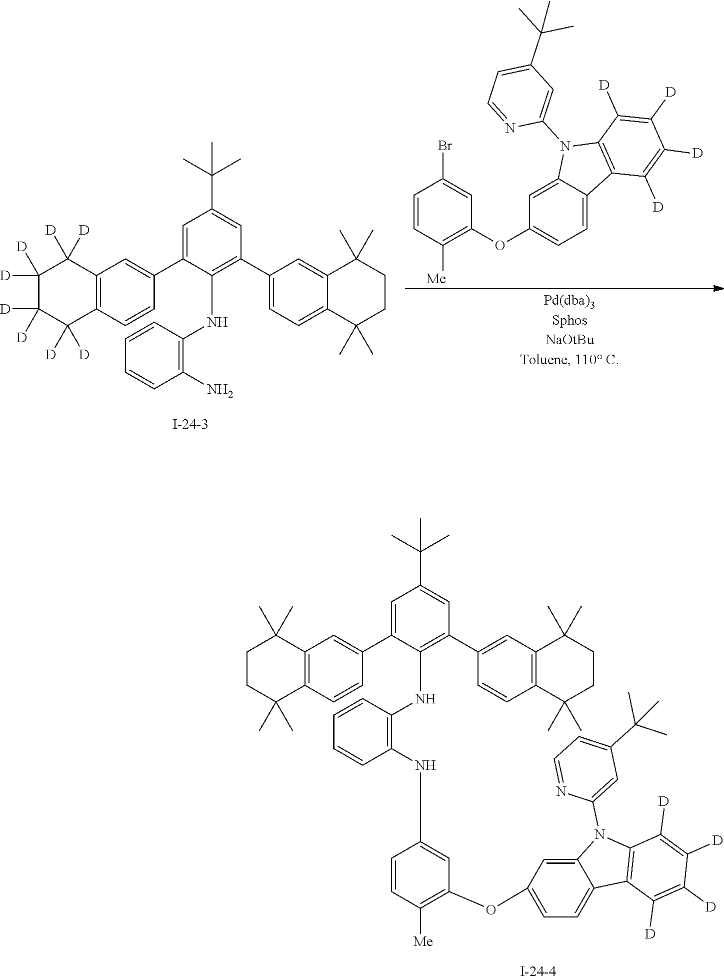

Intermediate I-24-3 (1.0 eq.), Intermediate I-17-5 (1.1 eq.), Pd₂(dba)₃ (0.050 eq.), SPhos (0.075 eq.), and sodium tertiary butoxide (2.0 eq.) were suspended in 100 ml of toluene and heated to 110° C. for 4 hours in a nitrogen atmosphere. After the mixture was cooled to room temperature, an organic layer was extracted by using ethyl acetate and water and dried with magnesium sulfate. The result obtained therefrom was purified by column chromatography (ethyl acetate/hexane (volume ratio 10:90)) to obtain Intermediate I-24-4 (yield: 70%).

### Synthesis of Intermediate I-24-5

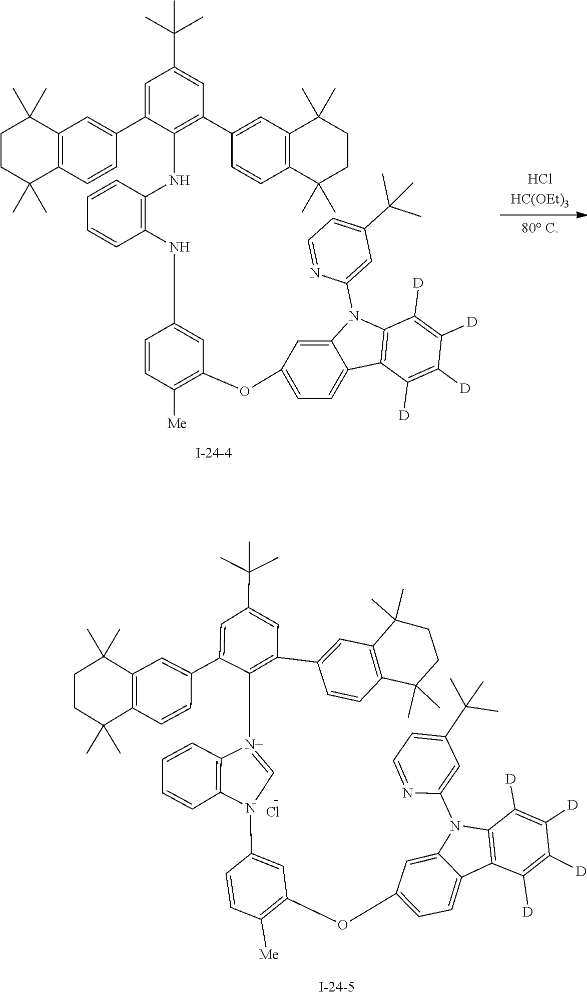 [SMILES: [2H]c1c([2H])c([2H])c2c(c1[2H])c1ccc(Oc3cc(Nc4ccccc4Nc4c(-c5ccc6c(c5)C(C)(C)CCC6(C)C)cc(C(C)(C)C)cc4-c4ccc5c(c4)C(C)(C)CCC5(C)C)ccc3C)cc1n2-c1cc(C(C)(C)C)ccn1 ; [2H]c1c([2H])c([2H])c2c(c1[2H])c1ccc(Oc3cc(-n4c[n+](-c5c(-c6ccc7c(c6)C(C)(C)CCC7(C)C)cc(C(C)(C)C)cc5-c5ccc6c(c5)C(C)(C)CCC6(C)C)c5ccccc54)ccc3C)cc1n2-c1cc(C(C)(C)C)ccn1 ; Cl]

Intermediate I-24-4 (1.0 eq.) was dissolved in 40 ml of triethyl orthoformate (50 eq.), and 0.98 ml of 12N hydrochloric acid (1.2 eq.) was added dropwise thereto. The reaction mixture was heated to 80° C. and stirred for 12 hours. When the reaction ended, the solvent was removed therefrom under reduced pressure, and an organic layer was extracted by using ethyl acetate and distilled water. The organic layer was dried with magnesium sulfate, and the result obtained therefrom was purified by column chromatography (methanol/methylene chloride (volume ratio 5:95)) to obtain Intermediate I-24-5 (yield: 81%).

### Synthesis of Compound BD24

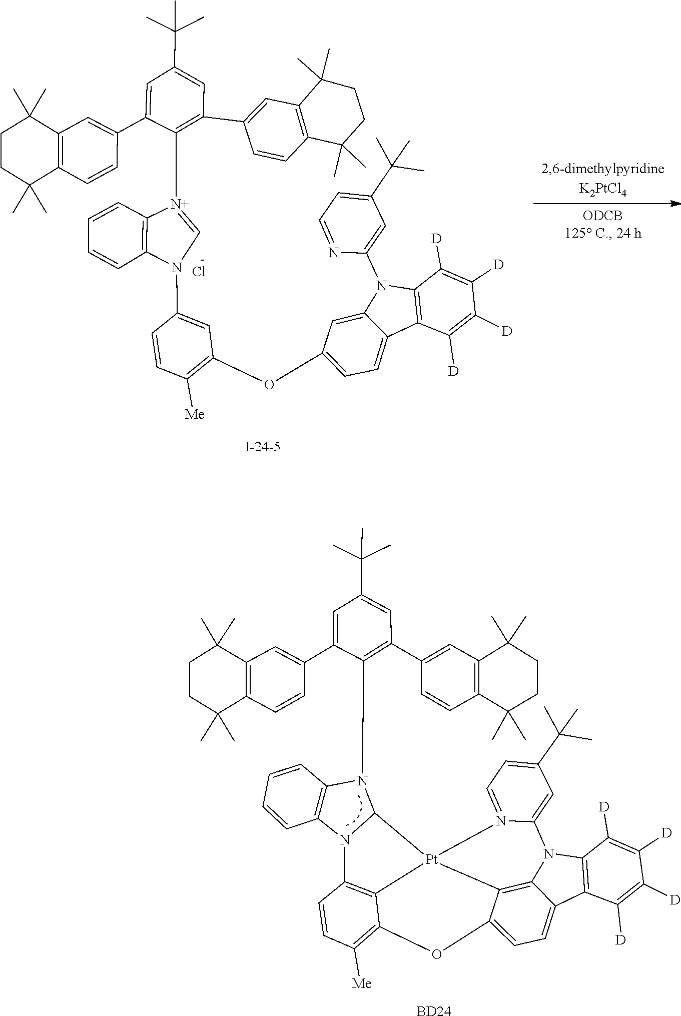

Intermediate I-24-5 (1.00 eq.), 2,6-dimethylpyridine (3.00 eq.), and potassium tetrachloroplatinate (K₂PtCl₄) (1.05 eq.) were suspended in 85 ml of ODCB and stirred at 125° C. for 24 hours by raising the temperature. When the reaction ended, the solvent was removed therefrom under reduced pressure, and an organic layer was extracted by using ethyl acetate and distilled water. The result obtained therefrom was dried with magnesium sulfate and purified by column chromatography (methylene chloride/hexane (volume ratio 50:50)) to obtain Compound BD24 (yield: 47%).

Synthesis methods of compounds other than the compounds of Synthesis Examples 1 to 6 may be readily recognized by those skilled in the art by referring to the synthesis paths and source materials.

### Comparative Example 1

As an anode, a glass substrate (product of Corning Inc.) with a 15 Q/cm² (1,200 Å) ITO formed thereon was cut to a size of 50 mm×50 mm×0.7 mm, sonicated by using isopropyl alcohol and pure water each for 5 minutes, washed by irradiation of ultraviolet rays and exposure of ozone thereto for 30 minutes, and mounted on a vacuum deposition apparatus.

2-TNATA was vacuum-deposited on the anode to form a hole injection layer having a thickness of 600 Å. 4,4′-bis[N-(1-naphthyl)-N-phenylamino]biphenyl (hereinafter, referred to as NPB) was vacuum-deposited on the hole injection layer to form a hole transport layer having a thickness of 300 Å.

Compound CE1, Compound ETH2 (second compound), Compound HTH42 (third compound), and Compound DFD30 (fourth compound) were vacuum-deposited on the hole transport layer to form an emission layer having a thickness of 400 Å. In this regard, the amount of Compound CE1 was 13 wt % based on the total amount (100 wt %) of the emission layer, the amount of Compound DFD30 was 1.5 wt % based on the total amount (100 wt %) of the emission layer, and the weight ratio of Compound ETH2 to Compound HTH42 was adjusted to 4:6. The organometallic compounds employed in forming the emission layer are shown in Table 1.

Compound ETH34 was vacuum-deposited on the emission layer to form a hole blocking layer having a thickness of 50 Å. ET46 and LiQ were vacuum-deposited on the hole blocking layer at a weight ratio of 4:6 to form an electron transport layer having a thickness of 310 Å. Yb was vacuum-deposited on the electron transport layer to form an electron injection layer having a thickness of 15 Å, and Mg was vacuum-deposited thereon to form a cathode having a thickness of 800 Å, thereby completing manufacture of a light-emitting device.

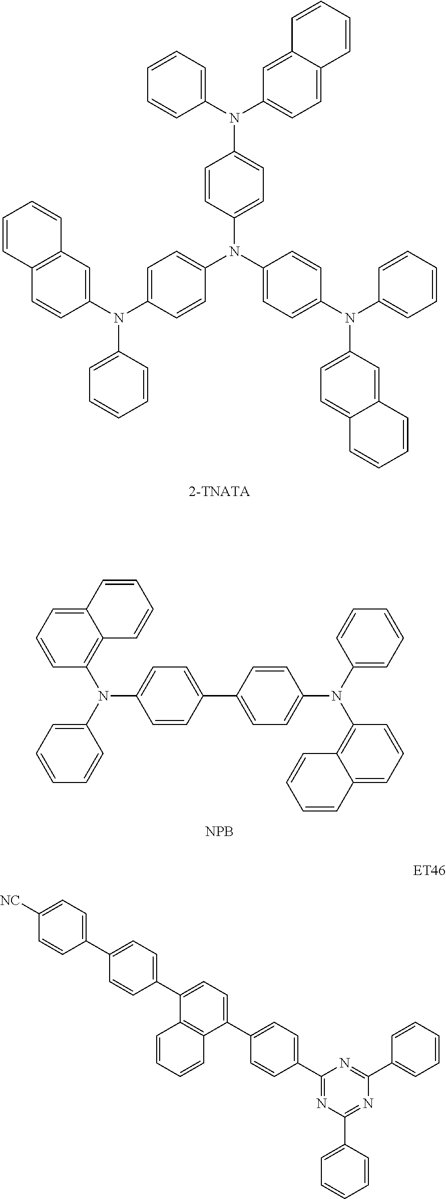 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; "NPB" ; N#Cc1ccc(-c2ccc(-c3ccc(-c4ccc(-c5nc(-c6ccccc6)nc(-c6ccccc6)n5)cc4)c4ccccc34)cc2)cc1]

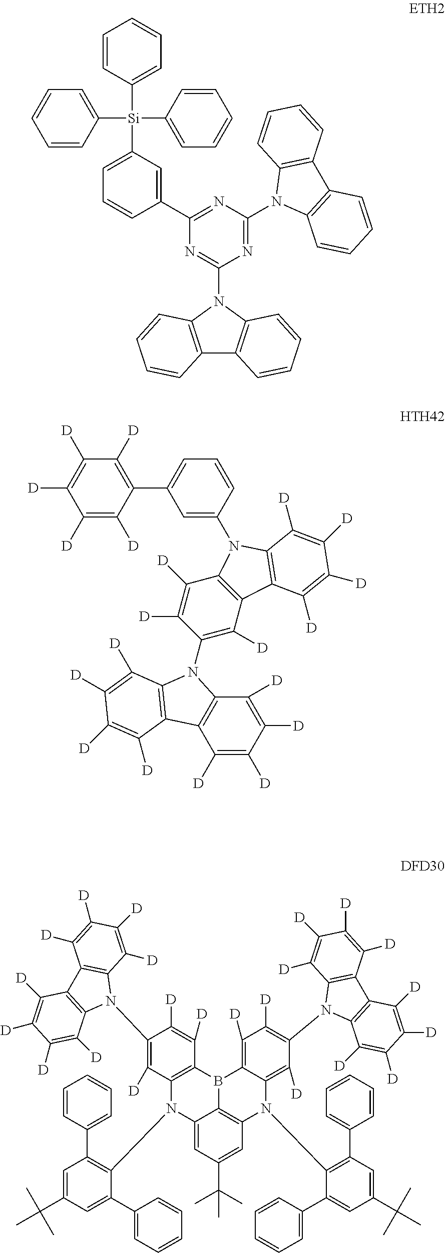

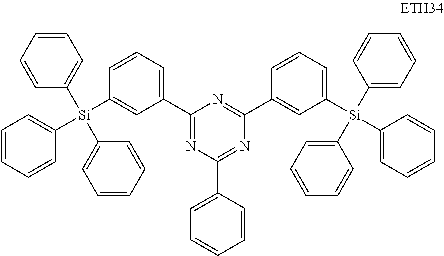 [SMILES: c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

### Comparative Examples 2 to 8

Light-emitting devices were manufactured in substantially the same manner as in Comparative Example 1, except that the organometallic compounds shown in Table 1 were used instead of Compound CE1 in forming the emission layer.

TABLE 1

| No. | Organometallic compound |
|---|---|
| Comparative Example 1 | CE1 |
| Comparative Example 2 | CE2 |
| Comparative Example 3 | CE3 |
| Comparative Example 4 | CE4 |
| Comparative Example 5 | CE5 |
| Comparative Example 6 | CE6 |
| Comparative Example 7 | CE7 |
| Comparative Example 8 | CE8 |

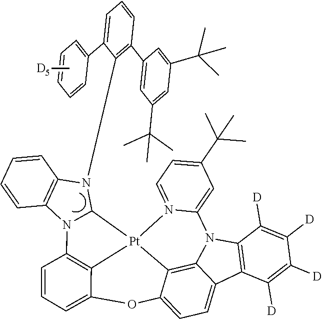

CE1 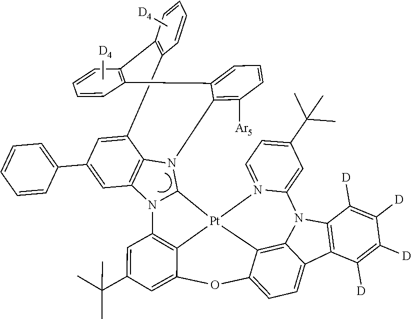
CE2 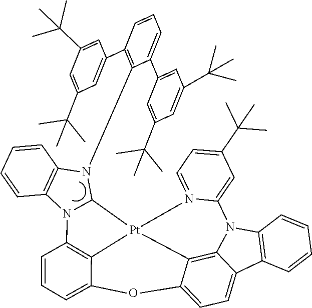
CE3 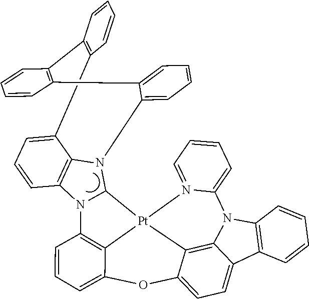
CE4 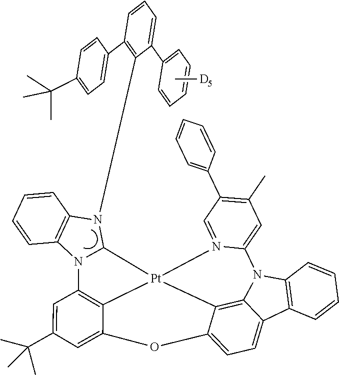
CE5 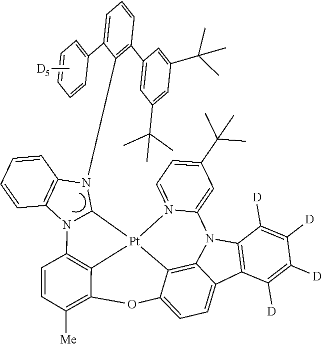
CE6 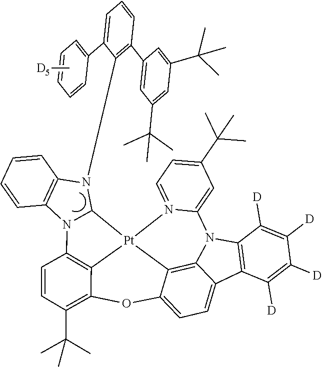
CE7 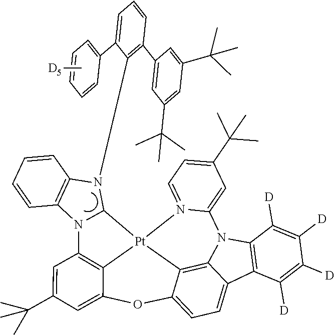
CE8

Ar₅ in Compound CE2 is a group represented by

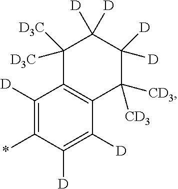 [SMILES: *c1c([2H])c([2H])c2c(c1[2H])C(C([2H])([2H])[2H])(C([2H])([2H])[2H])C([2H])([2H])C([2H])([2H])C2(C([2H])([2H])[2H])C([2H])([2H])[2H]]

and * in Ar₅ indicates a binding site to a neighboring atom.

### Examples 1 to 19

Light-emitting devices were manufactured in substantially the same manner as in Comparative Example 1, except that the organometallic compounds shown in Table 2 were used instead of Compound CE1 in forming the emission layer.

TABLE 2

| No. | Organometallic compound |
|---|---|
| Example 1 | BD1 |
| Example 2 | BD3 |
| Example 3 | BD5 |
| Example 4 | BD7 |
| Example 5 | BD9 |
| Example 6 | BD12 |
| Example 7 | BD15 |
| Example 8 | BD16 |
| Example 9 | BD17 |
| Example 10 | BD18 |
| Example 11 | BD19 |
| Example 12 | BD20 |
| Example 13 | BD21 |
| Example 14 | BD22 |
| Example 15 | BD23 |
| Example 16 | BD24 |
| Example 17 | BD25 |
| Example 18 | BD26 |
| Example 19 | BD27 |

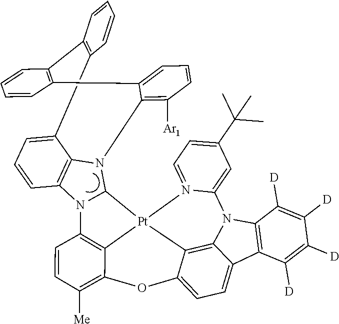

BD1 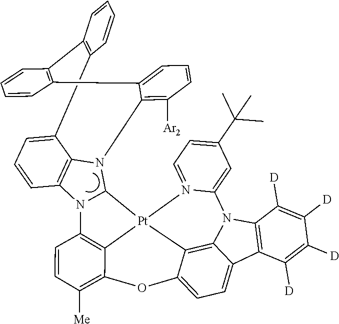
BD3 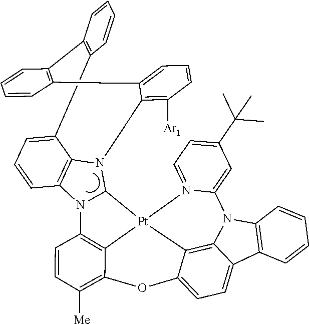
BD5 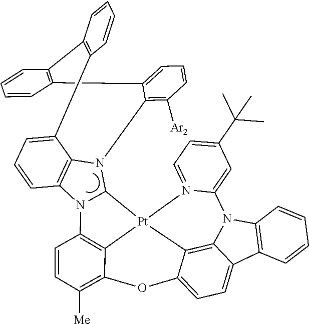
BD7 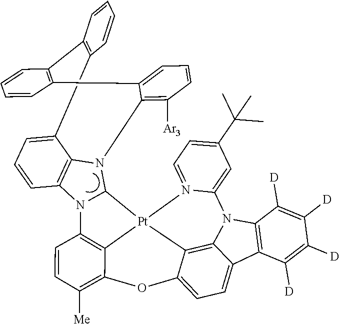
BD9 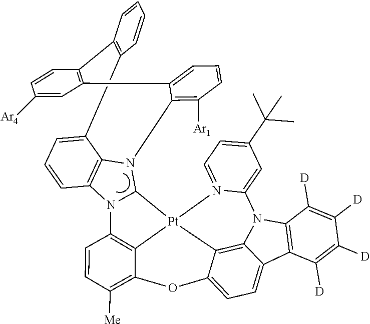
BD12 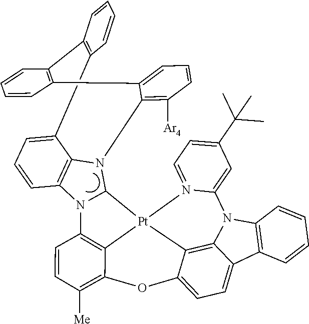
BD15 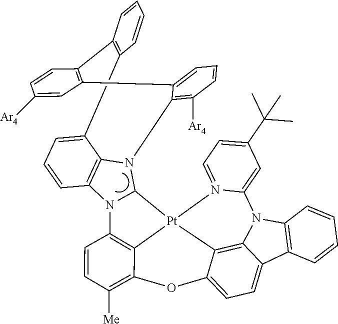
BD16 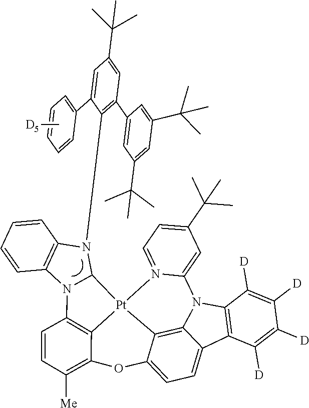
BD17 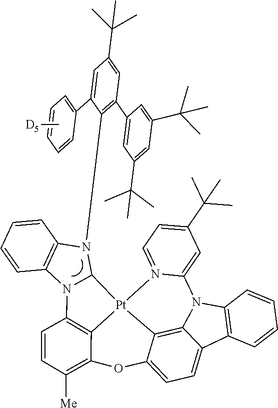
BD18 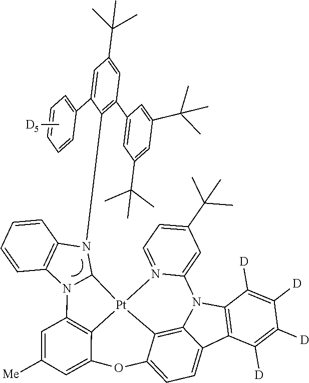
BD19 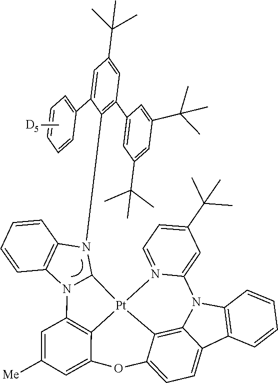
BD20 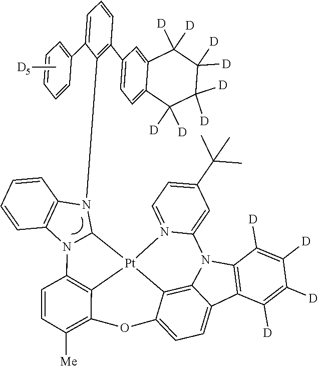
BD21 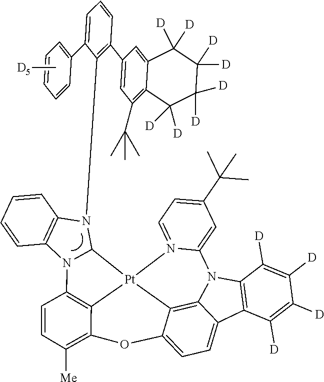
BD22 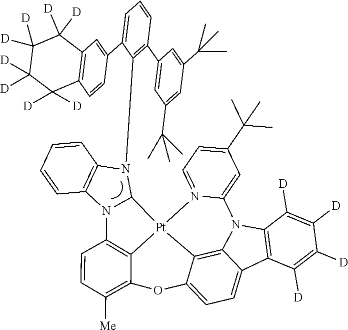
BD23 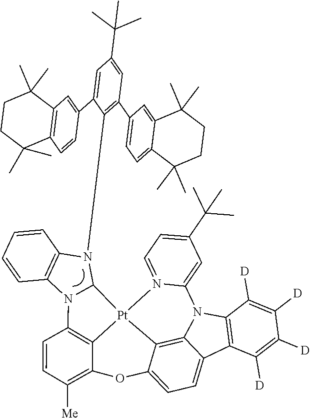
BD24 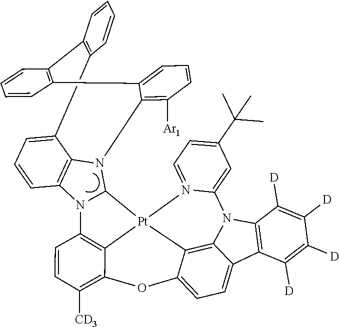
BD25 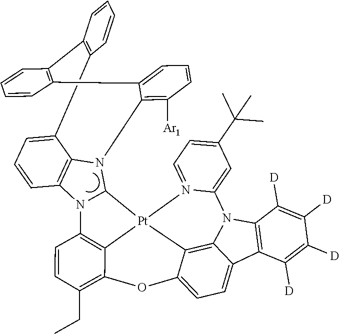
BD26 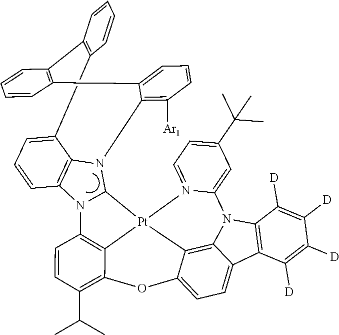
BD27

Ar₁ in Compounds BD1, BD5, and BD25 to BD27 is a group represented by

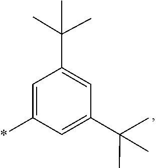 [SMILES: *c1cc(C(C)(C)C)cc(C(C)(C)C)c1]

Ar₂ in Compounds BD3 and BD7 is a group represented by

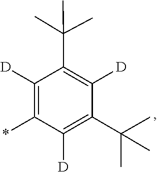 [SMILES: *c1c([2H])c(C(C)(C)C)c([2H])c(C(C)(C)C)c1[2H]]

Ar₃ in Compound BD9 is a group represented by

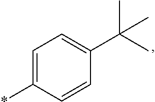 [SMILES: *c1ccc(C(C)(C)C)cc1]

Ar₄ in Compounds BD12, BD15, and BD16 is a group represented by

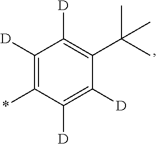 [SMILES: *c1c([2H])c([2H])c(C(C)(C)C)c([2H])c1[2H]]

and * in Ar₁ to Ar₄ indicates a binding site to a neighboring atom.

### Evaluation Example 1

The capacitance was measured by applying voltages from −4 V to 6 V to the light-emitting devices manufactured in Comparative Examples 1 to 8 and Examples 1 to 19, by using the Alpha-A high performance frequency analyzer equipment from Novocontrol Technologies at 500 Hz, and the amount of charge was calculated by using Equation 1:

$$Q = {\int }_{{V}_{1}}^{{V}_{2}} C \cdot dV \qquad [ Equation 1 ]$$

In Equation 1,
Q refers to the amount of charge,
C refers to capacitance,
V₁ was set to −2 V,
V₂ is a voltage corresponding to the maximum value of capacitance (Cₘₐₓ), and
dV is the measurement interval of voltage, and was set to 0.1 V.

The maximum value of capacitance (Cₘₐₓ) measured for each light-emitting device and the calculated amount of charge (Q) are shown in Table 3. Each of the maximum value of capacitance (Cₘₐₓ) and the value of the amount of charge (Q) are the average of 25 evaluations conducted for each light-emitting device. The relative maximum value of capacitance (relative Cₘₐₓ) is expressed relative to the maximum value of capacitance (100%) of Comparative Example 1, and the relative amount of charge (relative Q) is expressed relative to the amount of charge (100%) of Comparative Example 1.

TABLE 3

| | Organo- | | | | |
|---|---|---|---|---|---|
| | metallic | Cₘₐₓ | Relative | Q | Relative |
| No. | compound | (nF) | Cₘₐₓ (%) | (nC) | Q (%) |
| Comparative Example 1 | CE1 | 3.95 | 100 | 7.88 | 100 |
| Comparative Example 2 | CE2 | 4.71 | 119 | 9.92 | 126 |
| Comparative Example 3 | CE3 | 4.68 | 118 | 9.28 | 118 |
| Comparative Example 4 | CE4 | 4.02 | 102 | 8.92 | 113 |
| Comparative Example 5 | CE5 | 4.22 | 107 | 8.12 | 103 |
| Comparative Example 6 | CE6 | 4.56 | 115 | 8.94 | 113 |
| Comparative Example 7 | CE7 | 4.71 | 119 | 9.01 | 114 |
| Comparative Example 8 | CE8 | 4.66 | 118 | 9.40 | 119 |
| Example 1 | BD1 | 2.97 | 75 | 6.44 | 82 |
| Example 2 | BD3 | 2.83 | 72 | 5.99 | 76 |
| Example 3 | BD5 | 3.13 | 79 | 6.51 | 83 |
| Example 4 | BD7 | 3.15 | 80 | 6.92 | 88 |
| Example 5 | BD9 | 2.85 | 72 | 6.27 | 80 |
| Example 6 | BD12 | 3.38 | 86 | 7.18 | 91 |
| Example 7 | BD15 | 3.10 | 78 | 6.76 | 86 |
| Example 8 | BD16 | 3.58 | 90 | 6.75 | 86 |
| Example 9 | BD17 | 3.61 | 91 | 7.00 | 89 |
| Example 10 | BD18 | 3.62 | 92 | 7.22 | 92 |
| Example 11 | BD19 | 3.79 | 96 | 7.61 | 97 |
| Example 12 | BD20 | 3.79 | 96 | 7.46 | 95 |
| Example 13 | BD21 | 2.88 | 73 | 6.04 | 77 |
| Example 14 | BD22 | 2.94 | 74 | 6.39 | 81 |
| Example 15 | BD23 | 2.91 | 74 | 6.55 | 83 |
| Example 16 | BD24 | 2.98 | 75 | 6.88 | 87 |
| Example 17 | BD25 | 2.80 | 71 | 6.77 | 86 |
| Example 18 | BD26 | 2.88 | 73 | 6.84 | 87 |
| Example 19 | BD27 | 2.94 | 74 | 6.71 | 85 |

From Table 3, it was confirmed that the light-emitting devices according to Examples 1 to 19 exhibited a decrease in both the maximum value of capacitance and the amount of charge, compared to the light-emitting devices according to Comparative Examples 1 to 8.

Because the organometallic compound represented by Formula 1 satisfies both Conditions A and B, injection of holes may be relatively slow. Therefore, it is possible to move a hump that may occur in a low-voltage region to a high-voltage region and reduce the maximum value of capacitance. In an embodiment, the capacitance and amount of charge of a light-emitting device including the organometallic compound represented by Formula 1 may be reduced. As a result, the possibility of RC relay in an electronic apparatus including the light-emitting device may be reduced, thereby improving display quality.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

1. A light-emitting device comprising:
a first electrode;
a second electrode facing the first electrode; and
an interlayer between the first electrode and the second electrode and comprising an emission layer, wherein
the interlayer comprises an organometallic compound represented by Formula 1 and satisfies Conditions A and B: 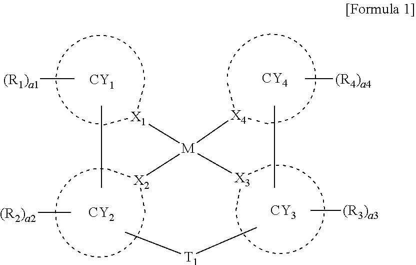
[Condition A]
in Formula 1, a moiety represented by 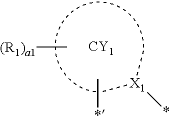
is a moiety represented by Formula 1-1 or Formula 1-2; and 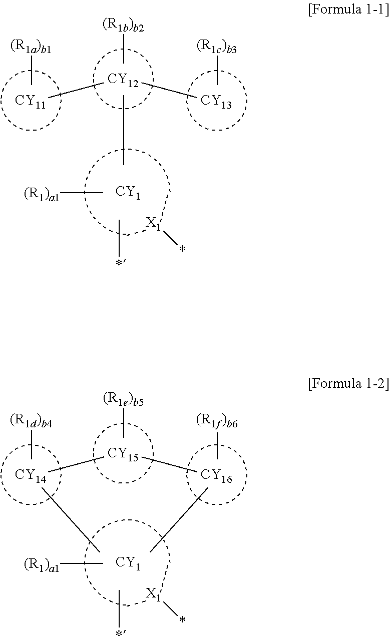
[Condition B]
at least one of R₂ in the number of a2 is each independently deuterium, a methyl group, an ethyl group, a propyl group, a methyl group that is substituted with at least one deuterium, an ethyl group that is substituted with at least one deuterium, or a propyl group that is substituted with at least one deuterium,
wherein in Formulae 1, 1-1, and 1-2,
M is platinum (Pt), palladium (Pd), gold (Au), silver (Ag), nickel (Ni), or copper(Cu),
X₁ to X₄ are each independently carbon (C) or nitrogen(N),
T₁ is a single bond, O, N(Z₁), or C(Z₁)(Z₂),
ring CY₁ to ring CY₄ and ring CY₁₁ to ring CY₁₆ are each independently a C₃-C₆₀ carbocyclic group or a C₁-C₆₀ heterocyclic group,
Z₁, Z₂, R₁ to R₄, and R₁ₐ to R_{1f} are each independently hydrogen, deuterium, —F, —Cl, —Br, —I, a hydroxyl group, a cyano group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a plurality of R₁ₐ are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1b} are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1c} are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1d} are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R₁ₑ are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1f} are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a1 to a4 and b1 to b6 are each independently an integer from 0 to 20,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or a combination thereof,
* indicates a binding site to M in Formula 1, and
*′ indicates a binding site to ring CY₂ in Formula 1.

2. The light-emitting device of claim 1, further comprising:
a second compound comprising at least one 7 L electron-deficient nitrogen-containing C₁-C₆₀ heterocyclic group, a third compound comprising a group represented by Formula 3, a fourth compound that is a delayed fluorescence compound, or a combination thereof, wherein
the organometallic compound, the second compound, the third compound, and the fourth compound are different from each other: 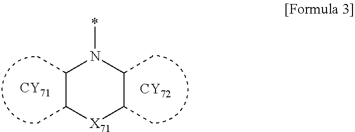
wherein in Formula 3,
ring CY₇₁ and ring CY₇₂ are each independently a π electron-rich C₃-C₆₀ cyclic group or a pyridine group,
X₇₁ is: a single bond; or a linking group including O, S, N, B, C, Si, or a combination thereof, and
* indicates a binding site to an atom included in a remaining part other than Formula 3 in the third compound.

3. The light-emitting device of claim 2, wherein
the second compound comprises a pyridine group, a pyrimidine group, a pyrazine group, a pyridazine group, a triazine group, or a combination thereof, and
the fourth compound is a compound including at least one cyclic group including boron (B) and nitrogen (N) as ring-forming atoms.

4. The light-emitting device of claim 2, wherein the emission layer comprises:
the organometallic compound; and
the second compound, the third compound, the fourth compound, or a combination thereof, and
the emission layer emits blue light.

5. An electronic apparatus comprising:
the light-emitting device of claim 1; and
a thin-film transistor electrically connected to the light-emitting device.

6. An electronic equipment comprising the light-emitting device of claim 1, wherein
the electronic equipment is a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet computer, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall including multiple displays tiled together, a theater screen, a stadium screen, a phototherapy device, or a signboard.

7. An organometallic compound represented by Formula 1 and that satisfies Conditions A and B: 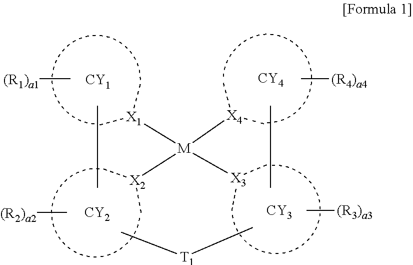
[Condition A]
in Formula 1, a moiety represented by 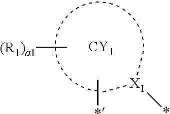
is a moiety represented by Formula 1-1 or Formula 1-2; and 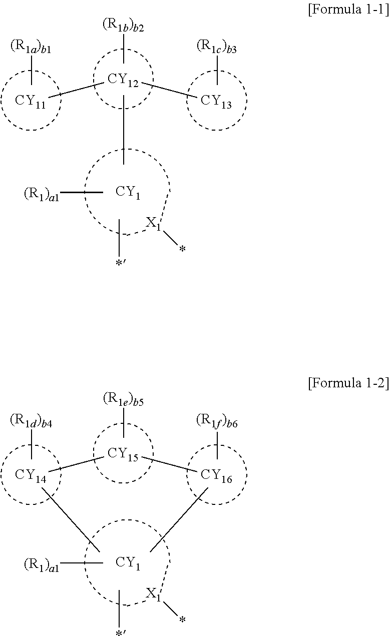
[Condition B]
at least one of R₂ in the number of a2 is each independently deuterium, a methyl group, an ethyl group, a propyl group, a methyl group that is substituted with at least one deuterium, an ethyl group that is substituted with at least one deuterium, or a propyl group that is substituted with at least one deuterium,
wherein in Formulae 1, 1-1, and 1-2,
M is platinum (Pt), palladium (Pd), gold (Au), silver (Ag), nickel (Ni), or copper(Cu),
X₁ to X₄ are each independently carbon (C) or nitrogen(N),
T₁ is a single bond, O, N(Z₁), or C(Z₁)(Z₂),
ring CY₁ to ring CY₄ and ring CY₁₁ to ring CY₁₆ are each independently a C₃-C₆₀ carbocyclic group or a C₁-C₆₀ heterocyclic group,
Z₁, Z₂, R₁ to R₄, and R₁ₐ to R_{1f} are each independently hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a plurality of R₁ₐ are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1b} are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1c} are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1d} are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R₁ₑ are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a plurality of R_{1f} are optionally bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
a1 to a4 and b1 to b6 are each independently an integer from 0 to 20,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁ to Q₃, Q₁₁ to Q₁₃, Q₂₁ to Q₂₃, and Q₃₁ to Q₃₃ are each independently:
hydrogen, deuterium, —F, —Cl, —Br, —I, a hydroxyl group, a cyano group, or a nitro group; or
a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or a combination thereof,
* indicates a binding site to M in Formula 1, and
*′ indicates a binding site to ring CY₂ in Formula 1.

8. The organometallic compound of claim 7, wherein in Formula 1, X₁ is a carbon atom of a carbene moiety.

9. The organometallic compound of claim 7, wherein in Formula 1, ring CY₁ is a nitrogen-containing C₁-C₆₀ heterocyclic group.

10. The organometallic compound of claim 7, wherein
ring CY₁₁ to ring CY₁₃ in Formula 1-1 are identical to each other, and
ring CY₁₄ to ring CY₁₆ in Formula 1-2 are identical to each other.

11. The organometallic compound of claim 7, wherein at least one of Conditions 1 to 3 is satisfied:
[Condition 1]
in Formula 1-1, a plurality of R₁ₐ are bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ;
[Condition 2]
in Formula 1-1, at least one R_{1b} is a tert-butyl group; and
[Condition 3]
in Formula 1-1, a plurality of R_{1c} are bonded to each other to form a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

12. The organometallic compound of claim 7, wherein in Formula 1-2, a ring formed to be surrounded by CY₁—CY₁₄—CY₁₅—CY₁₆ is a 9-membered ring.

13. The organometallic compound of claim 7, wherein in Formula 1, a moiety represented by 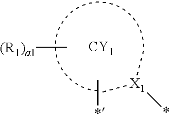
is a moiety represented by one of Formulae 1A to 1C: 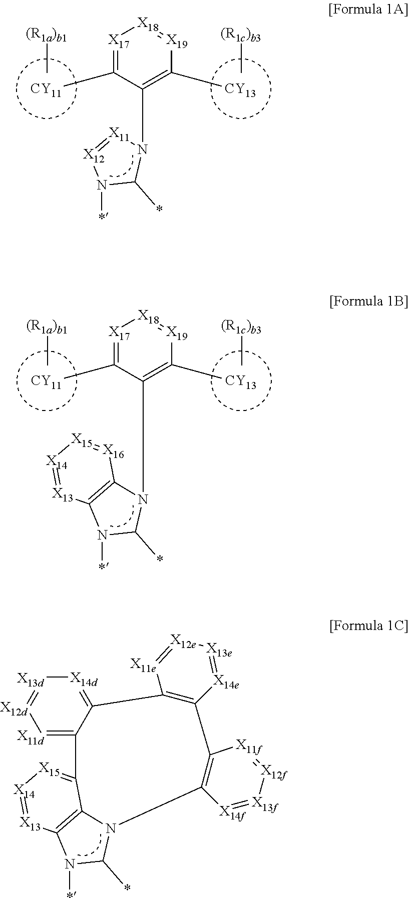
wherein in Formulae 1A, 1B, and 1C,
X₁₁ is N or C(R₁₁),
X₁₂ is N or C(R₁₂),
X₁₃ is N or C(R₁₃),
X₁₄ is N or C(R₁₄),
X₁₅ is N or C(R₁₅),
X₁₆ is N or C(R₁₆),
X₁₇ is N or C(R₁₇),
X₁₈ is N or C(R₁₈),
X₁₉ is N or C(R₁₉),
X_{11d} is N or C(R_{11d}),
X_{12d} is N or C(R_{12d}),
X_{13d} is N or C(R_{13d}),
X_{14d} is N or C(R_{14d}),
X₁₁ₑ is N or C(R₁₁ₑ),
X₁₂ₑ is N or C(R₁₂ₑ),
X₁₃ₑ is N or C(R₁₃ₑ),
X₁₄ₑ is N or C(R₁₄ₑ),
X_{11f} is N or C(R_{11f}),
X_{12f} is N or C(R_{12f}),
X_{13f} is N or C(R_{13f}),
X_{14f} is N or C(R_{14f}),
R₁₁ to R₁₆ are each independently the same as defined in connection with R₁ in Formula 1,
R₁₇ to R₁₉ are each independently the same as defined in connection with R_{1b} in Formula 1-1,
R_{11d} to R_{14d} are each independently the same as defined in connection with R_{1d} in Formula 1-2,
R₁₁ₑ to R₁₄ₑ are each independently the same as defined in connection with R₁ₑ in Formula 1-2,
R_{11f} to R_{14f} are each independently the same as defined in connection with R_{1f} in Formula 1-2, and
b1 and b3 are each independently an integer from 0 to 20.

14. The organometallic compound of claim 13, wherein in Formulae 1A and 1B, a moiety represented by 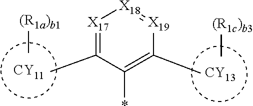
is a moiety represented by Formula AS: 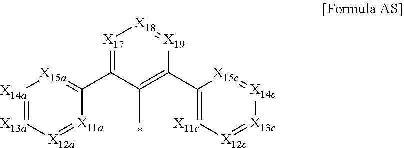
wherein in Formula AS,
X₁₇, X₁₈, and X₁₉ are each the same as defined in Formulae 1A and 1B,
X₁₁ₐ is N or C(R₁₁ₐ),
X₁₂ₐ is N or C(R₁₂ₐ),
X₁₃ₐ is N or C(R₁₃ₐ),
X₁₄ₐ is N or C(R₁₄ₐ),
X₁₅ₐ is N or C(R₁₅ₐ),
X_{11c} is N or C(R_{11c}),
X_{12c} is N or C(R_{12c}),
X_{13c} is N or C(R_{13c}),
X_{14c} is N or C(R_{14c}),
X_{15c} is N or C(R_{15c}),
R₁₁ₐ to R₁₅ₐ are each independently the same as defined in connection with R₁ₐ in Formula 1-1,
R_{11c} to R_{15c} are each independently the same as defined in connection with R_{1c} in Formula 1-1,
R₁₁ₐ and R₁₂ₐ, R₁₂ₐ and R₁₃ₐ, R₁₃ₐ and R₁₄ₐ, and R₁₄ₐ and R₁₅ₐ are each optionally bonded to each other to form a C₃-C₆₀ carbocyclic group that is unsubstituted or substituted with at least one R₁₀ₐ or a C₁-C₆₀ heterocyclic group that is unsubstituted or substituted with at least one R₁₀ₐ,
R_{11c} and R_{12c}, R_{12c} and R_{13c}, R_{13c} and R_{14c}, and R_{14c} and R_{15c} are each optionally bonded to each other to form a C₃-C₆₀ carbocyclic group that is unsubstituted or substituted with at least one R₁₀ₐ or a C₁-C₆₀ heterocyclic group that is unsubstituted or substituted with at least one R₁₀ₐ, and
* indicates a binding site to ring CY₁ in Formula 1.

15. The organometallic compound of claim 13, wherein in Formula 1C,
X₁₃ₑ is C(R₁₃ₑ), and R₁₃ₑ is a phenyl group that is substituted with at least one of deuterium and a tert-butyl group; or
X_{14f} is C(R_{14f}), and R_{14f} is a phenyl group that is substituted with at least one of deuterium and a tert-butyl group; or
X₁₃ₑ is C(R₁₃ₑ), X_{14f} is C(R_{14f}), and R₁₃ₑ and R_{14f} are each independently a phenyl group that is substituted with at least one of deuterium and a tert-butyl group.

16. The organometallic compound of claim 7, wherein in Formula 1, a moiety represented by 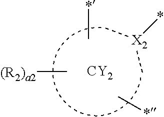
is a moiety represented by Formula 2-1: 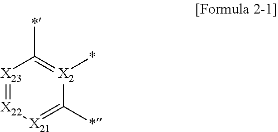
wherein in Formula 2-1,
X₂₁ is N or C(R₂₁),
X₂₂ is N or C(R₂₂),
X₂₃ is N or C(R₂₃),
X₂ is the same as defined in Formula 1,
R₂₁ to R₂₃ are each independently the same as defined in connection with R₂ in Formula 1,
at least one of R₂₁ and R₂₂ is each independently deuterium, a methyl group, an ethyl group, a propyl group, a methyl group that is substituted with at least one deuterium, an ethyl group that is substituted with at least one deuterium, or a propyl group that is substituted with at least one deuterium,
* indicates a binding site to M in Formula 1,
*′ indicates a binding site to ring CY₁ in Formula 1, and
*″ indicates a binding site to T₁ in Formula 1.

17. The organometallic compound of claim 7, wherein in Formula 1, ring CY₃ is:
a C₂-C₈ monocyclic group; or
a C₄-C₂₀ polycyclic group in which two or three C₂-C₈ monocyclic groups are condensed with each other.

18. The organometallic compound of claim 7, wherein in Formula 1, a moiety represented by 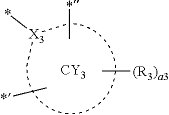
is a moiety represented by one of Formulae 3A to 3F: 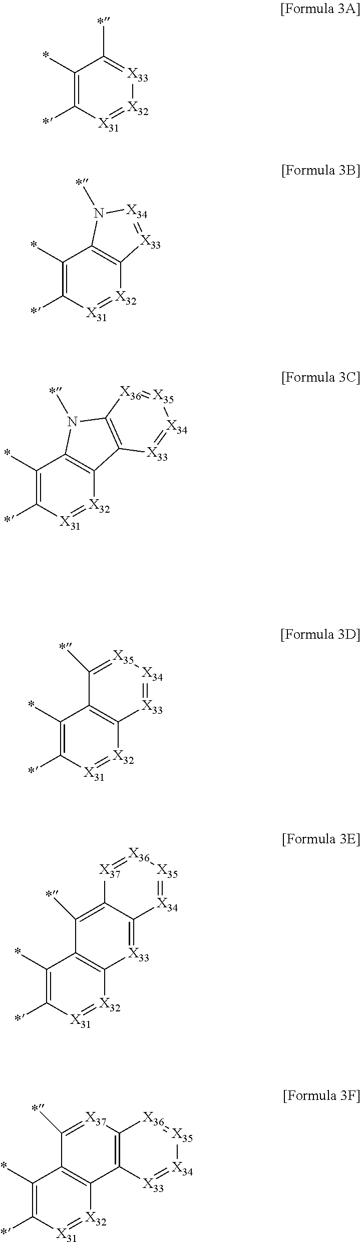
wherein in Formulae 3A to 3F,
X₃₁ is N or C(R₃₁),
X₃₂ is N or C(R₃₂),
X₃₃ is N or C(R₃₃),
X₃₄ is N or C(R₃₄),
X₃₅ is N or C(R₃₅),
X₃₆ is N or C(R₃₆),
X₃₇ is N or C(R₃₇),
R₃₁ to R₃₇ are each independently the same as defined in connection with R₃ in Formula 1,
* indicates a binding site to M in Formula 1,
*′ indicates a binding site to T₁ in Formula 1, and
*″ indicates a binding site to ring CY₄ in Formula 1.

19. The organometallic compound of claim 7, wherein in Formula 1, a moiety represented by 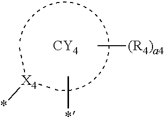
is a moiety represented by Formula 4-1: 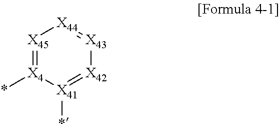
wherein in Formula 4-1,
X₄₁ is N or C,
X₄₂ is N or C(R₄₂),
X₄₃ is N or C(R₄₃),
X₄₄ is N or C(R₄₄),
X₄₅ is N or C(R₄₅),
X₄ is the same as defined in Formula 1,
R₄₂ to R₄₅ are each independently the same as defined in connection with R₄ in Formula 1,
* indicates a binding site to M in Formula 1, and
*′ indicates a binding site to ring CY₃ in Formula 1.

20. The organometallic compound of claim 7, wherein the organometallic compound is one of Compounds BD1 to BD27: 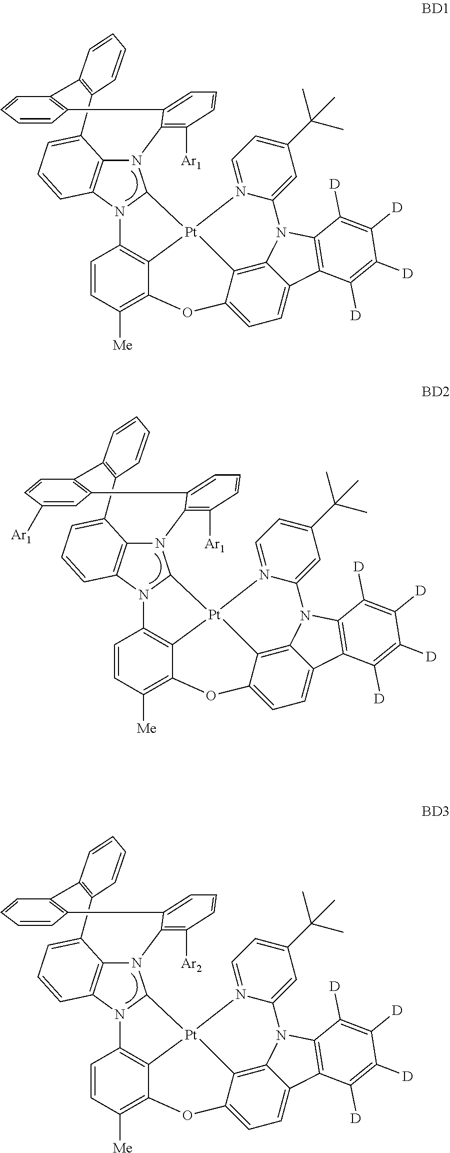 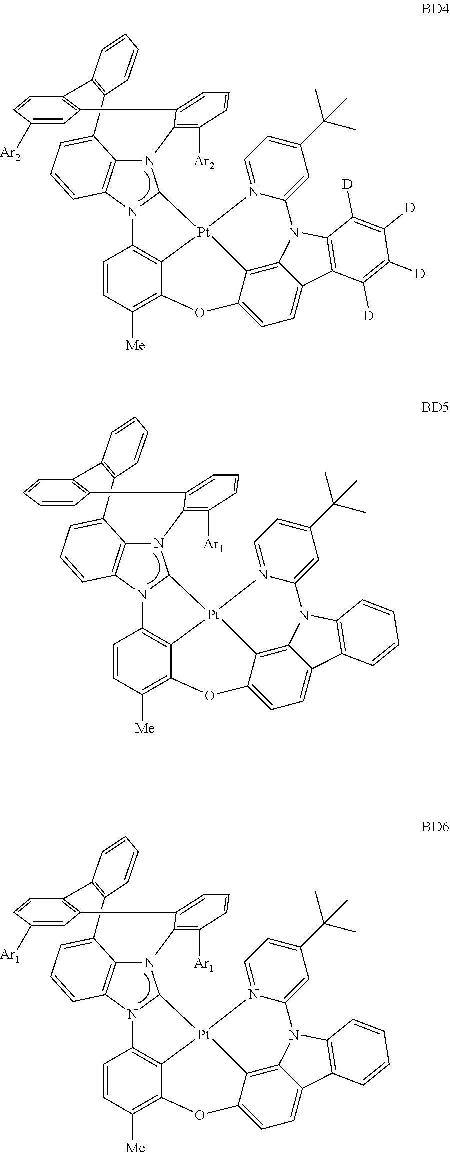 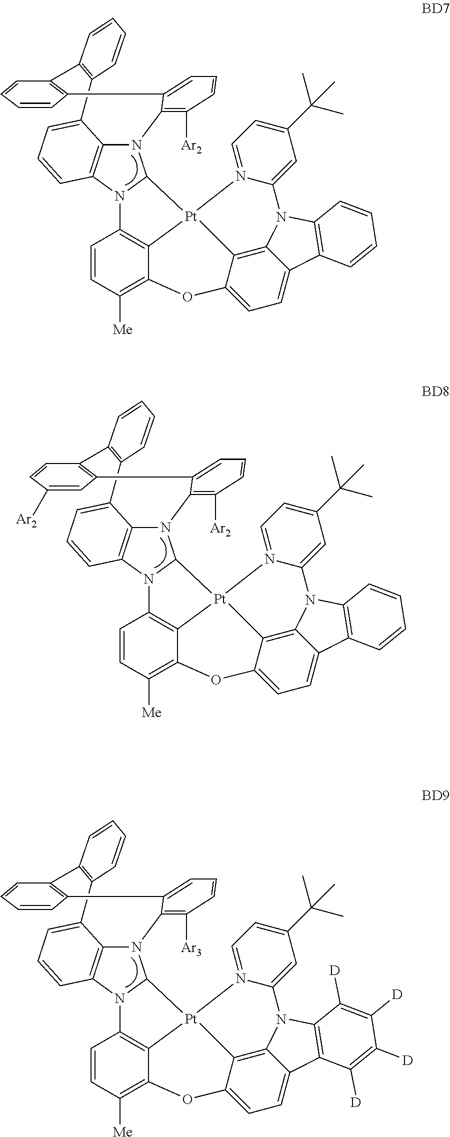 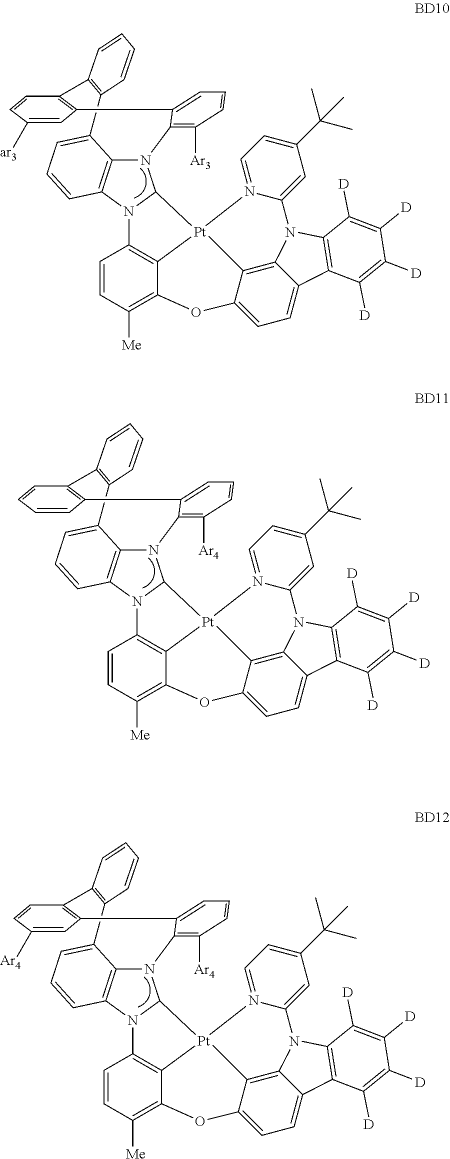 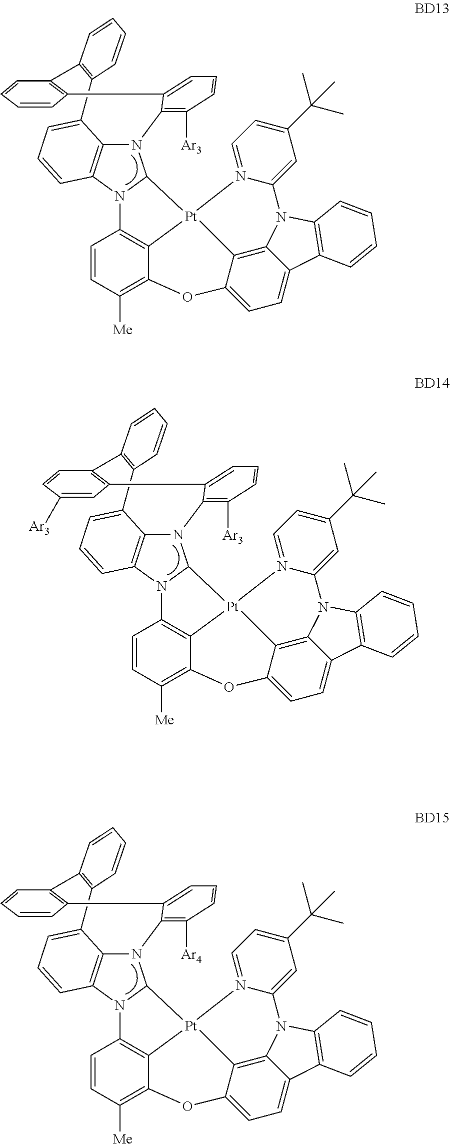 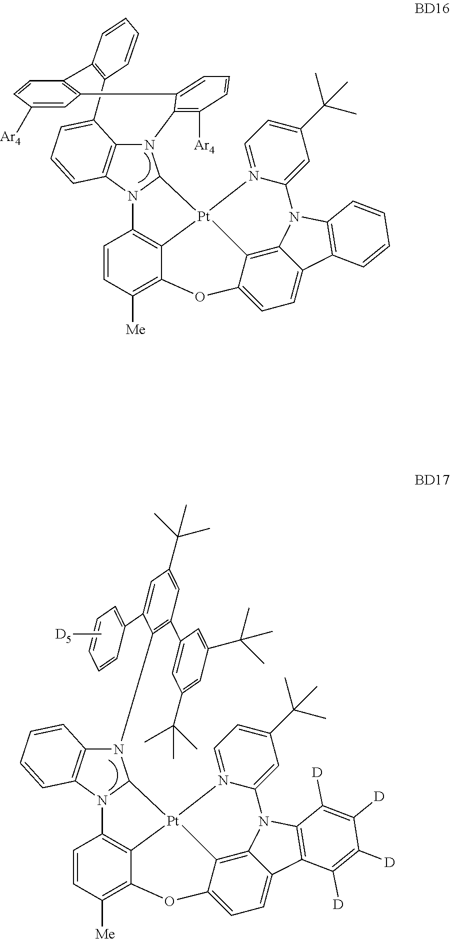 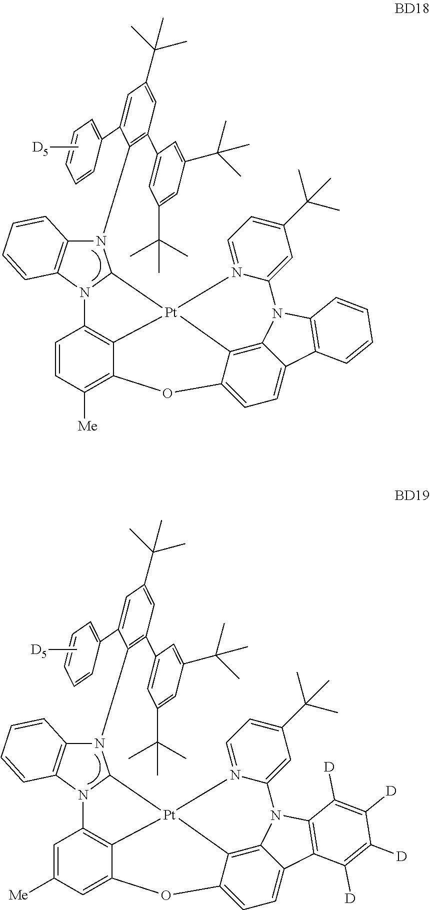 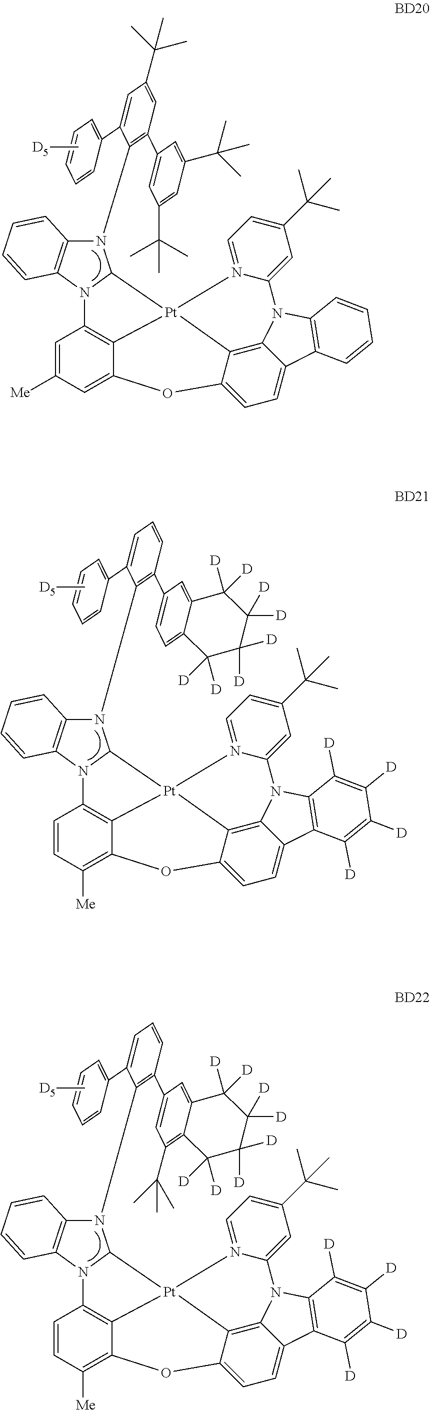 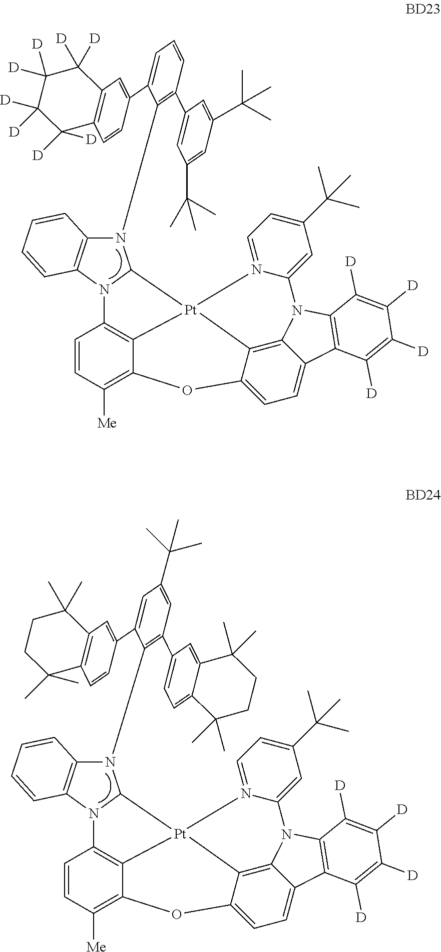 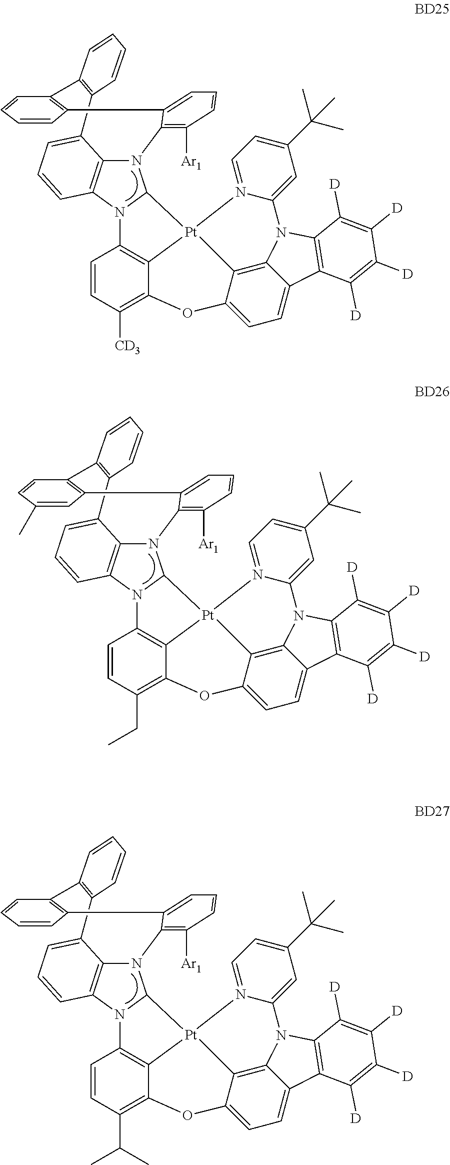
wherein in Compounds BD1 to BD16 and BD25 to BD27,
Ar₁ is a group represented by 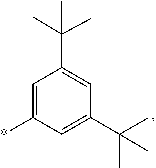 [SMILES: *c1cc(C(C)(C)C)cc(C(C)(C)C)c1]
Ar₂ is a group represented by 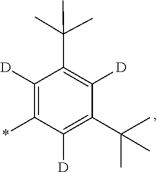 [SMILES: *c1c([2H])c(C(C)(C)C)c([2H])c(C(C)(C)C)c1[2H]]
Ar₃ is a group represented by 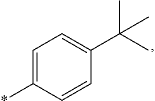 [SMILES: *c1ccc(C(C)(C)C)cc1]
Ar₄ is a group represented by 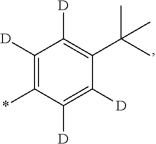 [SMILES: *c1c([2H])c([2H])c(C(C)(C)C)c([2H])c1[2H]]
and
* in Ar₁ to Ar₄ indicates a binding site to a neighboring atom.
